(19) United States
(12) Patent Application Publication
(10) Pub. No.: US 2015/0349802 A1
(43) Pub. Date: Dec. 3, 2015

(54) DATA PROCESSING DEVICE AND DATA PROCESSING METHOD

(71) Applicant: SONY CORPORATION, Tokyo (JP)

(72) Inventors: Yuji SHINOHARA, Kanagawa (JP); Makiko YAMAMOTO, Tokyo (JP)

(73) Assignee: SONY CORPORATION, Tokyo (JP)

(21) Appl. No.: 14/760,658

(22) PCT Filed: Jan. 27, 2014
(86) PCT No.: PCT/JP2014/051622

§ 371 Date: Jul. 13, 2015

(30) Foreign Application Priority Data
Feb. 8, 2013 (JP) 2013-023881

(51) Int. Cl. H03M 13/11; H03M 13/00

(52) U.S. Cl. CPC H03M 13/1148; H03M 13/616

(57) ABSTRACT

A data processing device including an encoding unit configured to encode an information bit into an LDPC code with a code length of 64800 bits and an encoding rate of 12/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns.

### TECHNICAL FIELD

The present disclosure relates to a data processing device and a data processing method, and, for example, especially relates to a data processing device and data processing method that can provide an LDPC code of an excellent error rate.

### BACKGROUND ART

An LDPC (Low Density Parity Check) code has the high error correction capability and has been recently adopted widely to a transmission system including satellite digital broadcasting such as DVB (Digital Video Broadcasting)-S.2 performed in Europe (for example, refer to Non-Patent Literature 1). In addition, adopting of the LDPC code to next-generation terrestrial digital broadcasting such as DVB-T.2 has been examined.

From a recent study, it is known that performance near a Shannon limit is obtained from the LDPC code when a code length increases, similar to a turbo code. Because the LDPC code has a property that a shortest distance is proportional to the code length, the LDPC code has advantages of a block error probability characteristic being superior and a so-called error floor phenomenon observed in a decoding characteristic of the turbo code being rarely generated, as characteristics thereof.

Hereinafter, the LDPC code will be specifically described. The LDPC code is a linear code and it is not necessary for the LDPC code to be a binary code. However, in this case, it is assumed that the LDPC code is the binary code.

A maximum characteristic of the LDPC code is that a parity check matrix defining the LDPC code is sparse. In this case, the sparse matrix is a matrix in which the number of “1” of elements of the matrix is very small (a matrix in which most elements are 0).

FIG. 1 illustrates an example of a parity check matrix H of the LDPC code.

In the parity check matrix H of FIG. 1, a weight of each column (the column weight) (the number of “1”) becomes “3” and a weight of each row (the row weight) becomes “6”.

In encoding using the LDPC code (LDPC encoding), for example, a generation matrix G is generated on the basis of the parity check matrix H and the generation matrix G is multiplied by binary information bits, so that a code word (LDPC code) is generated.

Specifically, an encoding device that performs the LDPC encoding first calculates the generation matrix G in which an expression GH^{T}=0 is realized, between a transposed matrix H^{T} of the parity check matrix H and the generation matrix G. In this case, when the generation matrix G is a K×N matrix, the encoding device multiplies the generation matrix G with a bit string (vector u) of information bits including K bits and generates a code word c (=uG) including N bits. The code word (LDPC code) that is generated by the encoding device is received at a reception side through a predetermined communication path.

The LDPC code can be decoded by an algorithm called probabilistic decoding suggested by Gallager, that is, a message passing algorithm using belief propagation on a so-called Tanner graph, including a variable node (also referred to as a message node) and a check node. Hereinafter, the variable node and the check node are appropriately referred to as nodes simply.

FIG. 2 illustrates a sequence of decoding of the LDPC code.

Hereinafter, a real value (a reception LLR) that is obtained by representing the likelihood of “0” of a value of an i-th code bit of the LDPC code (one code word) received by the reception side by a log likelihood ratio is appropriately referred to as a reception value u₀ᵢ. In addition, a message output from the check node is referred to as uⱼ and a message output from the variable node is referred to as vᵢ.

First, in decoding of the LDPC code, as illustrated in FIG. 2, in step S11, the LDPC code is received, the message (check node message) uⱼ is initialized to “0”, and a variable k taking an integer as a counter of repetition processing is initialized to “0”, and the processing proceeds to step S12. In step S12, the message (variable node message) vᵢ is calculated by performing an operation (variable node operation) represented by an expression (1), on the basis of the reception value u₀ᵢ obtained by receiving the LDPC code, and the message uⱼ is calculated by performing an operation (check node operation) represented by an expression (2), on the basis of the message vᵢ.

$$\begin{matrix}[ Math . 1 ] & \\ {v}_{i} = {u}_{0 i} + {\sum }_{j = 1}^{{d}_{v} - 1} {u}_{j} & ( 1 ) \\ [ Math . 2 ] & \\ tanh ( \frac{{u}_{j}}{2} ) = {\prod }_{i = 1}^{{d}_{c} - 1} tanh ( \frac{{v}_{i}}{2} ) & ( 2 )\end{matrix}$$

Here, dᵥ and d_{c} in an expression (1) and expression (2) are respectively parameters which can be arbitrarily selected and illustrates the number of “1” in the longitudinal direction (column) and transverse direction (row) of the parity check matrix H. For example, in the case of an LDPC code ((3, 6) LDPC code) with respect to the parity check matrix H with a column weight of 3 and a row weight of 6 as illustrated in FIGS. 1, dᵥ=3 and d_{c}=6 are established.

In the variable node operation of the expression (1) and the check node operation of the expression (2), because a message input from an edge (line coupling the variable node and the check node) for outputting the message is not an operation target, an operation range becomes 1 to dᵥ−1 or 1 to d_{c}−1. The check node operation of the expression (2) is performed actually by previously making a table of a function R (v₁, v₂) represented by an expression (3) defined by one output with respect to two inputs v₁ and v₂ and using the table consecutively (recursively), as represented by an expression (4).

[Math. 3]

x=2 tan h⁻¹{tan h(v₁/2)tan h(v₂/2}=R(v₁,v₂) (3)

[Math. 4]

uⱼ=R(v₁,R(v₂,R(v₃, . . . R(v_{d}_{_{c}}₋₂,v_{d}_{_{c}}₋₁)))) (4)

In step S12, the variable k is incremented by “1” and the processing proceeds to step S13. In step S13, it is determined whether the variable k is more than the predetermined repetition decoding number of times C. When it is determined in step S13 that the variable k is not more than C, the processing returns to step S12 and the same processing is repeated hereinafter.

When it is determined in step S13 that the variable k is more than C, the processing proceeds to step S14, the message vᵢ that corresponds to a decoding result to be finally output is calculated by performing an operation represented by an expression (5) and is output, and the decoding processing of the LDPC code ends.

$$\begin{matrix}[ Math . 5 ] & \\ {v}_{i} = {u}_{0 i} + {\sum }_{j = 1}^{{d}_{v}} {u}_{j} & ( 5 )\end{matrix}$$

In this case, the operation of the expression (5) is performed using messages uⱼ from all edges connected to the variable node, different from the variable node operation of the expression (1).

FIG. 3 illustrates an example of the parity check matrix H of the (3, 6) LDPC code (an encoding rate of 1/2 and a code length of 12).

In the parity check matrix H of FIG. 3, a weight of a column is set to 3 and a weight of a row is set to 6, similar to FIG. 1.

FIG. 4 illustrates a Tanner graph of the parity check matrix H of FIG. 3.

In FIG. 4, the check node is represented by “+” (plus) and the variable node is represented by “=” (equal). The check node and the variable node correspond to the row and the column of the parity check matrix H. A line that couples the check node and the variable node is the edge and corresponds to “1” of elements of the parity check matrix.

That is, when an element of a j-th row and an i-th column of the parity check matrix is 1, in FIG. 4, an i-th variable node (node of “=”) from the upper side and a j-th check node (node of “+”) from the upper side are connected by the edge. The edge shows that a code bit corresponding to the variable node has a restriction condition corresponding to the check node.

In a sum product algorithm that is a decoding method of the LDPC code, the variable node operation and the check node operation are repetitively performed.

FIG. 5 illustrates the variable node operation that is performed by the variable node.

In the variable node, the message vᵢ that corresponds to the edge for calculation is calculated by the variable node operation of the expression (1) using messages u₁ and u₂ from the remaining edges connected to the variable node and the reception value u₀ᵢ. The messages that correspond to the other edges are also calculated by the same method.

FIG. 6 illustrates the check node operation that is performed by the check node.

In this case, the check node operation of the expression (2) can be rewritten by an expression (6) using a relation of an expression a×b=exp{ln(|a|)+ln(|b|)}×sign(a)×sign(b). However, sign(x) is 1 in the case of x≧0 and is −1 in the case of x<0.

$$\begin{matrix}[ Math . 6 ] & \\ \begin{matrix}{u}_{j} = 2 {tanh}^{- 1} ( {\prod }_{i = 1}^{{d}_{c} - 1} tanh ( \frac{{v}_{i}}{2} ) ) \\ = 2 {tanh}^{- 1} [ exp \{ {\sum }_{i = 1}^{{d}_{c} - 1} ln ( \vert tanh ( \frac{{v}_{i}}{2} ) \vert ) \} \times {\prod }_{i = 1}^{{d}_{c} - 1} sign ( tanh ( \frac{{v}_{i}}{2} ) ) ] \\ = 2 {tanh}^{- 1} [ exp \{ - ( {\sum }_{i = 1}^{{d}_{c} - 1} - ln ( tanh ( \frac{\vert {v}_{i} \vert}{2} ) ) ) \} ] \times {\prod }_{i = 1}^{{d}_{c} - 1} sign ( {v}_{i} )\end{matrix} & ( 6 )\end{matrix}$$

In x≧0, if a function φ(x) is defined as an expression φ(x)=ln(tan h(x/2)), an expression φ⁻¹(x)=2 tan h⁻¹(e^{-X}) is realized. For this reason, the expression (6) can be changed to an expression (7).

$$\begin{matrix}[ Math . 7 ] & \\ {u}_{j} = {φ}^{- 1} ( {\sum }_{i = 1}^{{d}_{c} - 1} φ ( \vert {v}_{i} \vert ) ) \times {\prod }_{i = 1}^{{d}_{c} - 1} sign ( {v}_{i} ) & ( 7 )\end{matrix}$$

In the check node, the check node operation of the expression (2) is performed according to the expression (7).

That is, in the check node, as illustrated in FIG. 6, the message uⱼ that corresponds to the edge for calculation is calculated by the check node operation of the expression (7) using messages v₁, v₂, v₃, v₄, and v₅ from the remaining edges connected to the check node. The messages that correspond to the other edges are also calculated by the same method.

The function φ(x) of the expression (7) can be represented as φ(x)=ln((e^{x}+1)/(e^{x}−1)) and φ(x)=φ⁻¹(x) is satisfied in x>0. When the functions φ(x) and φ⁻¹(x) are mounted to hardware, the functions φ(x) and φ⁻¹(x) may be mounted using an LUT (Look Up Table). However, both the functions φ(x) and φ⁻¹(x) become the same LUT.

### CITATION LIST

### Patent Literature

Non-Patent Literature 1: DVB-S.2: ETSI EN 302 307 V1.2.1 (2009-08)

### SUMMARY OF INVENTION

### Technical Problem

A DVB standard such as the DVB-S.2, DVB-T.2, and DVB-C.2 which adopt the LDPC code makes the LDPC code as a symbol (symbolized) of orthogonal modulation (digital modulation) such as QPSK (Quadrature Phase Shift Keying) and the symbol is mapped to a signal point and is transmitted.

By the way, in recent years, for example, large capacity data such as a so-called 4 k image with resolution of width and length of 3840×2160 pixels about four times full hi-vision and a 3D (Dimension) image is requested to be efficiently transmitted.

However, if the efficiency of data transmission is prioritized, the error rate is deteriorated.

On the other hand, there is a case where it is requested to transmit data in an excellent error rate even if the efficiency of data transmission is somewhat sacrificed.

It is assumed that data transmission in various kinds of efficiency is requested in the future, but, according to an LDPC code, for example, by preparing a plurality of LDPC codes of different encoding rates, it is possible to perform data transmission in various kinds of efficiency.

Therefore, for data transmission, it is desirable to adopt LDPC codes of encoding rates, for which a somewhat large number (for example, the number equal to or greater than the number requested for data transmission) of encoding rates are easily set.

Further, even in a case where an LDPC code of any encoding rate is used, it is desirable that resistance against an error is high (strong), that is, an error rate is excellent.

The present disclosure is made considering such a situation, and can provide an LDPC code of an excellent error rate.

### Solution to Problem

A first processing device or data processing method according to the present technology includes an encoding unit or encoding step of encoding an information bit into an LDPC code with a code length of 64800 bits and an encoding rate of 12/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
2455 2650 6184 7016 7280 7409 7507 8261 8591 8829 11277 13729 14302 15883 17754 18506 19816 19940 22442 23981 26881 26981 28760 29688 31138 31497 32673 35889 37690 38665
50 327 3574 4465 5954 9702 10606 11684 11715 12627 14132 14951 20099 24111 24283 27026 27473 28162 30076 31032 31476 35031 36675 36914 37008 37425 37530 37689 38830 38856
59 102 5278 5548 5850 11840 13813 16641 19597 20543 24088 24298 25171 25224 26925 28312 28867 31551 31898 32849 33616 34486 34562 35252 35931 36107 37950 38494 38537 38547
79 2084 2361 2922 3048 3525 5712 9376 10012 10463 11842 15200 18443 19223 20476 21361 22584 24343 24594 28001 28304 28475 28969 31149 31528 32574 33007 35120 38245 38253
821 2803 8187 8501 10063 10497 14472 14570 15613 18469 19620 23034 24029 24578 26538 31025 32621 34134 34508 34988 35201 35907 36693 36793 37608 37998 38090 38506 38611 38682
9 50 88 1222 2430 2824 7233 9972 10225 15762 18283 18961 20711 28455 29946 32016 35611 35763 37263 37325 38287 38360 38416 38471 38518 38551 38643 38759 38763 38818
33 38 151 2523 3787 5069 6710 7667 8501 11083 17631 19589 24263 24684 24940 28493 30646 31916 33741 35060 35810 36284 36394 36400 38209 38312 38340 38782 38825 38858
8 49 84 381 4009 6978 9983 14028 14051 16325 17393 24325 25130 25838 30998 35159 36135 37516 37636 37837 37927 38433 38620 38647 38650 38699 38733 38784 38804 38862
44 76 4362 4480 8679 8833 13730 16493 16507 22419 24544 25614 25671 33032 33120 35219 35986 36415 36505 38169 38173 38327 38371 38468 38508 38546 38551 38747 38761 38853
16 683 1013 8364 8665 12213 12279 12643 13134 15450 16703 17846 20656 21664 22896 23487 25022 32049 32482 33647 35029 35197 36636 37162 38376 38408 38430 38520 38721 38734
3 760 1052 6377 8526 9014 11769 12589 16661 18156 20521 21303 23361 27434 32315 34602 34892 35078 35262 35639 36655 37893 38063 38578 38602 38719 38737 38748 38837 38861
15 30 79 99 16844 19586 24117 24702 25088 26129 27790 28383 30976 33472 34613 35266 35337 36278 36841 36980 37214 37651 37817 38085 38218 38338 38396 38432 38760 38812
12483 24049 35782 38706
12146 19270 23193 38389
26418 34831 37883 38501
25045 36512 37567 38487
15238 33547 38210 38696
14 6773 17384 38679
14367 16694 16867 38453
15371 37498 37910 38610
2509 18705 27907 28422
21246 37360 38125 38868
11357 23312 24884 36318
14467 19559 22338 37893
26899 35264 36300 37973
17311 28273 32934 38607
0 14452 16264 38585
6736 19801 31034 38279
35256 36593 38204 38655
10037 29019 32956 38670
98 17138 28233 37750
576 4888 14014 23030
2003 2470 18968 38841
1042 4623 8098 9963
61 3037 9719 27052
15129 26628 31307 37604
9791 11904 12369 34528
7996 15467 21456 38165
7644 12741 34083 38851
4766 26027 31133 38830
17783 36021 37697 38571
4925 9033 28100 32671
9452 23191 32529 36265
6124 19224 27145 30628
24 26468 35718 38718
14403 14741 20334 38444
322 15324 22539 33347
22663 29889 38488
7 13998 38748
8835 20728 20777
9742 24551 26087
23173 24287 38644
16606 30002 32432
30691 37266 38776
20366 21134 35082
21617 28615 29424
15974 26095 34262
92 35091 36358
9348 28177 38737
16104 37933 38151
14133 30118 38803
1314 37661 38852
19118 28886 37980
20212 22241 32326
3885 17856 38675
12577 21905 30465
28672 35317 35384
12880 16994 34495
16353 34789 38134
465 37194 38658
23 6202 38823
24020 25383 37955.

A second data processing device or data processing method according to the present technology includes a decoding unit or decoding step of decoding an LDPC code with a code length of 64800 bits and an encoding rate of 12/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
2455 2650 6184 7016 7280 7409 7507 8261 8591 8829 11277 13729 14302 15883 17754 18506 19816 19940 22442 23981 26881 26981 28760 29688 31138 31497 32673 35889 37690 38665
50 327 3574 4465 5954 9702 10606 11684 11715 12627 14132 14951 20099 24111 24283 27026 27473 28162 30076 31032 31476 35031 36675 36914 37008 37425 37530 37689 38830 38856
59 102 5278 5548 5850 11840 13813 16641 19597 20543 24088 24298 25171 25224 26925 28312 28867 31551 31898 32849 33616 34486 34562 35252 35931 36107 37950 38494 38537 38547
79 2084 2361 2922 3048 3525 5712 9376 10012 10463 11842 15200 18443 19223 20476 21361 22584 24343 24594 28001 28304 28475 28969 31149 31528 32574 33007 35120 38245 38253
821 2803 8187 8501 10063 10497 14472 14570 15613 18469 19620 23034 24029 24578 26538 31025 32621 34134 34508 34988 35201 35907 36693 36793 37608 37998 38090 38506 38611 38682
9 50 88 1222 2430 2824 7233 9972 10225 15762 18283 18961 20711 28455 29946 32016 35611 35763 37263 37325 38287 38360 38416 38471 38518 38551 38643 38759 38763 38818
33 38 151 2523 3787 5069 6710 7667 8501 11083 17631 19589 24263 24684 24940 28493 30646 31916 33741 35060 35810 36284 36394 36400 38209 38312 38340 38782 38825 38858
8 49 84 381 4009 6978 9983 14028 14051 16325 17393 24325 25130 25838 30998 35159 36135 37516 37636 37837 37927 38433 38620 38647 38650 38699 38733 38784 38804 38862
44 76 4362 4480 8679 8833 13730 16493 16507 22419 24544 25614 25671 33032 33120 35219 35986 36415 36505 38169 38173 38327 38371 38468 38508 38546 38551 38747 38761 38853
16 683 1013 8364 8665 12213 12279 12643 13134 15450 16703 17846 20656 21664 22896 23487 25022 32049 32482 33647 35029 35197 36636 37162 38376 38408 38430 38520 38721 38734
3 760 1052 6377 8526 9014 11769 12589 16661 18156 20521 21303 23361 27434 32315 34602 34892 35078 35262 35639 36655 37893 38063 38578 38602 38719 38737 38748 38837 38861
15 30 79 99 16844 19586 24117 24702 25088 26129 27790 28383 30976 33472 34613 35266 35337 36278 36841 36980 37214 37651 37817 38085 38218 38338 38396 38432 38760 38812
12483 24049 35782 38706
12146 19270 23193 38389
26418 34831 37883 38501
25045 36512 37567 38487
15238 33547 38210 38696
14 6773 17384 38679
14367 16694 16867 38453
15371 37498 37910 38610
2509 18705 27907 28422
21246 37360 38125 38868
11357 23312 24884 36318
14467 19559 22338 37893
26899 35264 36300 37973
17311 28273 32934 38607
0 14452 16264 38585
6736 19801 31034 38279
35256 36593 38204 38655
10037 29019 32956 38670
98 17138 28233 37750
576 4888 14014 23030
2003 2470 18968 38841
1042 4623 8098 9963
61 3037 9719 27052
15129 26628 31307 37604
9791 11904 12369 34528
7996 15467 21456 38165
7644 12741 34083 38851
4766 26027 31133 38830
17783 36021 37697 38571
4925 9033 28100 32671
9452 23191 32529 36265
6124 19224 27145 30628
24 26468 35718 38718
14403 14741 20334 38444
322 15324 22539 33347
22663 29889 38488
7 13998 38748
8835 20728 20777
9742 24551 26087
23173 24287 38644
16606 30002 32432
30691 37266 38776
20366 21134 35082
21617 28615 29424
15974 26095 34262
92 35091 36358
9348 28177 38737
16104 37933 38151
14133 30118 38803
1314 37661 38852
19118 28886 37980
20212 22241 32326
3885 17856 38675
12577 21905 30465
28672 35317 35384
12880 16994 34495
16353 34789 38134
465 37194 38658
23 6202 38823
24020 25383 37955.

A third data processing device or data processing method according to the present technology includes an encoding unit or encoding step of encoding an information bit into an LDPC code with a code length of 64800 bits and an encoding rate of 13/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
1153 2676 2759 5782 7192 10887 11573 11888 12383 18472 20695 21466 21753 23630 24580 25006 25182 25636 25887 29615 29677 31968 32188 32277 33135
935 5609 7730 9427 9519 10465 11182 12164 15765 17266 18156 20309 20542 21193 21697 22913 22989 23780 27048 30762 31731 35754 36161 36379 36710
644 2718 6995 7088 7898 11242 13921 14068 14328 15840 19581 19919 21938 22749 23311 23767 25945 26731 27405 27830 31023 32589 33239 33957 34456
17 131 2331 6624 10568 12965 16184 17665 19575 20690 22609 23378 24385 28281 30808 33083 34435 34509 36016 36355 36525 36580 36586 36636 36644
5 42 59 80 100 3327 4882 5238 6588 15417 17416 17476 18307 19336 20336 22770 33204 33302 34207 35133 35594 35650 36090 36619 36659
46 141 308 995 2267 2645 5224 5839 7945 8336 10865 14607 21285 22062 23225 23772 24190 25324 26738 29253 29674 33264 35593 36564 36608
55 2316 8545 13623 14353 14516 15773 18442 20172 21970 22319 26595 27849 29185 30141 31195 33614 34586 35699 35994 36309 36445 36516 36662 36665
17 59 82 955 5050 7239 17495 19753 23481 25131 30124 32434 33042 34583 35231 35786 36232 36336 36518 36530 36541 36584 36592 36629 36648
1 16 78 717 5622 7351 7729 9200 10674 12647 22946 24316 25268 28139 31794 32278 33243 34217 34485 34505 34929 35450 35865 36340 36565
15 36 73 2381 4118 6829 9453 11705 12402 14884 17442 19226 21328 25523 26538 29300 34635 35066 35547 35617 36285 36343 36599 36607 36708
27 58 3657 8026 9245 11874 14579 15588 16280 16426 22692 25061 27788 29797 31776 34992 35324 35529 36295 36298 36469 36608 36626 36661 36679
13 36 78 3785 5888 10015 13647 14824 18283 20262 26268 26890 27517 33128 33659 34191 35729 35965 36196 36381 36385 36501 36593 36659 36667
0 6 63 1713 8050 11113 18981 20118 22082 23210 24401 27239 31104 32963 33846 34334 35232 35626 36159 36424 36441 36457 36523 36609 36640
39 60 64 92 438 4764 6022 9256 14471 20458 23327 26872 30944 34061 34882 35249 35586 35642 35680 36092 36126 36548 36626 36633 36649
40 67 6336 8195 9735 19400 20396 21095 22015 28597 31367 33511 33932 34732 34847 35247 35543 36020 36258 36619 36651 36688 36693 36709 36717
13990 15734 24992 35907
448 14650 29725 36141
27195 27825 34118 35317
2514 7964 31027 31885
12966 22180 24997 33406
13568 17438 18377 36038
76 15846 25385 35720
1 758 23751 36083
2238 8449 29406 31840
80 14882 15923 33878
86 18320 24636 36111
5392 24119 31102 34507
6485 8182 14790 21264
13702 29065 35939 36554
9160 11429 36663 36691
9153 12051 20063 25493
37 3918 13758 18923
18643 24675 31646 33893
3941 9238 30160 36584
26037 31006 35886
115 8925 13728
8079 12229 21571
18315 34532 35200
14760 36073 36540
27155 28360 36381
24111 32816 36411
17214 32333 35208
10181 13269 24419
55 13696 29382
35958 36528 36673
21481 27758 31170
2161 27055 36569
14381 22920 36680
9113 19651 32334
2500 20917 29374
1966 30518 30855
14419 25676 36077
31502 33331 34982
23192 27819 36698
23130 34074 35969
39 82 9069
1665 23618 28887
13344 16378 16410
3753 6863 27107
5309 26232 29584
83 10780 35045
23884 31975 36715
8591 27909 35282
16924 29871 36684
11923 21783 30567
20309 26955 36030
33545 36648 36706
6851 9052 35671
2188 11594 34478
32 5093 24903
7863 21519 23494
2227 25547 36218
27745 35240 36580
8094 13505 31136
14191 28503 33160
14107 25438 30594
30235 33886 35034
14118 35846 36621.

A fourth data processing device or data processing method according to the present technology includes a decoding unit or decoding step of decoding an LDPC code with a code length of 64800 bits and an encoding rate of 13/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
1153 2676 2759 5782 7192 10887 11573 11888 12383 18472 20695 21466 21753 23630 24580 25006 25182 25636 25887 29615 29677 31968 32188 32277 33135
935 5609 7730 9427 9519 10465 11182 12164 15765 17266 18156 20309 20542 21193 21697 22913 22989 23780 27048 30762 31731 35754 36161 36379 36710
644 2718 6995 7088 7898 11242 13921 14068 14328 15840 19581 19919 21938 22749 23311 23767 25945 26731 27405 27830 31023 32589 33239 33957 34456
17 131 2331 6624 10568 12965 16184 17665 19575 20690 22609 23378 24385 28281 30808 33083 34435 34509 36016 36355 36525 36580 36586 36636 36644
5 42 59 80 100 3327 4882 5238 6588 15417 17416 17476 18307 19336 20336 22770 33204 33302 34207 35133 35594 35650 36090 36619 36659
46 141 308 995 2267 2645 5224 5839 7945 8336 10865 14607 21285 22062 23225 23772 24190 25324 26738 29253 29674 33264 35593 36564 36608
55 2316 8545 13623 14353 14516 15773 18442 20172 21970 22319 26595 27849 29185 30141 31195 33614 34586 35699 35994 36309 36445 36516 36662 36665
17 59 82 955 5050 7239 17495 19753 23481 25131 30124 32434 33042 34583 35231 35786 36232 36336 36518 36530 36541 36584 36592 36629 36648
1 16 78 717 5622 7351 7729 9200 10674 12647 22946 24316 25268 28139 31794 32278 33243 34217 34485 34505 34929 35450 35865 36340 36565
15 36 73 2381 4118 6829 9453 11705 12402 14884 17442 19226 21328 25523 26538 29300 34635 35066 35547 35617 36285 36343 36599 36607 36708
27 58 3657 8026 9245 11874 14579 15588 16280 16426 22692 25061 27788 29797 31776 34992 35324 35529 36295 36298 36469 36608 36626 36661 36679
13 36 78 3785 5888 10015 13647 14824 18283 20262 26268 26890 27517 33128 33659 34191 35729 35965 36196 36381 36385 36501 36593 36659 36667
0 6 63 1713 8050 11113 18981 20118 22082 23210 24401 27239 31104 32963 33846 34334 35232 35626 36159 36424 36441 36457 36523 36609 36640
39 60 64 92 438 4764 6022 9256 14471 20458 23327 26872 30944 34061 34882 35249 35586 35642 35680 36092 36126 36548 36626 36633 36649
40 67 6336 8195 9735 19400 20396 21095 22015 28597 31367 33511 33932 34732 34847 35247 35543 36020 36258 36619 36651 36688 36693 36709 36717
13990 15734 24992 35907
448 14650 29725 36141
27195 27825 34118 35317
2514 7964 31027 31885
12966 22180 24997 33406
13568 17438 18377 36038
76 15846 25385 35720
1 758 23751 36083
2238 8449 29406 31840
80 14882 15923 33878
86 18320 24636 36111
5392 24119 31102 34507
6485 8182 14790 21264
13702 29065 35939 36554
9160 11429 36663 36691
9153 12051 20063 25493
37 3918 13758 18923
18643 24675 31646 33893
3941 9238 30160 36584
26037 31006 35886
115 8925 13728
8079 12229 21571
18315 34532 35200
14760 36073 36540
27155 28360 36381
24111 32816 36411
17214 32333 35208
10181 13269 24419
55 13696 29382
35958 36528 36673
21481 27758 31170
2161 27055 36569
14381 22920 36680
9113 19651 32334
2500 20917 29374
1966 30518 30855
14419 25676 36077
31502 33331 34982
23192 27819 36698
23130 34074 35969
39 82 9069
1665 23618 28887
13344 16378 16410
3753 6863 27107
5309 26232 29584
83 10780 35045
23884 31975 36715
8591 27909 35282
16924 29871 36684
11923 21783 30567
20309 26955 36030
33545 36648 36706
6851 9052 35671
2188 11594 34478
32 5093 24903
7863 21519 23494
2227 25547 36218
27745 35240 36580
8094 13505 31136
14191 28503 33160
14107 25438 30594
30235 33886 35034
14118 35846 36621.

A fifth data processing device or data processing method according to the present technology includes an encoding unit or encoding step of encoding an information bit into an LDPC code with a code length of 64800 bits and an encoding rate of 14/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
2422 2919 3173 3795 4428 12681 13428 14654 17367 17687 19587 20017 23588 24353 25280 27167 29853 32040 32473 33170 33375
34 79 817 12478 12769 14798 15383 16688 16739 17538 21654 22792 25145 25588 26995 27388 31655 32133 32601 33452 34471
88 986 1907 2868 3657 6826 8595 11922 14704 17681 19503 20604 24251 28125 28612 29976 30687 31208 31464 33686 33909
526 3853 4486 6507 10616 11300 11453 13385 20007 21420 21441 22554 23794 24581 24959 27083 28710 30235 32852 34179 34327
43 1775 4405 5644 6553 8885 10337 11178 14114 15108 16189 16192 18490 18801 21475 22748 28269 28970 30758 31968 33554
27 624 1191 1470 4277 5054 5695 9632 10911 11365 13339 21097 23810 26677 27822 28433 29878 31026 32525 33335 33873
14 45 760 1098 1567 2003 6710 10195 12052 13024 13337 19088 22647 25050 25899 27035 28844 29927 33916 34033 34490
30 94 4493 11928 14051 17759 18541 20842 21277 24587 24948 25790 27442 31120 31205 31526 32107 32263 33696 34393 34529
3 4245 5284 7791 10196 10922 13992 14397 14947 16908 21032 24585 27219 30300 30981 32732 33362 33558 33725 34424 34537
78 6958 8297 15781 23302 23386 23863 25570 25734 31844 31919 32100 32815 33345 33531 33561 33889 34348 34504 34512 34530
52 90 775 3760 4099 6945 8954 11931 16578 20804 23252 26583 29420 32461 33695 33874 33964 34018 34177 34483 34506
81 1162 3084 3986 4494 8523 10309 10934 12819 16784 23113 23803 25952 29134 29930 30530 32021 33343 33400 33664 33685
0 35 57 1564 9062 19694 24489 24737 26422 27021 30630 31513 33317 33425 33545 33624 33743 33869 33875 34046 34519
58 639 2340 3613 19319 21917 24284 29214 29430 29736 32496 32785 32830 32835 33176 33323 33711 33967 34197 34438 34468
71 77 88 953 4233 7365 8395 15176 16662 18280 21989 24348 26847 27645 31050 31890 34119 34223 34235 34548 34551
163 4304 4697 7470 11857 12787 12837 18000 18472 18489 19730 27014 29653 29740 30070 30252 32769 33637 34382 34394 34555
7 29 79 7321 9770 11315 15354 16240 18888 19559 27783 28220 28924 30659 31474 33084 33310 33644 34282 34452 34557
8 24 41 4491 11252 14225 18230 25845 30258 30801 31349 32655 32932 32951 33058 33794 33889 34150 34338 34463 34494
13 13092 15747 23904 29675 29732 30199 31273 31928 32211 32704 32959 33056 33374 33646 33931 34043 34203 34426 34429 34509
6 11188 19937
11738 14763 34508
11 4674 25431
6346 9658 31716
13231 32283 33193
19187 31166 33846
297 27886 32712
74 8683 24435
2200 20501 21571
25 10097 29631
4515 32145 33245
13010 26434 29967
0 30598 33940
1342 27835 33782
2253 7519 33030
9079 13091 29109
20124 20880 27383
14317 16550 26394
84 2860 33197
21726 28620 31525
12888 23822 32157
1221 10300 34113
15613 22759 28517
4889 28647 31367
22184 25784 30338
21714 26800 28577
1408 15983 16148
6569 18901 23827
42 7606 25499
11193 13616 31040
8996 28561 30145
6335 23176 26286
6236 23314 24004
25452 30736 31684
3826 12150 21414
10711 17869 29177
13382 34510 34532
14491 16483 31945
77 16047 34221
17991 32178 32575
5508 6547 13800
4265 19226 25358
10154 23746 29274
3421 20929 34055
2976 9237 30748
17492 23256 34334
14069 21117 34122
2 30 34279
4782 18300 33733
153 4829 34472
6935 20289 25347
94 23931 34474
4955 13105 18305
3455 6361 16383
5195 13496 34289
1637 5512 18417
14082 20496 28064
12268 18659 23956
9430 22419 34549
6153 21548 24847
1995 12662 13605
13498 29840 31922
14059 14662 33208
20727 33280 34067
564 20975 23516.

A sixth data processing device or data processing method according to the present technology includes a decoding unit or decoding step of decoding an LDPC code with a code length of 64800 bits and an encoding rate of 14/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
2422 2919 3173 3795 4428 12681 13428 14654 17367 17687 19587 20017 23588 24353 25280 27167 29853 32040 32473 33170 33375
34 79 817 12478 12769 14798 15383 16688 16739 17538 21654 22792 25145 25588 26995 27388 31655 32133 32601 33452 34471
88 986 1907 2868 3657 6826 8595 11922 14704 17681 19503 20604 24251 28125 28612 29976 30687 31208 31464 33686 33909
526 3853 4486 6507 10616 11300 11453 13385 20007 21420 21441 22554 23794 24581 24959 27083 28710 30235 32852 34179 34327
43 1775 4405 5644 6553 8885 10337 11178 14114 15108 16189 16192 18490 18801 21475 22748 28269 28970 30758 31968 33554
27 624 1191 1470 4277 5054 5695 9632 10911 11365 13339 21097 23810 26677 27822 28433 29878 31026 32525 33335 33873
14 45 760 1098 1567 2003 6710 10195 12052 13024 13337 19088 22647 25050 25899 27035 28844 29927 33916 34033 34490
30 94 4493 11928 14051 17759 18541 20842 21277 24587 24948 25790 27442 31120 31205 31526 32107 32263 33696 34393 34529
3 4245 5284 7791 10196 10922 13992 14397 14947 16908 21032 24585 27219 30300 30981 32732 33362 33558 33725 34424 34537
78 6958 8297 15781 23302 23386 23863 25570 25734 31844 31919 32100 32815 33345 33531 33561 33889 34348 34504 34512 34530
52 90 775 3760 4099 6945 8954 11931 16578 20804 23252 26583 29420 32461 33695 33874 33964 34018 34177 34483 34506
81 1162 3084 3986 4494 8523 10309 10934 12819 16784 23113 23803 25952 29134 29930 30530 32021 33343 33400 33664 33685
0 35 57 1564 9062 19694 24489 24737 26422 27021 30630 31513 33317 33425 33545 33624 33743 33869 33875 34046 34519
58 639 2340 3613 19319 21917 24284 29214 29430 29736 32496 32785 32830 32835 33176 33323 33711 33967 34197 34438 34468
71 77 88 953 4233 7365 8395 15176 16662 18280 21989 24348 26847 27645 31050 31890 34119 34223 34235 34548 34551
163 4304 4697 7470 11857 12787 12837 18000 18472 18489 19730 27014 29653 29740 30070 30252 32769 33637 34382 34394 34555
7 29 79 7321 9770 11315 15354 16240 18888 19559 27783 28220 28924 30659 31474 33084 33310 33644 34282 34452 34557
8 24 41 4491 11252 14225 18230 25845 30258 30801 31349 32655 32932 32951 33058 33794 33889 34150 34338 34463 34494
13 13092 15747 23904 29675 29732 30199 31273 31928 32211 32704 32959 33056 33374 33646 33931 34043 34203 34426 34429 34509
6 11188 19937
11738 14763 34508
11 4674 25431
6346 9658 31716
13231 32283 33193
19187 31166 33846
297 27886 32712
74 8683 24435
2200 20501 21571
25 10097 29631
4515 32145 33245
13010 26434 29967
0 30598 33940
1342 27835 33782
2253 7519 33030
9079 13091 29109
20124 20880 27383
14317 16550 26394
84 2860 33197
21726 28620 31525
12888 23822 32157
1221 10300 34113
15613 22759 28517
4889 28647 31367
22184 25784 30338
21714 26800 28577
1408 15983 16148
6569 18901 23827
42 7606 25499
11193 13616 31040
8996 28561 30145
6335 23176 26286
6236 23314 24004
25452 30736 31684
3826 12150 21414
10711 17869 29177
13382 34510 34532
14491 16483 31945
77 16047 34221
17991 32178 32575
5508 6547 13800
4265 19226 25358
10154 23746 29274
3421 20929 34055
2976 9237 30748
17492 23256 34334
14069 21117 34122
2 30 34279
4782 18300 33733
153 4829 34472
6935 20289 25347
94 23931 34474
4955 13105 18305
3455 6361 16383
5195 13496 34289
1637 5512 18417
14082 20496 28064
12268 18659 23956
9430 22419 34549
6153 21548 24847
1995 12662 13605
13498 29840 31922
14059 14662 33208
20727 33280 34067
564 20975 23516.

A seventh data processing device or data processing method according to the present technology includes an encoding step of encoding an information bit into an LDPC code with a code length of 64800 bits and an encoding rate of 15/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
760 874 3785 6601 10266 14790 16713 18014 18215 20992 21237 21250 24161 24295 25360 25380 26306 28764 30139 30708 31719 31730 32179
191 7294 12316 12887 15172 15688 16749 18425 21102 25133 25875 25892 26013 26763 27058 29510 29746 30265 30326 30386 31467 31665 32391
76 2184 4641 6139 8656 9053 10603 15456 15797 15853 19689 21857 23984 24703 24732 26828 26912 27714 27978 28627 30815 31332 31701
13 5917 11178 13332 13401 16567 18144 18332 21502 22585 26654 27287 27474 27580 28266 28949 30045 30669 30950 31388 31786 31820 32319
723 9266 11501 12279 14691 14757 16829 18863 19022 19311 21466 22322 23441 23479 26959 29450 29621 30075 30305 32044 32050 32110 32387
42 3584 3807 6900 8188 12414 14341 20161 20466 23466 23722 26503 28207 29006 30745 30942 31023 31647 31668 31908 32130 32332 32338
2108 6363 8375 8971 10744 12734 15004 16460 16558 21479 22043 23858 24423 27887 28871 30000 30089 30596 30926 31378 31525 32333 32355
28 948 5841 6154 6643 10141 11528 12498 12525 13792 15031 18762 20383 20443 23824 25767 27445 27558 27979 31402 32064 32133 32394
14 19 2616 3474 4620 5333 6095 8507 8656 9411 13922 17800 18897 23695 25311 29891 30342 31067 31124 31139 31467 32019 32240
01082 2189 4147 8496 8986 10062 11294 16960 20197 23516 23989 24429 25718 29296 30293 31195 31351 31665 31820 32073 32355 32376
1661 4207 5859 14432 17329 18592 20431 20758 23186 23573 29558 29974 30107 30295 30396 30635 30935 31185 31534 31650 31685 31960 32007
89 4834 5934 6765 7256 7928 9025 12135 14585 23859 25231 25332 26519 26921 30891 31001 31496 31625 31700 31730 31852 32022 32224
5460 6506 6639 10691 16488 20520 21627 22863 25303 26209 26647 27502 27898 28112 28982 29023 29188 31060 31193 31673 31911 32200 32343
4652 9366 12753 13047 16124 19840 19846 19928 22041 26095 27473 28784 29506 29827 29958 30347 31018 31027 31904 32274 32300 32383 32387
2265 3996 4208 6150 7258 9151 9983 12269 12788 12986 15469 17063 26727 26859 28941 30162 30172 30616 30714 31315 31357 31818 32284
6518 11111 24325 32103
72 12699 23236 30992
8360 19792 19940 32358
14197 21794 25358 27036
4398 6859 18988 32137
841 22129 27876 31949
6974 7937 17758 27732
7040 9749 9755 32242
2949 17069 29881 30587
1373 9669 30875 32281
11884 12078 27981 32205
7736 24771 25380 32163
74 3602 19540 25410
16273 30193 32344 32355
1315 13197 20672 25600
13 9947 14814 27294
21919 29940 31822 32276
11 3234 17261 27366
18543 21226 24436 32375
18492 19557 22383 30490
24 17620 23927 32049
14847 22301 22903 29032
2676 11480 11692 18567
12192 31056 31967 32098
44 27120 32324 32378
5721 9533 32015 32311
30379 31576 31774 32209
5335 10732 31892 32363
11000 22458 32187 32398
1872 10630 32347 32391
16571 17488 23289 23346
27732 29271 29371 30145
3353 29492 31289 31868
2198 6637 10704 26015
15354 19712 25567
21163 24225 25981
4200 22366 31698
9311 18196 25010
28406 31360 31879
5159 6285 31195
28054 29700 31997
4049 10513 29649
78 29253 32396
1024 7865 16946
4124 20295 22713
14007 19361 32315
4044 12702 14541
25377 29764 31569
2057 25664 32000
8836 10649 14172
6497 27125 29138
11983 21816 29095
8545 16142 25004
13112 27787 32221
28 7470 32149
21978 31113 32332
24788 31901 32359
19016 31956 32312
8082 16436 22264
27 23947 28943
20 19713 25231
24 5409 25558
17325 22825 29039
58 30869 32333
52 7935 13780
76 27127 32224
16783 30121 30450
9138 17711 31443
16066 25671 32301
13418 14979 22933
11496 16370 20860
4727 10245 15174
1523 17435 32170
60 10068 32392
8324 27536 32209.

An eighth data processing device or data processing method according to the present technology includes a decoding unit or decoding step of decoding an LDPC code with a code length of 64800 bits and an encoding rate of 15/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
760 874 3785 6601 10266 14790 16713 18014 18215 20992 21237 21250 24161 24295 25360 25380 26306 28764 30139 30708 31719 31730 32179
191 7294 12316 12887 15172 15688 16749 18425 21102 25133 25875 25892 26013 26763 27058 29510 29746 30265 30326 30386 31467 31665 32391
76 2184 4641 6139 8656 9053 10603 15456 15797 15853 19689 21857 23984 24703 24732 26828 26912 27714 27978 28627 30815 31332 31701
13 5917 11178 13332 13401 16567 18144 18332 21502 22585 26654 27287 27474 27580 28266 28949 30045 30669 30950 31388 31786 31820 32319
723 9266 11501 12279 14691 14757 16829 18863 19022 19311 21466 22322 23441 23479 26959 29450 29621 30075 30305 32044 32050 32110 32387
42 3584 3807 6900 8188 12414 14341 20161 20466 23466 23722 26503 28207 29006 30745 30942 31023 31647 31668 31908 32130 32332 32338
2108 6363 8375 8971 10744 12734 15004 16460 16558 21479 22043 23858 24423 27887 28871 30000 30089 30596 30926 31378 31525 32333 32355
28 948 5841 6154 6643 10141 11528 12498 12525 13792 15031 18762 20383 20443 23824 25767 27445 27558 27979 31402 32064 32133 32394
14 19 2616 3474 4620 5333 6095 8507 8656 9411 13922 17800 18897 23695 25311 29891 30342 31067 31124 31139 31467 32019 32240
0 1082 2189 4147 8496 8986 10062 11294 16960 20197 23516 23989 24429 25718 29296 30293 31195 31351 31665 31820 32073 32355 32376
1661 4207 5859 14432 17329 18592 20431 20758 23186 23573 29558 29974 30107 30295 30396 30635 30935 31185 31534 31650 31685 31960 32007
89 4834 5934 6765 7256 7928 9025 12135 14585 23859 25231 25332 26519 26921 30891 31001 31496 31625 31700 31730 31852 32022 32224
5460 6506 6639 10691 16488 20520 21627 22863 25303 26209 26647 27502 27898 28112 28982 29023 29188 31060 31193 31673 31911 32200 32343
4652 9366 12753 13047 16124 19840 19846 19928 22041 26095 27473 28784 29506 29827 29958 30347 31018 31027 31904 32274 32300 32383 32387
2265 3996 4208 6150 7258 9151 9983 12269 12788 12986 15469 17063 26727 26859 28941 30162 30172 30616 30714 31315 31357 31818 32284
6518 11111 24325 32103
72 12699 23236 30992
8360 19792 19940 32358
14197 21794 25358 27036
4398 6859 18988 32137
841 22129 27876 31949
6974 7937 17758 27732
7040 9749 9755 32242
2949 17069 29881 30587
1373 9669 30875 32281
11884 12078 27981 32205
7736 24771 25380 32163
74 3602 19540 25410
16273 30193 32344 32355
1315 13197 20672 25600
13 9947 14814 27294
21919 29940 31822 32276
11 3234 17261 27366
18543 21226 24436 32375
18492 19557 22383 30490
24 17620 23927 32049
14847 22301 22903 29032
2676 11480 11692 18567
12192 31056 31967 32098
44 27120 32324 32378
5721 9533 32015 32311
30379 31576 31774 32209
5335 10732 31892 32363
11000 22458 32187 32398
1872 10630 32347 32391
16571 17488 23289 23346
27732 29271 29371 30145
3353 29492 31289 31868
2198 6637 10704 26015
15354 19712 25567
21163 24225 25981
4200 22366 31698
9311 18196 25010
28406 31360 31879
5159 6285 31195
28054 29700 31997
4049 10513 29649
78 29253 32396
1024 7865 16946
4124 20295 22713
14007 19361 32315
4044 12702 14541
25377 29764 31569
2057 25664 32000
8836 10649 14172
6497 27125 29138
11983 21816 29095
8545 16142 25004
13112 27787 32221
28 7470 32149
21978 31113 32332
24788 31901 32359
19016 31956 32312
8082 16436 22264
27 23947 28943
20 19713 25231
24 5409 25558
17325 22825 29039
58 30869 32333
52 7935 13780
76 27127 32224
16783 30121 30450
9138 17711 31443
16066 25671 32301
13418 14979 22933
11496 16370 20860
4727 10245 15174
1523 17435 32170
60 10068 32392
8324 27536 32209.

A ninth data processing device or data processing method according to the present technology includes an encoding unit or encoding step of encoding an information bit into an LDPC code with a code length of 64800 bits and an encoding rate of 16/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
3111 4871 6505 6799 7635 11197 14052 14348 14826 15557 15659 18613 21220 22340 22401 27614 28374 29255 29841
3361 4302 5676 9039 12309 14206 14677 15432 18320 20678 22348 23548 24612 27694 28211 28562 29155 29406 29548
5 53 3037 4529 5584 5648 17104 18025 18489 20393 24434 24500 24814 25552 25565 26415 27851 29090 29780
5161 5493 5523 10121 12283 13234 14979 17374 18240 20035 24222 25047 26289 26734 28216 28403 28465 28810 29385
43 186 1836 4590 11586 12799 13507 13724 14711 15317 21647 23476 24193 24699 25994 28699 29940 30122 30203
2003 3800 5130 6577 9365 10145 11356 15819 15932 16104 18223 19103 20631 22002 23366 26895 28896 28976 30165
23 9657 11412 13196 15347 15358 16644 17463 18784 19185 26582 28301 28342 28525 28922 29224 29957 30116 30120
2206 3177 4177 6441 7458 11162 15727 16894 19718 20753 20946 22516 22660 26757 26827 26850 28909 29822 30046
739 3969 4582 14549 15188 15831 21294 22417 22460 23015 25237 25515 26568 26656 27187 27924 28526 29071 29734
4208 4241 4427 6512 14103 18082 22518 23522 24048 24879 27014 28704 28753 29196 29438 29571 29695 29829 30174
13 32 3455 8111 10978 13661 13856 18718 19398 20224 22663 23517 26241 27440 28748 28817 28979 29377 30187
1463 3641 4046 6345 6676 10287 12165 13506 15052 15192 20449 23322 23426 24120 25788 26284 27049 28460 30124
1569 3052 3370 5187 6418 12733 15343 15725 16555 19231 25563 26273 27866 28411 28938 29006 29339 29387 29566
77 4306 7810 12815 18400 19686 19803 20446 20940 21189 22144 23248 24200 25226 28695 28801 29268 30118 30206
45 649 1691 4421 8406 9642 10567 11550 12441 15117 17109 18327 19727 24980 26328 27075 27235 28892 30221
12483 13895 20152 20245 20655 21468 22162 22961 24057 24365 24605 25411 26180 26761 27446 29507 30100 30181 30216
44 1264 3026 7950 8626 14270 17615 17922 18819 23010 23725 25137 25284 25409 27704 28128 28675 29774 30092
55 2812 7572 7825 8647 19309 20122 20243 20787 22530 22612 24719 24955 25546 26352 26396 26477 29301 29918
6419 11660 28980 30169
62 7613 22157 25645
3958 5559 27517 28608
2395 6628 21235 27555
750 14167 14443 29001
14265 15570 28940 29039
77 600 7982 16623
19331 26506 29810 30208
1269 1541 23861 27282
19 12841 24031 27927
1666 14901 16818 28517
3189 11786 18478 23399
6495 10934 16584 25011
8 28009 28559 30049
58 1288 17394 18565
13723 28172 29034
8440 9110 16677
12909 17320 30012
24814 27014 29165
17859 24172 24616
13076 28350 28463
22 10992 13100
13027 14490 29661
8454 13705 30238
11 21997 22751
12860 16875 26073
14510 26256 29962
3886 4042 27359
11582 29084 29204
17120 28447 29009
21893 24307 30195
79 20747 27546
34 8136 23729
19787 29064 29759
18463 22634 26188
6266 6668 8406
12813 19765 27450
37 29680 29989
4708 9183 26121
46 3504 4132
69 18724 30090
24867 27125 30171
2214 4898 23823
20902 27008 30091
7073 17524 29356
120 2952 29234
3325 23880 29001
65 9413 21897
26943 27109 29732
602 29267 29947
8477 14722 24091
7886 28109 29997
12730 27726 29820
27 12228 30239
17638 28758 30236
24 13634 30168
8892 16810 25858
5263 9232 29835
527 18583 30143
28 1820 21525
2574 24420 29901
3 6599 20094
3484 24193 24838
43 12248 22044
1052 1669 27379
20703 28365 30141
892 23049 29633
9076 16913 27030
10878 11979 29525
38 62 5737
61 3446 17492
12701 21553 29475
10928 30088 30163
16919 26239 28009
59 25348 27313
21414 28574 29768
4515 19286 28017
19661 20675 26662.

A tenth data processing device or data processing method according to the present technology includes a decoding unit or decoding step of decoding an LDPC code with a code length of 64800 bits and an encoding rate of 16/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
3111 4871 6505 6799 7635 11197 14052 14348 14826 15557 15659 18613 21220 22340 22401 27614 28374 29255 29841
3361 4302 5676 9039 12309 14206 14677 15432 18320 20678 22348 23548 24612 27694 28211 28562 29155 29406 29548
5 53 3037 4529 5584 5648 17104 18025 18489 20393 24434 24500 24814 25552 25565 26415 27851 29090 29780
5161 5493 5523 10121 12283 13234 14979 17374 18240 20035 24222 25047 26289 26734 28216 28403 28465 28810 29385
43 186 1836 4590 11586 12799 13507 13724 14711 15317 21647 23476 24193 24699 25994 28699 29940 30122 30203
2003 3800 5130 6577 9365 10145 11356 15819 15932 16104 18223 19103 20631 22002 23366 26895 28896 28976 30165
23 9657 11412 13196 15347 15358 16644 17463 18784 19185 26582 28301 28342 28525 28922 29224 29957 30116 30120
2206 3177 4177 6441 7458 11162 15727 16894 19718 20753 20946 22516 22660 26757 26827 26850 28909 29822 30046
739 3969 4582 14549 15188 15831 21294 22417 22460 23015 25237 25515 26568 26656 27187 27924 28526 29071 29734
4208 4241 4427 6512 14103 18082 22518 23522 24048 24879 27014 28704 28753 29196 29438 29571 29695 29829 30174
13 32 3455 8111 10978 13661 13856 18718 19398 20224 22663 23517 26241 27440 28748 28817 28979 29377 30187
1463 3641 4046 6345 6676 10287 12165 13506 15052 15192 20449 23322 23426 24120 25788 26284 27049 28460 30124
1569 3052 3370 5187 6418 12733 15343 15725 16555 19231 25563 26273 27866 28411 28938 29006 29339 29387 29566
77 4306 7810 12815 18400 19686 19803 20446 20940 21189 22144 23248 24200 25226 28695 28801 29268 30118 30206
45 649 1691 4421 8406 9642 10567 11550 12441 15117 17109 18327 19727 24980 26328 27075 27235 28892 30221
12483 13895 20152 20245 20655 21468 22162 22961 24057 24365 24605 25411 26180 26761 27446 29507 30100 30181 30216
44 1264 3026 7950 8626 14270 17615 17922 18819 23010 23725 25137 25284 25409 27704 28128 28675 29774 30092
55 2812 7572 7825 8647 19309 20122 20243 20787 22530 22612 24719 24955 25546 26352 26396 26477 29301 29918
6419 11660 28980 30169
62 7613 22157 25645
3958 5559 27517 28608
2395 6628 21235 27555
750 14167 14443 29001
14265 15570 28940 29039
77 600 7982 16623
19331 26506 29810 30208
1269 1541 23861 27282
19 12841 24031 27927
1666 14901 16818 28517
3189 11786 18478 23399
6495 10934 16584 25011
8 28009 28559 30049
58 1288 17394 18565
13723 28172 29034
8440 9110 16677
12909 17320 30012
24814 27014 29165
17859 24172 24616
13076 28350 28463
22 10992 13100
13027 14490 29661
8454 13705 30238
11 21997 22751
12860 16875 26073
14510 26256 29962
3886 4042 27359
11582 29084 29204
17120 28447 29009
21893 24307 30195
79 20747 27546
34 8136 23729
19787 29064 29759
18463 22634 26188
6266 6668 8406
12813 19765 27450
37 29680 29989
4708 9183 26121
46 3504 4132
69 18724 30090
24867 27125 30171
2214 4898 23823
20902 27008 30091
7073 17524 29356
120 2952 29234
3325 23880 29001
65 9413 21897
26943 27109 29732
602 29267 29947
8477 14722 24091
7886 28109 29997
12730 27726 29820
27 12228 30239
17638 28758 30236
24 13634 30168
8892 16810 25858
5263 9232 29835
527 18583 30143
28 1820 21525
2574 24420 29901
3 6599 20094
3484 24193 24838
43 12248 22044
1052 1669 27379
20703 28365 30141
892 23049 29633
9076 16913 27030
10878 11979 29525
38 62 5737
61 3446 17492
12701 21553 29475
10928 30088 30163
16919 26239 28009
59 25348 27313
21414 28574 29768
4515 19286 28017
19661 20675 26662.

An eleventh data processing device or data processing method according to the present technology includes an encoding unit or encoding step of encoding an information bit into an LDPC code with a code length of 64800 bits and an encoding rate of 17/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
3638 3722 7015 10458 11119 12197 14103 14536 17412 18774 22287 22612 22713 25635 27548 27686 27778 27826
5324 7803 10924 11606 12282 12502 12860 16739 22141 23364 23709 23875 25369 26285 26862 26922 26948 27844
118 2886 6188 8567 8753 10752 11895 11939 12361 12739 14031 15749 16127 16638 18517 22030 23682 27925
158 489 824 1854 2935 4257 6997 11791 15452 15664 16719 19672 24085 25188 25240 25283 25636 27011
2918 5981 6349 7833 12983 14033 14242 14344 17083 17405 19655 21959 22550 23777 27153 27827 27848 27921
3265 5089 6050 6323 10714 18435 20910 21582 24038 24361 24712 25131 25484 26901 27073 27174 27309 27693
17 26 32 3083 10749 11918 11982 12657 13842 14454 18559 20569 23993 27282 27712 27732 27772 27820
3991 4273 5550 8223 9048 10163 12392 15961 19676 20564 20586 21360 24139 26555 27189 27334 27708 27844
1611 3553 6046 9278 10150 13220 13670 14436 17764 19828 20986 21353 21723 25542 25691 26339 27591 27823
6173 6835 7028 7803 8388 8626 11307 15884 17784 18339 19512 24249 26438 27137 27255 27594 27770 28072
67 486 3205 5487 10201 11054 14546 20328 23045 23272 23673 25248 25527 25802 26578 27235 27872 27971
23 3605 3873 13976 16258 18335 18529 20465 22508 24880 24946 25672 26326 26479 26514 27758 28026 28047
2183 7317 10716 11014 11637 20111 21269 22729 23581 25870 25891 27176 27185 27709 27747 27912 28003 28024
12 31 53 68 1492 9988 15395 19124 20807 23692 25299 25979 26394 27022 27026 27092 27576 28041
18 52 4442 12761 15481 17938 20266 24312 24821 25137 25916 26131 26642 26851 27065 27311 27697 27987
49 4516 5076 12930 15048 20703 21360 22615 25025 25577 25997 26353 26659 26701 27206 27655 28030 28037
36 1654 2703 8738 13150 15338 18464 20505 21404 25826 25911 27400 27433 27513 27891 28011 28015 28043
40 54 6027 11231 14164 15995 17839 19890 22537 25509 26043 26700 27141 27166 27182 27660 27893 27990
2840 11826 14170 15701 15758 17947 19094 23029 26232 26528 26556 26849 27015 27456 27761 27881 27987 28036
30 680 1541 5734 8251 19767 20127 21120 22480 25861 25867 26517 26755 26821 27220 27547 27793 27875
1630 5956 7702 9606 10458 10541 17763 19609 21908 23593 24189 24356 24896 25180 26091 27038 27081 27422
2459 2748 22536 23254
597 7455 22226 26562
12250 13286 13325 25013
8523 13590 27754
39 19867 24723
19403 21896 22752
8491 20514 23236
4300 25422 27311
11586 19002 28004
10358 19197 20224
11549 24404 24743
25288 26238 27603
7064 7516 12667
10495 22956 25193
2138 16441 19980
57 3925 20396
26 3672 6014
8425 24543 26134
8188 8317 24909
40 2219 17740
4187 10940 11324
2447 7425 20795
46 13240 16149
37 12701 25168
4044 5791 27998
33 24019 25005
18081 22487 23003
13 20833 25074
15660 22973 27116
2816 17854 27914
18148 23098 27712
3886 19711 20993
54 17332 26188
10188 16959 27174
74 14117 23707
8805 19540 27887
25062 27736 28002
1698 16599 28039
19195 24524 25323
6814 27968 27986
942 972 24673
4760 24441 27142
680 11557 27969
4544 14190 19878
15369 18267 27683
9155 20072 26804
65 5166 12757
49 14369 26870
1 35 26298
5975 12813 19445
20809 27226 27431
59 75 5907
9940 17252 27654
11221 14695 17335
10851 18647 27885
8004 26096 26754
7 23111 27220
22256 26278 27521
1087 24826 28022
3753 11220 15209
11595 12395 27701
21 67 1577
11832 25290 26155
13569 19238 19712
5240 18333 22195
3466 20906 25558
18549 24520 27963
17078 18683 28070
7525 21035 27052
25555 26737 27020
10046 10066 15471
7526 19774 27813
10476 11424 27594
18349 24493 27123
5476 26410 28071
7964 14835 18804
33 4787 25619
757 6564 13708
23472 27330 28015
7067 19247 22116
7363 27544 27851.

A twelfth data processing device or data processing method according to the present technology includes a decoding unit or decoding step of decoding an LDPC code with a code length of 64800 bits and an encoding rate of 17/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
3638 3722 7015 10458 11119 12197 14103 14536 17412 18774 22287 22612 22713 25635 27548 27686 27778 27826
5324 7803 10924 11606 12282 12502 12860 16739 22141 23364 23709 23875 25369 26285 26862 26922 26948 27844
118 2886 6188 8567 8753 10752 11895 11939 12361 12739 14031 15749 16127 16638 18517 22030 23682 27925
158 489 824 1854 2935 4257 6997 11791 15452 15664 16719 19672 24085 25188 25240 25283 25636 27011
2918 5981 6349 7833 12983 14033 14242 14344 17083 17405 19655 21959 22550 23777 27153 27827 27848 27921
3265 5089 6050 6323 10714 18435 20910 21582 24038 24361 24712 25131 25484 26901 27073 27174 27309 27693
17 26 32 3083 10749 11918 11982 12657 13842 14454 18559 20569 23993 27282 27712 27732 27772 27820
3991 4273 5550 8223 9048 10163 12392 15961 19676 20564 20586 21360 24139 26555 27189 27334 27708 27844
1611 3553 6046 9278 10150 13220 13670 14436 17764 19828 20986 21353 21723 25542 25691 26339 27591 27823
6173 6835 7028 7803 8388 8626 11307 15884 17784 18339 19512 24249 26438 27137 27255 27594 27770 28072
67 486 3205 5487 10201 11054 14546 20328 23045 23272 23673 25248 25527 25802 26578 27235 27872 27971
23 3605 3873 13976 16258 18335 18529 20465 22508 24880 24946 25672 26326 26479 26514 27758 28026 28047
2183 7317 10716 11014 11637 20111 21269 22729 23581 25870 25891 27176 27185 27709 27747 27912 28003 28024
12 31 53 68 1492 9988 15395 19124 20807 23692 25299 25979 26394 27022 27026 27092 27576 28041
18 52 4442 12761 15481 17938 20266 24312 24821 25137 25916 26131 26642 26851 27065 27311 27697 27987
49 4516 5076 12930 15048 20703 21360 22615 25025 25577 25997 26353 26659 26701 27206 27655 28030 28037
36 1654 2703 8738 13150 15338 18464 20505 21404 25826 25911 27400 27433 27513 27891 28011 28015 28043
40 54 6027 11231 14164 15995 17839 19890 22537 25509 26043 26700 27141 27166 27182 27660 27893 27990
2840 11826 14170 15701 15758 17947 19094 23029 26232 26528 26556 26849 27015 27456 27761 27881 27987 28036
30 680 1541 5734 8251 19767 20127 21120 22480 25861 25867 26517 26755 26821 27220 27547 27793 27875
1630 5956 7702 9606 10458 10541 17763 19609 21908 23593 24189 24356 24896 25180 26091 27038 27081 27422
2459 2748 22536 23254
597 7455 22226 26562
12250 13286 13325 25013
8523 13590 27754
39 19867 24723
19403 21896 22752
8491 20514 23236
4300 25422 27311
11586 19002 28004
10358 19197 20224
11549 24404 24743
25288 26238 27603
7064 7516 12667
10495 22956 25193
2138 16441 19980
57 3925 20396
26 3672 6014
8425 24543 26134
8188 8317 24909
40 2219 17740
4187 10940 11324
2447 7425 20795
46 13240 16149
37 12701 25168
4044 5791 27998
33 24019 25005
18081 22487 23003
13 20833 25074
15660 22973 27116
2816 17854 27914
18148 23098 27712
3886 19711 20993
54 17332 26188
10188 16959 27174
74 14117 23707
8805 19540 27887
25062 27736 28002
1698 16599 28039
19195 24524 25323
6814 27968 27986
942 972 24673
4760 24441 27142
680 11557 27969
4544 14190 19878
15369 18267 27683
9155 20072 26804
65 5166 12757
49 14369 26870
1 35 26298
5975 12813 19445
20809 27226 27431
59 75 5907
9940 17252 27654
11221 14695 17335
10851 18647 27885
8004 26096 26754
7 23111 27220
22256 26278 27521
1087 24826 28022
3753 11220 15209
11595 12395 27701
21 67 1577
11832 25290 26155
13569 19238 19712
5240 18333 22195
3466 20906 25558
18549 24520 27963
17078 18683 28070
7525 21035 27052
25555 26737 27020
10046 10066 15471
7526 19774 27813
10476 11424 27594
18349 24493 27123
5476 26410 28071
7964 14835 18804
33 4787 25619
757 6564 13708
23472 27330 28015
7067 19247 22116
7363 27544 27851.

According to the present technology, an information bit is encoded into an LDPC code with a code length of 64800 bits and an encoding rate of 12/30, 13/30, 14/30, 15/30, 16/30, or 17/30 based on a parity check matrix of an LDPC (Low Density Parity Check) code.

According to the present technology, an LDPC code with a code length of 64800 bits and an encoding rate of 12/30, 13/30, 14/30, 15/30, 16/30, or 17/30 is decoded based on a parity check matrix of an LDPC (Low Density Parity Check) code.

The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns.

A parity check matrix initial value table with an encoding rate of 12/30 is expressed as follows
2455 2650 6184 7016 7280 7409 7507 8261 8591 8829 11277 13729 14302 15883 17754 18506 19816 19940 22442 23981 26881 26981 28760 29688 31138 31497 32673 35889 37690 38665
50 327 3574 4465 5954 9702 10606 11684 11715 12627 14132 14951 20099 24111 24283 27026 27473 28162 30076 31032 31476 35031 36675 36914 37008 37425 37530 37689 38830 38856
59 102 5278 5548 5850 11840 13813 16641 19597 20543 24088 24298 25171 25224 26925 28312 28867 31551 31898 32849 33616 34486 34562 35252 35931 36107 37950 38494 38537 38547
79 2084 2361 2922 3048 3525 5712 9376 10012 10463 11842 15200 18443 19223 20476 21361 22584 24343 24594 28001 28304 28475 28969 31149 31528 32574 33007 35120 38245 38253
821 2803 8187 8501 10063 10497 14472 14570 15613 18469 19620 23034 24029 24578 26538 31025 32621 34134 34508 34988 35201 35907 36693 36793 37608 37998 38090 38506 38611 38682
9 50 88 1222 2430 2824 7233 9972 10225 15762 18283 18961 20711 28455 29946 32016 35611 35763 37263 37325 38287 38360 38416 38471 38518 38551 38643 38759 38763 38818
33 38 151 2523 3787 5069 6710 7667 8501 11083 17631 19589 24263 24684 24940 28493 30646 31916 33741 35060 35810 36284 36394 36400 38209 38312 38340 38782 38825 38858
8 49 84 381 4009 6978 9983 14028 14051 16325 17393 24325 25130 25838 30998 35159 36135 37516 37636 37837 37927 38433 38620 38647 38650 38699 38733 38784 38804 38862
44 76 4362 4480 8679 8833 13730 16493 16507 22419 24544 25614 25671 33032 33120 35219 35986 36415 36505 38169 38173 38327 38371 38468 38508 38546 38551 38747 38761 38853
16 683 1013 8364 8665 12213 12279 12643 13134 15450 16703 17846 20656 21664 22896 23487 25022 32049 32482 33647 35029 35197 36636 37162 38376 38408 38430 38520 38721 38734
3 760 1052 6377 8526 9014 11769 12589 16661 18156 20521 21303 23361 27434 32315 34602 34892 35078 35262 35639 36655 37893 38063 38578 38602 38719 38737 38748 38837 38861
15 30 79 99 16844 19586 24117 24702 25088 26129 27790 28383 30976 33472 34613 35266 35337 36278 36841 36980 37214 37651 37817 38085 38218 38338 38396 38432 38760 38812
12483 24049 35782 38706
12146 19270 23193 38389
26418 34831 37883 38501
25045 36512 37567 38487
15238 33547 38210 38696
14 6773 17384 38679
14367 16694 16867 38453
15371 37498 37910 38610
2509 18705 27907 28422
21246 37360 38125 38868
11357 23312 24884 36318
14467 19559 22338 37893
26899 35264 36300 37973
17311 28273 32934 38607
0 14452 16264 38585
6736 19801 31034 38279
35256 36593 38204 38655
10037 29019 32956 38670
98 17138 28233 37750
576 4888 14014 23030
2003 2470 18968 38841
1042 4623 8098 9963
61 3037 9719 27052
15129 26628 31307 37604
9791 11904 12369 34528
7996 15467 21456 38165
7644 12741 34083 38851
4766 26027 31133 38830
17783 36021 37697 38571
4925 9033 28100 32671
9452 23191 32529 36265
6124 19224 27145 30628
24 26468 35718 38718
14403 14741 20334 38444
322 15324 22539 33347
22663 29889 38488
7 13998 38748
8835 20728 20777
9742 24551 26087
23173 24287 38644
16606 30002 32432
30691 37266 38776
20366 21134 35082
21617 28615 29424
15974 26095 34262
92 35091 36358
9348 28177 38737
16104 37933 38151
14133 30118 38803
1314 37661 38852
19118 28886 37980
20212 22241 32326
3885 17856 38675
12577 21905 30465
28672 35317 35384
12880 16994 34495
16353 34789 38134
465 37194 38658
23 6202 38823
24020 25383 37955.

A parity check matrix initial value table with an encoding rate of 13/30 is expressed as follows
1153 2676 2759 5782 7192 10887 11573 11888 12383 18472 20695 21466 21753 23630 24580 25006 25182 25636 25887 29615 29677 31968 32188 32277 33135
935 5609 7730 9427 9519 10465 11182 12164 15765 17266 18156 20309 20542 21193 21697 22913 22989 23780 27048 30762 31731 35754 36161 36379 36710
644 2718 6995 7088 7898 11242 13921 14068 14328 15840 19581 19919 21938 22749 23311 23767 25945 26731 27405 27830 31023 32589 33239 33957 34456
17 131 2331 6624 10568 12965 16184 17665 19575 20690 22609 23378 24385 28281 30808 33083 34435 34509 36016 36355 36525 36580 36586 36636 36644
5 42 59 80 100 3327 4882 5238 6588 15417 17416 17476 18307 19336 20336 22770 33204 33302 34207 35133 35594 35650 36090 36619 36659
46 141 308 995 2267 2645 5224 5839 7945 8336 10865 14607 21285 22062 23225 23772 24190 25324 26738 29253 29674 33264 35593 36564 36608
55 2316 8545 13623 14353 14516 15773 18442 20172 21970 22319 26595 27849 29185 30141 31195 33614 34586 35699 35994 36309 36445 36516 36662 36665
17 59 82 955 5050 7239 17495 19753 23481 25131 30124 32434 33042 34583 35231 35786 36232 36336 36518 36530 36541 36584 36592 36629 36648
1 16 78 717 5622 7351 7729 9200 10674 12647 22946 24316 25268 28139 31794 32278 33243 34217 34485 34505 34929 35450 35865 36340 36565
15 36 73 2381 4118 6829 9453 11705 12402 14884 17442 19226 21328 25523 26538 29300 34635 35066 35547 35617 36285 36343 36599 36607 36708
27 58 3657 8026 9245 11874 14579 15588 16280 16426 22692 25061 27788 29797 31776 34992 35324 35529 36295 36298 36469 36608 36626 36661 36679
13 36 78 3785 5888 10015 13647 14824 18283 20262 26268 26890 27517 33128 33659 34191 35729 35965 36196 36381 36385 36501 36593 36659 36667
0 6 63 1713 8050 11113 18981 20118 22082 23210 24401 27239 31104 32963 33846 34334 35232 35626 36159 36424 36441 36457 36523 36609 36640
39 60 64 92 438 4764 6022 9256 14471 20458 23327 26872 30944 34061 34882 35249 35586 35642 35680 36092 36126 36548 36626 36633 36649
40 67 6336 8195 9735 19400 20396 21095 22015 28597 31367 33511 33932 34732 34847 35247 35543 36020 36258 36619 36651 36688 36693 36709 36717
13990 15734 24992 35907
448 14650 29725 36141
27195 27825 34118 35317
2514 7964 31027 31885
12966 22180 24997 33406
13568 17438 18377 36038
76 15846 25385 35720
1 758 23751 36083
2238 8449 29406 31840
80 14882 15923 33878
86 18320 24636 36111
5392 24119 31102 34507
6485 8182 14790 21264
13702 29065 35939 36554
9160 11429 36663 36691
9153 12051 20063 25493
37 3918 13758 18923
18643 24675 31646 33893
3941 9238 30160 36584
26037 31006 35886
115 8925 13728
8079 12229 21571
18315 34532 35200
14760 36073 36540
27155 28360 36381
24111 32816 36411
17214 32333 35208
10181 13269 24419
55 13696 29382
35958 36528 36673
21481 27758 31170
2161 27055 36569
14381 22920 36680
9113 19651 32334
2500 20917 29374
1966 30518 30855
14419 25676 36077
31502 33331 34982
23192 27819 36698
23130 34074 35969
39 82 9069
1665 23618 28887
13344 16378 16410
3753 6863 27107
5309 26232 29584
83 10780 35045
23884 31975 36715
8591 27909 35282
16924 29871 36684
11923 21783 30567
20309 26955 36030
33545 36648 36706
6851 9052 35671
2188 11594 34478
32 5093 24903
7863 21519 23494
2227 25547 36218
27745 35240 36580
8094 13505 31136
14191 28503 33160
14107 25438 30594
30235 33886 35034
14118 35846 36621.

A parity check matrix initial value table with an encoding rate of 14/30 is expressed as follows
2422 2919 3173 3795 4428 12681 13428 14654 17367 17687 19587 20017 23588 24353 25280 27167 29853 32040 32473 33170 33375
34 79 817 12478 12769 14798 15383 16688 16739 17538 21654 22792 25145 25588 26995 27388 31655 32133 32601 33452 34471
88 986 1907 2868 3657 6826 8595 11922 14704 17681 19503 20604 24251 28125 28612 29976 30687 31208 31464 33686 33909
526 3853 4486 6507 10616 11300 11453 13385 20007 21420 21441 22554 23794 24581 24959 27083 28710 30235 32852 34179 34327
43 1775 4405 5644 6553 8885 10337 11178 14114 15108 16189 16192 18490 18801 21475 22748 28269 28970 30758 31968 33554
27 624 1191 1470 4277 5054 5695 9632 10911 11365 13339 21097 23810 26677 27822 28433 29878 31026 32525 33335 33873
14 45 760 1098 1567 2003 6710 10195 12052 13024 13337 19088 22647 25050 25899 27035 28844 29927 33916 34033 34490
30 94 4493 11928 14051 17759 18541 20842 21277 24587 24948 25790 27442 31120 31205 31526 32107 32263 33696 34393 34529
3 4245 5284 7791 10196 10922 13992 14397 14947 16908 21032 24585 27219 30300 30981 32732 33362 33558 33725 34424 34537
78 6958 8297 15781 23302 23386 23863 25570 25734 31844 31919 32100 32815 33345 33531 33561 33889 34348 34504 34512 34530
52 90 775 3760 4099 6945 8954 11931 16578 20804 23252 26583 29420 32461 33695 33874 33964 34018 34177 34483 34506
81 1162 3084 3986 4494 8523 10309 10934 12819 16784 23113 23803 25952 29134 29930 30530 32021 33343 33400 33664 33685
0 35 57 1564 9062 19694 24489 24737 26422 27021 30630 31513 33317 33425 33545 33624 33743 33869 33875 34046 34519
58 639 2340 3613 19319 21917 24284 29214 29430 29736 32496 32785 32830 32835 33176 33323 33711 33967 34197 34438 34468
71 77 88 953 4233 7365 8395 15176 16662 18280 21989 24348 26847 27645 31050 31890 34119 34223 34235 34548 34551
163 4304 4697 7470 11857 12787 12837 18000 18472 18489 19730 27014 29653 29740 30070 30252 32769 33637 34382 34394 34555
7 29 79 7321 9770 11315 15354 16240 18888 19559 27783 28220 28924 30659 31474 33084 33310 33644 34282 34452 34557
8 24 41 4491 11252 14225 18230 25845 30258 30801 31349 32655 32932 32951 33058 33794 33889 34150 34338 34463 34494
13 13092 15747 23904 29675 29732 30199 31273 31928 32211 32704 32959 33056 33374 33646 33931 34043 34203 34426 34429 34509
6 11188 19937
11738 14763 34508
11 4674 25431
6346 9658 31716
13231 32283 33193
19187 31166 33846
297 27886 32712
74 8683 24435
2200 20501 21571
25 10097 29631
4515 32145 33245
13010 26434 29967
0 30598 33940
1342 27835 33782
2253 7519 33030
9079 13091 29109
20124 20880 27383
14317 16550 26394
84 2860 33197
21726 28620 31525
12888 23822 32157
1221 10300 34113
15613 22759 28517
4889 28647 31367
22184 25784 30338
21714 26800 28577
1408 15983 16148
6569 18901 23827
42 7606 25499
11193 13616 31040
8996 28561 30145
6335 23176 26286
6236 23314 24004
25452 30736 31684
3826 12150 21414
10711 17869 29177
13382 34510 34532
14491 16483 31945
77 16047 34221
17991 32178 32575
5508 6547 13800
4265 19226 25358
10154 23746 29274
3421 20929 34055
2976 9237 30748
17492 23256 34334
14069 21117 34122
2 30 34279
4782 18300 33733
153 4829 34472
6935 20289 25347
94 23931 34474
4955 13105 18305
3455 6361 16383
5195 13496 34289
1637 5512 18417
14082 20496 28064
12268 18659 23956
9430 22419 34549
6153 21548 24847
1995 12662 13605
13498 29840 31922
14059 14662 33208
20727 33280 34067
564 20975 23516.

A parity check matrix initial value table with an encoding rate of 15/30 is expressed as follows
760 874 3785 6601 10266 14790 16713 18014 18215 20992 21237 21250 24161 24295 25360 25380 26306 28764 30139 30708 31719 31730 32179
191 7294 12316 12887 15172 15688 16749 18425 21102 25133 25875 25892 26013 26763 27058 29510 29746 30265 30326 30386 31467 31665 32391
76 2184 4641 6139 8656 9053 10603 15456 15797 15853 19689 21857 23984 24703 24732 26828 26912 27714 27978 28627 30815 31332 31701
13 5917 11178 13332 13401 16567 18144 18332 21502 22585 26654 27287 27474 27580 28266 28949 30045 30669 30950 31388 31786 31820 32319
723 9266 11501 12279 14691 14757 16829 18863 19022 19311 21466 22322 23441 23479 26959 29450 29621 30075 30305 32044 32050 32110 32387
42 3584 3807 6900 8188 12414 14341 20161 20466 23466 23722 26503 28207 29006 30745 30942 31023 31647 31668 31908 32130 32332 32338
2108 6363 8375 8971 10744 12734 15004 16460 16558 21479 22043 23858 24423 27887 28871 30000 30089 30596 30926 31378 31525 32333 32355
28 948 5841 6154 6643 10141 11528 12498 12525 13792 15031 18762 20383 20443 23824 25767 27445 27558 27979 31402 32064 32133 32394
14 19 2616 3474 4620 5333 6095 8507 8656 9411 13922 17800 18897 23695 25311 29891 30342 31067 31124 31139 31467 32019 32240
0 1082 2189 4147 8496 8986 10062 11294 16960 20197 23516 23989 24429 25718 29296 30293 31195 31351 31665 31820 32073 32355 32376
1661 4207 5859 14432 17329 18592 20431 20758 23186 23573 29558 29974 30107 30295 30396 30635 30935 31185 31534 31650 31685 31960 32007
89 4834 5934 6765 7256 7928 9025 12135 14585 23859 25231 25332 26519 26921 30891 31001 31496 31625 31700 31730 31852 32022 32224
5460 6506 6639 10691 16488 20520 21627 22863 25303 26209 26647 27502 27898 28112 28982 29023 29188 31060 31193 31673 31911 32200 32343
4652 9366 12753 13047 16124 19840 19846 19928 22041 26095 27473 28784 29506 29827 29958 30347 31018 31027 31904 32274 32300 32383 32387
2265 3996 4208 6150 7258 9151 9983 12269 12788 12986 15469 17063 26727 26859 28941 30162 30172 30616 30714 31315 31357 31818 32284
6518 11111 24325 32103
72 12699 23236 30992
8360 19792 19940 32358
14197 21794 25358 27036
4398 6859 18988 32137
841 22129 27876 31949
6974 7937 17758 27732
7040 9749 9755 32242
2949 17069 29881 30587
1373 9669 30875 32281
11884 12078 27981 32205
7736 24771 25380 32163
74 3602 19540 25410
16273 30193 32344 32355
1315 13197 20672 25600
13 9947 14814 27294
21919 29940 31822 32276
11 3234 17261 27366
18543 21226 24436 32375
18492 19557 22383 30490
24 17620 23927 32049
14847 22301 22903 29032
2676 11480 11692 18567
12192 31056 31967 32098
44 27120 32324 32378
5721 9533 32015 32311
30379 31576 31774 32209
5335 10732 31892 32363
11000 22458 32187 32398
1872 10630 32347 32391
16571 17488 23289 23346
27732 29271 29371 30145
3353 29492 31289 31868
2198 6637 10704 26015
15354 19712 25567
21163 24225 25981
4200 22366 31698
9311 18196 25010
28406 31360 31879
5159 6285 31195
28054 29700 31997
4049 10513 29649
78 29253 32396
1024 7865 16946
4124 20295 22713
14007 19361 32315
4044 12702 14541
25377 29764 31569
2057 25664 32000
8836 10649 14172
6497 27125 29138
11983 21816 29095
8545 16142 25004
13112 27787 32221
28 7470 32149
21978 31113 32332
24788 31901 32359
19016 31956 32312
8082 16436 22264
27 23947 28943
20 19713 25231
24 5409 25558
17325 22825 29039
58 30869 32333
52 7935 13780
76 27127 32224
16783 30121 30450
9138 17711 31443
16066 25671 32301
13418 14979 22933
11496 16370 20860
4727 10245 15174
1523 17435 32170
60 10068 32392
8324 27536 32209.

A parity check matrix initial value table with an encoding rate of 16/30 is expressed as follows
3111 4871 6505 6799 7635 11197 14052 14348 14826 15557 15659 18613 21220 22340 22401 27614 28374 29255 29841
3361 4302 5676 9039 12309 14206 14677 15432 18320 20678 22348 23548 24612 27694 28211 28562 29155 29406 29548
5 53 3037 4529 5584 5648 17104 18025 18489 20393 24434 24500 24814 25552 25565 26415 27851 29090 29780
5161 5493 5523 10121 12283 13234 14979 17374 18240 20035 24222 25047 26289 26734 28216 28403 28465 28810 29385
43 186 1836 4590 11586 12799 13507 13724 14711 15317 21647 23476 24193 24699 25994 28699 29940 30122 30203
2003 3800 5130 6577 9365 10145 11356 15819 15932 16104 18223 19103 20631 22002 23366 26895 28896 28976 30165
23 9657 11412 13196 15347 15358 16644 17463 18784 19185 26582 28301 28342 28525 28922 29224 29957 30116 30120
2206 3177 4177 6441 7458 11162 15727 16894 19718 20753 20946 22516 22660 26757 26827 26850 28909 29822 30046
739 3969 4582 14549 15188 15831 21294 22417 22460 23015 25237 25515 26568 26656 27187 27924 28526 29071 29734
4208 4241 4427 6512 14103 18082 22518 23522 24048 24879 27014 28704 28753 29196 29438 29571 29695 29829 30174
13 32 3455 8111 10978 13661 13856 18718 19398 20224 22663 23517 26241 27440 28748 28817 28979 29377 30187
1463 3641 4046 6345 6676 10287 12165 13506 15052 15192 20449 23322 23426 24120 25788 26284 27049 28460 30124
1569 3052 3370 5187 6418 12733 15343 15725 16555 19231 25563 26273 27866 28411 28938 29006 29339 29387 29566
77 4306 7810 12815 18400 19686 19803 20446 20940 21189 22144 23248 24200 25226 28695 28801 29268 30118 30206
45 649 1691 4421 8406 9642 10567 11550 12441 15117 17109 18327 19727 24980 26328 27075 27235 28892 30221
12483 13895 20152 20245 20655 21468 22162 22961 24057 24365 24605 25411 26180 26761 27446 29507 30100 30181 30216
44 1264 3026 7950 8626 14270 17615 17922 18819 23010 23725 25137 25284 25409 27704 28128 28675 29774 30092
55 2812 7572 7825 8647 19309 20122 20243 20787 22530 22612 24719 24955 25546 26352 26396 26477 29301 29918
6419 11660 28980 30169
62 7613 22157 25645
3958 5559 27517 28608
2395 6628 21235 27555
750 14167 14443 29001
14265 15570 28940 29039
77 600 7982 16623
19331 26506 29810 30208
1269 1541 23861 27282
19 12841 24031 27927
1666 14901 16818 28517
3189 11786 18478 23399
6495 10934 16584 25011
8 28009 28559 30049
58 1288 17394 18565
13723 28172 29034
8440 9110 16677
12909 17320 30012
24814 27014 29165
17859 24172 24616
13076 28350 28463
22 10992 13100
13027 14490 29661
8454 13705 30238
11 21997 22751
12860 16875 26073
14510 26256 29962
3886 4042 27359
11582 29084 29204
17120 28447 29009
21893 24307 30195
79 20747 27546
34 8136 23729
19787 29064 29759
18463 22634 26188
6266 6668 8406
12813 19765 27450
37 29680 29989
4708 9183 26121
46 3504 4132
69 18724 30090
24867 27125 30171
2214 4898 23823
20902 27008 30091
7073 17524 29356
120 2952 29234
3325 23880 29001
65 9413 21897
26943 27109 29732
602 29267 29947
8477 14722 24091
7886 28109 29997
12730 27726 29820
27 12228 30239
17638 28758 30236
24 13634 30168
8892 16810 25858
5263 9232 29835
527 18583 30143
28 1820 21525
2574 24420 29901
3 6599 20094
3484 24193 24838
43 12248 22044
1052 1669 27379
20703 28365 30141
892 23049 29633
9076 16913 27030
10878 11979 29525
38 62 5737
61 3446 17492
12701 21553 29475
10928 30088 30163
16919 26239 28009
59 25348 27313
21414 28574 29768
4515 19286 28017
19661 20675 26662.

A parity check matrix initial value table with an encoding rate of 17/30 is expressed as follows
3638 3722 7015 10458 11119 12197 14103 14536 17412 18774 22287 22612 22713 25635 27548 27686 27778 27826
5324 7803 10924 11606 12282 12502 12860 16739 22141 23364 23709 23875 25369 26285 26862 26922 26948 27844
118 2886 6188 8567 8753 10752 11895 11939 12361 12739 14031 15749 16127 16638 18517 22030 23682 27925
158 489 824 1854 2935 4257 6997 11791 15452 15664 16719 19672 24085 25188 25240 25283 25636 27011
2918 5981 6349 7833 12983 14033 14242 14344 17083 17405 19655 21959 22550 23777 27153 27827 27848 27921
3265 5089 6050 6323 10714 18435 20910 21582 24038 24361 24712 25131 25484 26901 27073 27174 27309 27693
17 26 32 3083 10749 11918 11982 12657 13842 14454 18559 20569 23993 27282 27712 27732 27772 27820
3991 4273 5550 8223 9048 10163 12392 15961 19676 20564 20586 21360 24139 26555 27189 27334 27708 27844
1611 3553 6046 9278 10150 13220 13670 14436 17764 19828 20986 21353 21723 25542 25691 26339 27591 27823
6173 6835 7028 7803 8388 8626 11307 15884 17784 18339 19512 24249 26438 27137 27255 27594 27770 28072
67 486 3205 5487 10201 11054 14546 20328 23045 23272 23673 25248 25527 25802 26578 27235 27872 27971
23 3605 3873 13976 16258 18335 18529 20465 22508 24880 24946 25672 26326 26479 26514 27758 28026 28047
2183 7317 10716 11014 11637 20111 21269 22729 23581 25870 25891 27176 27185 27709 27747 27912 28003 28024
12 31 53 68 1492 9988 15395 19124 20807 23692 25299 25979 26394 27022 27026 27092 27576 28041
18 52 4442 12761 15481 17938 20266 24312 24821 25137 25916 26131 26642 26851 27065 27311 27697 27987
49 4516 5076 12930 15048 20703 21360 22615 25025 25577 25997 26353 26659 26701 27206 27655 28030 28037
36 1654 2703 8738 13150 15338 18464 20505 21404 25826 25911 27400 27433 27513 27891 28011 28015 28043
40 54 6027 11231 14164 15995 17839 19890 22537 25509 26043 26700 27141 27166 27182 27660 27893 27990
2840 11826 14170 15701 15758 17947 19094 23029 26232 26528 26556 26849 27015 27456 27761 27881 27987 28036
30 680 1541 5734 8251 19767 20127 21120 22480 25861 25867 26517 26755 26821 27220 27547 27793 27875
1630 5956 7702 9606 10458 10541 17763 19609 21908 23593 24189 24356 24896 25180 26091 27038 27081 27422
2459 2748 22536 23254
597 7455 22226 26562
12250 13286 13325 25013
8523 13590 27754
39 19867 24723
19403 21896 22752
8491 20514 23236
4300 25422 27311
11586 19002 28004
10358 19197 20224
11549 24404 24743
25288 26238 27603
7064 7516 12667
10495 22956 25193
2138 16441 19980
57 3925 20396
26 3672 6014
8425 24543 26134
8188 8317 24909
40 2219 17740
4187 10940 11324
2447 7425 20795
46 13240 16149
37 12701 25168
4044 5791 27998
33 24019 25005
18081 22487 23003
13 20833 25074
15660 22973 27116
2816 17854 27914
18148 23098 27712
3886 19711 20993
54 17332 26188
10188 16959 27174
74 14117 23707
8805 19540 27887
25062 27736 28002
1698 16599 28039
19195 24524 25323
6814 27968 27986
942 972 24673
4760 24441 27142
680 11557 27969
4544 14190 19878
15369 18267 27683
9155 20072 26804
65 5166 12757
49 14369 26870
1 35 26298
5975 12813 19445
20809 27226 27431
59 75 5907
9940 17252 27654
11221 14695 17335
10851 18647 27885
8004 26096 26754
7 23111 27220
22256 26278 27521
1087 24826 28022
3753 11220 15209
11595 12395 27701
21 67 1577
11832 25290 26155
13569 19238 19712
5240 18333 22195
3466 20906 25558
18549 24520 27963
17078 18683 28070
7525 21035 27052
25555 26737 27020
10046 10066 15471
7526 19774 27813
10476 11424 27594
18349 24493 27123
5476 26410 28071
7964 14835 18804
33 4787 25619
757 6564 13708
23472 27330 28015
7067 19247 22116
7363 27544 27851.

The data processing device may be an independent device and may be an internal block constituting one device.

### Advantageous Effects of Invention

According to the present disclosure, it is possible to provide an LDPC code of an excellent error rate.

### BRIEF DESCRIPTION OF DRAWINGS

FIG. 1 is an illustration of a parity check matrix H of an LDPC code.

FIG. 2 is a flowchart illustrating a decoding sequence of an LDPC code.

FIG. 3 is an illustration of an example of a parity check matrix of an LDPC code.

FIG. 4 is an illustration of a Tanner graph of a parity check matrix.

FIG. 5 is an illustration of a variable node.

FIG. 6 is an illustration of a check node.

FIG. 7 is an illustration of a configuration example of an embodiment of a transmission system to which the present invention is applied.

FIG. 8 is a block diagram illustrating a configuration example of a transmitting device 11.

FIG. 9 is a block diagram illustrating a configuration example of a bit interleaver 116.

FIG. 10 is an illustration of a parity check matrix.

FIG. 11 is an illustration of a parity matrix.

FIG. 12 is an illustration of a parity check matrix of an LDPC code defined in a standard of DVB-S.2.

FIG. 13 is an illustration of a parity check matrix of an LDPC code defined in a standard of DVB-S.2.

FIG. 14 is an illustration of signal point arrangement of 16QAM.

FIG. 15 is an illustration of signal point arrangement of 64QAM.

FIG. 16 is an illustration of signal point arrangement of 64QAM.

FIG. 17 is an illustration of signal point arrangement of 64QAM.

FIG. 18 is an illustration of signal point arrangement defined in the standard of DVB-S.2.

FIG. 19 is an illustration of signal point arrangement defined in the standard of DVB-S.2.

FIG. 20 is an illustration of signal point arrangement defined in the standard of DVB-S.2.

FIG. 21 is an illustration of signal point arrangement defined in the standard of DVB-S.2.

FIG. 22 is an illustration of processing of a demultiplexer 25.

FIG. 23 is an illustration of processing of a demultiplexer 25.

FIG. 24 is an illustration of a Tanner graph for decoding of an LDPC code.

FIG. 25 is an illustration of a parity matrix H_{T} becoming a staircase structure and a Tanner graph corresponding to the parity matrix H_{T}.

FIG. 26 is an illustration of a parity matrix H_{T} of a parity check matrix H corresponding to an LDPC code after parity interleave.

FIG. 27 is an illustration of a transformed parity check matrix.

FIG. 28 is an illustration of processing of a column twist interleaver 24.

FIG. 29 is an illustration of a column number of a memory 31 necessary for a column twist interleave and an address of a write start position.

FIG. 30 is an illustration of a column number of a memory 31 necessary for a column twist interleave and an address of a write start position.

FIG. 31 is a flowchart illustrating processing executed by a bit interleaver 116 and a QAM encoder 117.

FIG. 32 is an illustration of a model of a communication path adopted by simulation.

FIG. 33 is an illustration of a relation of an error rate obtained by simulation and a Doppler frequency f_{d} of a flutter.

FIG. 34 is an illustration of a relation of an error rate obtained by simulation and a Doppler frequency f_{d} of a flutter.

FIG. 35 is a block diagram illustrating a configuration example of an LDPC encoder 115.

FIG. 36 is a flowchart illustrating processing of an LDPC encoder 115.

FIG. 37 is an illustration of an example of a parity check matrix initial value table in which an encoding rate is 1/4 and a code length is 16200.

FIG. 38 is an illustration of a method of calculating a parity check matrix H from a parity check matrix initial value table.

FIG. 39 is an illustration of the characteristic of BER/FER of an LDPC code whose code length defined in the standard of DVB-S.2 is 64800 bits.

FIG. 40 is an illustration of an example of a parity check matrix initial value table in which an encoding rate is 2/30 and a code length is 64800.

FIG. 41 is an illustration of an example of a parity check matrix initial value table in which an encoding rate is 3/30 and a code length is 64800.

FIG. 42 is an illustration of an example of a parity check matrix initial value table in which an encoding rate is 4/30 and a code length is 64800.

FIG. 43 is an illustration of an example of a parity check matrix initial value table in which an encoding rate is 5/30 and a code length is 64800.

FIG. 44 is an illustration of an example of a parity check matrix initial value table in which an encoding rate is 6/30 and a code length is 64800.

FIG. 45 is an illustration of an example of a parity check matrix initial value table in which an encoding rate is 7/30 and a code length is 64800.

FIG. 46 is an illustration of an example of a parity check matrix initial value table in which an encoding rate is 8/30 and a code length is 64800.

FIG. 47 is an illustration of an example of a parity check matrix initial value table in which an encoding rate is 8/30 and a code length is 64800.

FIG. 48 is an illustration of an example of a parity check matrix initial value table in which an encoding rate is 9/30 and a code length is 64800.

FIG. 49 is an illustration of an example of a parity check matrix initial value table in which an encoding rate is 9/30 and a code length is 64800.

FIG. 50 is an illustration of an example of a parity check matrix initial value table in which an encoding rate is 10/30 and a code length is 64800.

FIG. 51 is an illustration of an example of a parity check matrix initial value table in which an encoding rate is 10/30 and a code length is 64800.

FIG. 52 is an illustration of an example of a parity check matrix initial value table in which an encoding rate is 11/30 and a code length is 64800.

FIG. 53 is an illustration of an example of a parity check matrix initial value table in which an encoding rate is 11/30 and a code length is 64800.

FIG. 54 is an illustration of an example of a parity check matrix initial value table in which an encoding rate is 12/30 and a code length is 64800.

FIG. 55 is an illustration of an example of a parity check matrix initial value table in which an encoding rate is 12/30 and a code length is 64800.

FIG. 56 is an illustration of an example of a parity check matrix initial value table in which an encoding rate is 13/30 and a code length is 64800.

FIG. 57 is an illustration of an example of a parity check matrix initial value table in which an encoding rate is 13/30 and a code length is 64800.

FIG. 58 is an illustration of an example of a parity check matrix initial value table in which an encoding rate is 14/30 and a code length is 64800.

FIG. 59 is an illustration of an example of a parity check matrix initial value table in which an encoding rate is 14/30 and a code length is 64800.

FIG. 60 is an illustration of an example of a parity check matrix initial value table in which an encoding rate is 15/30 and a code length is 64800.

FIG. 61 is an illustration of an example of a parity check matrix initial value table in which an encoding rate is 15/30 and a code length is 64800.

FIG. 62 is an illustration of an example of a parity check matrix initial value table in which an encoding rate is 16/30 and a code length is 64800.

FIG. 63 is an illustration of an example of a parity check matrix initial value table in which an encoding rate is 16/30 and a code length is 64800.

FIG. 64 is an illustration of an example of a parity check matrix initial value table in which an encoding rate is 16/30 and a code length is 64800.

FIG. 65 is an illustration of an example of a parity check matrix initial value table in which an encoding rate is 17/30 and a code length is 64800.

FIG. 66 is an illustration of an example of a parity check matrix initial value table in which an encoding rate is 17/30 and a code length is 64800.

FIG. 67 is an illustration of an example of a parity check matrix initial value table in which an encoding rate is 17/30 and a code length is 64800.

FIG. 68 is an illustration of an example of a parity check matrix initial value table in which an encoding rate is 18/30 and a code length is 64800.

FIG. 69 is an illustration of an example of a parity check matrix initial value table in which an encoding rate is 18/30 and a code length is 64800.

FIG. 70 is an illustration of an example of a parity check matrix initial value table in which an encoding rate is 18/30 and a code length is 64800.

FIG. 71 is an illustration of an example of a parity check matrix initial value table in which an encoding rate is 19/30 and a code length is 64800.

FIG. 72 is an illustration of an example of a parity check matrix initial value table in which an encoding rate is 19/30 and a code length is 64800.

FIG. 73 is an illustration of an example of a parity check matrix initial value table in which an encoding rate is 19/30 and a code length is 64800.

FIG. 74 is an illustration of an example of a parity check matrix initial value table in which an encoding rate is 20/30 and a code length is 64800.

FIG. 75 is an illustration of an example of a parity check matrix initial value table in which an encoding rate is 20/30 and a code length is 64800.

FIG. 76 is an illustration of an example of a parity check matrix initial value table in which an encoding rate is 20/30 and a code length is 64800.

FIG. 77 is an illustration of an example of a parity check matrix initial value table in which an encoding rate is 21/30 and a code length is 64800.

FIG. 78 is an illustration of an example of a parity check matrix initial value table in which an encoding rate is 21/30 and a code length is 64800.

FIG. 79 is an illustration of an example of a parity check matrix initial value table in which an encoding rate is 21/30 and a code length is 64800.

FIG. 80 is an illustration of an example of a parity check matrix initial value table in which an encoding rate is 22/30 and a code length is 64800.

FIG. 81 is an illustration of an example of a parity check matrix initial value table in which an encoding rate is 22/30 and a code length is 64800.

FIG. 82 is an illustration of an example of a parity check matrix initial value table in which an encoding rate is 22/30 and a code length is 64800.

FIG. 83 is an illustration of an example of a parity check matrix initial value table in which an encoding rate is 23/30 and a code length is 64800.

FIG. 84 is an illustration of an example of a parity check matrix initial value table in which an encoding rate is 23/30 and a code length is 64800.

FIG. 85 is an illustration of an example of a parity check matrix initial value table in which an encoding rate is 23/30 and a code length is 64800.

FIG. 86 is an illustration of an example of a parity check matrix initial value table in which an encoding rate is 24/30 and a code length is 64800.

FIG. 87 is an illustration of an example of a parity check matrix initial value table in which an encoding rate is 24/30 and a code length is 64800.

FIG. 88 is an illustration of an example of a parity check matrix initial value table in which an encoding rate is 24/30 and a code length is 64800.

FIG. 89 is an illustration of an example of a parity check matrix initial value table in which an encoding rate is 25/30 and a code length is 64800.

FIG. 90 is an illustration of an example of a parity check matrix initial value table in which an encoding rate is 25/30 and a code length is 64800.

FIG. 91 is an illustration of an example of a parity check matrix initial value table in which an encoding rate is 25/30 and a code length is 64800.

FIG. 92 is an illustration of an example of a parity check matrix initial value table in which an encoding rate is 26/30 and a code length is 64800.

FIG. 93 is an illustration of an example of a parity check matrix initial value table in which an encoding rate is 26/30 and a code length is 64800.

FIG. 94 is an illustration of an example of a parity check matrix initial value table in which an encoding rate is 26/30 and a code length is 64800.

FIG. 95 is an illustration of an example of a parity check matrix initial value table in which an encoding rate is 27/30 and a code length is 64800.

FIG. 96 is an illustration of an example of a parity check matrix initial value table in which an encoding rate is 27/30 and a code length is 64800.

FIG. 97 is an illustration of an example of a parity check matrix initial value table in which an encoding rate is 27/30 and a code length is 64800.

FIG. 98 is an illustration of an example of a parity check matrix initial value table in which an encoding rate is 27/30 and a code length is 64800.

FIG. 99 is an illustration of an example of a parity check matrix initial value table in which an encoding rate is 28/30 and a code length is 64800.

FIG. 100 is an illustration of an example of a parity check matrix initial value table in which an encoding rate is 28/30 and a code length is 64800.

FIG. 101 is an illustration of an example of a parity check matrix initial value table in which an encoding rate is 28/30 and a code length is 64800.

FIG. 102 is an illustration of an example of a parity check matrix initial value table in which an encoding rate is 28/30 and a code length is 64800.

FIG. 103 is an illustration of an example of a parity check matrix initial value table in which an encoding rate is 29/30 and a code length is 64800.

FIG. 104 is an illustration of an example of a parity check matrix initial value table in which an encoding rate is 29/30 and a code length is 64800.

FIG. 105 is an illustration of an example of a parity check matrix initial value table in which an encoding rate is 29/30 and a code length is 64800.

FIG. 106 is an illustration of an example of a parity check matrix initial value table in which an encoding rate is 29/30 and a code length is 64800.

FIG. 107 is an illustration of a Tanner graph of an ensemble of a degree sequence in which the column weight is 3 and the row weight is 6.

FIG. 108 is an illustration of an example of a Tanner graph of an ensemble of a multi-edge type.

FIG. 109 is an illustration of the minimum cycle length and performance threshold of a parity check matrix of an LDPC code with a code length of 64800.

FIG. 110 is an illustration of a parity check matrix of an LDPC code with a code length of 64800.

FIG. 111 is an illustration of a parity check matrix of an LDPC code with a code length of 64800.

FIG. 112 is an illustration of a simulation result of BER/FER of an LDPC code with a code length of 64800.

FIG. 113 is an illustration of a simulation result of BER/FER of an LDPC code with a code length of 64800.

FIG. 114 is an illustration of a simulation result of BER/FER of an LDPC code with a code length of 64800.

FIG. 115 is an illustration of a BCH code used for simulation of BER/FER of an LDPC code with a code length of 64800.

FIG. 116 is a block diagram illustrating a configuration example of a receiving device 12.

FIG. 117 is a block diagram illustrating a configuration example of a bit deinterleaver 165.

FIG. 118 is a flowchart illustrating processing executed by a QAM decoder 164, a bit deinterleaver 165, and an LDPC decoder 166.

FIG. 119 is an illustration of an example of a parity check matrix of an LDPC code.

FIG. 120 is an illustration of a matrix (transformed parity check matrix) obtained by executing row replacement and column replacement with respect to a parity check matrix.

FIG. 121 is an illustration of a transformed parity check matrix divided in a 5×5 unit.

FIG. 122 is a block diagram illustrating a configuration example of a decoding device that collectively performs P node operations.

FIG. 123 is a block diagram illustrating a configuration example of an LDPC decoder 166.

FIG. 124 is an illustration of processing of a multiplexer 54 constituting a bit deinterleaver 165.

FIG. 125 is an illustration of processing of a column twist deinterleaver 55.

FIG. 126 is a block diagram illustrating another configuration example of a bit deinterleaver 165.

FIG. 127 is a block diagram illustrating a first configuration example of a reception system that can be applied to a receiving device 12.

FIG. 128 is a block diagram illustrating a second configuration example of a reception system that can be applied to a receiving device 12.

FIG. 129 is a block diagram illustrating a third configuration example of a reception system that can be applied to a receiving device 12.

FIG. 130 is a block diagram illustrating a configuration example of an embodiment of a computer to which the present technology is applied.

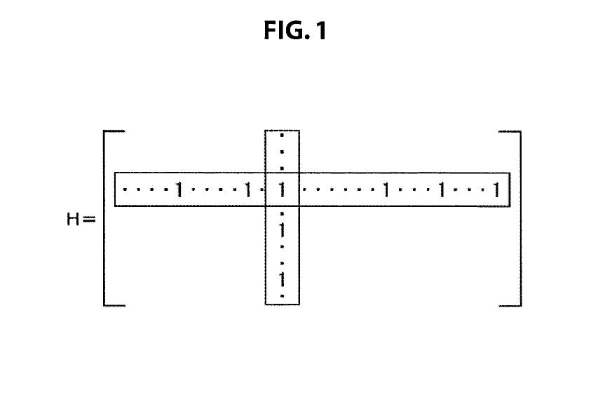

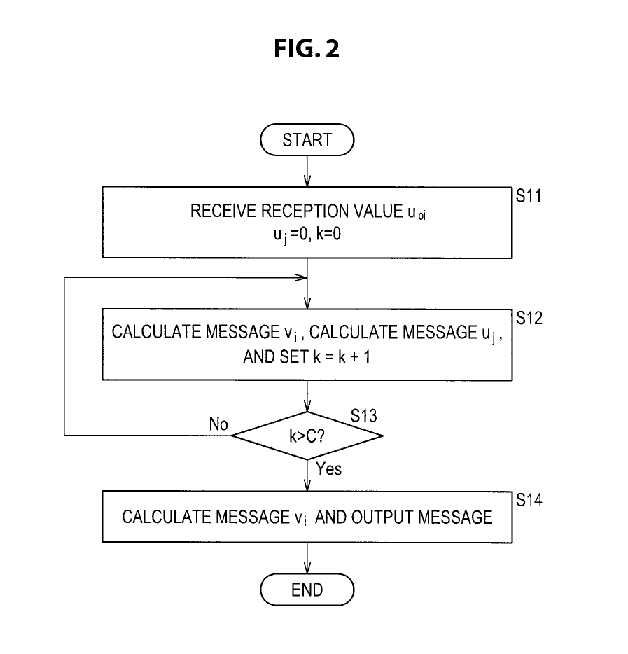

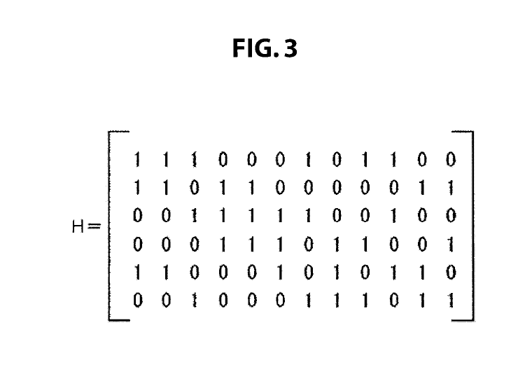

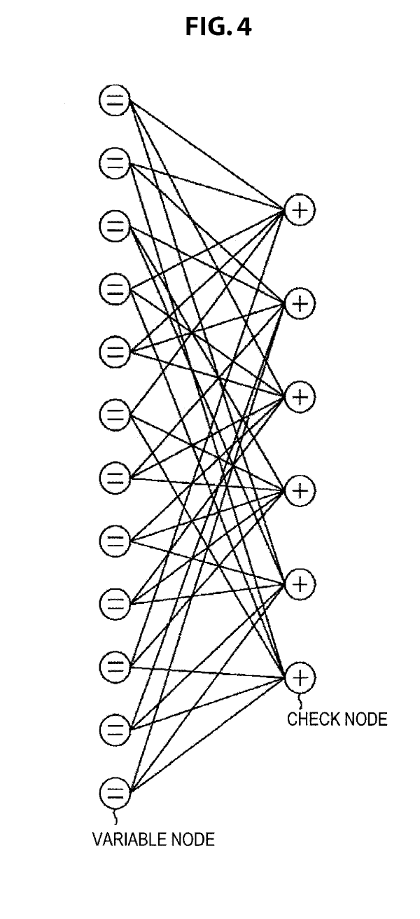

### DESCRIPTION OF EMBODIMENTS

### Configuration Example of Transmission System to which Present Disclosure is Applied

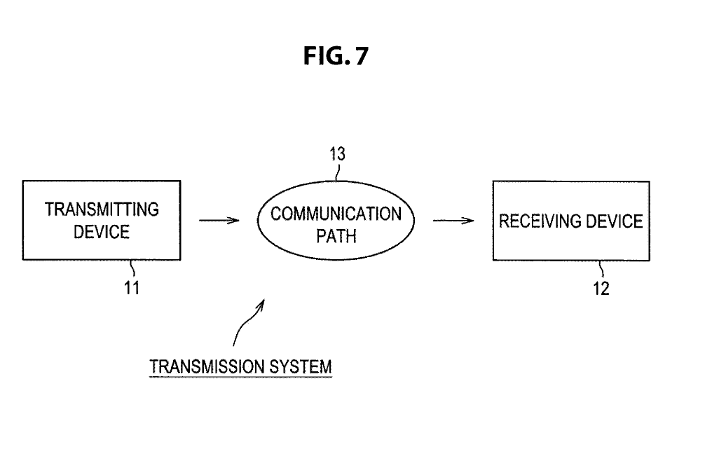

FIG. 7 illustrates a configuration example of an embodiment of a transmission system (a system means a logical gathering of a plurality of devices and a device of each configuration may be arranged or may not be arranged in the same casing) to which the present invention is applied.

In FIG. 7, the transmission system includes a transmitting device 11 and a receiving device 12.

For example, the transmitting device 11 transmits (broadcasts) (transfers) a program of television broadcasting, and so on. That is, for example, the transmitting device 11 encodes target data that is a transmission target such as image data and audio data as a program into LDPC codes, and, for example, transmits them through a communication path 13 such as a satellite circuit, a ground wave and a cable (wire circuit).

The receiving device 12 receives the LDPC code transmitted from the transmitting device 11 through the communication path 13, decodes the LDPC code to obtain the target data, and outputs the target data.

In this case, it is known that the LDPC code used by the transmission system of FIG. 7 shows the very high capability in an AWGN (Additive White Gaussian Noise) communication path.

Meanwhile, in the communication path 13, burst error or erasure may be generated. Especially in the case where the communication path 13 is the ground wave, for example, in an OFDM (Orthogonal Frequency Division Multiplexing) system, power of a specific symbol may become 0 (erasure) according to delay of an echo (paths other than a main path), under a multi-path environment in which D/U (Desired to Undesired Ratio) is 0 dB (power of Undesired=echo is equal to power of Desired=main path).

In the flutter (communication path in which delay is 0 and an echo having a Doppler frequency is added), when D/U is 0 dB, entire power of an OFDM symbol at a specific time may become 0 (erasure) by the Doppler frequency.

In addition, the burst error may be generated due to a situation of a wiring line from a receiving unit (not illustrated in the drawings) of the side of the receiving device 12 such as an antenna receiving a signal from the transmitting device 11 to the receiving device 12 or instability of a power supply of the receiving device 12.

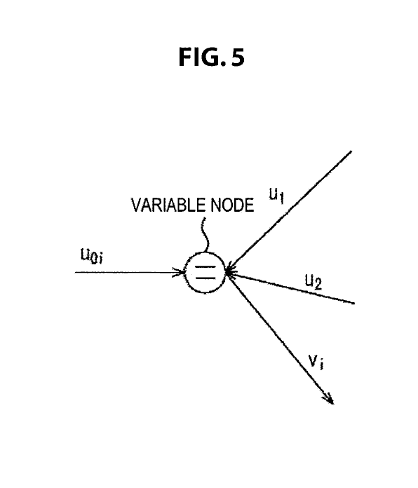

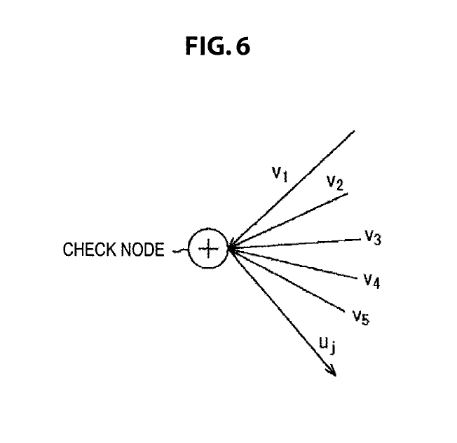

Meanwhile, in decoding of the LDPC code, in the variable node corresponding to the column of the parity check matrix H and the code bit of the LDPC code, as illustrated in FIG. 5 described above, the variable node operation of the expression (1) with the addition of (the reception value u0i of) the code bit of the LDPC code is performed. For this reason, if error is generated in the code bits used for the variable node operation, precision of the calculated message is deteriorated.

In the decoding of the LDPC code, in the check node, the check node operation of the expression (7) is performed using the message calculated by the variable node connected to the check node. For this reason, if the number of check nodes in which error (including erasure) is generated simultaneously in (the code bits of the LDPC codes corresponding to) the plurality of connected variable nodes increases, decoding performance is deteriorated.

That is, if the two or more variable nodes of the variable nodes connected to the check node become simultaneously erasure, the check node returns a message in which the probability of a value being 0 and the probability of a value being 1 are equal to each other, to all the variable nodes. In this case, the check node that returns the message of the equal probabilities does not contribute to one decoding processing (one set of the variable node operation and the check node operation). As a result, it is necessary to increase the repetition number of times of the decoding processing, the decoding performance is deteriorated, and consumption power of the receiving device 12 that performs decoding of the LDPC code increases.

Therefore, in the transmission system of FIG. 7, tolerance against the burst error or the erasure can be improved while performance in the AWGN communication path is maintained.

### Configuration Example of Transmitting Device 11

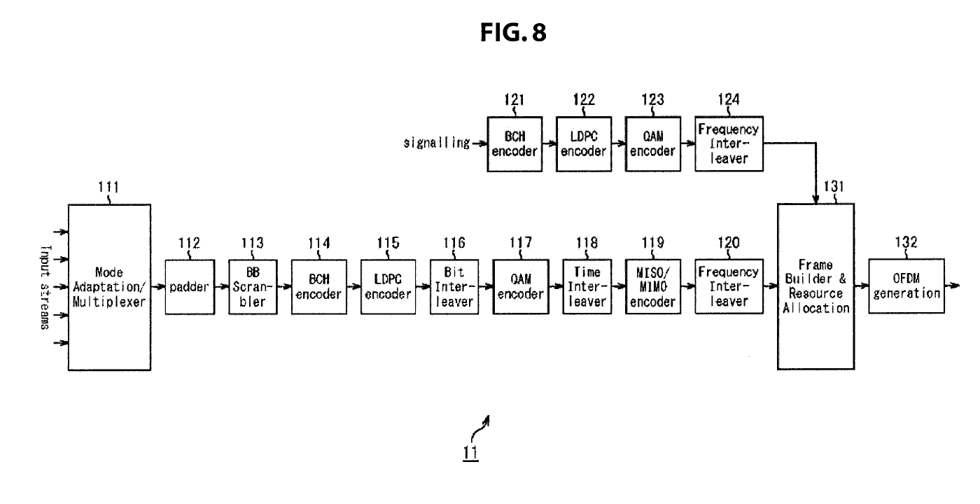

FIG. 8 is a block diagram illustrating a configuration example of the transmitting device 11 of FIG. 7.

In the transmitting device 11, one or more input streams corresponding to target data are supplied to a mode adaptation/multiplexer 111.

The mode adaptation/multiplexer 111 performs mode selection and processes such as multiplexing of one or more input streams supplied thereto, as needed, and supplies data obtained as a result to a padder 112.

The padder 112 performs necessary zero padding (insertion of Null) with respect to the data supplied from the mode adaptation/multiplexer 111 and supplies data obtained as a result to a BB scrambler 113.

The BB scrambler 113 performs base-band scrambling (BB scrambling) with respect to the data supplied from the padder 112 and supplies data obtained as a result to a BCH encoder 114.

The BCH encoder 114 performs BCH encoding with respect to the data supplied from the BB scrambler 113 and supplies data obtained as a result as LDPC target data to be an LDPC encoding target to an LDPC encoder 115.

The LDPC encoder 115 performs LDPC encoding according to a parity check matrix in which a parity matrix to be a portion corresponding to a parity bit of an LDPC code becomes a staircase structure with respect to the LDPC target data supplied from the BCH encoder 114, and outputs an LDPC code in which the LDPC target data is information bits.

That is, the LDPC encoder 115 performs the LDPC encoding to encode the LDPC target data with an LDPC such as the LDPC code (corresponding to the parity check matrix) defined in the predetermined standard of the DVB-S.2, the DVB-T.2, the DVB-C.2 or the like and outputs the predetermined LDPC code (corresponding to the parity check matrix) or the like obtained as a result.

The LDPC code defined in the standard of the DVB-S.2, the DVB-T.2, and the DVB-C.2 is an IRA (Irregular Repeat Accumulate) code and a parity matrix of the parity check matrix of the LDPC code becomes a staircase structure. The parity matrix and the staircase structure will be described later. The IRA code is described in “Irregular Repeat-Accumulate Codes”, H. Jin, A. Khandekar, and R. J. McEliece, in Proceedings of 2nd International Symposium on Turbo codes and Related Topics, pp. 1-8, September 2000, for example.

The LDPC code that is output by the LDPC encoder 115 is supplied to the bit interleaver 116.

The bit interleaver 116 performs bit interleave to be described later with respect to the LDPC code supplied from the LDPC encoder 115 and supplies the LDPC code after the bit interleave to a QAM encoder 117.

The QAM encoder 117 maps the LDPC code supplied from the bit interleaver 116 to a signal point representing one symbol of orthogonal modulation in a unit (symbol unit) of code bits of one or more bits of the LDPC code and performs the orthogonal modulation (multilevel modulation).

That is, the QAM encoder 117 performs maps the LDPC code supplied from the bit interleaver 116 to a signal point determined by a modulation method performing the orthogonal modulation of the LDPC code, on an IQ plane (IQ constellation) defined by an I axis representing an I component of the same phase as a carrier and a Q axis representing a Q component orthogonal to the carrier, and performs the orthogonal modulation.

In this case, as the modulation method of the orthogonal modulation performed by the QAM encoder 117, there are modulation methods including the modulation method defined in the standard of the DVB-S.2, the DVB-T.2, the DVB-C.2 or the like, and other modulation method, that is, BPSK (Binary Phase Shift Keying), QPSK (Quadrature Phase Shift Keying), 16APSK (Amplitude Phase-Shift Keying), 32APSK, 16QAM (Quadrature Amplitude Modulation), 64QAM, 256QAM, 1024QAM, 4096QAM, 4PAM (Pulse Amplitude Modulation), or the like. In the QAM encoder 117, to perform the orthogonal modulation based on which modulation method is previously set according to an operation of an operator of the transmitting device 11.

Data (symbol mapped to the signal point) that is obtained by processing in the QAM encoder 117 is supplied to the time interleaver 118.

The time interleaver 118 performs time interleave (interleave in a time direction) in a unit of symbol with respect to the data (symbol) supplied from the QAM encoder 117 and supplies data obtained as a result to an MISO/MIMO encoder (MISO/MIMO encoder) 119.

The MISO/MIMO encoder 119 performs spatiotemporal encoding with respect to the data (symbol) supplied from the time interleaver 118 and supplies the data to the frequency interleaver 120.

The frequency interleaver 120 performs frequency interleave (interleave in a frequency direction) in a unit of symbol with respect to the data (symbol) supplied from the MISO/MIMO encoder 119 and supplies the data to a frame builder/resource allocation unit 131.

On the other hand, for example, control data (signalling) for transfer control such as BB signaling (Base Band Signalling) (BB Header) is supplied to the BCH encoder 121.

The BCH encoder 121 performs the BCH encoding with respect to the signaling supplied thereto and supplies data obtained as a result to an LDPC encoder 122, similar to the BCH encoder 114.

The LDPC encoder 122 sets the data supplied from the BCH encoder 121 as LDPC target data, performs the LDPC encoding with respect to the data, and supplies an LDPC code obtained as a result to a QAM encoder 123, similar to the LDPC encoder 115.

The QAM encoder 123 maps the LDPC code supplied from the LDPC encoder 122 to a signal point representing one symbol of orthogonal modulation in a unit (symbol unit) of code bits of one or more bits of the LDPC code, performs the orthogonal modulation, and supplies data (symbol) obtained as a result to the frequency interleaver 124, similar to the QAM encoder 117.

The frequency interleaver 124 performs the frequency interleave in a unit of symbol with respect to the data (symbol) supplied from the QAM encoder 123 and supplies the data to the frame builder/resource allocation unit 131, similar to the frequency interleaver 120.

The frame builder/resource allocation unit 131 inserts symbols of pilots into necessary positions of the data (symbols) supplied from the frequency interleavers 120 and 124, configures a frame (for example, a physical layer (PL) frame, a T2 frame, a C2 frame, and so on) including symbols of a predetermined number from data (symbols) obtained as a result, and supplies the frame to an OFDM generating unit 132.

The OFDM generating unit 132 generates an OFDM signal corresponding to the frame from the frame supplied from the frame builder/resource allocation unit 131 and transmits the OFDM signal through the communication path 13 (FIG. 7).

Here, for example, the transmitting device 11 can be configured without including part of the blocks illustrated in FIG. 8 such as the time interleaver 118, the MISO/MIMO encoder 119, the frequency interleaver 120 and the frequency interleaver 124.

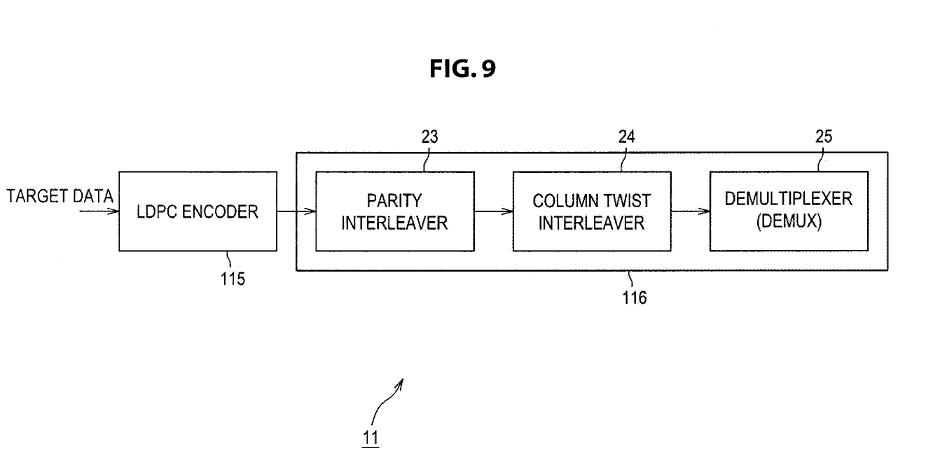

FIG. 9 illustrates a configuration example of the bit interleaver 116 of FIG. 8.

The bit interleaver 116 is a data processing device that interleaves data and includes the parity interleaver 23, the column twist interleaver 24, and a demultiplexer (DEMUX) 25. Here, the bit interleaver 116 can be configured without including one or both of the parity interleaver 23 and the column twist interleaver 24.

The parity interleaver 23 performs parity interleave for interleaving the parity bits of the LDPC code supplied from the LDPC encoder 115 into positions of other parity bits and supplies the LDPC code after the parity interleave to the column twist interleaver 24.

The column twist interleaver 24 performs the column twist interleave with respect to the LDPC code supplied from the parity interleaver 23 and supplies the LDPC code after the column twist interleave to the demultiplexer 25.

That is, in the QAM encoder 117 of FIG. 8, the code bits of one or more bits of the LDPC code are mapped to the signal point representing one symbol of the orthogonal modulation and are transmitted.

In the column twist interleaver 24, the column twist interleave to be described later is performed as rearrangement processing for rearranging the code bits of the LDPC code supplied from the parity interleaver 23, such that a plurality of code bits of the LDPC code corresponding to 1 in any one row of the parity check matrix used by the LDPC encoder 115 are not included in one symbol.

The demultiplexer 25 executes interchange processing for interchanging positions of two or more code bits of the LDPC code becoming the symbol, with respect to the LDPC code supplied from the column twist interleaver 24, and obtains an LDPC code in which tolerance against the AWGN is reinforced. In addition, the demultiplexer 25 supplies two or more code bits of the LDPC code obtained by the interchange processing as the symbol to the QAM encoder 117 (FIG. 8).

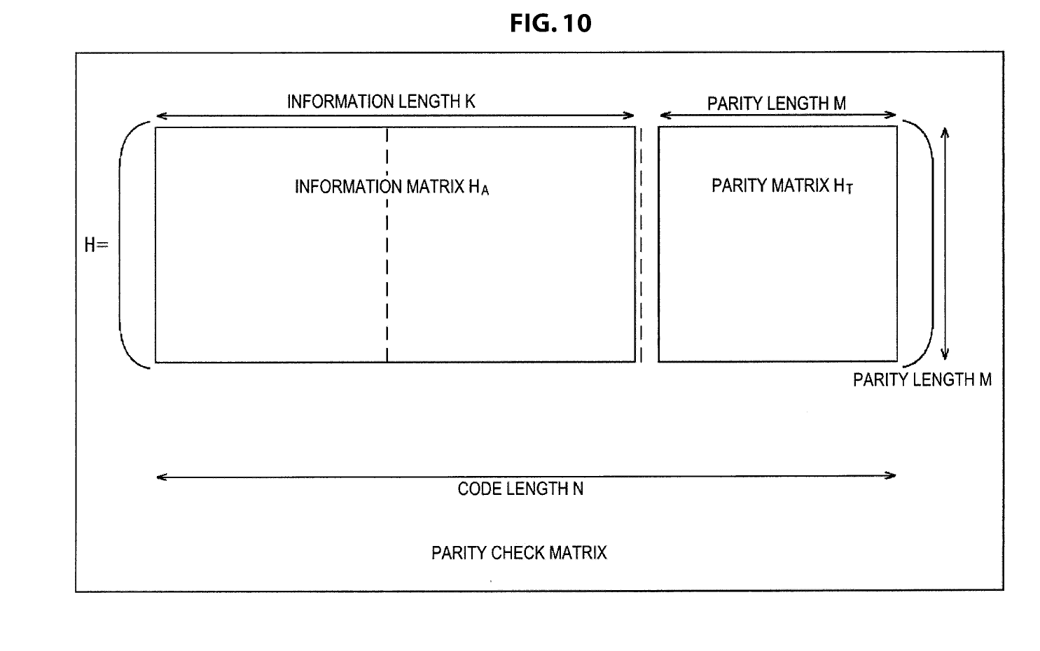

Next, FIG. 10 illustrates the parity check matrix H that is used for LDPC encoding by the LDPC encoder 115 of FIG. 8.

The parity check matrix H becomes an LDGM (Low-Density Generation Matrix) structure and can be represented by an expression H=[H_{A}|H_{T}] (a matrix in which elements of the information matrix H_{A} are set to left elements and elements of the parity matrix H_{T} are set to right elements), using an information matrix H_{A} of a portion corresponding to information bits among the code bits of the LDPC code and a parity matrix H_{T} corresponding to the parity bits.

In this case, a bit number of the information bits among the code bits of one LDPC code (one code word) and a bit number of the parity bits are referred to as an information length K and a parity length M, respectively, and a bit number of the code bits of one LDPC code is referred to as a code length N (=K+M).

The information length K and the parity length M of the LDPC code having the certain code length N are determined by an encoding rate. The parity check matrix H becomes a matrix in which row×column is M×N. The information matrix H_{A} becomes a matrix of M×K and the parity matrix H_{T} becomes a matrix of M×M.

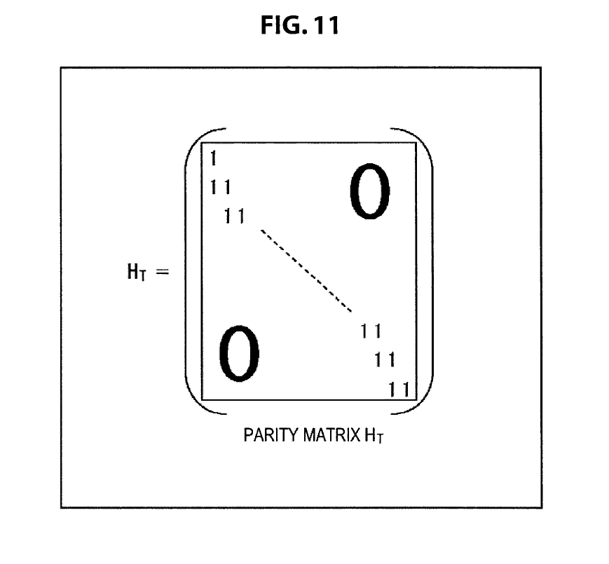

FIG. 11 illustrates the parity matrix H_{T} of the parity check matrix H of the LDPC code that is defined in the standard of the DVB-S.2, the DVB-T.2, and the DVB-C.2.

The parity matrix H_{T} of the parity check matrix H of the LDPC code that is defined in the standard of the DVB-T.2 or the like becomes a staircase structure matrix (lower bidagonal matrix) in which elements of 1 are arranged in a staircase shape, as illustrated in FIG. 11. The row weight of the parity matrix H_{T} becomes 1 with respect to the first row and becomes 2 with respect to the remaining rows. The column weight becomes 1 with respect to the final column and becomes 2 with respect to the remaining columns.

As described above, the LDPC code of the parity check matrix H in which the parity matrix H_{T} becomes the staircase structure can be easily generated using the parity check matrix H.

That is, the LDPC code (one code word) is represented by a row vector c and a column vector obtained by transposing the row vector is represented by C^{T}. In addition, a portion of information bits of the row vector c to be the LDPC code is represented by a row vector A and a portion of the parity bits is represented by a row vector T.

The row vector c can be represented by an expression c=[A|T] (a row vector in which elements of the row vector A are set to left elements and elements of the row vector T are set to right elements), using the row vector A corresponding to the information bits and the row vector T corresponding to the parity bits.

In the parity check matrix H and the row vector c=[A|T] corresponding to the LDPC code, it is necessary to satisfy an expression Hc^{T}=0. The row vector T that corresponds to the parity bits constituting the row vector c=[A|T] satisfying the expression Hc^{T}=0 can be sequentially calculated by setting elements of each row to 0, sequentially (in order) from elements of a first row of the column vector Hc^{T} in the expression Hc^{T}=0, when the parity matrix H_{T} of the parity check matrix H=[H_{A}|H_{T}] becomes the staircase structure illustrated in FIG. 11.

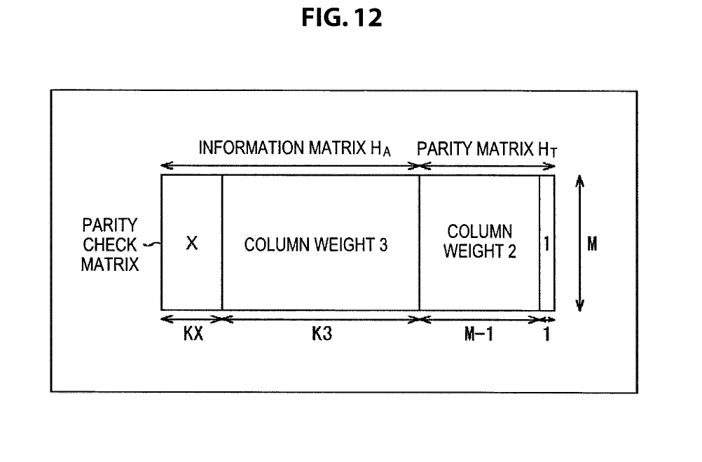

FIG. 12 is an illustration of the parity check matrix H of the LDPC code that is defined in the standard of the DVB-T.2 or the like.

The column weight becomes X with respect KX columns from a first column of the parity check matrix H of the LDPC code defined in the standard of the DVB-T.2 or the like, becomes 3 with respect to the following K3 columns, becomes 2 with respect to the following (M−1) columns, and becomes 1 with respect to a final column.

In this case, KX+K3+M−1+1 is equal to the code length N.

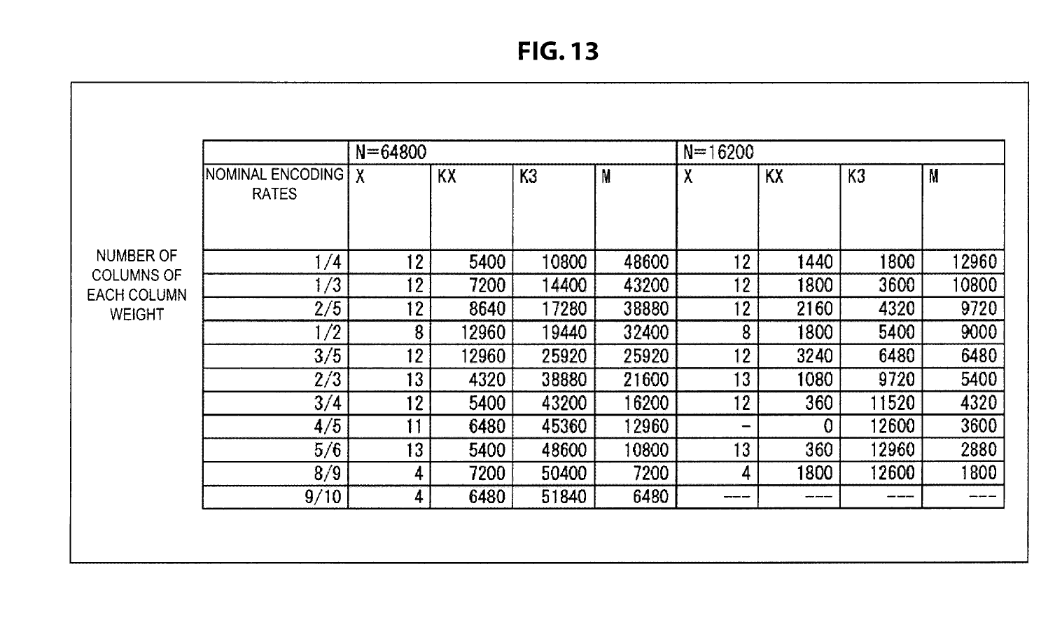

FIG. 13 is an illustration of column numbers KX, K3, and M and a column weight X, with respect to each encoding rate r of the LDPC code defined in the standard of the DVB-T.2 or the like.

In the standard of the DVB-T.2 or the like, LDPC codes that have code lengths N of 64800 bits and 16200 bits are defined.

With respect to the LDPC code having the code length N of 64800 bits, 11 encoding rates (nominal rates) of 1/4, 1/3, 2/5, 1/2, 3/5, 2/3, 3/4, 4/5, 5/6, 8/9, and 9/10 are defined. With respect to the LDPC code having the code length N of 16200 bits, 10 encoding rates of 1/4, 1/3, 2/5, 1/2, 3/5, 2/3, 3/4, 4/5, 5/6, and 8/9 are defined.

Hereinafter, the code length N of the 64800 bits is referred to as 64 kbits and the code length N of the 16200 is referred to as 16 kbits.

With respect to the LDPC code, it is known that an error rate is low in a code bit corresponding to a column of which a column weight of the parity check matrix H is large.

In the parity check matrix H that is illustrated in FIGS. 12 and 13 and is defined in the standard of the DVB-T.2 or the like, a column weight of a column of a head side (left side) tends to be large. Therefore, with respect to the LDPC code corresponding to the parity check matrix H, a code bit of a head side tends to be strong for error (there is tolerance against the error) and a code bit of an ending side tends to be weak for the error.

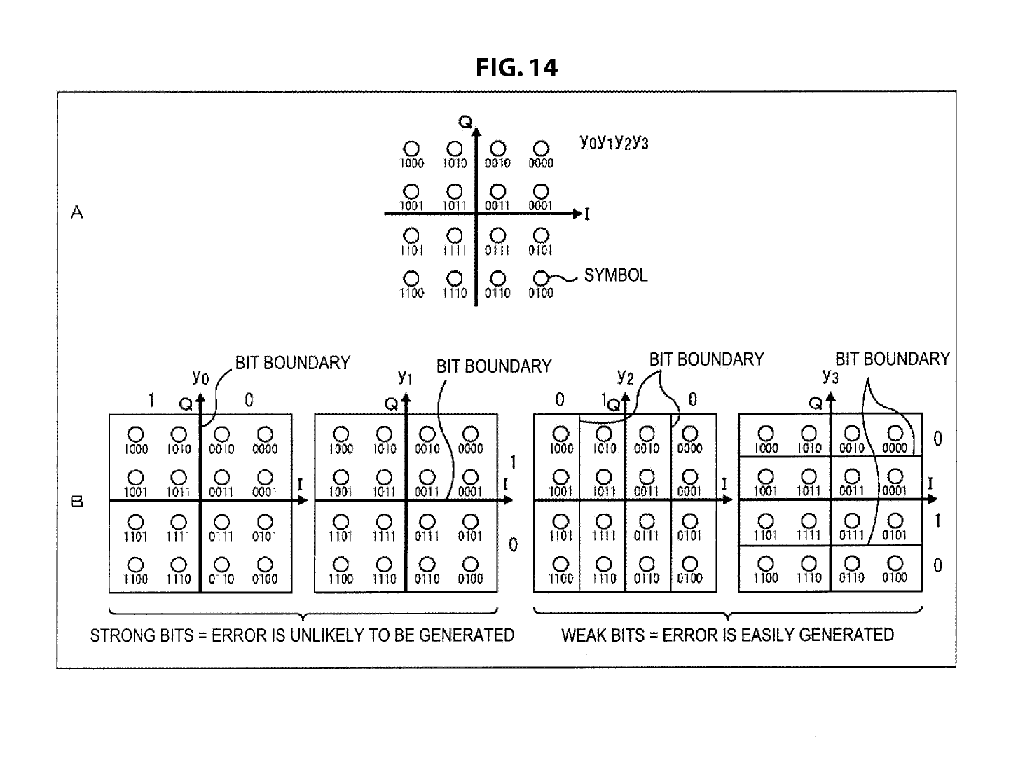

Next, FIG. 14 illustrates an arrangement example of (signal points corresponding to) 16 symbols on an IQ plane, when 16QAM is performed by the QAM encoder 117 of FIG. 8.

That is, A of FIG. 14 illustrates symbols of the 16QAM of the DVB-T.2.

In the 16QAM, one symbol is represented by 4 bits and 16 symbols (=2⁴) exist. The 16 symbols are arranged such that an I direction×a Q direction becomes a 4×4 square shape, on the basis of an original point of the IQ plane.

If an (i+1)-th bit from a most significant bit of a bit string represented by one symbol is represented as a bit yᵢ, the 4 bits represented by one symbol of the 16QAM are can be represented as bits y₀, y₁, y₂, and y₃, respectively, sequentially from the most significant bit. When a modulation method is the 16QAM, 4 bits of code bits of the LDPC code become a symbol (symbol value) of 4 bits y₀ to y₃ (symbolized).

B of FIG. 14 illustrates a bit boundary with respect to each of the 4 bits (hereinafter, referred to as symbol bits) y₀ to y₃ represented by the symbol of the 16QAM.

In this case, a bit boundary with respect to the symbol bit yᵢ (in FIG. 14, i=0, 1, 2, and 3) means a boundary of a symbol of which a symbol bit yᵢ becomes 0 and a symbol of which a symbol bit yᵢ becomes 1.

As illustrated by B of FIG. 14, only one place of the Q axis of the IQ plane becomes a bit boundary with respect to the most significant symbol bit y₀ of the 4 symbol bits y₀ to y₃ represented by the symbol of the 16QAM and only one place of the I axis of the IQ plane becomes a bit boundary with respect to the second (second from the most significant bit) symbol bit y₁.

With respect to the third symbol bit y₂, two places of a place between first and second columns from the left side and a place between third and four columns, among the 4×4 symbols, become bit boundaries.

With respect to the fourth symbol bit y₃, two places of a place between first and second rows from the upper side and a place between third and four rows, among the 4×4 symbols, become bit boundaries.

In the symbol bits yᵢ that are represented by the symbols, when the number of symbols apart from the bit boundaries is large, the error is difficult to be generated (the error probability is low) and when the number of symbols close to the bit boundaries is large, the error is easily generated (the error probability is high).

If the bits (strong for the error) in which the error is difficult to be generated are referred to as “strong bits” and the bits (weak for the error) in which the error is easily generated are referred to as “weak bits”, with respect to the 4 symbol bits y₀ to y₃ of the symbol of the 16QAM, the most significant symbol bit y₀ and the second symbol bit y₁ become the strong bits and the third symbol bit y₂ and the fourth symbol bit y₃ become the weak bits.

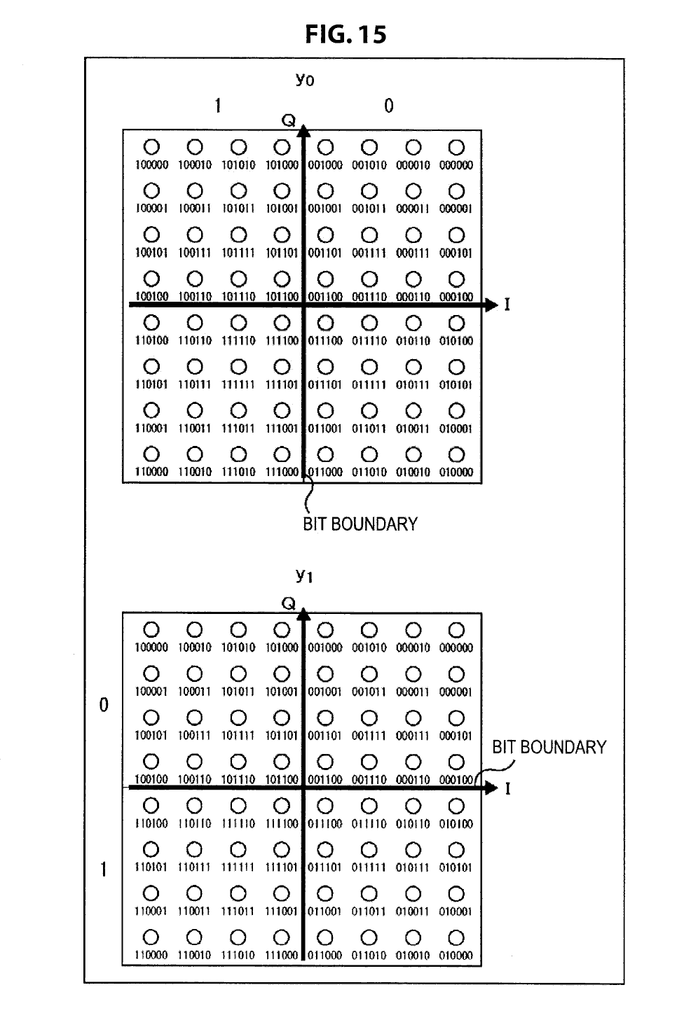

FIGS. 15 to 17 illustrate an arrangement example of (signal points corresponding to) 64 symbols on an IQ plane, that is, symbols of the 16QAM of the DVB-T.2, when the 64QAM is performed by the QAM encoder 117 of FIG. 8.

In the 64QAM, one symbol represents 6 bits and 64 symbols (=2⁶) exist. The 64 symbols are arranged such that an I direction×a Q direction becomes an 8×8 square shape, on the basis of an original point of the IQ plane.

The symbol bits of one symbol of the 64QAM can be represented as y₀, y₁, y₂, y₃, y₄, and y₅, sequentially from the most significant bit. When the modulation method is the 64QAM, 6 bits of code bits of the LDPC code become a symbol of symbol bits y₀ to y₅ of 6 bits.

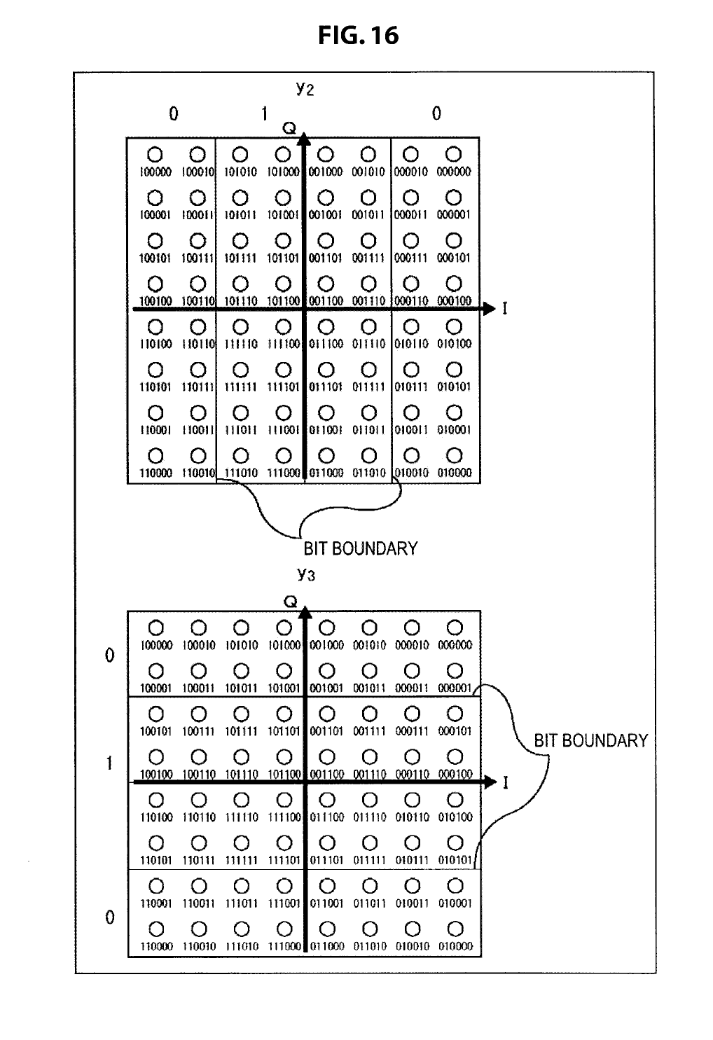

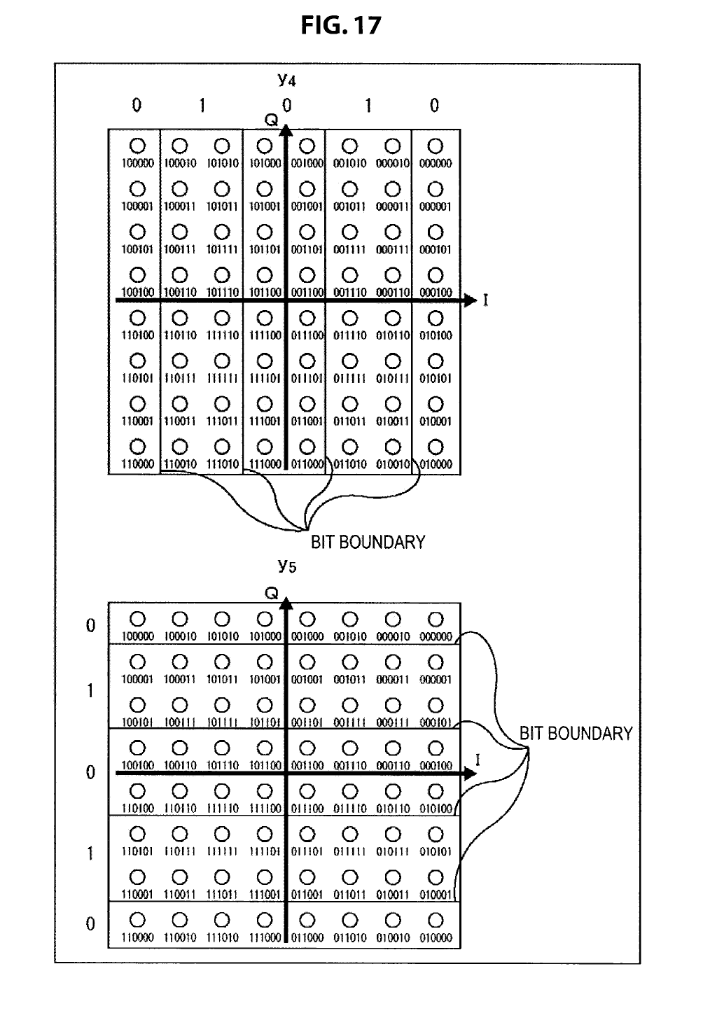

In this case, FIG. 15 illustrates a bit boundary with respect to each of the most significant symbol bit y₀ and the second symbol bit y₁ among the symbol bits y₀ to y₅ of the symbol of the 64QAM, FIG. 16 illustrates a bit boundary with respect to each of the third symbol bit y₂ and the fourth symbol bit y₃, and FIG. 17 illustrates a bit boundary with respect to each of the fifth symbol bit y₄ and the sixth symbol bit y₅.

As illustrated in FIG. 15, the bit boundary with respect to each of the most significant symbol bit y₀ and the second symbol bit y₁ becomes one place. As illustrated in FIG. 16, the bit boundaries with respect to each of the third symbol bit y₂ and the fourth symbol bit y₃ become two places. As illustrated in FIG. 17, the bit boundaries with respect to each of the fifth symbol bit y₄ and the sixth symbol bit y₅ become four places.

Therefore, with respect to the symbol bits y₀ to y₅ of the symbol of the 64QAM, the most significant symbol bit y₀ and the second symbol bit y₁ become strong bits and the third symbol bit y₂ and the fourth symbol bit y₃ become next strong bits. In addition, the fifth symbol bit y₄ and the sixth symbol bit y₅ become weak bits.

From FIGS. 14 and 15 to 17, it can be known that, with respect to the symbol bits of the symbol of the orthogonal modulation, the upper bits tend to become the strong bits and the lower bits tend to become the weak bits.

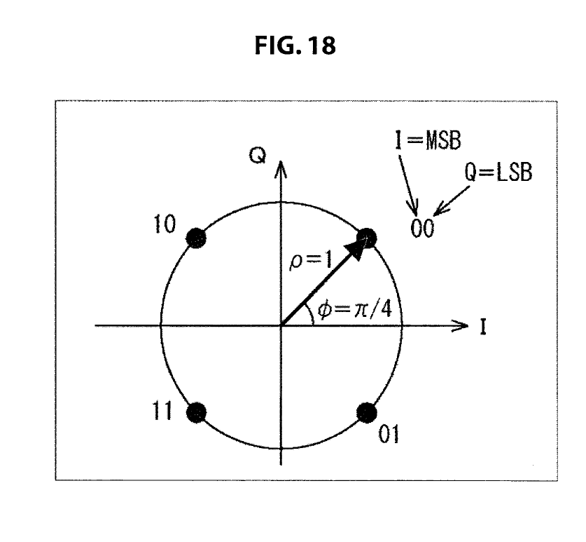

FIG. 18 is an illustration of an example of arrangement on the IQ plane of (signal points corresponding to) 4 symbols in a case where a satellite circuit is adopted as the communication path 13 (FIG. 7) and QPSK is performed in the QAM encoder 117 of FIG. 8, that is, for example, an illustration of symbols of QPSK of DVB-S.2.

In QPSK of DVB-S.2, a symbol is mapped on any of 4 signal points on the circumference of a circle whose radius centering on the origin of the IQ plane is ρ.

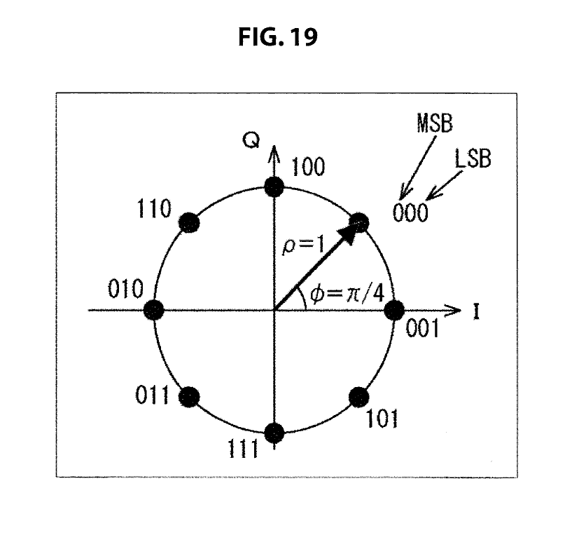

FIG. 19 is an illustration of an example of arrangement on the IQ plane of 8 symbols in a case where a satellite circuit is adopted as the communication path 13 (FIG. 7) and 8PSK is performed in the QAM encoder 117 of FIG. 8, that is, for example, an illustration of symbols of 8PSK of DVB-S.2.

In 8PSK of DVB-S.2, a symbol is mapped on any of 8 signal points on the circumference of a circle whose radius centering on the origin of the IQ plane is ρ.

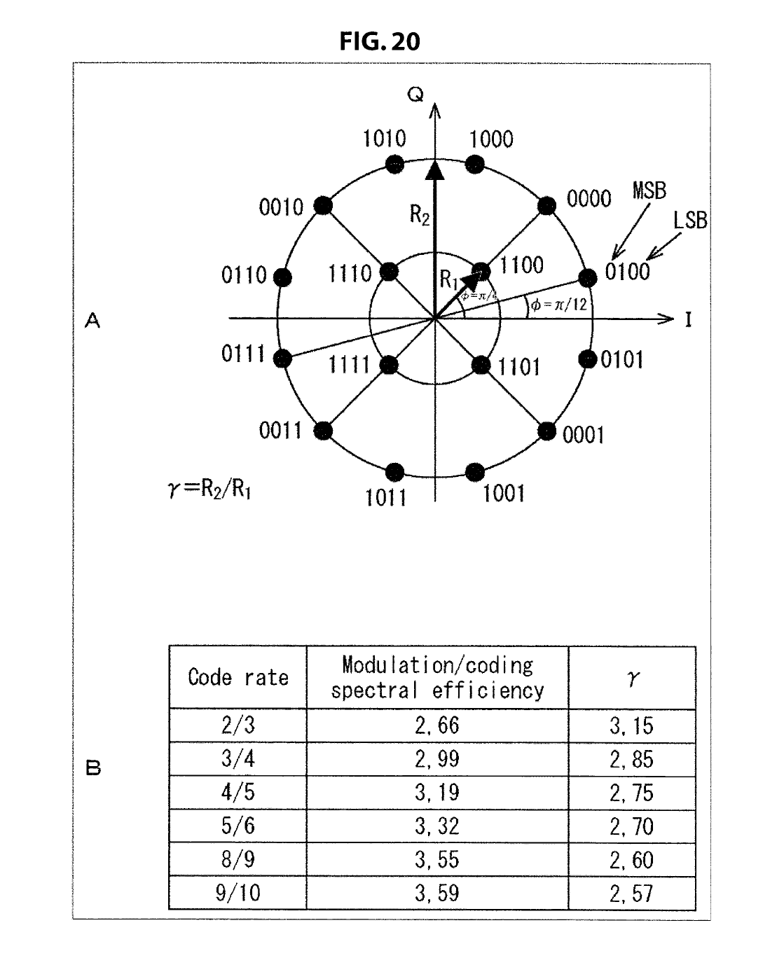

FIG. 20 is an example of arrangement on the IQ plane of 16 symbols in a case where a satellite circuit is adopted as the communication path 13 (FIG. 7) and 16APSK is performed in the QAM encoder 117 of FIG. 8, that is, for example, an illustration of symbols of 16APSK of DVB-S.2.

A of FIG. 20 illustrates the arrangement of signal points of 16APSK of DVB-S.2.

In 16APSK of DVB-S.2, a symbol is mapped on any of totally 16 signal points of 4 signal points on the circumference of a circle whose radius centering on the origin of the IQ plane is R₁ and 12 signal points on the circumference of a circle whose radius is R₂ (>R₁).

B of FIG. 20 illustrates γ=R₂/R₁ which is the ratio of radiuses R₂ and R₁ in the arrangement of signal points of 16APSK of DVB-S.2.

In the arrangement of signal points of 16APSK of DVB-S.2, ratio γ of radiuses R₂ and R₁ varies depending on each encoding rate.

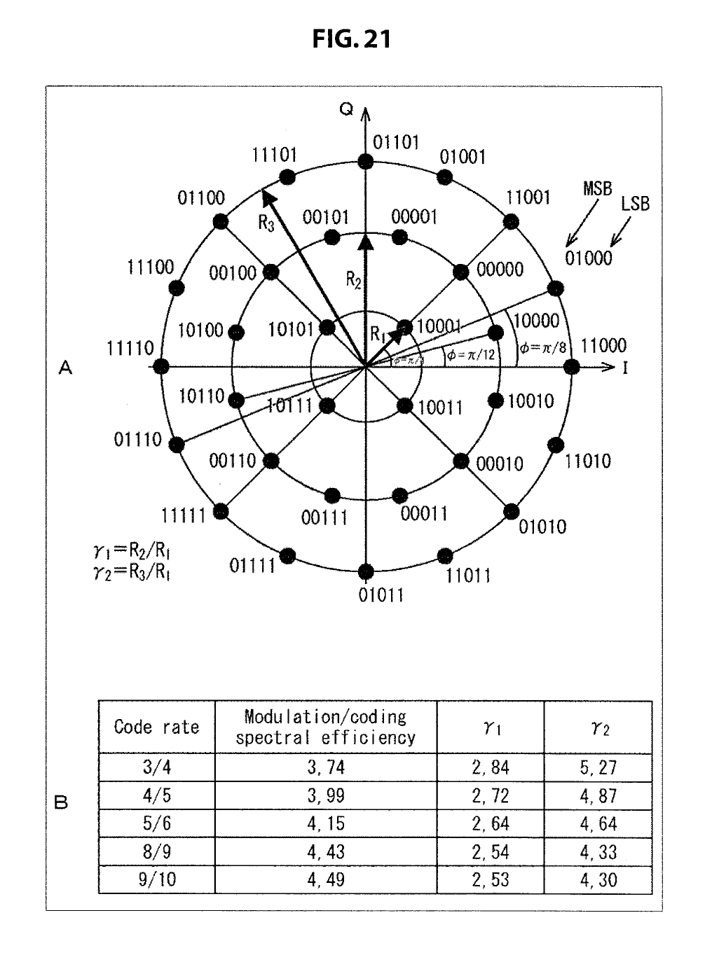

FIG. 21 is an example of arrangement on the IQ plane of 32 symbols in a case where a satellite circuit is adopted as the communication path 13 (FIG. 7) and 32APSK is performed in the QAM encoder 117 of FIG. 8, that is, for example, an illustration of symbols of 32APSK of DVB-S.2.

A of FIG. 21 illustrates the arrangement of signal points of 32APSK of DVB-S.2.

In 32APSK of DVB-S.2, a symbol is mapped on any of totally 32 signal points of 4 signal points on the circumference of a circle whose radius centering on the origin of the IQ plane is R₁, 12 signal points on the circumference of a circle whose radius is R₂ (>R₁) and 16 signal points on the circumference of a circle whose radius is R₃ (>R₂).

B of FIG. 21 illustrates γ₁=R₂/R₁ which is the ratio of radiuses R₂ and R₁ in the arrangement of signal points of 32APSK of DVB-S.2 and γ₂=R₃/R₁ which is the ratio of radiuses R₃ and R₁.

In the arrangement of signal points of 32APSK of DVB-S.2, ratio γ₁ of radiuses R₂ and R₁ and ratio γ₂ of radiuses R₃ and R₁ vary depending on each encoding rate.

Even for symbol bits of the symbols of each quadrature modulation (QPSK, 8PSK, 16APSK and 32APSK) of DVB-S.2 illustrating the arrangement of signal points in FIG. 18 to FIG. 21, similar to the cases of FIG. 14 to FIG. 17, there are strong bits and weak bits.

As described in FIGS. 12 and 13, with respect to the LDPC code output by the LDPC encoder 115 (FIG. 8), code bits strong for the error and code bits weak for the error exist.

As described in FIGS. 14 to 21, with respect to the symbol bits of the symbol of the orthogonal modulation performed by the QAM encoder 117, the strong bits and the weak bits exist.

Therefore, if the code bits of the LDPC code strong for the error are allocated to the weak symbol bits of the symbol of the orthogonal modulation, tolerance against the error is lowered as a whole.

Therefore, an interleaver that interleaves the code bits of the LDPC code in such a manner that the code bits of the LDPC code weak for the error are allocated to the strong bits (symbol bits) of the symbol of the orthogonal modulation is suggested.

The demultiplexer 25 of FIG. 9 can execute processing of the interleaver.

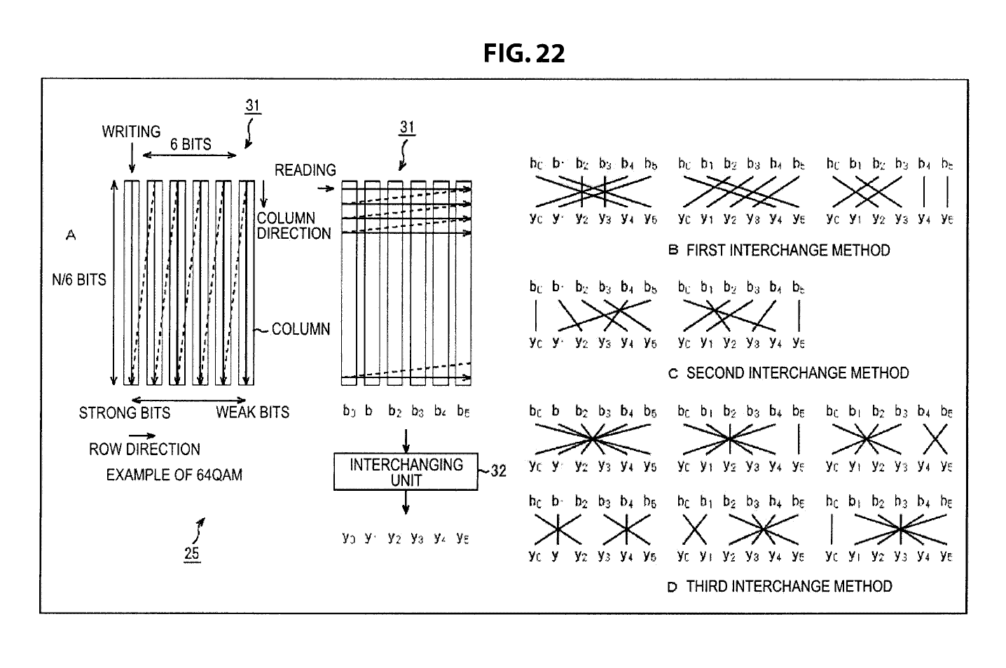

FIG. 22 is an illustration of processing of the demultiplexer 25 of FIG. 9.

That is, A of FIG. 18 illustrates a functional configuration example of the demultiplexer 25.

The demultiplexer 25 includes a memory 31 and an interchanging unit 32.

An LDPC code is supplied from the LDPC encoder 115 to the memory 31.

The memory 31 has a storage capacity to store mb bits in a row (transverse) direction and store N/(mb) bits in a column (longitudinal) direction. The memory 31 writes code bits of the LDPC code supplied thereto in the column direction, reads the code bits in the row direction, and supplies the code bits to the interchanging unit 32.

In this case, N (=information length K+parity length M) represents a code length of the LDPC code, as described above.

In addition, m represents a bit number of the code bits of the LDPC code that becomes one symbol and b represents a multiple that is a predetermined positive integer and is used to perform integral multiplication of m. As described above, the demultiplexer 25 symbolizes the code bits of the LDPC code. However, the multiple b represents the number of symbols obtained by one-time symbolization of the demultiplexer 25.

A of FIG. 22 illustrates a configuration example of the demultiplexer 25 in a case where a modulation method is 64QAM or the like in which mapping is performed on any of 64 signal points, and therefore bit number m of the code bits of the LDPC code becoming one symbol is 6 bits.

In A of FIG. 22, the multiple b becomes 1. Therefore, the memory 31 has a storage capacity in which a column direction×a row direction is N/(6×1)×(6×1) bits.

In this case, a storage region of the memory 31 in which the row direction is 1 bit and which extends in the column direction is appropriately referred to as a column hereinafter. In A of FIG. 22, the memory 31 includes 6 (=6×1) columns.

In the demultiplexer 25, writing of the code bits of the LDPC code in a downward direction (column direction) from the upper side of the columns constituting the memory 31 is performed toward the columns of a rightward direction from the left side.

If writing of the code bits ends to the bottom of the rightmost column, the code bits are read in a unit of 6 bits (mb bits) in the row direction from a first row of all the columns constituting the memory 31 and are supplied to the interchanging unit 32.

The interchanging unit 32 executes interchange processing for interchanging positions of the code bits of the 6 bits from the memory 31 and outputs 6 bits obtained as a result as 6 symbol bits y₀, y₁, y₂, y₃, y₄, and y₅ representing one symbol of the 64QAM.

That is, the code bits of the mb bits (in this case, 6 bits) are read from the memory 31 in the row direction. However, if the i-th (i=0, 1, . . . , and mb−1) bit from the most significant bit, of the code bits of the mb bits read from the memory 31, is represented as a bit bᵢ, the code bits of the 6 bits that are read from the memory 31 in the row direction can be represented as bits b₀, b₁, b₂, b₃, b₄, and b₅, sequentially from the most significant bit.

With the relation of the column weights described in FIGS. 12 and 13, the code bit in a direction of the bit b₀ becomes a code bit strong for the error and the code bit in a direction of the bit b₅ becomes a code bit weak for the error.

In the interchanging unit 32, interchange processing for interchanging the positions of the code bits b₀ to b₅ of the 6 bits from the memory 31, such that the code bits weak for the error among the code bits b₀ to b₅ of the 6 bits from the memory 31 are allocated to the strong bits among the symbol bits y₀ to y₅ of one symbol of the 64QAM, can be executed.

In this case, as interchange methods for interchanging the code bits b₀ to b₅ of the 6 bits from the memory 31 and allocating the code bits b₀ to b₅ of the 6 bits to the 6 symbol bits y₀ to y₅ representing one symbol of the 64QAM, various methods are suggested from individual companies.

B of FIG. 22 illustrates a first interchange method, C of FIG. 22 illustrates a second interchange method, and D of FIG. 22 illustrates a third interchange method.

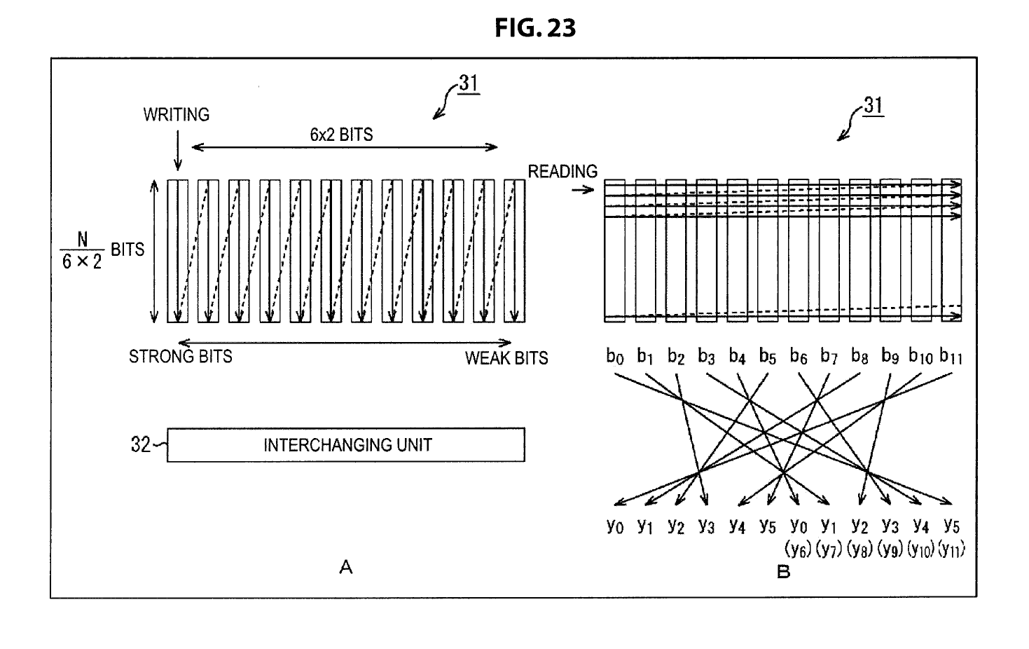

In B of FIG. 22 to D of FIG. 22 (and FIG. 23 to be described later), a line segment coupling the bits bᵢ and yⱼ means that the code bit bᵢ is allocated to the symbol bit yⱼ of the symbol (interchanged with a position of the symbol bit yⱼ).

As the first interchange method of B of FIG. 22, to adopt any one of three kinds of interchange methods is suggested. As the second interchange method of C of FIG. 22, to adopt any one of two kinds of interchange methods is suggested.

As the third interchange method of D of FIG. 22, to sequentially select six kinds of interchange methods and use the interchange method is suggested.

FIG. 23 illustrates a configuration example of the demultiplexer 25 in a case where a modulation method is 64QAM or the like in which mapping is performed on any of 64 signal points (therefore, bit number m of the code bits of the LDPC code mapped on one symbol is 6 bits as well as FIG. 22) and multiple b is 2, and the fourth interchange method.

When the multiple b is 2, the memory 31 has a storage capacity in which a column direction×a row direction is N/(6×2)×(6×2) bits and includes 12 (=6×2) columns.

A of FIG. 23 illustrates a sequence of writing the LDPC code to the memory 31.

In the demultiplexer 25, as described in FIG. 22, writing of the code bits of the LDPC code in a downward direction (column direction) from the upper side of the columns constituting the memory 31 is performed toward the columns of a rightward direction from the left side.

If writing of the code bits ends to the bottom of the rightmost column, the code bits are read in a unit of 12 bits (mb bits) in the row direction from a first row of all the columns constituting the memory 31 and are supplied to the interchanging unit 32.

The interchanging unit 32 executes interchange processing for interchanging positions of the code bits of the 12 bits from the memory 31 using the fourth interchange method and outputs 12 bits obtained as a result as 12 bits representing two symbols (b symbols) of the 64QAM, that is, six symbol bits y0, y₁, y₂, y₃, y₄, and y₅ representing one symbol of the 64QAM and six symbol bits y₀, y₁, y₂, y₃, y₄, and y₅ representing a next one symbol.

In this case, B of FIG. 23 illustrates the fourth interchange method of the interchange processing by the interchanging unit 32 of A of FIG. 23.

When the multiple b is 2 (or 3 or more), in the interchange processing, the code bits of the mb bits are allocated to the symbol bits of the mb bits of the b consecutive symbols. In the following explanation including the explanation of FIG. 23, the (i+1)-th bit from the most significant bit of the symbol bits of the mb bits of the b consecutive symbols is represented as a bit (symbol bit) yᵢ, for the convenience of explanation.

What kind of code bits are appropriate to be interchanged, that is, the improvement of the error rate in the AWGN communication path is different according to the encoding rate or the code length of the LDPC code and the modulation method.

[Parity Interleave]

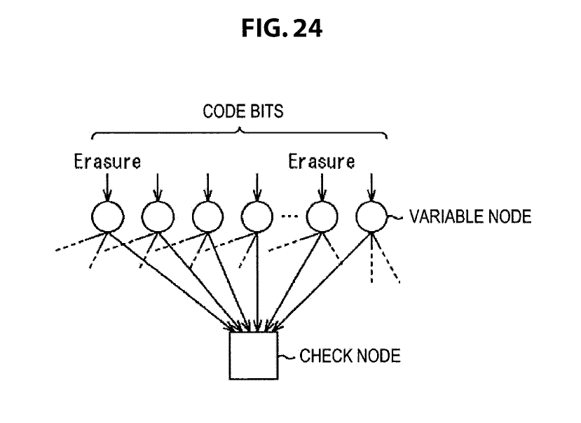

Next, the parity interleave by the parity interleaver 23 of FIG. 9 will be described with reference to FIGS. 24 to 26.

FIG. 24 illustrates (a part of) a Tanner graph of the parity check matrix of the LDPC code.

As illustrated in FIG. 24, if a plurality of, for example, two variable nodes among (the code bits corresponding to) the variable nodes connected to the check node simultaneously become the error such as the erasure, the check node returns a message in which the probability of a value being 0 and the probability of a value being 1 are equal to each other, to all the variable nodes connected to the check node. For this reason, if the plurality of variable nodes connected to the same check node simultaneously become the erasure, decoding performance is deteriorated.

Meanwhile, the LDPC code that is output by the LDPC encoder 115 of FIG. 8 and is defined in the standard of the DVB-S.2 or the like is an IRA code and the parity matrix H_{T} of the parity check matrix H becomes a staircase structure, as illustrated in FIG. 11.

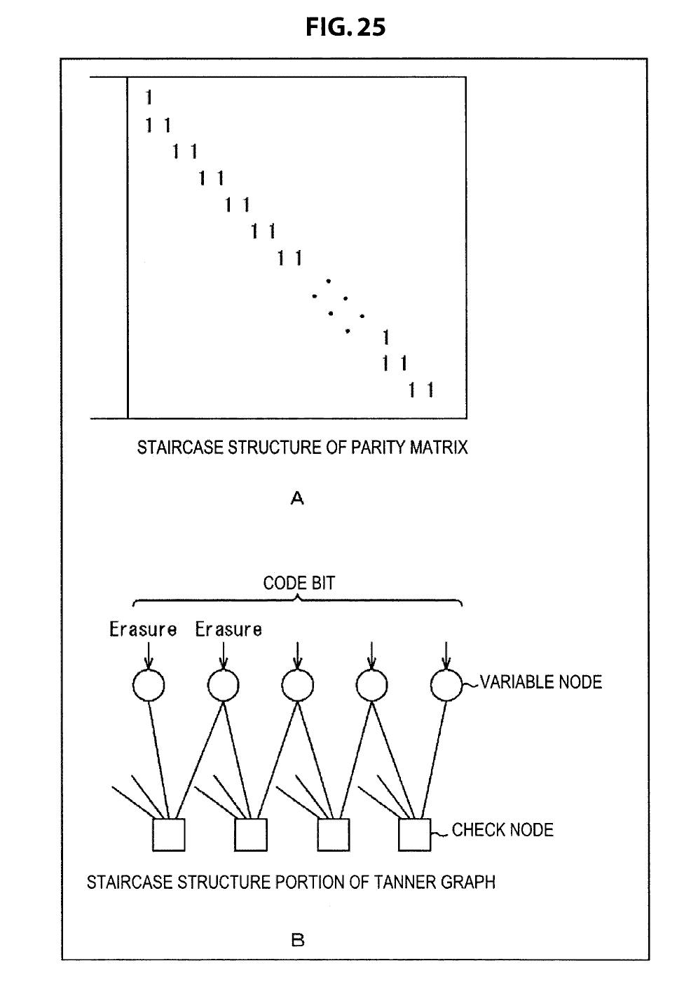

FIG. 25 illustrates the parity matrix H_{T} becoming the staircase structure and a Tanner graph corresponding to the parity matrix H_{T}.

That is, A of FIG. 25 illustrates the parity matrix HT becoming the staircase structure and B of FIG. 25 illustrates the Tanner graph corresponding to the parity matrix HT of A of FIG. 25.

In the parity matrix H_{T} with a staircase structure, elements of 1 are adjacent in each row (excluding the first row). Therefore, in the Tanner graph of the parity matrix H_{T}, two adjacent variable nodes corresponding to a column of two adjacent elements in which the value of the parity matrix H_{T} is 1 are connected with the same check node.

Therefore, when parity bits corresponding to two above-mentioned adjacent variable nodes become errors at the same time by burst error and erasure, and so on, the check node connected with two variable nodes (variable nodes to find a message by the use of parity bits) corresponding to those two parity bits that became errors returns message that the probability with a value of 0 and the probability with a value of 1 are equal probability, to the variable nodes connected with the check node, and therefore the performance of decoding is deteriorated. Further, when the burst length (bit number of parity bits that continuously become errors) becomes large, the number of check nodes that return the message of equal probability increases and the performance of decoding is further deteriorated.

Therefore, the parity interleaver 23 (FIG. 9) performs the parity interleave for interleaving the parity bits of the LDPC code from the LDPC encoder 115 into positions of other parity bits, to prevent the decoding performance from being deteriorated.

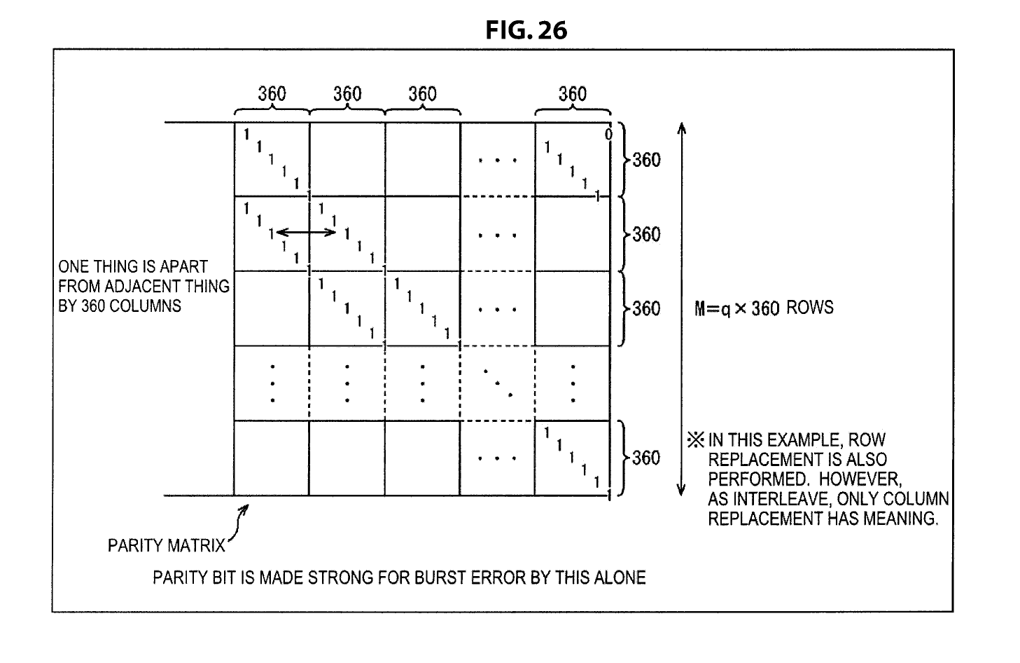

FIG. 26 illustrates the parity matrix H_{T} of the parity check matrix H corresponding to the LDPC code after the parity interleave performed by the parity interleaver 23 of FIG. 9.

In this case, the information matrix H_{A} of the parity check matrix H corresponding to the LDPC code that is output by the LDPC encoder 115 and is defined in the standard of the DVB-S.2 or the like becomes a cyclic structure.

The cyclic structure means a structure in which a certain column is matched with a column obtained by cyclically shifting another column. For example, the cyclic structure includes a structure in which a position of 1 of each row of P columns becomes a position obtained by cyclically shifting a first column of the P columns in a column direction by a value proportional to a value q obtained by dividing a parity length M, for every P columns. Hereinafter, the P columns in the cyclic structure are appropriately referred to as a column number of a unit of the cyclic structure.

As an LDPC code defined in a standard such as DVB-S.2, as described in FIG. 12 and FIG. 13, there are two kinds of LDPC codes whose code length N is 64800 bits and 16200 bits, and, for both of those two kinds of LDPC codes, the column number P which is a unit of a cyclic structure is defined as 360 which is one of divisors excluding 1 and M among the divisors of the parity length M.

The parity length M becomes a value other than primes represented by an expression M=q×P=q×360, using a value q different according to the encoding rate. Therefore, similar to the column number P of the unit of the cyclic structure, the value q is one other than 1 and M among the divisors of the parity length M and is obtained by dividing the parity length M by the column number P of the unit of the cyclic structure (the product of P and q to be the divisors of the parity length M becomes the parity length M).

As described above, when information length is assumed to be K, an integer equal to or greater than 0 and less than P is assumed to be x and an integer equal to or greater than 0 and less than q is assumed to be y, the parity interleaver 23 interleaves the K+qx+y+1-th code bit among code bits of an LDPC code of N bits to the position of the K+Py+x+1-th code bit as parity interleave.

Since both of the K+qx+y+1-th code bit and the K+Py+x+1-th code bit are code bits after the K+1-th one, they are parity bits, and therefore the positions of the parity bits of the LDPC code are moved according to the parity interleave.

According to the parity interleave, (the parity bits corresponding to) the variable nodes connected to the same check node are separated by the column number P of the unit of the cyclic structure, that is, 360 bits in this case. For this reason, when the burst length is less than 360 bits, the plurality of variable nodes connected to the same check node can be prevented from simultaneously becoming the error. As a result, tolerance against the burst error can be improved.

The LDPC code after the interleave for interleaving the (K+qx+y+1)-th code bit into the position of the (K+Py+x+1)-th code bit is matched with an LDPC code of a parity check matrix (hereinafter, referred to as a transformed parity check matrix) obtained by performing column replacement for replacing the (K+qx+y+1)-th column of the original parity check matrix H with the (K+Py+x+1)-th column.

In the parity matrix of the transformed parity check matrix, as illustrated in FIG. 26, a pseudo cyclic structure that uses the P columns (in FIG. 26, 360 columns) as a unit appears.

In this case, the pseudo cyclic structure means a structure in which a cyclic structure is formed except for a part thereof. The transformed parity check matrix that is obtained by performing the column replacement corresponding to the parity interleave with respect to the parity check matrix of the LDPC code defined in the standard of the DVB-S.2 or the like becomes the pseudo cyclic structure, not the (perfect) cyclic structure, because the number of elements of 1 is less than 1 (elements of 0 exist) in a portion (shifted matrix to be described later) of 360 rows×360 columns of a right corner portion thereof.

The transformed parity check matrix of FIG. 26 becomes a matrix that is obtained by performing the column replacement corresponding to the parity interleave and replacement (row replacement) of a row to configure the transformed parity check matrix with a constitutive matrix to be described later, with respect to the original parity check matrix H.

[Column Twist Interleave]

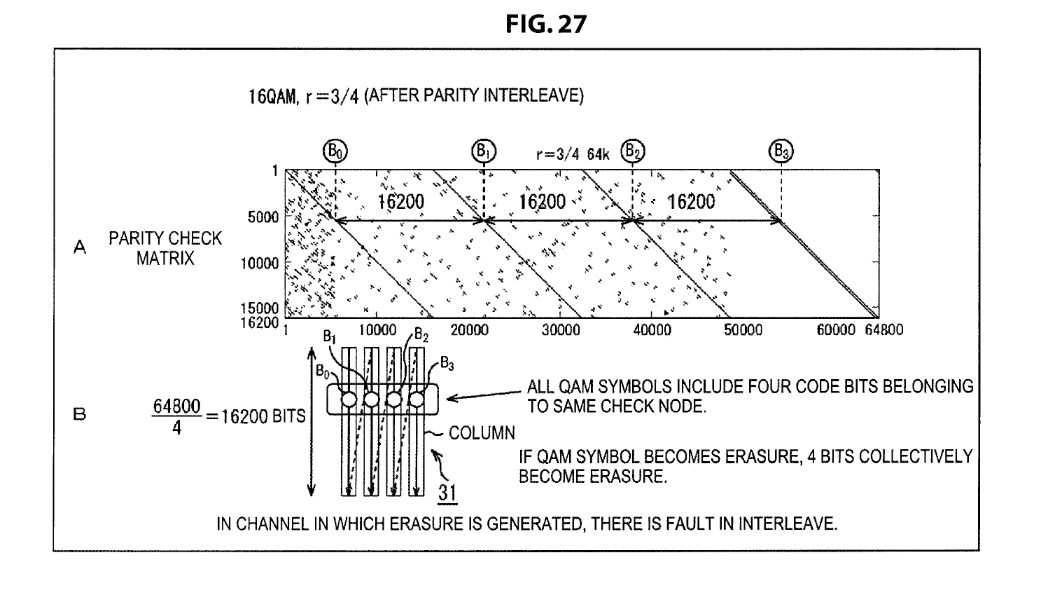

Next, column twist interleave corresponding to rearrangement processing by the column twist interleaver 24 of FIG. 9 will be described with reference to FIGS. 27 to 30.

In the transmitting device 11 of FIG. 8, one or more bits of the code bits of the LDPC code are transmitted as one symbol. That is, when two bits of the code bits are set as one symbol, the QPSK is used as the modulation method and when four bits of the code bits are set as one symbol, the APSK or the 16QAM is used as the modulation method.

As such, when the two or more bits of the code bits are transmitted as one symbol, if the erasure is generated in a certain symbol, all of the code bits of the symbol become the error (erasure).

Therefore, it is necessary to prevent the variable nodes corresponding to the code bits of one symbol from being connected to the same check node, in order to decrease the probability of (the code bits corresponding to) the plurality of variable nodes connected to the same check node simultaneously becoming the erasure to improve the decoding performance.

Meanwhile, as described above, in the parity check matrix H of the LDPC code that is output by the LDPC encoder 115 and is defined in the standard of the DVB-S.2 or the like, the information matrix H_{A} has the cyclic structure and the parity matrix H_{T} has the staircase structure. As described in FIG. 26, in the transformed parity check matrix to be the parity check matrix of the LDPC code after the parity interleave, the cyclic structure (in fact, the pseudo cyclic structure as described above) appears in the parity matrix.

FIG. 27 illustrates a transformed parity check matrix.

That is, A of FIG. 27 illustrates a transformed parity check matrix of a parity check matrix H of an LDPC code in which a code length N is 64800 bits and an encoding rate (r) is 3/4.

In A of FIG. 27, in the transformed parity check matrix, a position of an element of which a value becomes 1 is shown by a point (•).

B of FIG. 27 illustrates processing executed by the demultiplexer 25 (FIG. 9), with respect to the LDPC code of the transformed parity check matrix of A of FIG. 27, that is, the LDPC code after the parity interleave.

In B of FIG. 27, with an assumption that a modulation method is a method in which a symbol is mapped on any of 16 signal points such as 16APSK and 16QAM, the code bits of the LDPC code after the parity interleave are written in four columns forming the memory 31 of the demultiplexer 25 in the column direction.

The code bits that are written in the column direction in the four columns constituting the memory 31 are read in a unit of four bits in the row direction and become one symbol.

In this case, code bits B₀, B₁, B₂, and B₃ of the four bits that become one symbol may become code bits corresponding to 1 in any one row of the transformed parity check matrix of A of FIG. 27. In this case, the variable nodes that correspond to the code bits B₀, B₁, B₂, and B₃ are connected to the same check node.

Therefore, when the code bits B₀, B₁, B₂, and B₃ of the four bits of one symbol become the code bits corresponding to 1 in any one row of the transformed parity check matrix, if the erasure is generated in the symbol, an appropriate message may not be calculated in the same check node to which the variable nodes corresponding to the code bits B₀, B₁, B₂, and B₃ are connected. As a result, the decoding performance is deteriorated.

With respect to the encoding rates other than 3/4, the plurality of code bits corresponding to the plurality of variable nodes connected to the same check node may become one symbol of the APSK or the 16QAM, similar to the above case.

Therefore, the column twist interleaver 24 performs the column twist interleave for interleaving the code bits of the LDPC code after the parity interleave from the parity interleaver 23, such that the plurality of code bits corresponding to 1 in any one row of the transformed parity check matrix are not included in one symbol.

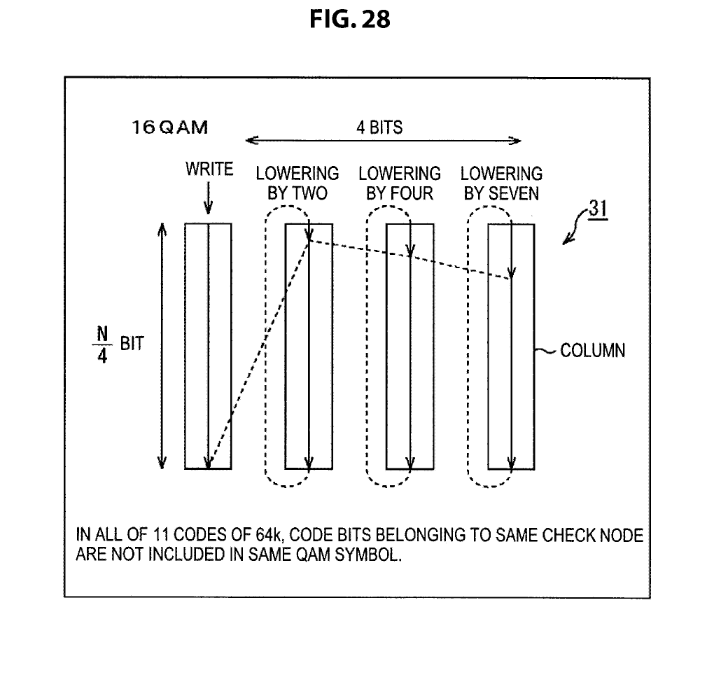

FIG. 28 is an illustration of the column twist interleave.

That is, FIG. 28 illustrates the memory 31 (FIGS. 22 and 23) of the demultiplexer 25.

As described in FIG. 22, the memory 31 has a storage capacity to store mb bits in the column (longitudinal) direction and store N/(mb) bits in the row (transverse) direction and includes mb columns. The column twist interleaver 24 writes the code bits of the LDPC code in the column direction with respect to the memory 31, controls a write start position when the code bits are read in the row direction, and performs the column twist interleave.

That is, in the column twist interleaver 24, the write start position to start writing of the code bits is appropriately changed with respect to each of the plurality of columns, such that the plurality of code bits read in the row direction and becoming one symbol do not become the code bits corresponding to 1 in any one row of the transformed parity check matrix (the code bits of the LDPC code are rearranged such that the plurality of code bits corresponding to 1 in any one row of the parity check matrix are not included in the same symbol).

In this case, FIG. 28 illustrates a configuration example of the memory 31 when the modulation method is the 16 APSK or the 16QAM and the multiple b described in FIG. 22 is 1. Therefore, the bit number m of the code bits of the LDPC code becoming one symbol is 4 bits and the memory 31 includes 4 (=mb) columns.

The column twist interleaver 24 performs writing of the code bits of the LDPC code (instead of the demultiplexer 25 of FIG. 22) in the downward direction (column direction) from the upper side of the four columns constituting the memory 31, toward the columns of the rightward direction from the left side.

If writing of the code bits ends to the rightmost column, the column twist interleaver 24 reads the code bits in a unit of four bits (mb bits) in the row direction from the first row of all the columns constituting the memory 31 and outputs the code bits as the LDPC code after the column twist interleave to the interchanging unit 32 (FIGS. 22 and 23) of the demultiplexer 25.

However, in the column twist interleaver 24, if an address of a position of a head (top) of each column is set to 0 and an address of each position of the column direction is represented by an ascending integer, a write start position is set to a position of which an address is 0, with respect to a leftmost column. A write start position is set to a position of which an address is 2, with respect to a second (from the left side) column. A write start position is set to a position of which an address is 4, with respect to a third column. A write start position is set to a position of which an address is 7, with respect to a fourth column.

With respect to the columns in which the write start positions are the positions other than the position of which the address is 0, after the code bits are written to a lowermost position, the position returns to the head (the position of which the address is 0) and writing is performed to the position immediately before the write start position. Then, writing with respect to a next (right) column is performed.

By performing the column twist interleave described above, with respect to the LDPC codes that are defined in the standard of the DVB-T.2 or the like, the plurality of code bits corresponding to the plurality of variable nodes connected to the same check node can be prevented from becoming one symbol of the APSK or the 16QAM (being included in the same symbol). As a result, decoding performance in a communication path in which the erasure exists can be improved.

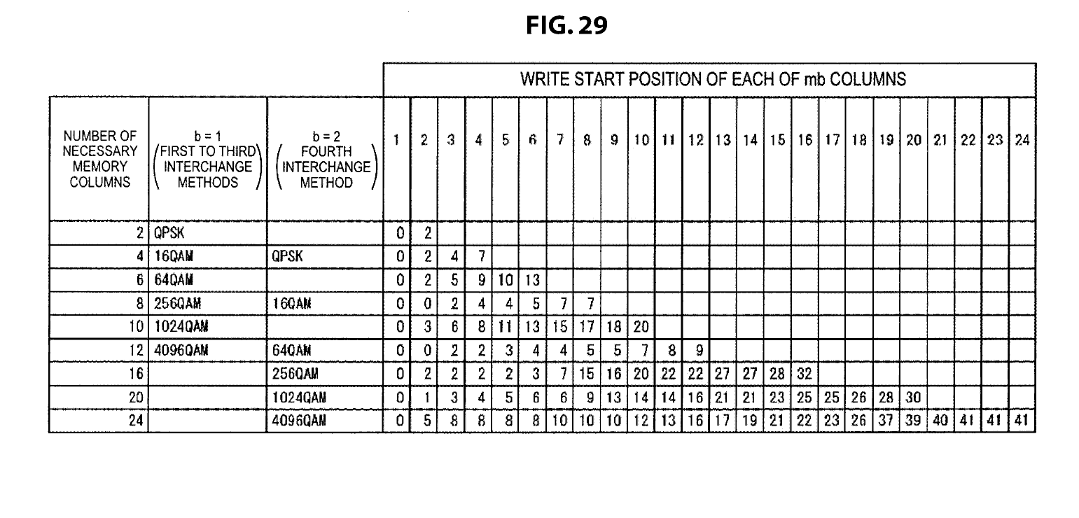

FIG. 29 illustrates a column number of the memory 31 necessary for the column twist interleave and an address of a write start position for each modulation method, with respect to LDPC codes of 11 encoding rates defined in the standard of the DVB-T.2 and having a code length N of 64800.

When the multiple b is 1, the QPSK is adopted as the modulation method, and a bit number m of one symbol is 2 bits, according to FIG. 29, the memory 31 has two columns to store 2×1 (=mb) bits in the row direction and stores 64800/(2×1) bits in the column direction.

A write start position of a first column of the two columns of the memory 31 becomes a position of which an address is 0 and a write start position of a second column becomes a position of which an address is 2.

For example, when any one of the first to third interchange methods of FIG. 22 is adopted as the interchange method of the interchange processing of the demultiplexer 25 (FIG. 9), the multiple b becomes 1.

When the multiple b is 2, the QPSK is adopted as the modulation method, and a bit number m of one symbol is 2 bits, according to FIG. 29, the memory 31 has four columns to store 2×2 bits in the row direction and stores 64800/(2×2) bits in the column direction.

A write start position of a first column of the four columns of the memory 31 becomes a position of which an address is 0, a write start position of a second column becomes a position of which an address is 2, a write start position of a third column becomes a position of which an address is 4, and a write start position of a fourth column becomes a position of which an address is 7.

For example, when the fourth interchange method of FIG. 23 is adopted as the interchange method of the interchange processing of the demultiplexer 25 (FIG. 9), the multiple b becomes 2.

When the multiple b is 1, the 16QAM is adopted as the modulation method, and a bit number m of one symbol is 4 bits, according to FIG. 29, the memory 31 has four columns to store 4×1 bits in the row direction and stores 64800/(4×1) bits in the column direction.

A write start position of a first column of the four columns of the memory 31 becomes a position of which an address is 0, a write start position of a second column becomes a position of which an address is 2, a write start position of a third column becomes a position of which an address is 4, and a write start position of a fourth column becomes a position of which an address is 7.

When the multiple b is 2, the 16QAM is adopted as the modulation method, and a bit number m of one symbol is 4 bits, according to FIG. 29, the memory 31 has eight columns to store 4×2 bits in the row direction and stores 64800/(4×2) bits in the column direction.

A write start position of a first column of the eight columns of the memory 31 becomes a position of which an address is 0, a write start position of a second column becomes a position of which an address is 0, a write start position of a third column becomes a position of which an address is 2, a write start position of a fourth column becomes a position of which an address is 4, a write start position of a fifth column becomes a position of which an address is 4, a write start position of a sixth column becomes a position of which an address is 5, a write start position of a seventh column becomes a position of which an address is 7, and a write start position of a eighth column becomes a position of which an address is 7.

When the multiple b is 1, the 64QAM is adopted as the modulation method, and a bit number m of one symbol is 6 bits, according to FIG. 29, the memory 31 has six columns to store 6×1 bits in the row direction and stores 64800/(6×1) bits in the column direction.

A write start position of a first column of the six columns of the memory 31 becomes a position of which an address is 0, a write start position of a second column becomes a position of which an address is 2, a write start position of a third column becomes a position of which an address is 5, a write start position of a fourth column becomes a position of which an address is 9, a write start position of a fifth column becomes a position of which an address is 10, and a write start position of a sixth column becomes a position of which an address is 13.

When the multiple b is 2, the 64QAM is adopted as the modulation method, and a bit number m of one symbol is 6 bits, according to FIG. 29, the memory 31 has twelve columns to store 6×2 bits in the row direction and stores 64800/(6×2) bits in the column direction.

A write start position of a first column of the twelve columns of the memory 31 becomes a position of which an address is 0, a write start position of a second column becomes a position of which an address is 0, a write start position of a third column becomes a position of which an address is 2, a write start position of a fourth column becomes a position of which an address is 2, a write start position of a fifth column becomes a position of which an address is 3, a write start position of a sixth column becomes a position of which an address is 4, a write start position of a seventh column becomes a position of which an address is 4, a write start position of a eighth column becomes a position of which an address is 5, a write start position of a ninth column becomes a position of which an address is 5 a write start position of a tenth column becomes a position of which an address is 7, a write start position of a eleventh column becomes a position of which an address is 8, and a write start position of a twelfth column becomes a position of which an address is 9.

When the multiple b is 1, the 256QAM is adopted as the modulation method, and a bit number m of one symbol is 8 bits, according to FIG. 29, the memory 31 has eight columns to store 8×1 bits in the row direction and stores 64800/(8×2) bits in the column direction.

A write start position of a first column of the eight columns of the memory 31 becomes a position of which an address is 0, a write start position of a second column becomes a position of which an address is 0, a write start position of a third column becomes a position of which an address is 2, a write start position of a fourth column becomes a position of which an address is 4, a write start position of a fifth column becomes a position of which an address is 4, a write start position of a sixth column becomes a position of which an address is 5, a write start position of a seventh column becomes a position of which an address is 7, and a write start position of a eighth column becomes a position of which an address is 7.

When the multiple b is 2, the 256QAM is adopted as the modulation method, and a bit number m of one symbol is 8 bits, according to FIG. 29, the memory 31 has sixteen columns to store 8×2 bits in the row direction and stores 64800/(8×2) bits in the column direction.

A write start position of a first column of the sixteen columns of the memory 31 becomes a position of which an address is 0, a write start position of a second column becomes a position of which an address is 2, a write start position of a third column becomes a position of which an address is 2, a write start position of a fourth column becomes a position of which an address is 2, a write start position of a fifth column becomes a position of which an address is 2, a write start position of a sixth column becomes a position of which an address is 3, a write start position of a seventh column becomes a position of which an address is 7, a write start position of a eighth column becomes a position of which an address is 15, a write start position of a ninth column becomes a position of which an address is 16 a write start position of a tenth column becomes a position of which an address is 20, a write start position of a eleventh column becomes a position of which an address is 22, a write start position of a twelfth column becomes a position of which an address is 22, a write start position of a thirteenth column becomes a position of which an address is 27, a write start position of a fourteenth column becomes a position of which an address is 27, a write start position of a fifteenth column becomes a position of which an address is 28, and a write start position of a sixteenth column becomes a position of which an address is 32.

When the multiple b is 1, the 1024QAM is adopted as the modulation method, and a bit number m of one symbol is 10 bits, according to FIG. 29, the memory 31 has ten columns to store 10×1 bits in the row direction and stores 64800/(10×1) bits in the column direction.

A write start position of a first column of the ten columns of the memory 31 becomes a position of which an address is 0, a write start position of a second column becomes a position of which an address is 3, a write start position of a third column becomes a position of which an address is 6, a write start position of a fourth column becomes a position of which an address is 8, a write start position of a fifth column becomes a position of which an address is 11, a write start position of a sixth column becomes a position of which an address is 13, a write start position of a seventh column becomes a position of which an address is 15, a write start position of a eighth column becomes a position of which an address is 17, a write start position of a ninth column becomes a position of which an address is 18 and a write start position of a tenth column becomes a position of which an address is 20.

When the multiple b is 2, the 1024QAM is adopted as the modulation method, and a bit number m of one symbol is 10 bits, according to FIG. 29, the memory 31 has twenty columns to store 10×2 bits in the row direction and stores 64800/(10×2) bits in the column direction.

A write start position of a first column of the twenty columns of the memory 31 becomes a position of which an address is 0, a write start position of a second column becomes a position of which an address is 1, a write start position of a third column becomes a position of which an address is 3, a write start position of a fourth column becomes a position of which an address is 4, a write start position of a fifth column becomes a position of which an address is 5, a write start position of a sixth column becomes a position of which an address is 6, a write start position of a seventh column becomes a position of which an address is 6, a write start position of a eighth column becomes a position of which an address is 9, a write start position of a ninth column becomes a position of which an address is 13 a write start position of a tenth column becomes a position of which an address is 14, a write start position of a eleventh column becomes a position of which an address is 14, a write start position of a twelfth column becomes a position of which an address is 16, a write start position of a thirteenth column becomes a position of which an address is 21, a write start position of a fourteenth column becomes a position of which an address is 21, a write start position of a fifteenth column becomes a position of which an address is 23, a write start position of a sixteenth column becomes a position of which an address is 25, a write start position of a seventeenth column becomes a position of which an address is 25, a write start position of a eighteenth column becomes a position of which an address is 26, a write start position of a nineteenth column becomes a position of which an address is 28, and a write start position of a twentieth column becomes a position of which an address is 30.

When the multiple b is 1, the 4096QAM is adopted as the modulation method, and a bit number m of one symbol is 12 bits, according to FIG. 29, the memory 31 has twelve columns to store 12×1 bits in the row direction and stores 64800/(12×1) bits in the column direction.

A write start position of a first column of the twelve columns of the memory 31 becomes a position of which an address is 0, a write start position of a second column becomes a position of which an address is 0, a write start position of a third column becomes a position of which an address is 2, a write start position of a fourth column becomes a position of which an address is 2, a write start position of a fifth column becomes a position of which an address is 3, a write start position of a sixth column becomes a position of which an address is 4, a write start position of a seventh column becomes a position of which an address is 4, a write start position of a eighth column becomes a position of which an address is 5, a write start position of a ninth column becomes a position of which an address is 5 a write start position of a tenth column becomes a position of which an address is 7, a write start position of a eleventh column becomes a position of which an address is 8, and a write start position of a twelfth column becomes a position of which an address is 9.

When the multiple b is 2, the 4096QAM is adopted as the modulation method, and a bit number m of one symbol is 12 bits, according to FIG. 29, the memory 31 has twenty four columns to store 12×2 bits in the row direction and stores 64800/(12×2) bits in the column direction.

A write start position of a first column of the twenty four columns of the memory 31 becomes a position of which an address is 0, a write start position of a second column becomes a position of which an address is 5, a write start position of a third column becomes a position of which an address is 8, a write start position of a fourth column becomes a position of which an address is 8, a write start position of a fifth column becomes a position of which an address is 8, a write start position of a sixth column becomes a position of which an address is 8, a write start position of a seventh column becomes a position of which an address is 10, a write start position of a eighth column becomes a position of which an address is 10, a write start position of a ninth column becomes a position of which an address is 10 a write start position of a tenth column becomes a position of which an address is 12, a write start position of a eleventh column becomes a position of which an address is 13, a write start position of a twelfth column becomes a position of which an address is 16, a write start position of a thirteenth column becomes a position of which an address is 17, a write start position of a fourteenth column becomes a position of which an address is 19, a write start position of a fifteenth column becomes a position of which an address is 21, a write start position of a sixteenth column becomes a position of which an address is 22, a write start position of a seventeenth column becomes a position of which an address is 23, a write start position of a eighteenth column becomes a position of which an address is 26, a write start position of a nineteenth column becomes a position of which an address is 37, a write start position of a twentieth column becomes a position of which an address is 39, a write start position of a twenty first column becomes a position of which an address is 40, a write start position of a twenty second column becomes a position of which an address is 41, a write start position of a twenty third column becomes a position of which an address is 41, and a write start position of a twenty fourth column becomes a position of which an address is 41.

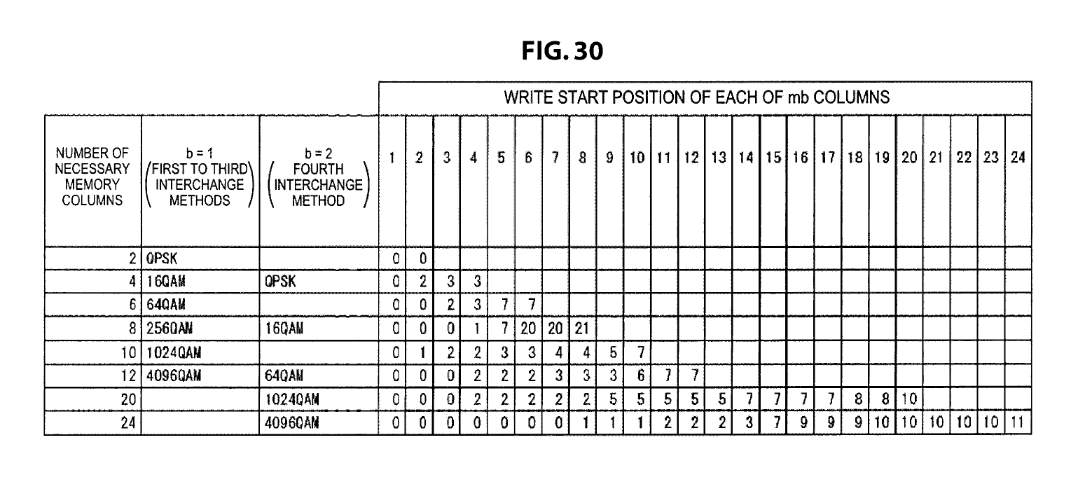

FIG. 30 illustrates a column number of the memory 31 necessary for the column twist interleave and an address of a write start position for each modulation method, with respect to LDPC codes of 10 encoding rates defined in the standard of the DVB-T.2 and having a code length N of 16200.

When the multiple b is 1, the QPSK is adopted as the modulation method, and a bit number m of one symbol is 2 bits, according to FIG. 30, the memory 31 has two columns to store 2×1 bits in the row direction and stores 16200/(2×1) bits in the column direction.

A write start position of a first column of the two columns of the memory 31 becomes a position of which an address is 0 and a write start position of a second column becomes a position of which an address is 0.

When the multiple b is 2, the QPSK is adopted as the modulation method, and a bit number m of one symbol is 2 bits, according to FIG. 30, the memory 31 has four columns to store 2×2 (=mb) bits in the row direction and stores 16200/(2×2) bits in the column direction.

A write start position of a first column of the four columns of the memory 31 becomes a position of which an address is 0, a write start position of a second column becomes a position of which an address is 2, a write start position of a third column becomes a position of which an address is 3, and a write start position of a fourth column becomes a position of which an address is 3.

When the multiple b is 1, the 16QAM is adopted as the modulation method, and a bit number m of one symbol is 4 bits, according to FIG. 30, the memory 31 has four columns to store 4×1 bits in the row direction and stores 16200/(4×1) bits in the column direction.

A write start position of a first column of the four columns of the memory 31 becomes a position of which an address is 0, a write start position of a second column becomes a position of which an address is 2, a write start position of a third column becomes a position of which an address is 3, and a write start position of a fourth column becomes a position of which an address is 3.

When the multiple b is 2, the 16QAM is adopted as the modulation method, and a bit number m of one symbol is 4 bits, according to FIG. 30, the memory 31 has eight columns to store 4×2 bits in the row direction and stores 16200/(4×2) bits in the column direction.

A write start position of a first column of the eight columns of the memory 31 becomes a position of which an address is 0, a write start position of a second column becomes a position of which an address is 0, a write start position of a third column becomes a position of which an address is 0, a write start position of a fourth column becomes a position of which an address is 1, a write start position of a fifth column becomes a position of which an address is 7, a write start position of a sixth column becomes a position of which an address is 20, a write start position of a seventh column becomes a position of which an address is 20, and a write start position of a eighth column becomes a position of which an address is 21.

When the multiple b is 1, the 64QAM is adopted as the modulation method, and a bit number m of one symbol is 6 bits, according to FIG. 30, the memory 31 has six columns to store 6×1 bits in the row direction and stores 16200/(6×1) bits in the column direction.

A write start position of a first column of the six columns of the memory 31 becomes a position of which an address is 0, a write start position of a second column becomes a position of which an address is 0, a write start position of a third column becomes a position of which an address is 2, a write start position of a fourth column becomes a position of which an address is 3, a write start position of a fifth column becomes a position of which an address is 7, and a write start position of a sixth column becomes a position of which an address is 7.

When the multiple b is 2, the 64QAM is adopted as the modulation method, and a bit number m of one symbol is 6 bits, according to FIG. 30, the memory 31 has twelve columns to store 6×2 bits in the row direction and stores 16200/(6×2) bits in the column direction.

A write start position of a first column of the twelve columns of the memory 31 becomes a position of which an address is 0, a write start position of a second column becomes a position of which an address is 0, a write start position of a third column becomes a position of which an address is 0, a write start position of a fourth column becomes a position of which an address is 2, a write start position of a fifth column becomes a position of which an address is 2, a write start position of a sixth column becomes a position of which an address is 2, a write start position of a seventh column becomes a position of which an address is 3, a write start position of a eighth column becomes a position of which an address is 3, a write start position of a ninth column becomes a position of which an address is 3 a write start position of a tenth column becomes a position of which an address is 6, a write start position of a eleventh column becomes a position of which an address is 7, and a write start position of a twelfth column becomes a position of which an address is 7.

When the multiple b is 1, the 256QAM is adopted as the modulation method, and a bit number m of one symbol is 8 bits, according to FIG. 30, the memory 31 has eight columns to store 8×1 bits in the row direction and stores 16200/(8×1) bits in the column direction.

A write start position of a first column of the eight columns of the memory 31 becomes a position of which an address is 0, a write start position of a second column becomes a position of which an address is 0, a write start position of a third column becomes a position of which an address is 0, a write start position of a fourth column becomes a position of which an address is 1, a write start position of a fifth column becomes a position of which an address is 7, a write start position of a sixth column becomes a position of which an address is 20, a write start position of a seventh column becomes a position of which an address is 20, and a write start position of a eighth column becomes a position of which an address is 21.

When the multiple b is 1, the 1024QAM is adopted as the modulation method, and a bit number m of one symbol is 10 bits, according to FIG. 30, the memory 31 has ten columns to store 10×1 bits in the row direction and stores 16200/(10×1) bits in the column direction.

A write start position of a first column of the ten columns of the memory 31 becomes a position of which an address is 0, a write start position of a second column becomes a position of which an address is 1, a write start position of a third column becomes a position of which an address is 2, a write start position of a fourth column becomes a position of which an address is 2, a write start position of a fifth column becomes a position of which an address is 3, a write start position of a sixth column becomes a position of which an address is 3, a write start position of a seventh column becomes a position of which an address is 4, a write start position of a eighth column becomes a position of which an address is 4, a write start position of a ninth column becomes a position of which an address is 5, and a write start position of a tenth column becomes a position of which an address is 7.

When the multiple b is 2, the 1024QAM is adopted as the modulation method, and a bit number m of one symbol is 10 bits, according to FIG. 30, the memory 31 has twenty columns to store 10×2 bits in the row direction and stores 16200/(10×2) bits in the column direction.

A write start position of a first column of the twenty columns of the memory 31 becomes a position of which an address is 0, a write start position of a second column becomes a position of which an address is 0, a write start position of a third column becomes a position of which an address is 0, a write start position of a fourth column becomes a position of which an address is 2, a write start position of a fifth column becomes a position of which an address is 2, a write start position of a sixth column becomes a position of which an address is 2, a write start position of a seventh column becomes a position of which an address is 2, a write start position of a eighth column becomes a position of which an address is 2, a write start position of a ninth column becomes a position of which an address is 5 a write start position of a tenth column becomes a position of which an address is 5, a write start position of a eleventh column becomes a position of which an address is 5, a write start position of a twelfth column becomes a position of which an address is 5, a write start position of a thirteenth column becomes a position of which an address is 5, a write start position of a fourteenth column becomes a position of which an address is 7, a write start position of a fifteenth column becomes a position of which an address is 7, a write start position of a sixteenth column becomes a position of which an address is 7, a write start position of a seventeenth column becomes a position of which an address is 7, a write start position of a eighteenth column becomes a position of which an address is 8, a write start position of a nineteenth column becomes a position of which an address is 8, and a write start position of a twentieth column becomes a position of which an address is 10.

When the multiple b is 1, the 4096QAM is adopted as the modulation method, and a bit number m of one symbol is 12 bits, according to FIG. 30, the memory 31 has twelve columns to store 12×1 bits in the row direction and stores 16200/(12×1) bits in the column direction.

A write start position of a first column of the twelve columns of the memory 31 becomes a position of which an address is 0, a write start position of a second column becomes a position of which an address is 0, a write start position of a third column becomes a position of which an address is 0, a write start position of a fourth column becomes a position of which an address is 2, a write start position of a fifth column becomes a position of which an address is 2, a write start position of a sixth column becomes a position of which an address is 2, a write start position of a seventh column becomes a position of which an address is 3, a write start position of a eighth column becomes a position of which an address is 3, a write start position of a ninth column becomes a position of which an address is 3 a write start position of a tenth column becomes a position of which an address is 6, a write start position of a eleventh column becomes a position of which an address is 7, and a write start position of a twelfth column becomes a position of which an address is 7.

When the multiple b is 2, the 4096QAM is adopted as the modulation method, and a bit number m of one symbol is 12 bits, according to FIG. 30, the memory 31 has twenty four columns to store 12×2 bits in the row direction and stores 16200/(12×2) bits in the column direction.

A write start position of a first column of the twenty four columns of the memory 31 becomes a position of which an address is 0, a write start position of a second column becomes a position of which an address is 0, a write start position of a third column becomes a position of which an address is 0, a write start position of a fourth column becomes a position of which an address is 0, a write start position of a fifth column becomes a position of which an address is 0, a write start position of a sixth column becomes a position of which an address is 0, a write start position of a seventh column becomes a position of which an address is 0, a write start position of a eighth column becomes a position of which an address is 1, a write start position of a ninth column becomes a position of which an address is 1 a write start position of a tenth column becomes a position of which an address is 1, a write start position of a eleventh column becomes a position of which an address is 2, a write start position of a twelfth column becomes a position of which an address is 2, a write start position of a thirteenth column becomes a position of which an address is 2, a write start position of a fourteenth column becomes a position of which an address is 3, a write start position of a fifteenth column becomes a position of which an address is 7, a write start position of a sixteenth column becomes a position of which an address is 9, a write start position of a seventeenth column becomes a position of which an address is 9, a write start position of a eighteenth column becomes a position of which an address is 9, a write start position of a nineteenth column becomes a position of which an address is 10, a write start position of a twentieth column becomes a position of which an address is 10, a write start position of a twenty first column becomes a position of which an address is 10, a write start position of a twenty second column becomes a position of which an address is 10, a write start position of a twenty third column becomes a position of which an address is 10, and a write start position of a twenty fourth column becomes a position of which an address is 11.

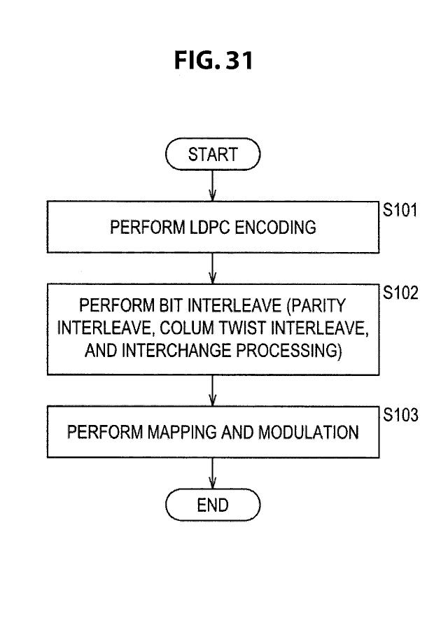

FIG. 31 is a flowchart illustrating processing executed by the LDPC encoder 115, the bit interleaver 116, and the QAM encoder 117 of FIG. 8.

The LDPC encoder 115 awaits supply of the LDPC target data from the BCH encoder 114. In step S101, the LDPC encoder 115 encodes the LDPC target data with the LDPC code and supplies the LDPC code to the bit interleaver 116. The processing proceeds to step S102.

In step S102, the bit interleaver 116 performs bit interleave with respect to the LDPC code supplied from the LDPC encoder 115 and supplies a symbol obtained by symbolizing the LDPC code after the bit interleave to the QAM encoder 117. The processing proceeds to step S103.

That is, in step S102, in the bit interleaver 116 (FIG. 9), the parity interleaver 23 performs parity interleave with respect to the LDPC code supplied from the LDPC encoder 115 and supplies the LDPC code after the parity interleave to the column twist interleaver 24.

The column twist interleaver 24 performs column twist interleave with respect to the LDPC code supplied from the parity interleaver 23 and supplies the LDPC code to the demultiplexer 25.

The demultiplexer 25 executes interchange processing for interchanging the code bits of the LDPC code after the column twist interleave by the column twist interleaver 24 and making the code bits after the interchange become symbol bits (bits representing a symbol) of the symbol.

Here, the interchange processing by the demultiplexer 25 can be performed according to the first or fourth interchange methods illustrated in FIG. 22 and FIG. 23, and, moreover, can be performed according to a predetermined allocation rule defined beforehand to allocate a symbol bit showing a symbol to a code bit of the LDPC code.

The symbol that is obtained by the interchange processing by the demultiplexer 25 is supplied from the demultiplexer 25 to the QAM encoder 117.

In step S103, the QAM encoder 117 maps the symbol supplied from the demultiplexer 25 to a signal point determined by the modulation method of the orthogonal modulation performed by the QAM encoder 117, performs the orthogonal modulation, and supplies data obtained as a result to the time interleaver 118.

As described above, the parity interleave or the column twist interleave is performed, so that tolerance against the erasure or the burst error when the plurality of code bits of the LDPC code are transmitted as one symbol can be improved.

In FIG. 9, the parity interleaver 23 to be a block to perform the parity interleave and the column twist interleaver 24 to be a block to perform the column twist interleave are individually configured for the convenience of explanation. However, the parity interleaver 23 and the column twist interleaver 24 can be integrally configured.

That is, both the parity interleave and the column twist interleave can be performed by writing and reading of the code bits with respect to the memory and can be represented by a matrix to convert an address (write address) to perform writing of the code bits into an address (read address) to perform reading of the code bits.

Therefore, if a matrix obtained by multiplying a matrix representing the parity interleave and a matrix representing the column twist interleave is calculated, the code bits are converted by the matrix, the parity interleave is performed, and a column twist interleave result of the LDPC code after the parity interleave can be obtained.

In addition to the parity interleaver 23 and the column twist interleaver 24, the demultiplexer 25 can be integrally configured.

That is, the interchange processing executed by the demultiplexer 25 can be represented by the matrix to convert the write address of the memory 31 storing the LDPC code into the read address.

Therefore, if a matrix obtained by multiplying the matrix representing the parity interleave, the matrix representing the column twist interleave, and the matrix representing the interchange processing is calculated, the parity interleave, the column twist interleave, and the interchange processing can be collectively executed by the matrix.

Only one of the parity interleave and the column twist interleave may be performed or both the parity interleave and the column twist interleave may not be performed. For example, like DVB-S.2, in a case where the communication path 13 (FIG. 7) is a satellite circuit or the like which is different from AWGN and for which burst error and flutter, and so on, do not have to be considered so much, it is possible to cause the parity interleave and the column twist interleave not to be performed.

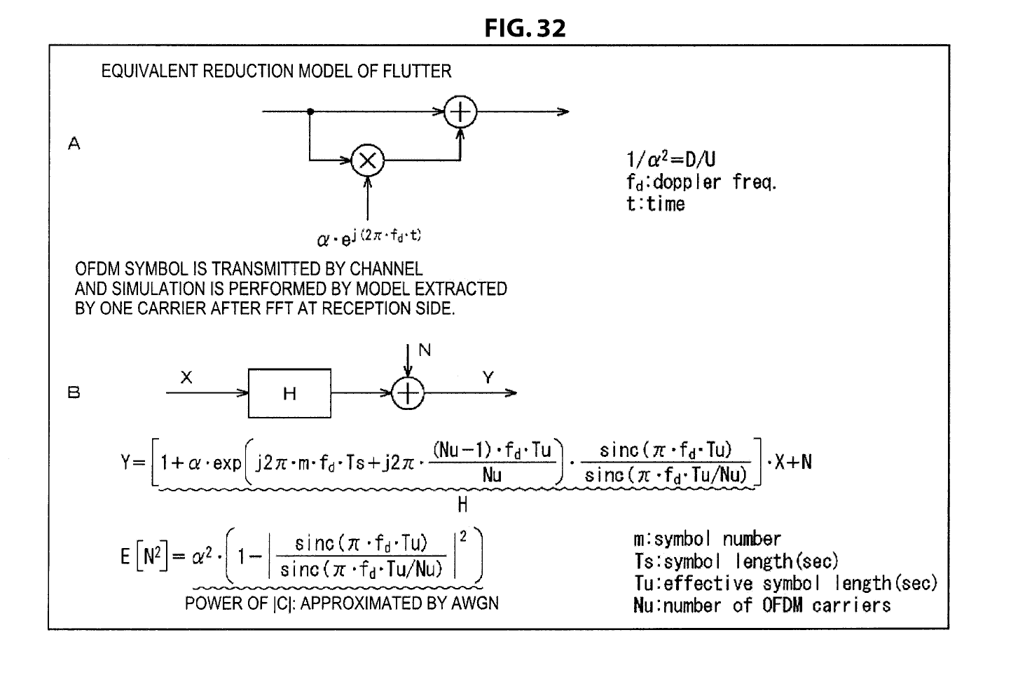

Next, simulation to measure an error rate (bit error rate) that is performed with respect to the transmitting device 11 of FIG. 8 will be described with reference to FIGS. 32 to 34.

The simulation is performed by adopting a communication path in which a flutter having D/U of 0 dB exists.

FIG. 32 illustrates a model of a communication path that is adopted by the simulation.

That is, A of FIG. 32 illustrates a model of a flutter that is adopted by the simulation.

In addition, B of FIG. 32 illustrates a model of a communication path in which the flutter represented by the model of A of FIG. 32 exists.

In B of FIG. 32, H represents the model of the flutter of A of FIG. 32. In B of FIG. 32, N represents ICI (Inter Carrier Interference). In the simulation, an expectation value E[N²] of power is approximated by the AWGN.

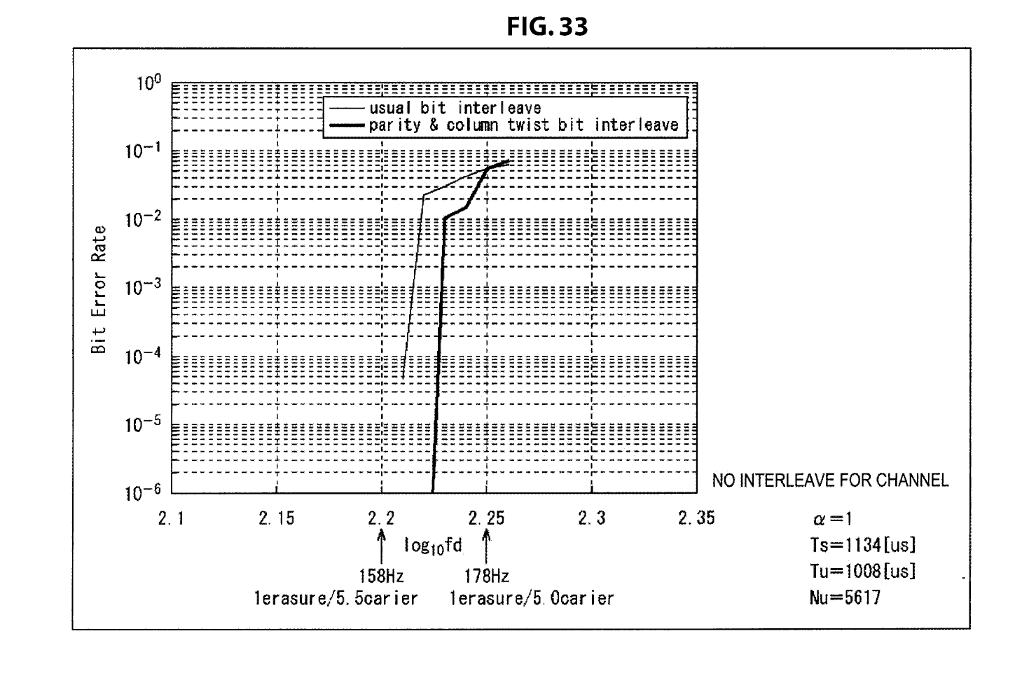

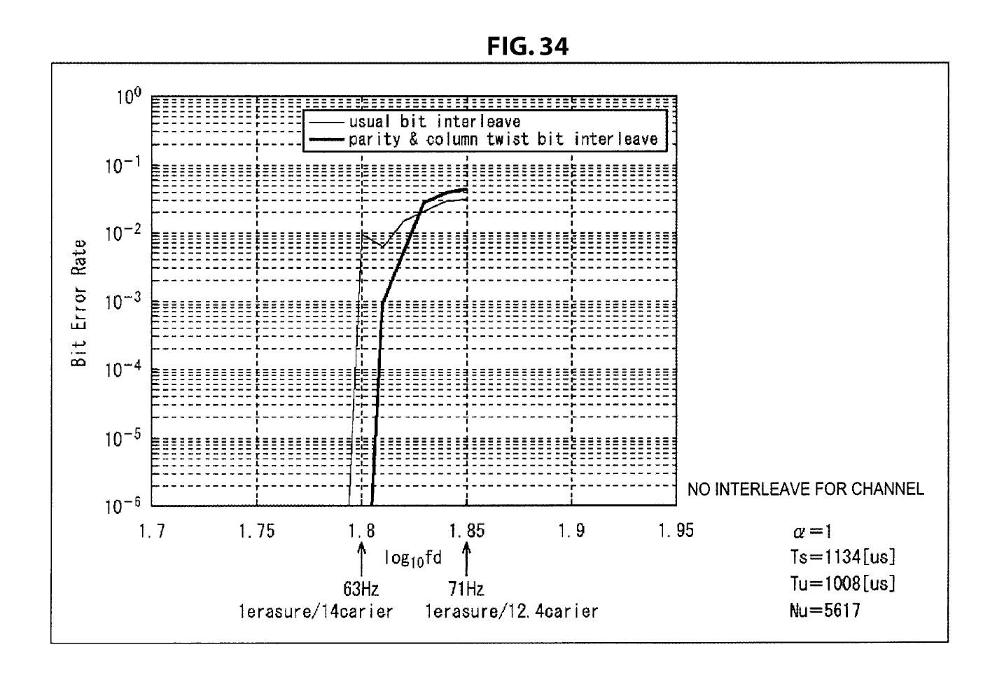

FIGS. 33 and 34 illustrate a relation of an error rate obtained by the simulation and a Doppler frequency f_{d} of the flutter.

FIG. 33 illustrates a relation of the error rate and the Doppler frequency f_{d} when a modulation method is the 16QAM, an encoding rate (r) is (3/4), and an interchange method is the first interchange method. FIG. 34 illustrates a relation of the error rate and the Doppler frequency f_{d} when the modulation method is the 64QAM, the encoding rate (r) is (5/6), and the interchange method is the first interchange method.

In FIGS. 33 and 34, a thick line shows a relation of the error rate and the Doppler frequency f_{d} when all of the parity interleave, the column twist interleave, and the interchange processing are performed and a thin line shows a relation of the error rate and the Doppler frequency f_{d} when only the interchange processing among the parity interleave, the column twist interleave, and the interchange processing is performed.

In both FIGS. 33 and 34, it can be known that the error rate is further improved (decreased) when all of the parity interleave, the column twist interleave, and the interchange processing are performed, as compared with when only the interchange processing is executed.

### Configuration Example of LDPC Encoder 115

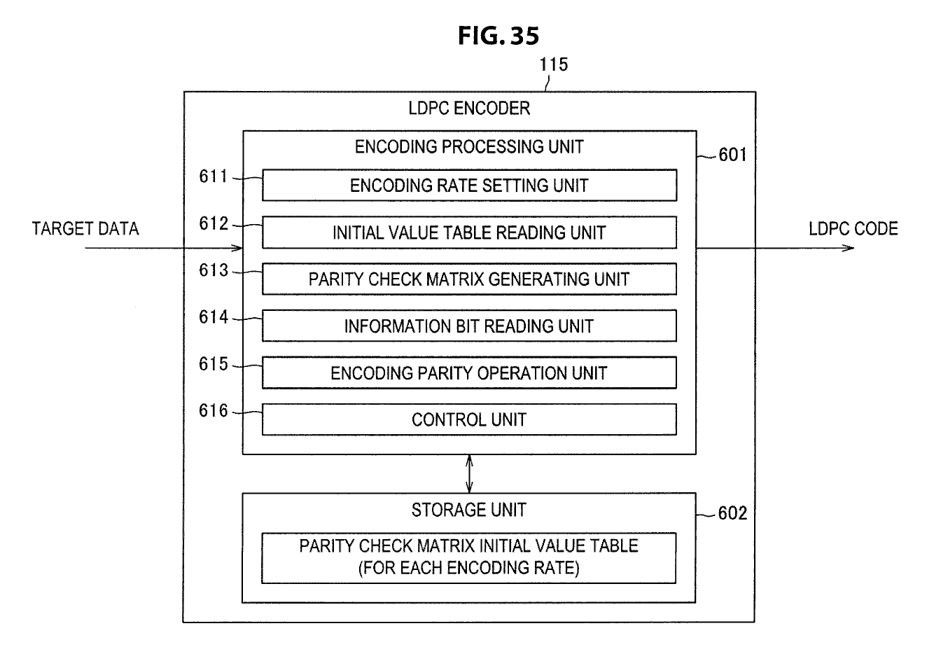

FIG. 35 is a block diagram illustrating a configuration example of the LDPC encoder 115 of FIG. 8.

The LDPC encoder 122 of FIG. 8 is also configured in the same manner.

As described in FIGS. 12 and 13, in the standard of the DVB-S.2 or the like, the LDPC codes that have the two code lengths N of 64800 bits and 16200 bits are defined.

With respect to the LDPC code having the code length N of 64800 bits, 11 encoding rates of 1/4, 1/3, 2/5, 1/2, 3/5, 2/3, 3/4, 4/5, 5/6, 8/9, and 9/10 are defined. With respect to the LDPC code having the code length N of 16200 bits, 10 encoding rates of 1/4, 1/3, 2/5, 1/2, 3/5, 2/3, 3/4, 4/5, 5/6, and 8/9 are defined (FIGS. 12 and 13).

For example, the LDPC encoder 115 can perform encoding (error correction encoding) using the LDPC code of each encoding rate having the code length N of 64800 bits or 16200 bits, according to the parity check matrix H prepared for each code length N and each encoding rate.

The LDPC encoder 115 includes an encoding processing unit 601 and a storage unit 602.

The encoding processing unit 601 includes an encoding rate setting unit 611, an initial value table reading unit 612, a parity check matrix generating unit 613, an information bit reading unit 614, an encoding parity operation unit 615, an a control unit 616. The encoding processing unit 601 performs the LDPC encoding of LDPC target data supplied to the LDPC encoder 115 and supplies an LDPC code obtained as a result to the bit interleaver 116 (FIG. 8).

That is, the encoding rate setting unit 611 sets the code length N and the encoding rate of the LDPC code, according to an operation of an operator.

The initial value table reading unit 612 reads a parity check matrix initial value table to be described later, which corresponds to the code length N and the encoding rate set by the encoding rate setting unit 611, from the storage unit 602.

The parity check matrix generating unit 613 generates a parity check matrix H by arranging elements of 1 of an information matrix H_{A} corresponding to an information length K (=information length N−parity length M) according to the code length N and the encoding rate set by the encoding rate setting unit 611 in the column direction with a period of 360 columns (column number P of a unit of the cyclic structure), on the basis of the parity check matrix initial value table read by the initial value table reading unit 612, and stores the parity check matrix H in the storage unit 602.

The information bit reading unit 614 reads (extracts) information bits corresponding to the information length K, from the LDPC target data supplied to the LDPC encoder 115.

The encoding parity operation unit 615 reads the parity check matrix H generated by the parity check matrix generating unit 613 from the storage unit 602, and generates a code word (LDPC code) by calculating parity bits for the information bits read by the information bit reading unit 614 on the basis of a predetermined expression using the parity check matrix H.

The control unit 616 controls each block constituting the encoding processing unit 601.

In the storage unit 602, a plurality of parity check matrix initial value tables that correspond to the plurality of encoding rates illustrated in FIGS. 12 and 13, with respect to the code lengths N such as the 64800 bits and 16200 bits, are stored. In addition, the storage unit 602 temporarily stores data that is necessary for processing of the encoding processing unit 601.

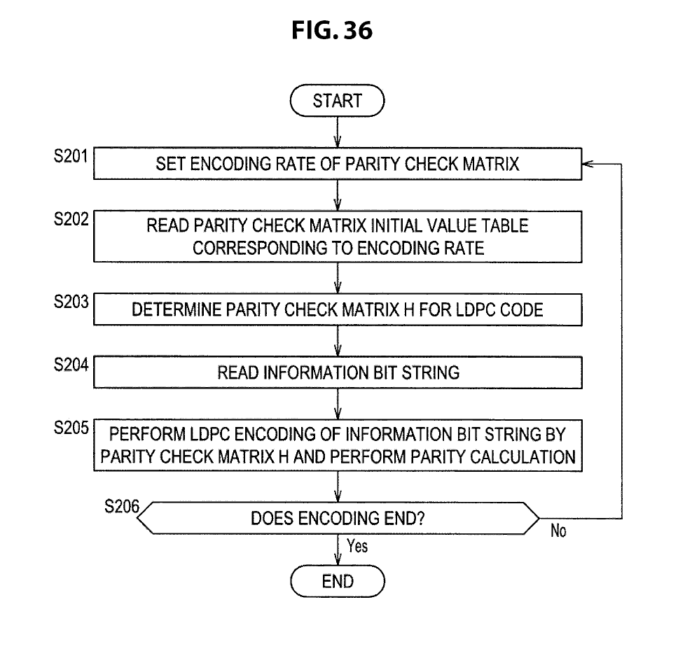

FIG. 36 is a flowchart illustrating processing of the LDPC encoder 115 of FIG. 35.

In step S201, the encoding rate setting unit 611 determines (sets) the code length N and the encoding rate r to perform the LDPC encoding.

In step S202, the initial value table reading unit 612 reads the previously determined parity check matrix initial value table corresponding to the code length N and the encoding rate r determined by the encoding rate setting unit 611, from the storage unit 602.

In step S203, the parity check matrix generating unit 613 calculates (generates) the parity check matrix H of the LDPC code of the code length N and the encoding rate r determined by the encoding rate setting unit 611, using the parity check matrix initial value table read from the storage unit 602 by the initial value table reading unit 612, supplies the parity check matrix to the storage unit 602, and stores the parity check matrix in the storage unit.

In step S204, the information bit reading unit 614 reads the information bits of the information length K (=N×r) corresponding to the code length N and the encoding rate r determined by the encoding rate setting unit 611, from the LDPC target data supplied to the LDPC encoder 115, reads the parity check matrix H calculated by the parity check matrix generating unit 613 from the storage unit 602, and supplies the information bits and the parity check matrix to the encoding parity operation unit 615.

In step S205, the encoding parity operation unit 615 sequentially operates parity bits of a code word c that satisfies an expression (8) using the information bits and the parity check matrix H that have been read from the information bit reading unit 614.

Hc^{T}=0 (8)

In the expression (8), c represents a row vector as the code word (LDPC code) and c^{T} represents transposition of the row vector c.

As described above, when a portion of the information bits of the row vector c as the LDPC code (one code word) is represented by a row vector A and a portion of the parity bits is represented by a row vector T, the row vector c can be represented by an expression c=[A/T], using the row vector A as the information bits and the row vector T as the parity bits.

In the parity check matrix H and the row vector c=[A|T] corresponding to the LDPC code, it is necessary to satisfy an expression Hc^{T}=0. The row vector T that corresponds to the parity bits constituting the row vector c=[A|T] satisfying the expression Hc^{T}=0 can be sequentially calculated by setting elements of each row to 0, sequentially from elements of a first row of the column vector Hc^{T} in the expression Hc^{T}=0, when the parity matrix H_{T} of the parity check matrix H=[H_{A}|H_{T}] becomes the staircase structure illustrated in FIG. 11.

If the encoding parity operation unit 615 calculates the parity bits T with respect to the information bits A from the information bit reading unit 614, the encoding parity operation unit 615 outputs the code word c=[A/T] represented by the information bits A and the parity bits T as an LDPC encoding result of the information bits A.

Then, in step S206, the control unit 616 determines whether the LDPC encoding ends. When it is determined in step S206 that the LDPC encoding does not end, that is, when there is LDPC target data to perform the LDPC encoding, the processing returns to step S201 (or step S204). Hereinafter, the processing of steps S201 (or step S204) to S206 is repeated.

When it is determined in step S206 that the LDPC encoding ends, that is, there is no LDPC target data to perform the LDPC encoding, the LDPC encoder 115 ends the processing.

As described above, the parity check matrix initial value table corresponding to each code length N and each encoding rate r is prepared and the LDPC encoder 115 performs the LDPC encoding of the predetermined code length N and the predetermined encoding rate r, using the parity check matrix H generated from the parity check matrix initial value table corresponding to the predetermined code length N and the predetermined encoding rate r.

### Example of the Parity Check Matrix Initial Value Table

The parity check matrix initial value table is a table that represents positions of elements of 1 of the information matrix H_{A} (FIG. 10) of the parity check matrix H corresponding to the information length K according to the code length N and the encoding rate r of the LDPC code (LDPC code defined by the parity check matrix H) for every 360 columns (column number P of a unit of the cyclic structure) and is previously made for each parity check matrix H of each code length N and each encoding rate r.

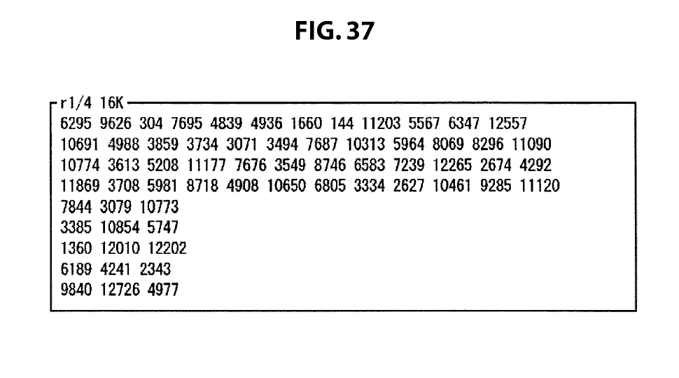

FIG. 37 is an illustration of an example of the parity check matrix initial value table.

That is, FIG. 37 illustrates a parity check matrix initial value table with respect to the parity check matrix H that is defined in the standard of the DVB-T.2 and has the code length N of 16200 bits and the encoding rate (an encoding rate of notation of the DVB-T.2) r of 1/4.

The parity check matrix generating unit 613 (FIG. 35) calculates the parity check matrix H using the parity check matrix initial value table, as follows.

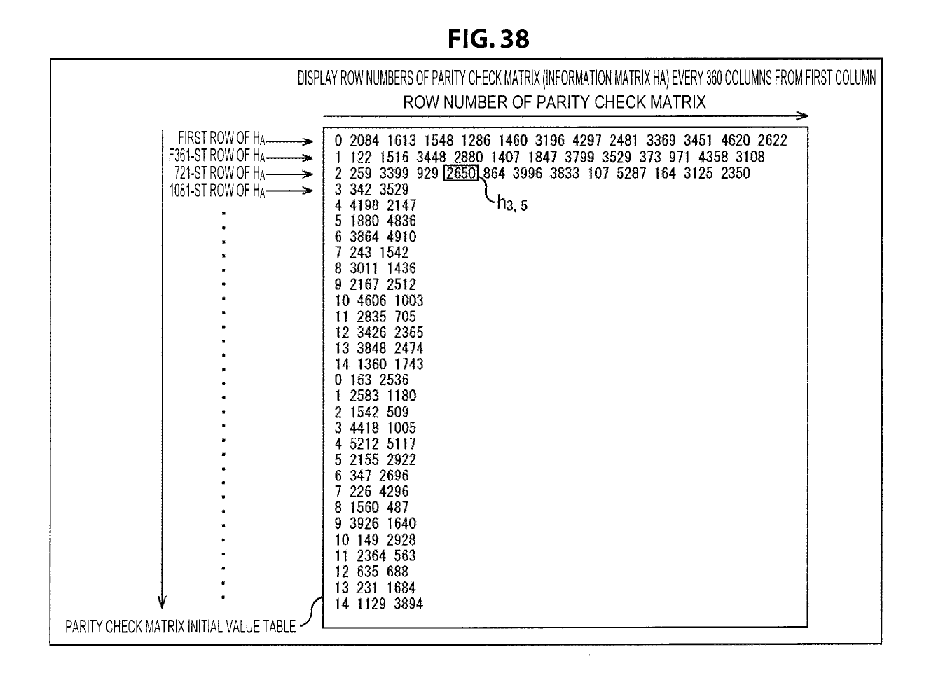

That is, FIG. 38 illustrates a method of calculating the parity check matrix H from the parity check matrix initial value table.

The parity check matrix initial value table in FIG. 38 illustrates a parity check matrix initial value table with respect to the parity check matrix H that is defined in the standard of the DVB-T.2 and has the code length N of 16200 bits and the encoding rate r of 2/3.

As described above, the parity check matrix initial value table is the table that represents the positions of the elements of 1 of the information matrix H_{A} (FIG. 10) corresponding to the information length K according to the code length N and the encoding rate r of the LDPC code for every 360 columns (column number P of a unit of the cyclic structure). In the i-th row thereof, row numbers (row numbers when a row number of a first row of the parity check matrix H is set to 0) of elements of 1 of a (1+360×(i−1)-th column of the parity check matrix H are arranged by a number of column weights of the (1+360×(i−1)-th column.

In this case, because the parity matrix H_{T} (FIG. 10) of the parity check matrix H corresponding to the parity length M is determined as illustrated in FIG. 25, according to the parity check matrix initial value table, the information matrix H_{A} (FIG. 10) of the parity check matrix H corresponding to the information length K is calculated.

A row number k+1 of the parity check matrix initial value table is different according to the information length K.

A relation of an expression (9) is realized between the information length K and the row number k+1 of the parity check matrix initial value table.

K=(k+1)×360 (9)

In this case, 360 of the expression (9) is the column number P of the unit of the cyclic structure described in FIG. 26.

In the parity check matrix initial value table of FIG. 38, 13 numerical values are arranged from the first row to the third row and 3 numerical values are arranged from the fourth row to the (k+1)-th row (in FIG. 38, the 30th row).

Therefore, the column weights of the parity check matrix H that are calculated from the parity check matrix initial value table of FIG. 38 are 13 from the first column to the (1+360×(3−1)−1)-th column and are 3 from the (1+360×(3−1))-th column to the K-th column.

The first row of the parity check matrix initial value table of FIG. 38 becomes 0, 2084, 1613, 1548, 1286, 1460, 3196, 4297, 2481, 3369, 3451, 4620, and 2622, which shows that elements of rows having row numbers of 0, 2084, 1613, 1548, 1286, 1460, 3196, 4297, 2481, 3369, 3451, 4620, and 2622 are 1 (and the other elements are 0), in the first column of the parity check matrix H.

The second row of the parity check matrix initial value table of FIG. 38 becomes 1, 122, 1516, 3448, 2880, 1407, 1847, 3799, 3529, 373, 971, 4358, and 3108, which shows that elements of rows having row numbers of 1, 122, 1516, 3448, 2880, 1407, 1847, 3799, 3529, 373, 971, 4358, and 3108 are 1, in the 361 (=1+360×(2−1))-th column of the parity check matrix H.

As described above, the parity check matrix initial value table represents positions of elements of 1 of the information matrix H_{A} of the parity check matrix H for every 360 columns.

The columns other than the (1+360×(i−1))-th column of the parity check matrix H, that is, the individual columns from the (2+360×(i−1))-th column to the (360×i)-th column are arranged by cyclically shifting elements of 1 of the (1+360×(i−1))-th column determined by the parity check matrix initial value table periodically in a downward direction (downward direction of the columns) according to the parity length M.

That is, the (2+360×(i−1))-th column is obtained by cyclically shifting (1+360×(i−1))-th column in the downward direction by M/360 (=q) and the next (3+360×(i−1))-th column is obtained by cyclically shifting (1+360×(i−1))-th column in the downward direction by 2×M/360 (=2×q) (obtained by cyclically shifting (2+360×(i−1))-th column in the downward direction by M/360 (=q)).

If a numerical value of a j-th column (j-th column from the left side) of an i-th row (i-th row from the upper side) of the parity check matrix initial value table is represented as h_{i,j} and a row number of the j-th element of 1 of the w-th column of the parity check matrix H is represented as H_{w-j}, the row number H_{w-j} of the element of 1 of the w-th column to be a column other than the (1+360×(i−1))-th column of the parity check matrix H can be calculated by an expression (10).

H_{W-j}=mod {h_{i,j}+mod((w−1),P)×q,M) (10)

In this case, mod(x, y) means a remainder that is obtained by dividing x by y.

In addition, P is a column number of a unit of the cyclic structure described above. For example, in the standard of the DVB-S.2, the DVB-T.2, and the DVB-C.2, P is 360 as described above. In addition, q is a value M/360 that is obtained by dividing the parity length M by the column number P (=360) of the unit of the cyclic structure.

The parity check matrix generating unit 613 (FIG. 35) specifies the row numbers of the elements of 1 of the (1+360×(i−1))-th column of the parity check matrix H by the parity check matrix initial value table.

The parity check matrix generating unit 613 (FIG. 35) calculates the row number H_{w-j} of the element of 1 of the w-th column to be the column other than the (1+360×(i−1))-th column of the parity check matrix H, according to the expression (10), and generates the parity check matrix H in which the element of the obtained row number is set to 1.

[New LDPC Code]

By the way, the suggestion of a standard that improves DVB-S.2 (which may be called DVB-Sx below) is requested.

In CfT (Call for Technology) submitted to a standardization conference of DVB-Sx, a predetermined number of ModCod (combination of a modulation method (Modulation) and an LDPC code (Code)) is requested for each range (range) of C/N (Carrier to Noise ratio) (SNR (Signal to Noise Ratio)) according to the use case.

That is, in CfT, as the first request, it is requested that 20 pieces of ModCod are prepared in a range of 7 dB in which C/N is from 5 dB to 12 dB, for the usage of DTH (Direct To Home).

In addition, in CfT, as the second request, it is requested that 22 pieces of ModCod are prepared in a range of 12 dB in which C/N is from 12 dB to 24 dB, as the third request, it is requested that 12 pieces of ModCod are prepared in a range of 8 dB in which C/N is from −3 dB to 5 dB, and, as the fourth request, it is requested that 5 pieces of ModCod are prepared in a range of 7 dB in which C/N is from −10 dB to −3 dB.

Moreover, in CfT, it is requested that FER (Frame Error Rate) of ModCod in the first or fourth requests becomes about 10⁻⁵ (or less).

Here, in CfT, the priority of the first request is “1” which is the highest, and the priority of any of the second to fourth requests is “2” which is lower than the first request.

Therefore, in the present disclosure, at least in CfT, (a parity check matrix of) an LDPC code that can satisfy the first request of the highest priority is provided as a new LDPC code.

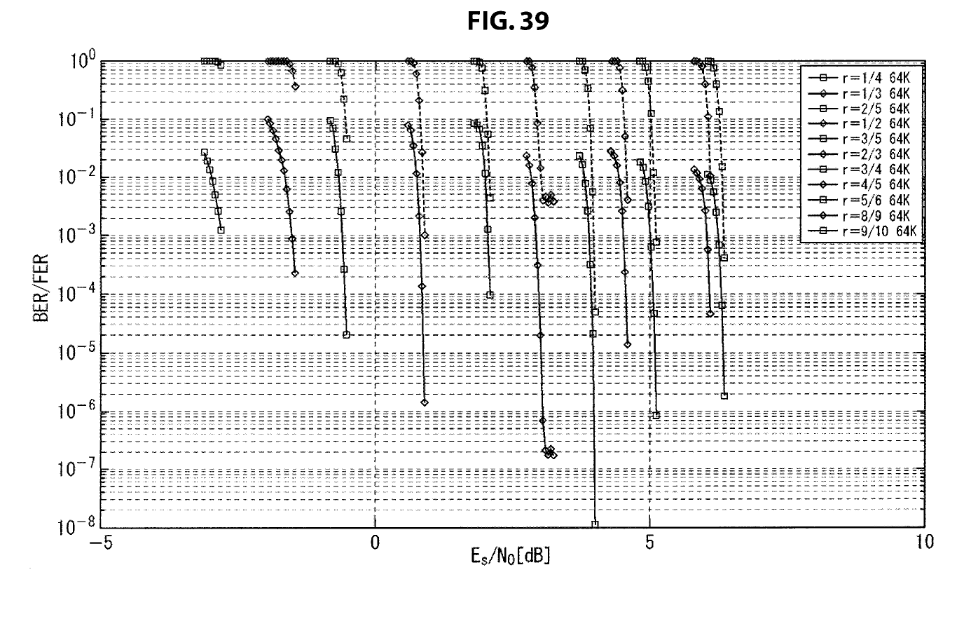

FIG. 39 illustrates a BER/FER curve in a case where QPSK is adopted as a modulation method, for LDPC codes of 11 encoding rates with a code length N of 64 k.

In FIG. 39, the horizontal axis shows Eₛ/N₀ (signal-to-noise power ratio per symbol) corresponding to C/N, and the vertical axis shows FER/BER. Here, in FIG. 39, the solid line shows FER and the dotted line shows BER (Bit Error Rate).

In FIG. 39, there is a FER (BER) curve in a case where QPSK is adopted as a code method, for LSPC codes of 11 encoding rates with a code length N of 64 k defined in DVB-S.2, in a range in which Eₛ/N₀ is 10 dB.

That is, in FIG. 39, there are 11 FER curves of ModCod in which a modulation method is fixed to QPSK, in a range of about 10 dB of Eₛ/N₀ from about −3 dB to about 7 dB.

Therefore, as for LSPC codes of 11 encoding rates with a code length N of 64 k defined in DVB-S.2, the average interval of FER curves of ModCod (which may be called an average interval below) is about 1 dB (≈10 dB/(10−1))

Meanwhile, since it is requested to prepare 20 pieces of ModCod in a range in which Eₛ/N₀ (C/N) is 7 dB in the first request of CfT, the average interval of FER curves of ModCod is about 0.3 dB (≈7 dB/(20−1)).

In a case where a modulation method is fixed to one kind such as QPSK to take margin, as compared with the case of DVB-S.2 in which ModCod with an average interval of about 1 dB can be obtained by LDPC codes of 11 encoding rates, LDPC codes of the number about three times of 11 encoding rates (≈1 dB/0.3 dB), that is, LDPC codes of about 30 encoding rates only have to be provided to acquire ModCod with an average interval of 0.3 dB to satisfy the first request of CfT.

Therefore, the present disclosure prepares an LDPC code with an encoding rate of i/30 (where i denotes a positive integer less than 30) and a code length of 64 k as an LDPC code of an encoding rate for which about 30 encoding rates are easily set, and provides it as a new LDPC code that satisfies at least the first request with the highest priority in CIT.

Here, as for the new LDPC code, from the viewpoint that the affinity (compatibility) with DVB-S.2 is maintained as much as possible, similar to an LDPC code defined in DVB-S.2, parity matrix H_{T} of the parity check matrix H is assumed to have a staircase structure (FIG. 11).

In addition, as for the new LDPC code, similar to the LDPC code defined in DVB-S.2, the information matrix H_{A} of the parity check matrix H is assumed to be a cyclic structure and column number P which is the unit of the cyclic structure is assumed to be 360.

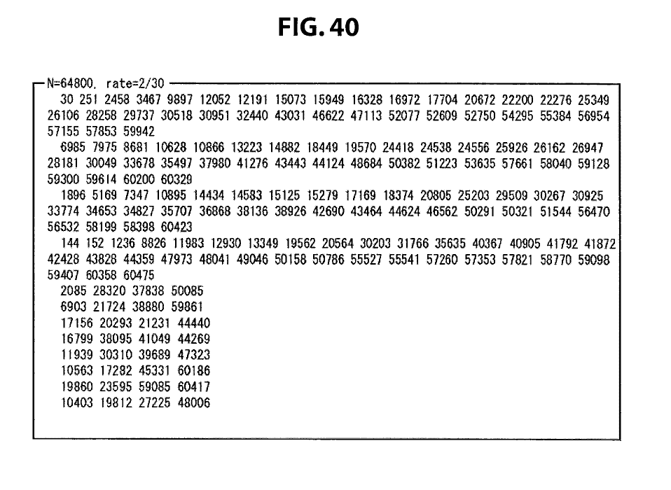

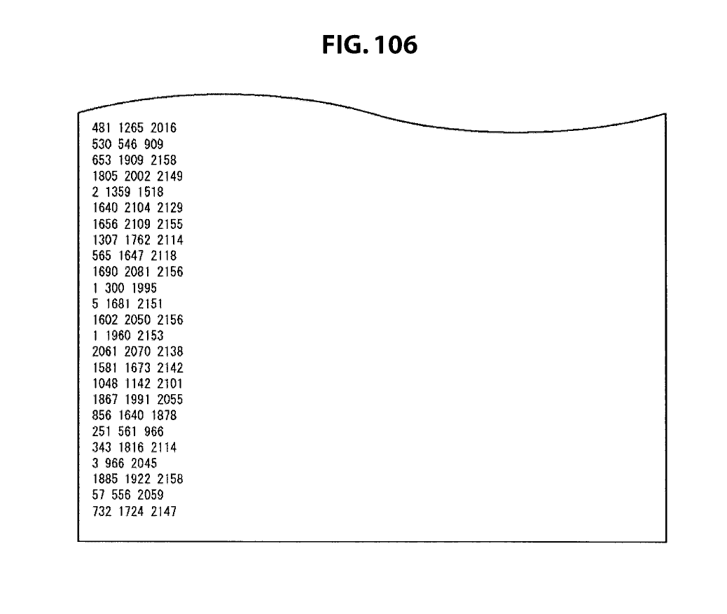

FIG. 40 to FIG. 106 are diagrams illustrating examples of a parity check matrix initial value table of a new LDPC code with a code length N of 64 k bits and an encoding rate of i/30 as described above.

Here, since the new LDPC code is an LDPC code in which the encoding rate is expressed by i/30, there are LDPC codes with 29 encoding rates of 1/30, 2/30, 3/30 . . . 28/30 and 29/30 at maximum.

However, as for an LDPC code with an encoding rate of 1/30, there is a possibility that the use is restricted in respect of efficiency. Moreover, as for an LDPC code with an encoding rate of 29/30, the use may be restricted in respect of the error rate (BER/FER).

Therefore, one or both of the LDPC code with an encoding rate of 1/30 and the LDPC code with an encoding rate of 29/30 among the LDPC codes with 29 encoding rates of encoding rates 1/30 to 29/30 can be assumed not to be treated as a new LDPC code.

Here, for example, LDPC codes with 28 encoding rates of encoding rates 2/30 to 29/30 among encoding rates 1/30 to 29/30 are assumed as new LDPC codes, and a parity check matrix initial value table with respect to the parity check matrix H of the new LDPC codes are shown below.

FIG. 40 illustrates a parity check matrix initial value table with respect to the parity check matrix H of the LDPC code with a code length N of 64 k bits and an encoding rate of 2/30.

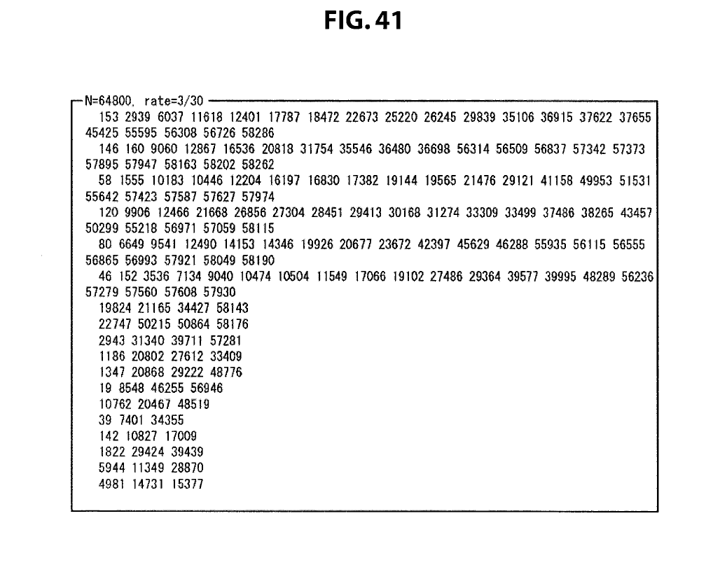

FIG. 41 illustrates a parity check matrix initial value table with respect to the parity check matrix H of the LDPC code with a code length N of 64 k bits and an encoding rate of 3/30.

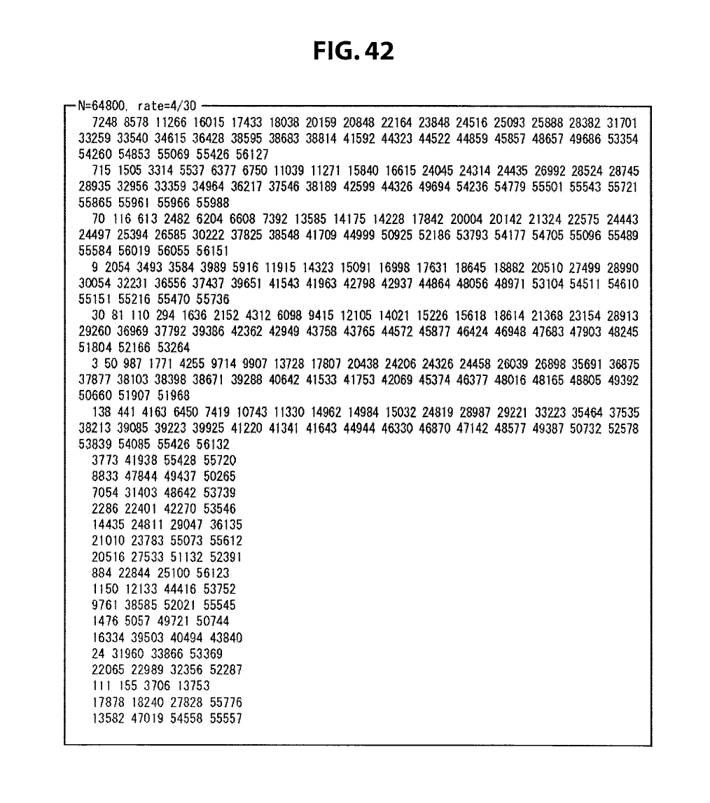

FIG. 42 illustrates a parity check matrix initial value table with respect to the parity check matrix H of the LDPC code with a code length N of 64 k bits and an encoding rate of 4/30.

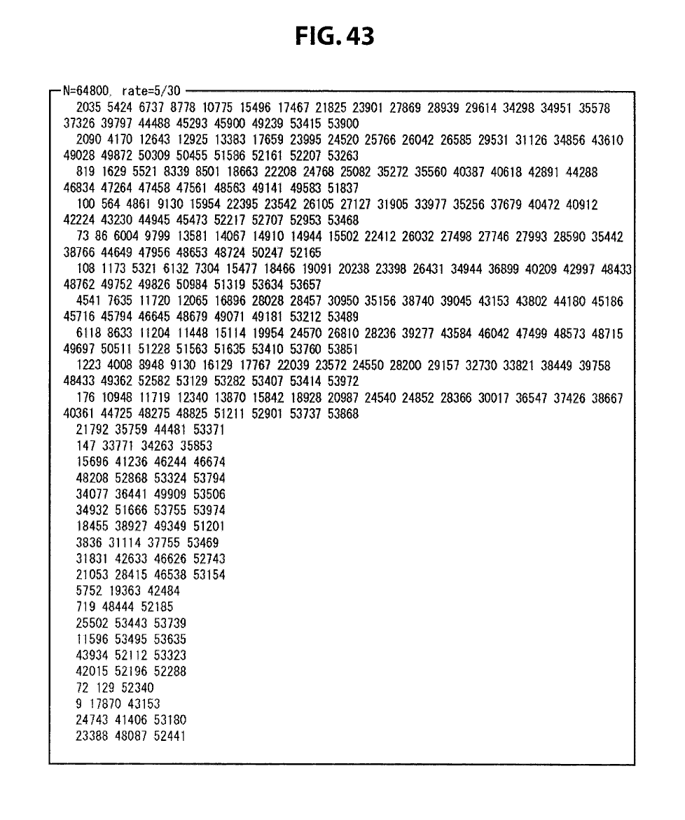

FIG. 43 illustrates a parity check matrix initial value table with respect to the parity check matrix H of the LDPC code with a code length N of 64 k bits and an encoding rate of 5/30.

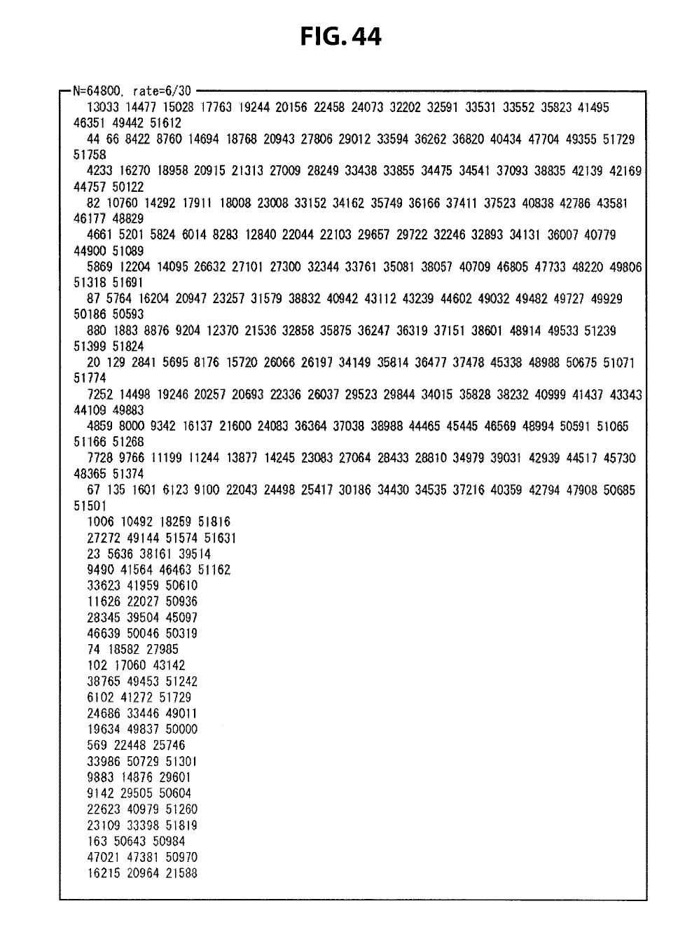

FIG. 44 illustrates a parity check matrix initial value table with respect to the parity check matrix H of the LDPC code with a code length N of 64 k bits and an encoding rate of 6/30.

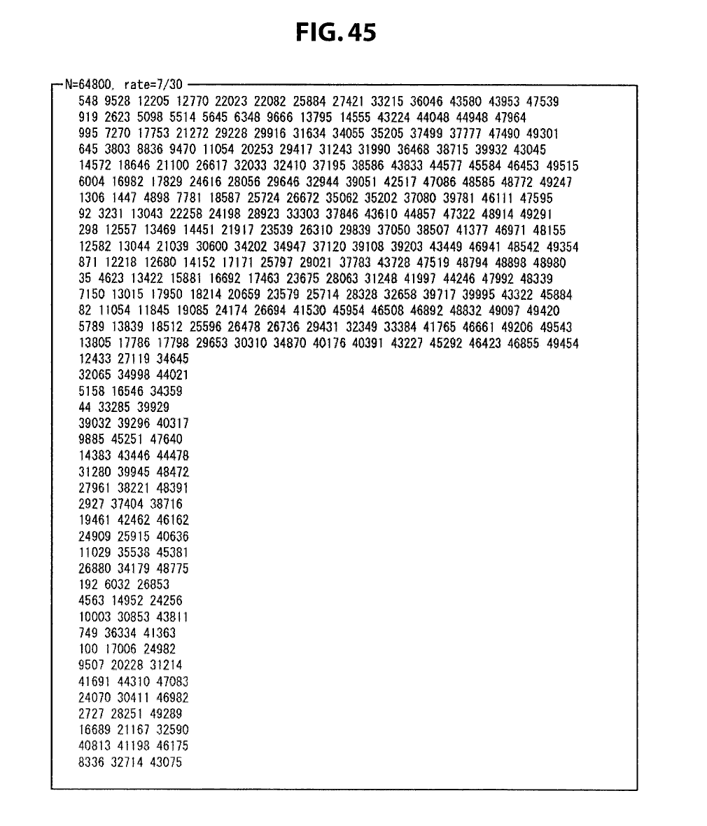

FIG. 45 illustrates a parity check matrix initial value table with respect to the parity check matrix H of the LDPC code with a code length N of 64 k bits and an encoding rate of 7/30.

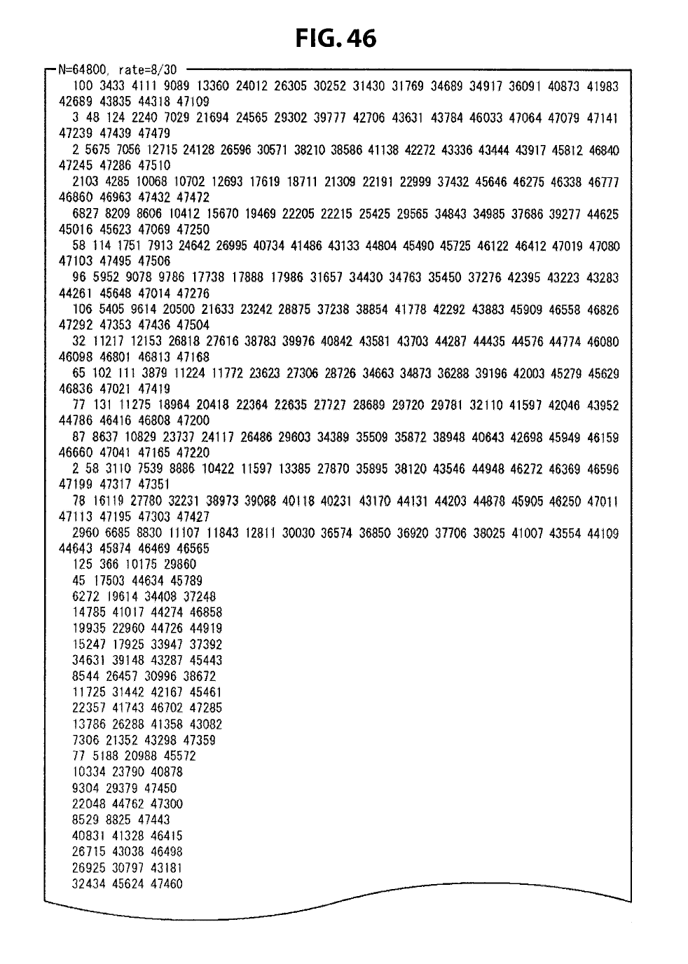

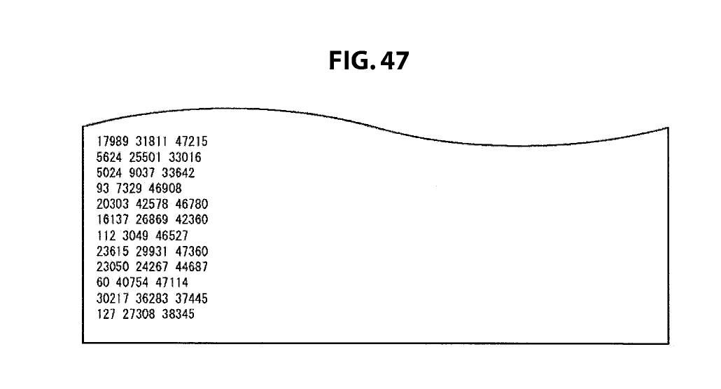

FIGS. 46 and 47 illustrate a parity check matrix initial value table with respect to the parity check matrix H of the LDPC code with a code length N of 64 k bits and an encoding rate of 8/30.

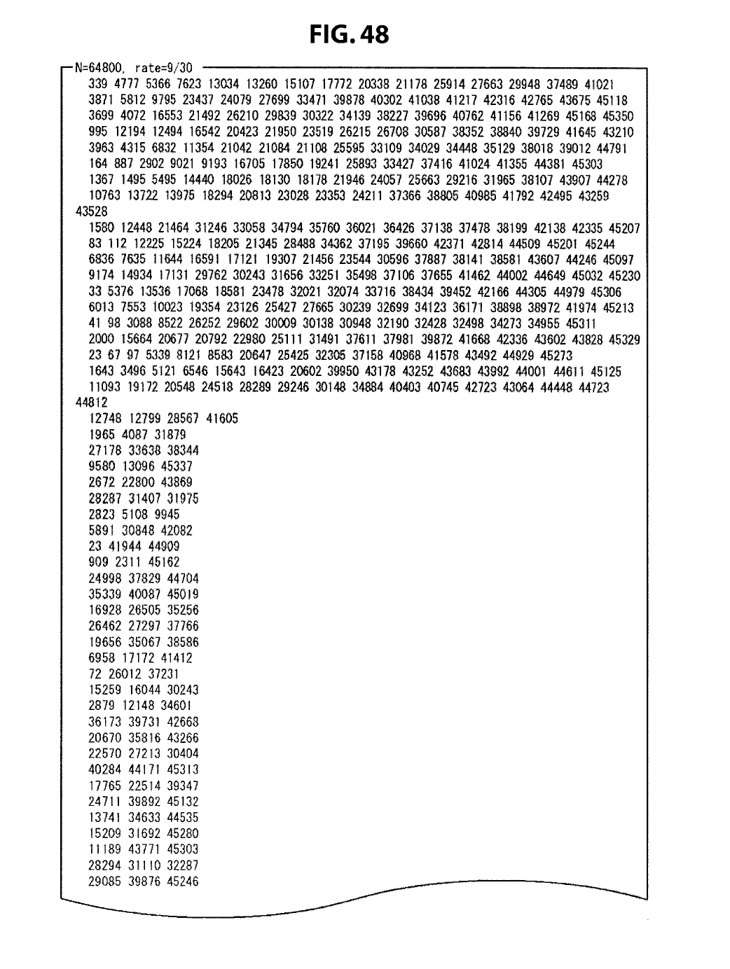

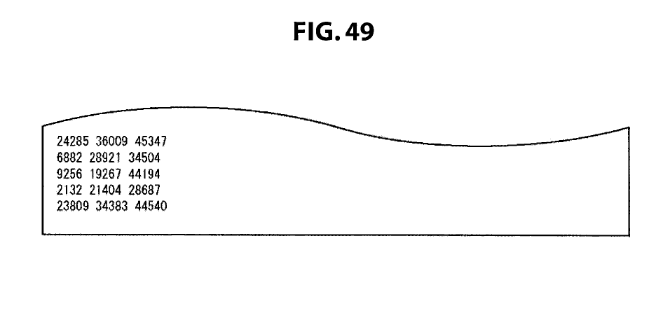

FIGS. 48 and 49 illustrate a parity check matrix initial value table with respect to the parity check matrix H of the LDPC code with a code length N of 64 k bits and an encoding rate of 9/30.

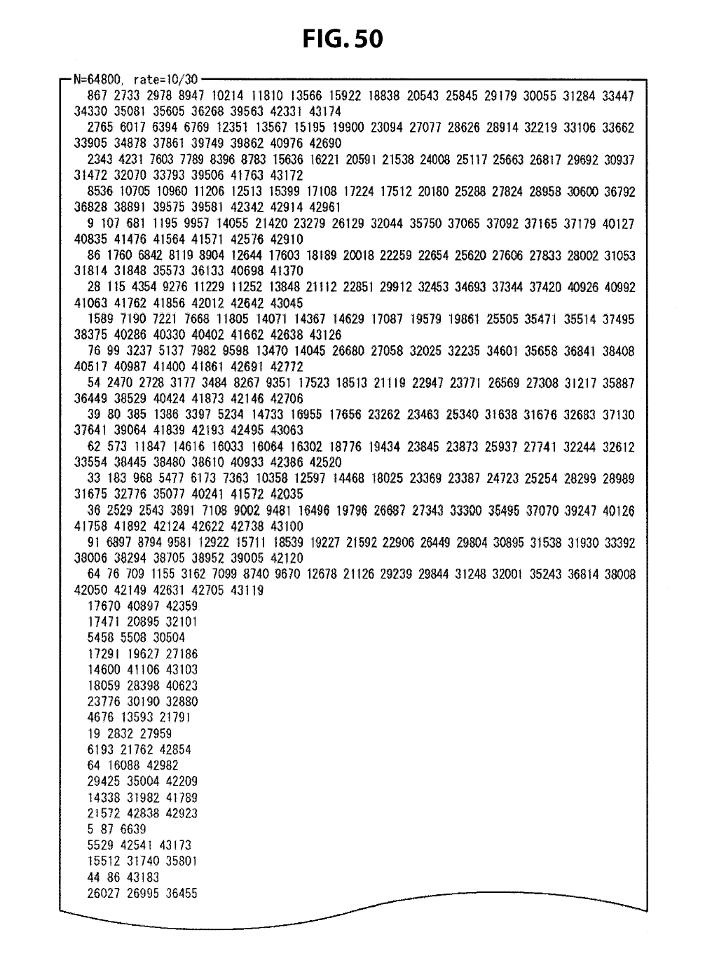

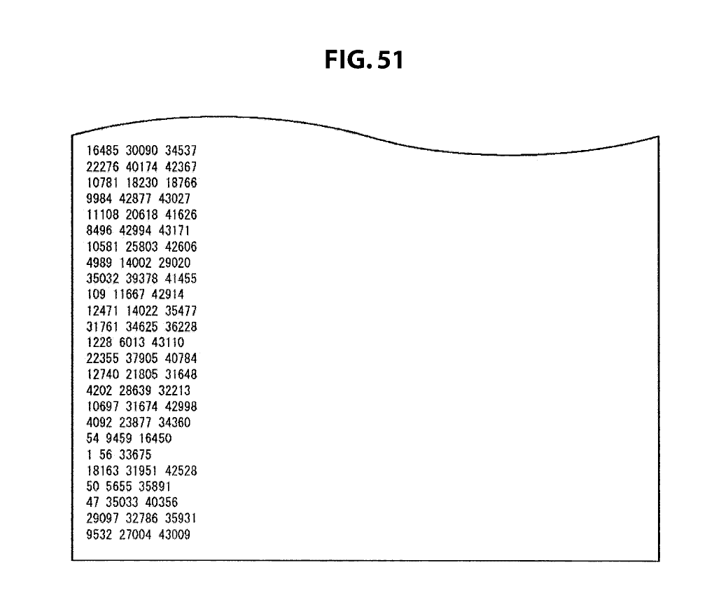

FIGS. 50 and 51 illustrate a parity check matrix initial value table with respect to the parity check matrix H of the LDPC code with a code length N of 64 k bits and an encoding rate of 10/30.

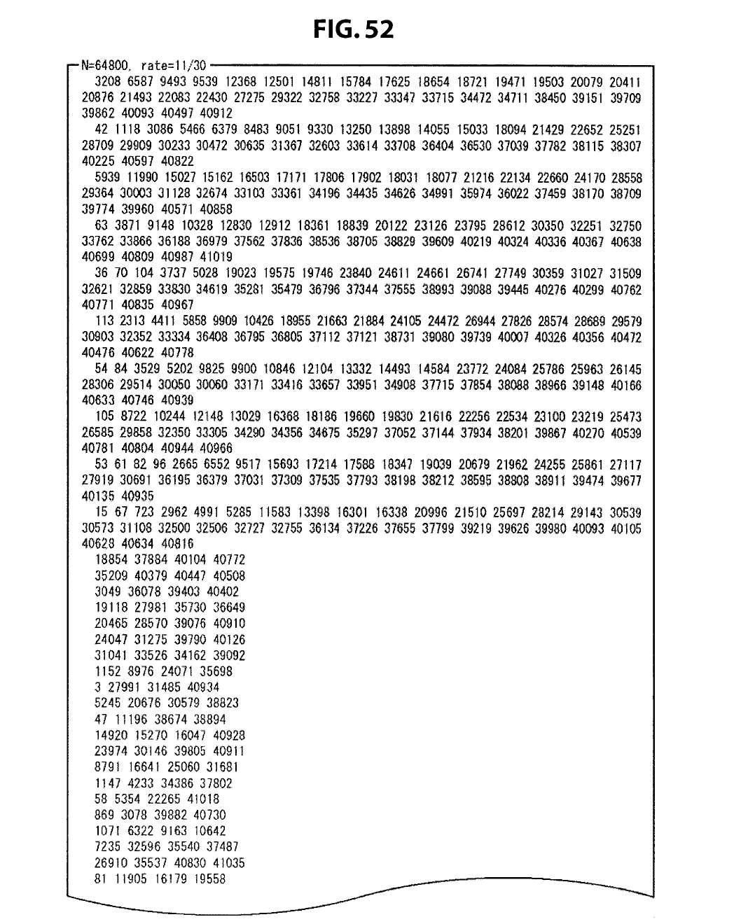

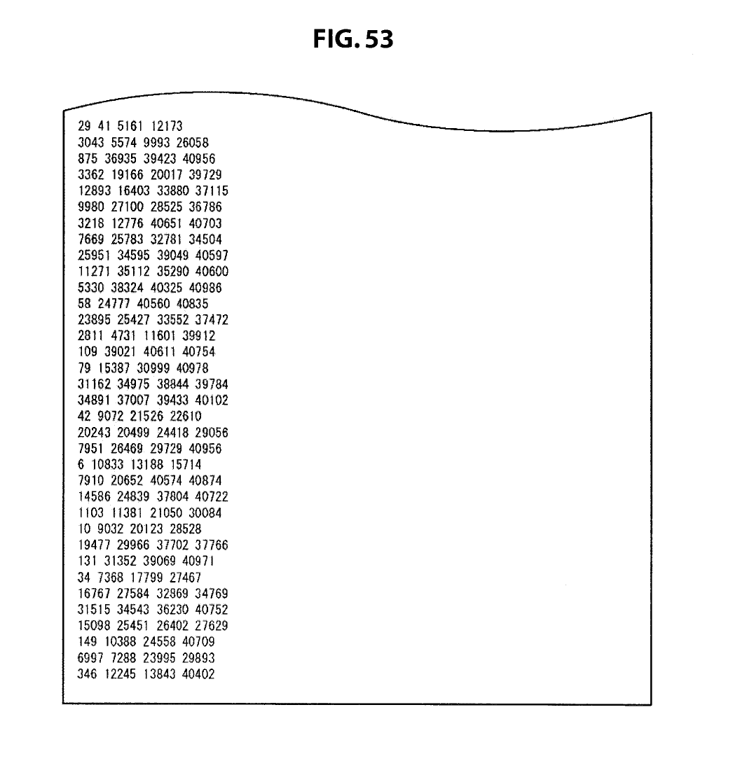

FIGS. 52 and 53 illustrate a parity check matrix initial value table with respect to the parity check matrix H of the LDPC code with a code length N of 64 k bits and an encoding rate of 11/30.

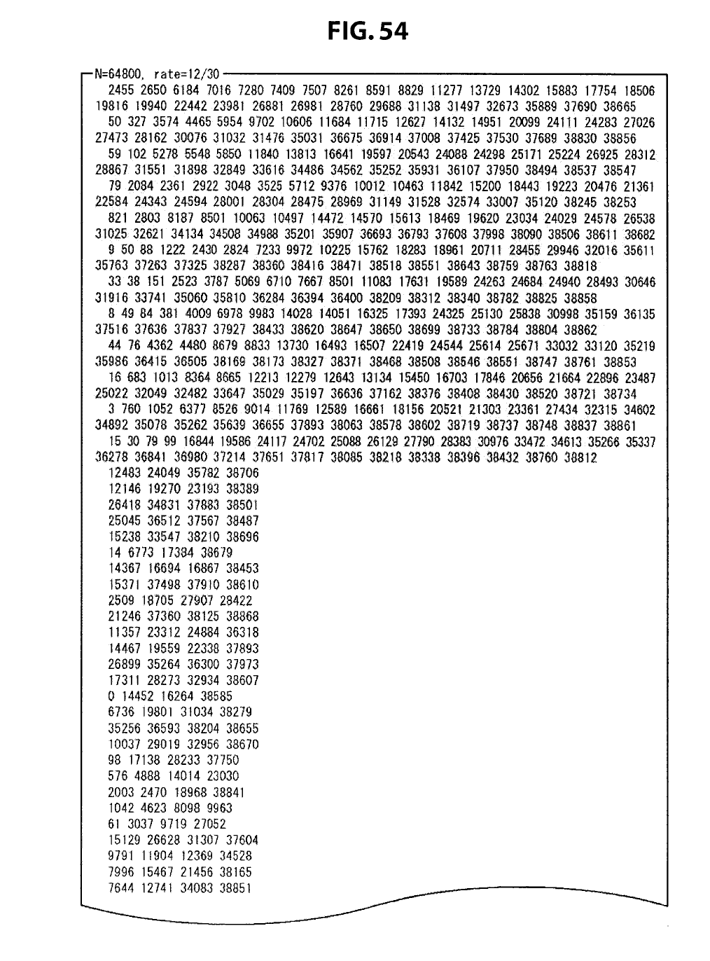

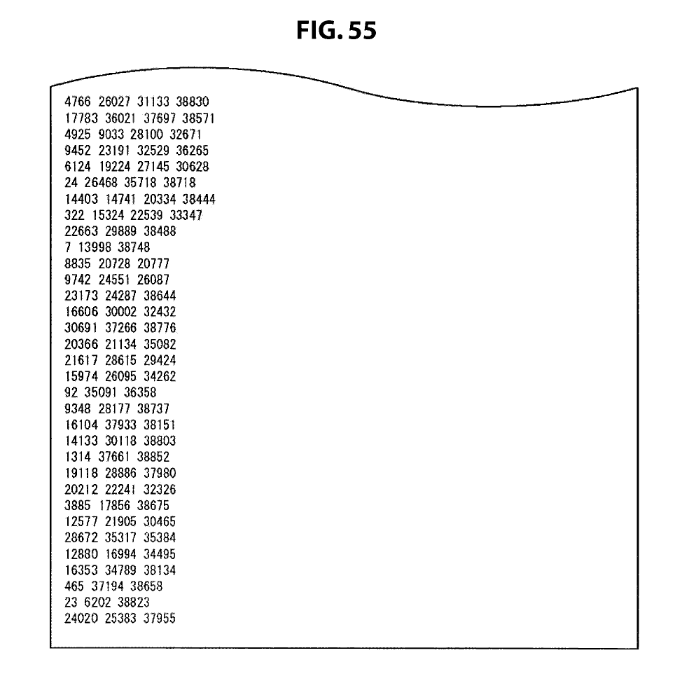

FIGS. 54 and 55 illustrate a parity check matrix initial value table with respect to the parity check matrix H of the LDPC code with a code length N of 64 k bits and an encoding rate of 12/30.

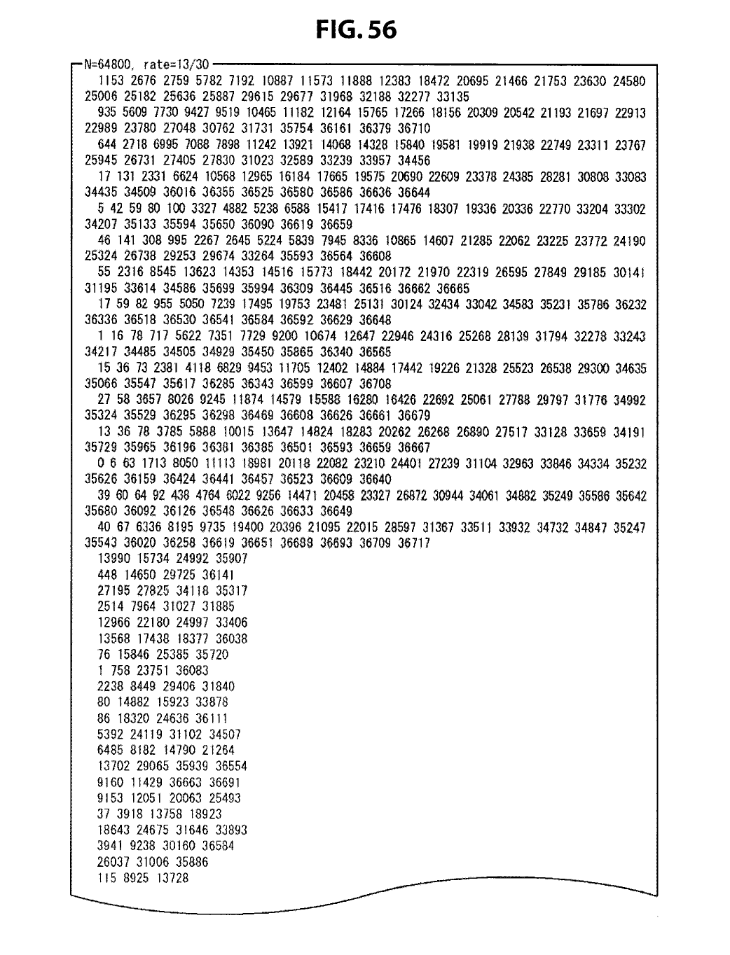

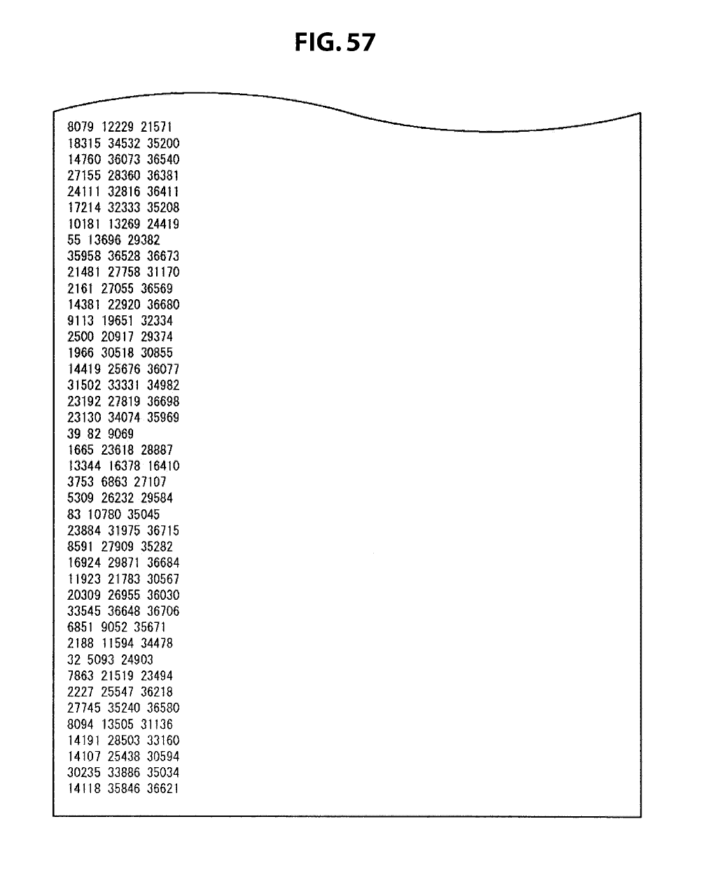

FIGS. 56 and 57 illustrate a parity check matrix initial value table with respect to the parity check matrix H of the LDPC code with a code length N of 64 k bits and an encoding rate of 13/30.

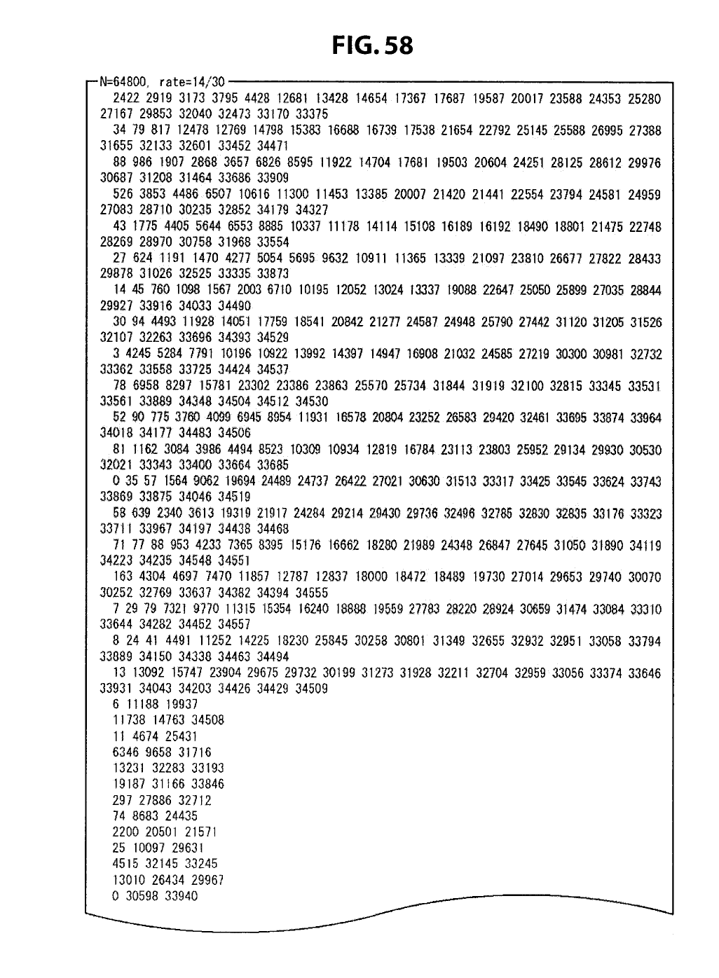

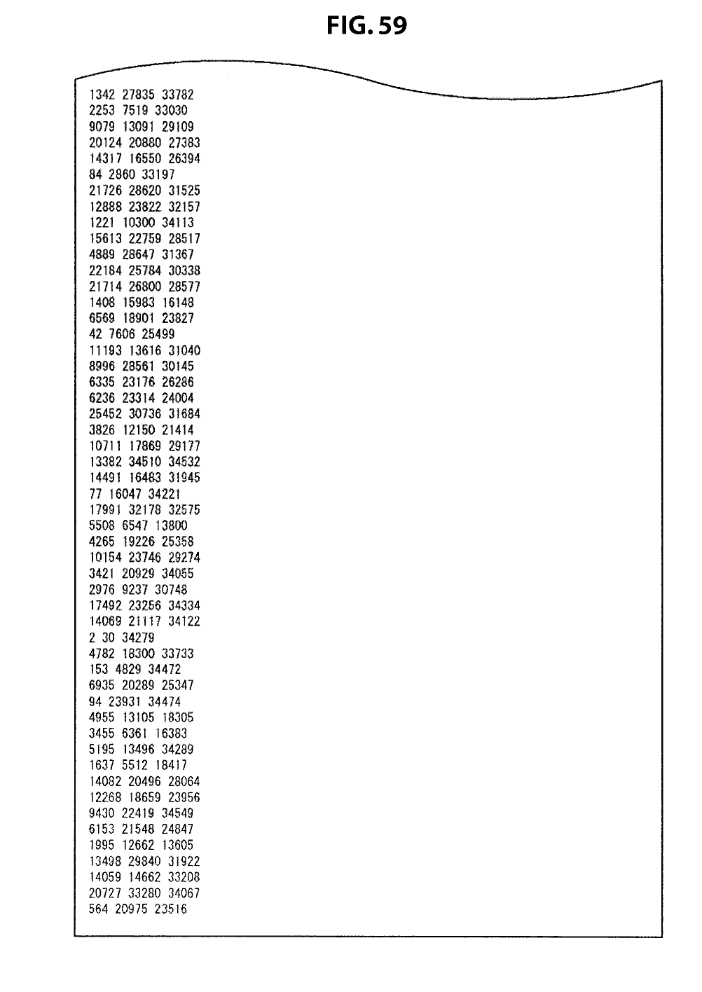

FIGS. 58 and 59 illustrate a parity check matrix initial value table with respect to the parity check matrix H of the LDPC code with a code length N of 64 k bits and an encoding rate of 14/30.

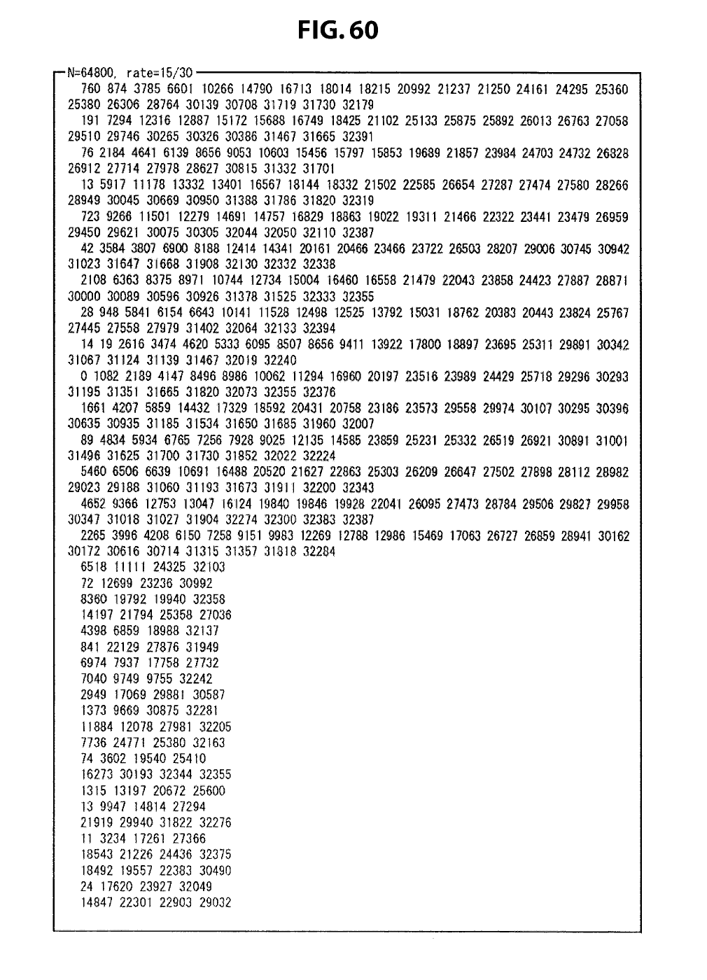

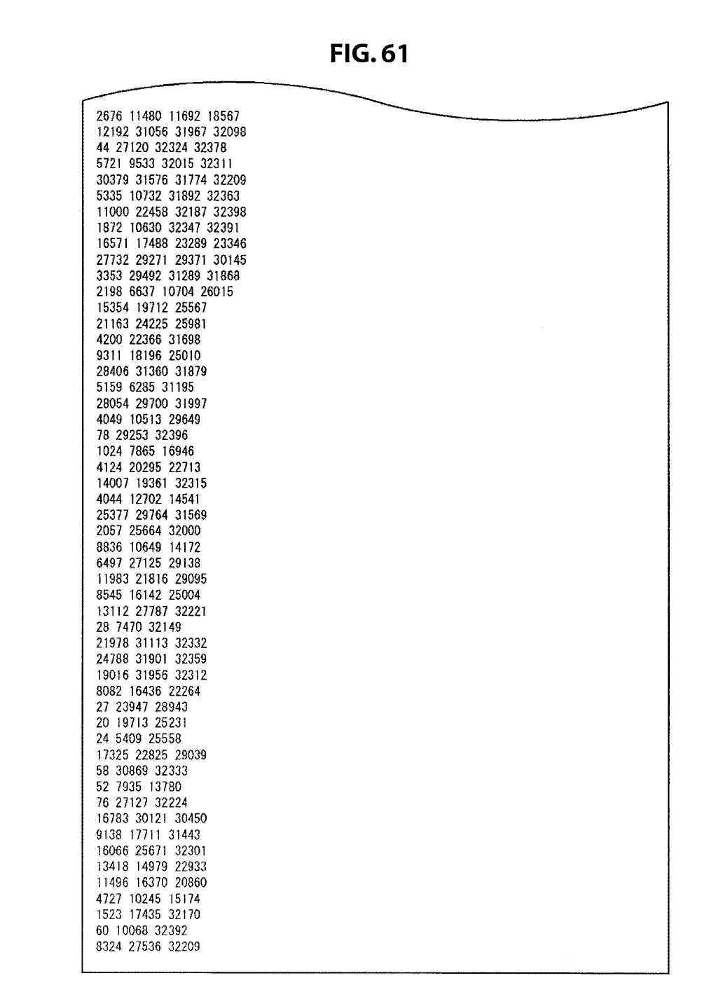

FIGS. 60 and 61 illustrate a parity check matrix initial value table with respect to the parity check matrix H of the LDPC code with a code length N of 64 k bits and an encoding rate of 15/30.

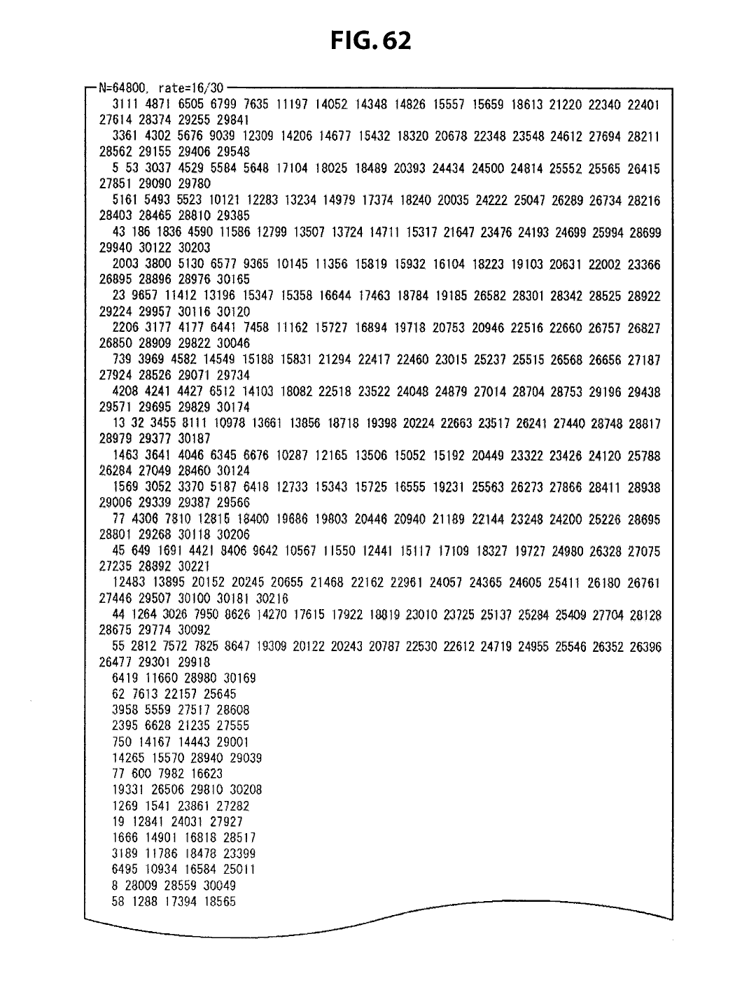

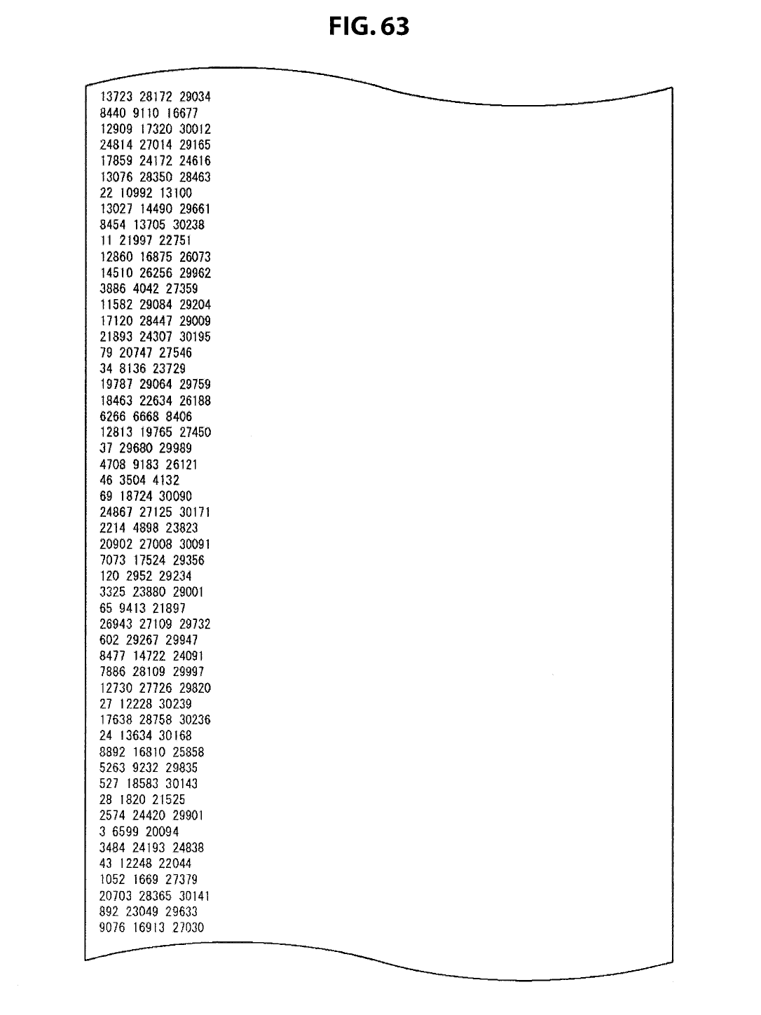

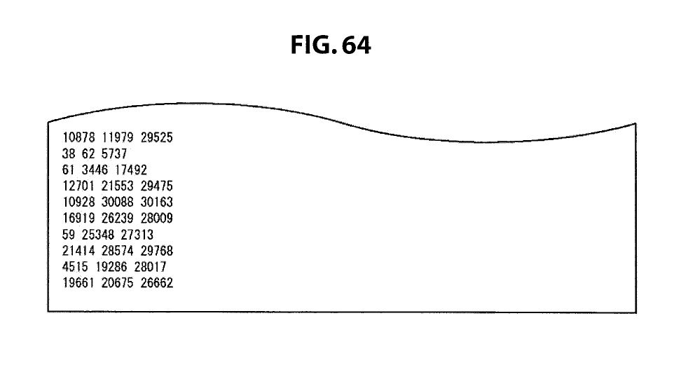

FIGS. 62, 63, and 64 illustrate a parity check matrix initial value table with respect to the parity check matrix H of the LDPC code with a code length N of 64 k bits and an encoding rate of 16/30.

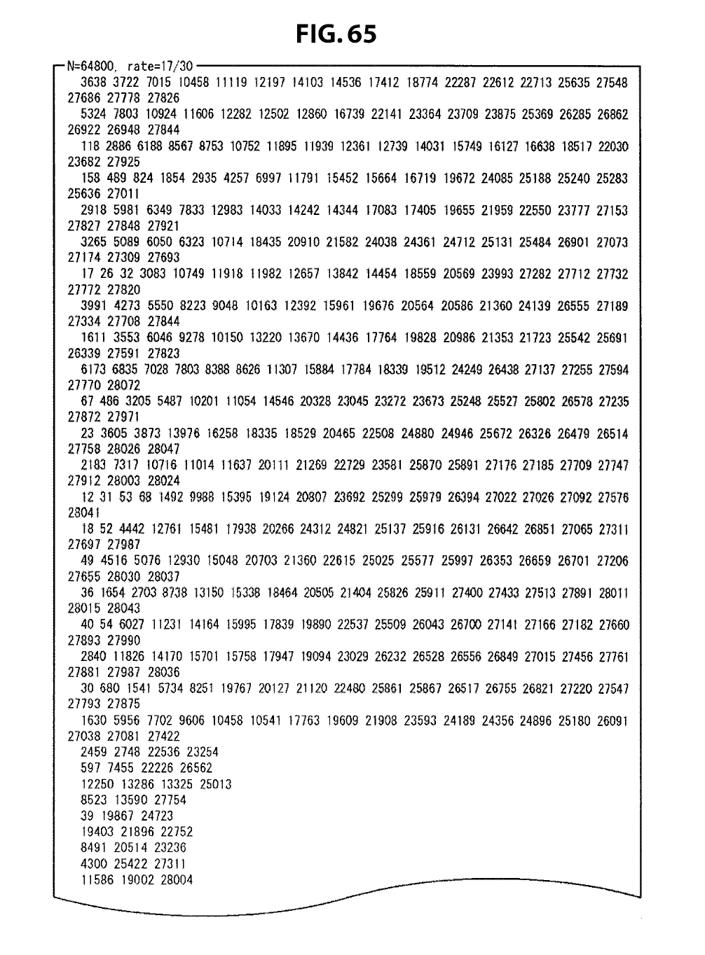

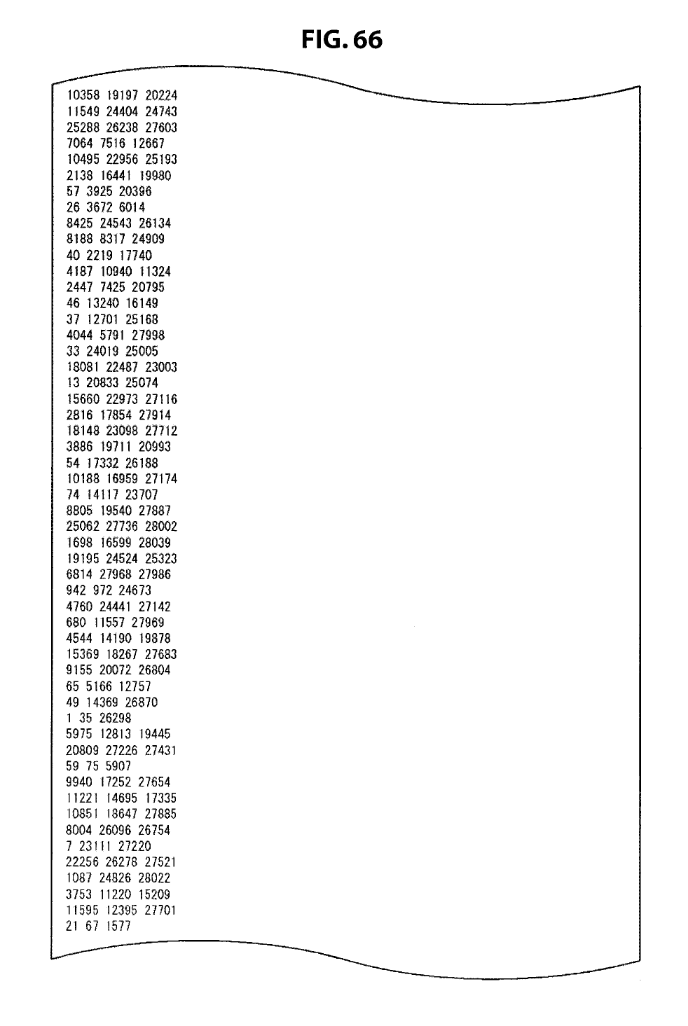

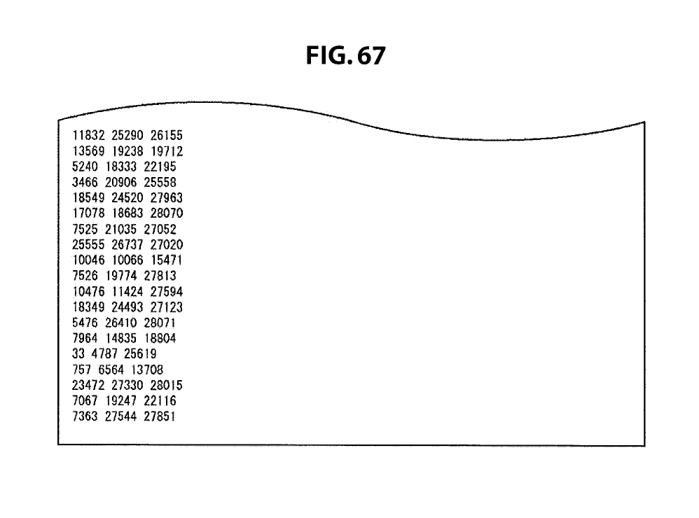

FIGS. 65, 66, and 67 illustrate a parity check matrix initial value table with respect to the parity check matrix H of the LDPC code with a code length N of 64 k bits and an encoding rate of 17/30.

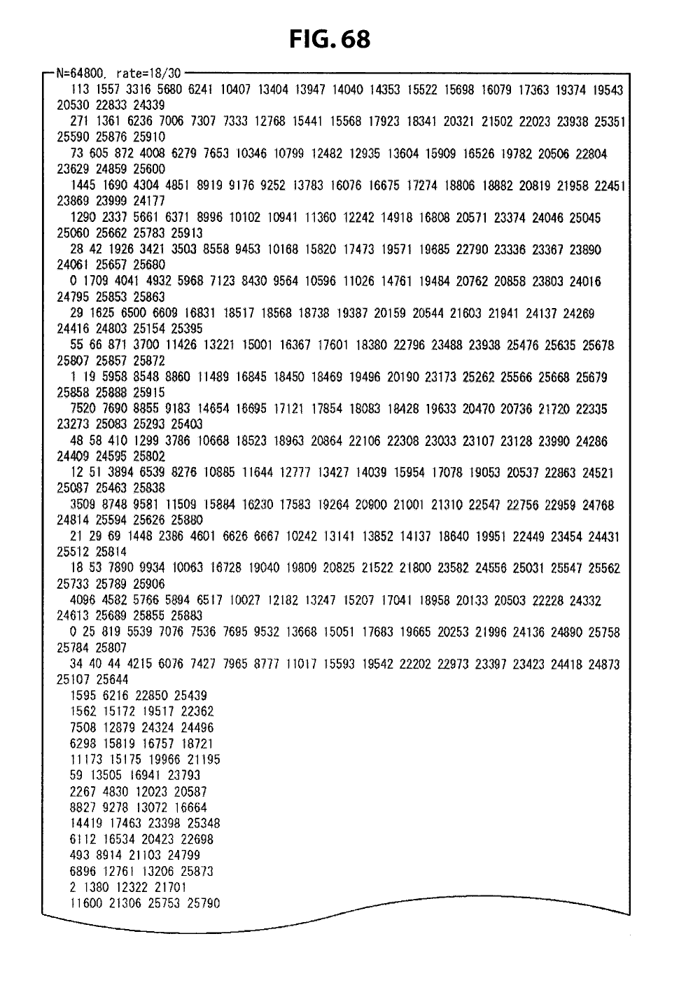

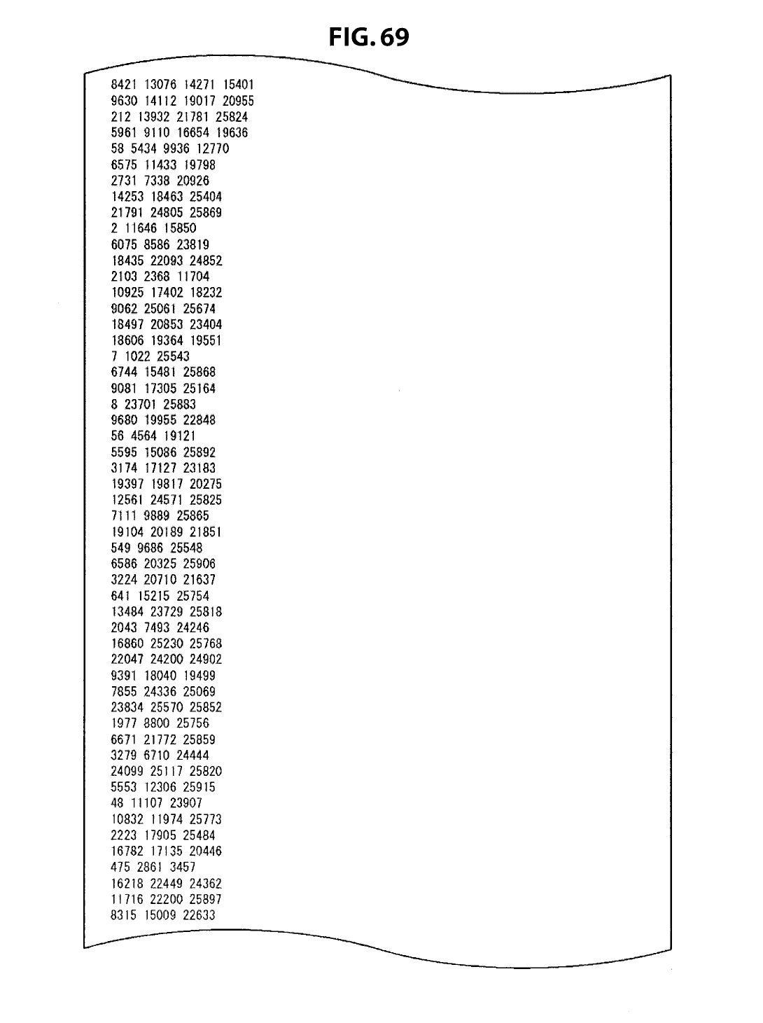

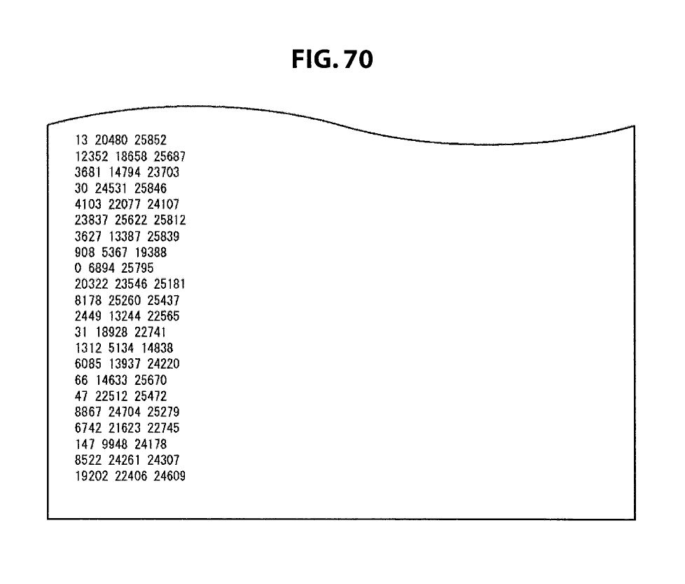

FIGS. 68, 69, and 70 illustrate a parity check matrix initial value table with respect to the parity check matrix H of the LDPC code with a code length N of 64 k bits and an encoding rate of 18/30.

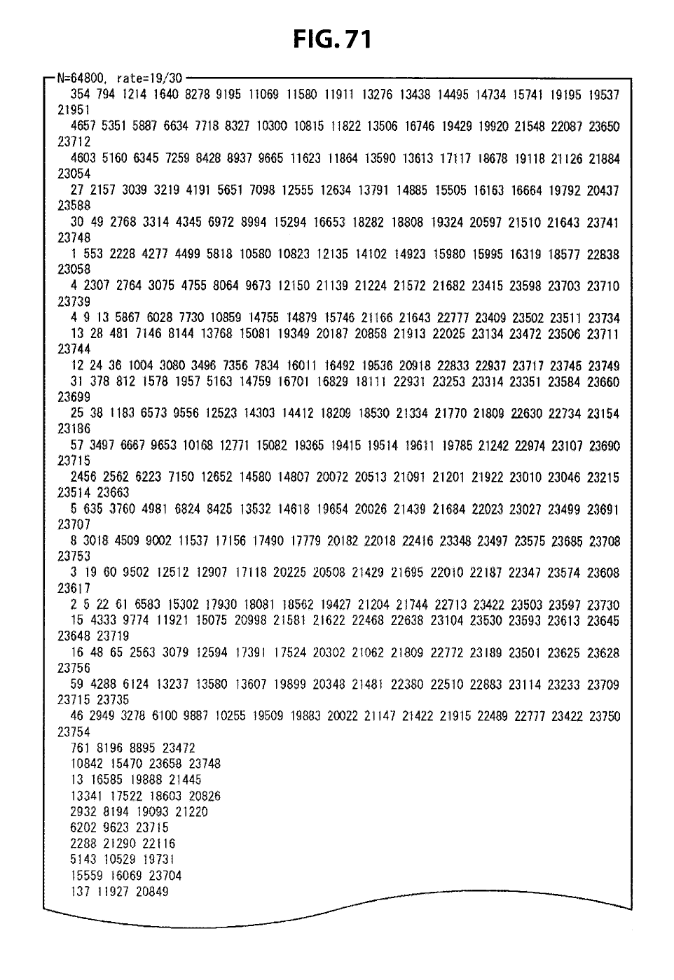

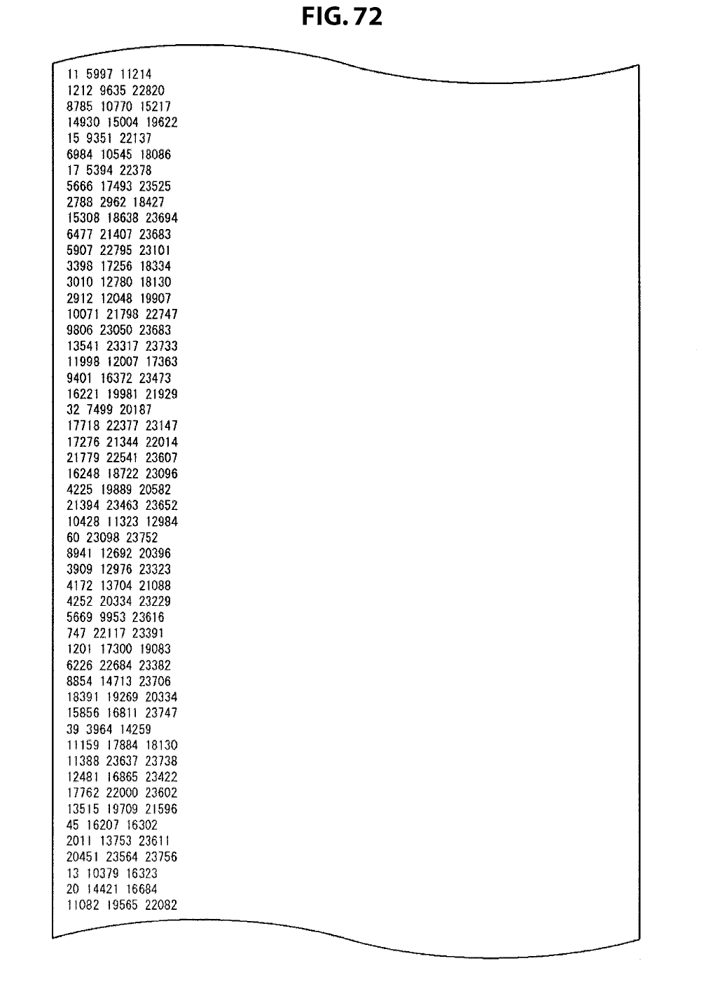

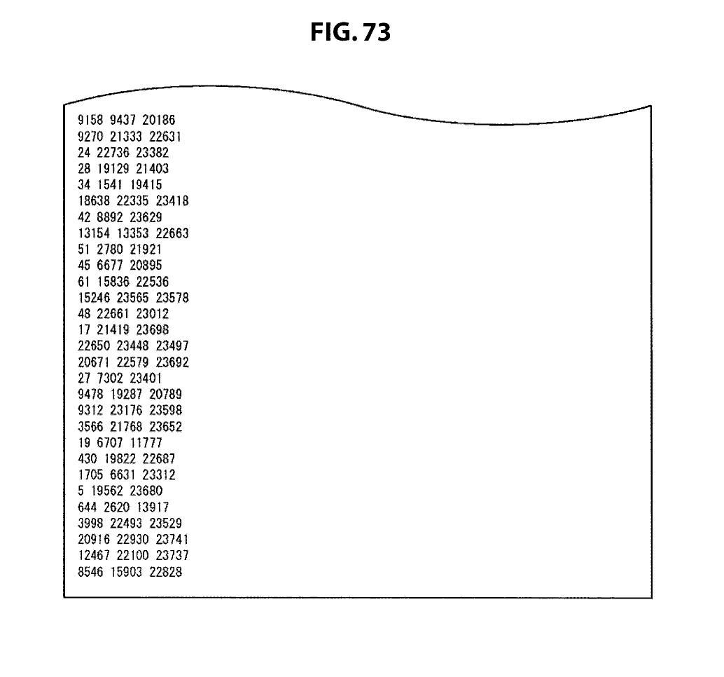

FIGS. 71, 72, and 73 illustrate a parity check matrix initial value table with respect to the parity check matrix H of the LDPC code with a code length N of 64 k bits and an encoding rate of 19/30.

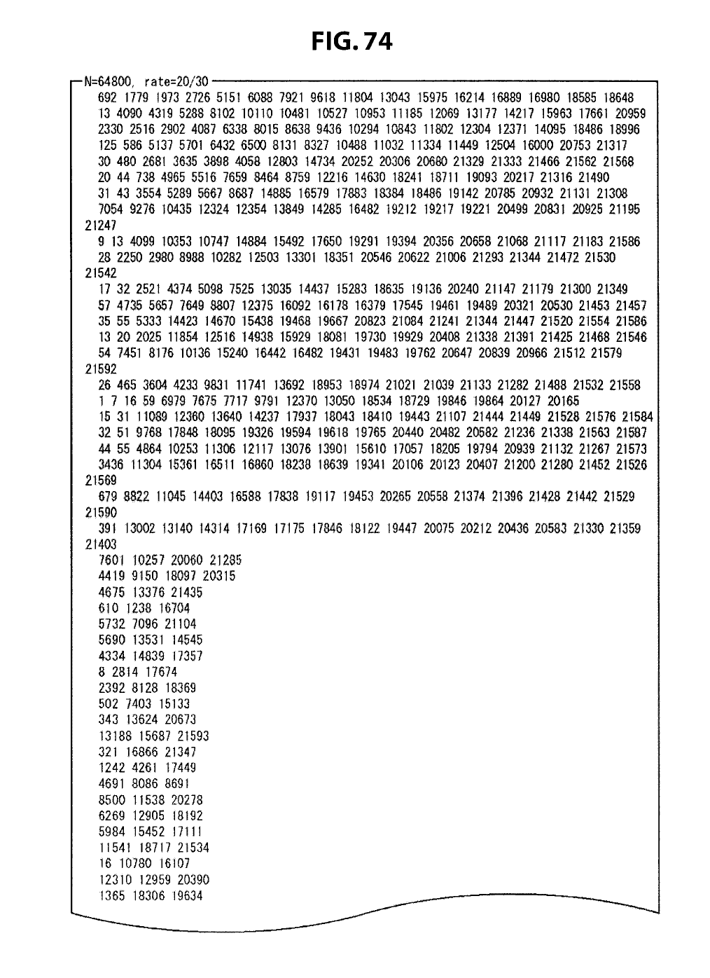

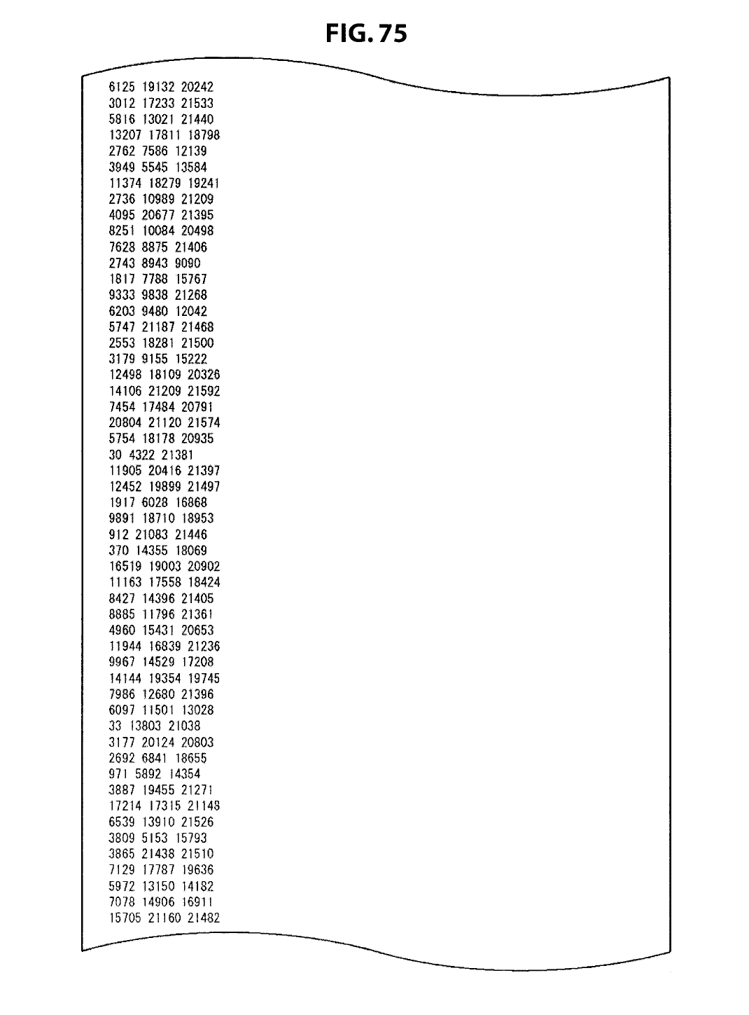

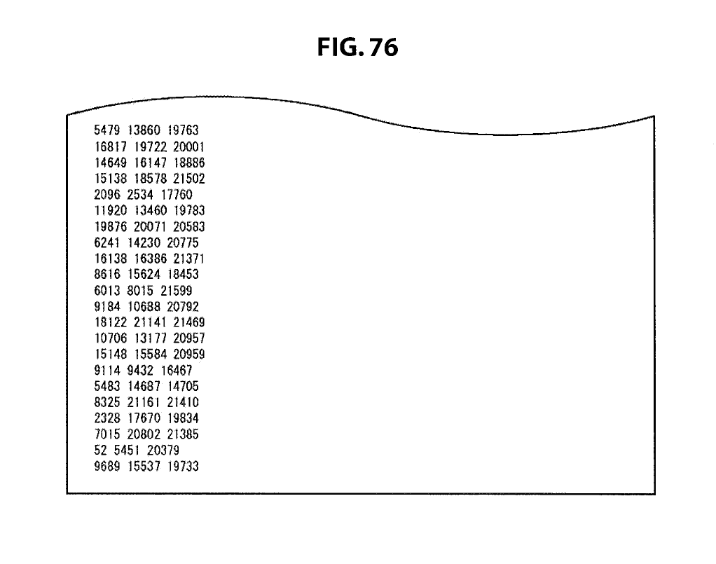

FIGS. 74, 75, and 76 illustrate a parity check matrix initial value table with respect to the parity check matrix H of the LDPC code with a code length N of 64 k bits and an encoding rate of 20/30.

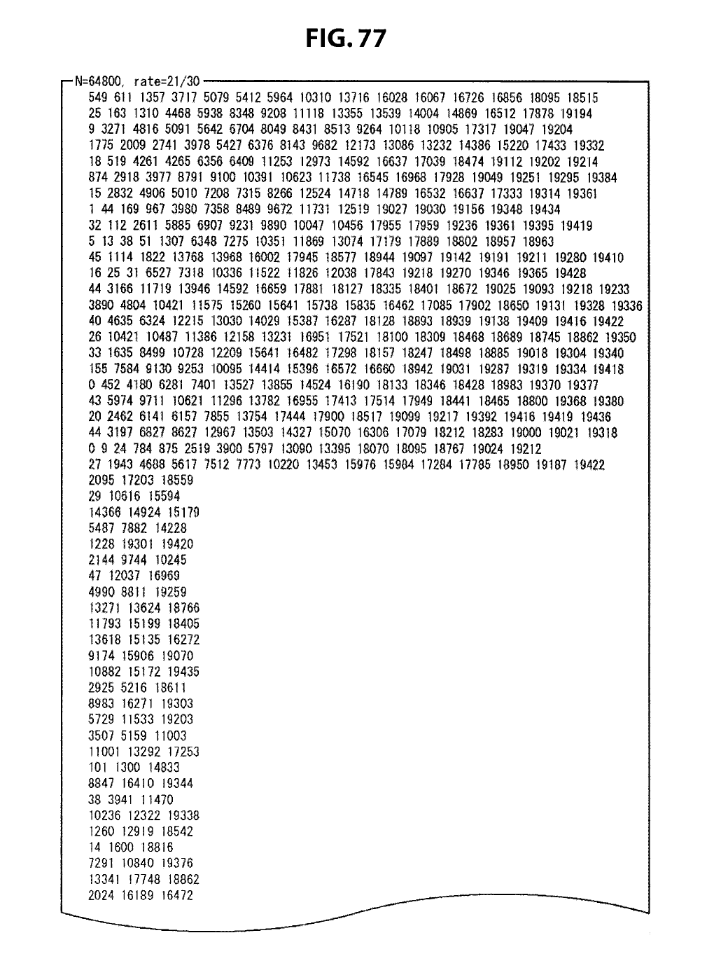

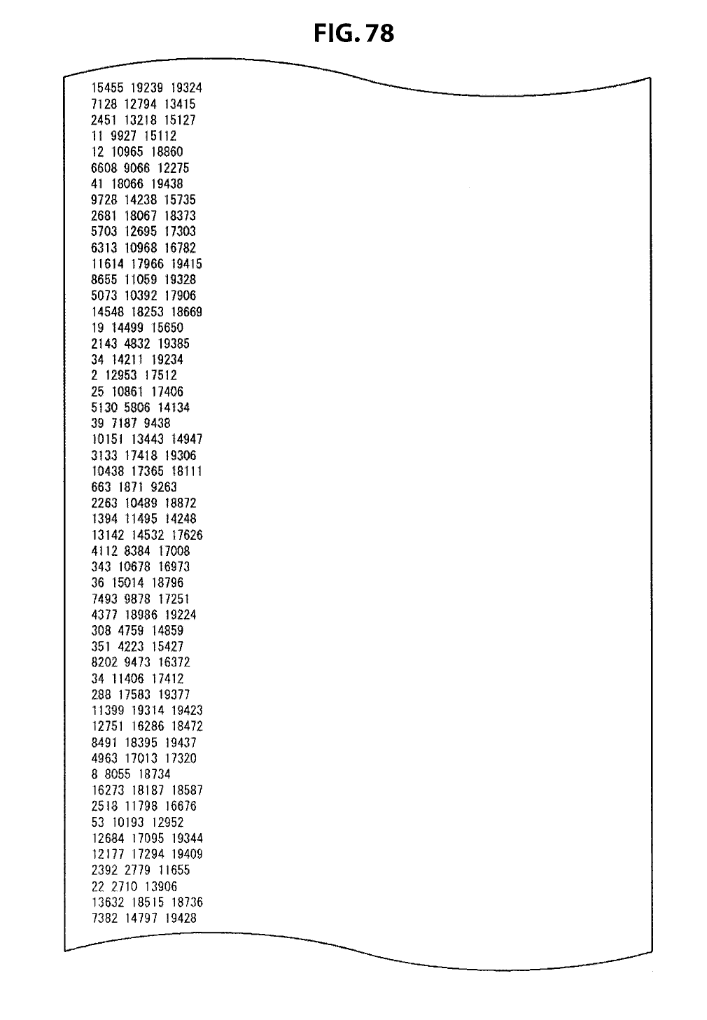

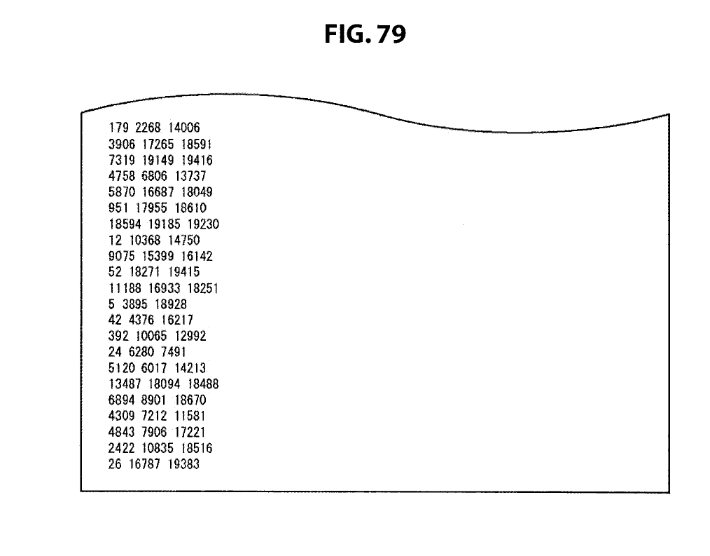

FIGS. 77, 78, and 79 illustrate a parity check matrix initial value table with respect to the parity check matrix H of the LDPC code with a code length N of 64 k bits and an encoding rate of 21/30.

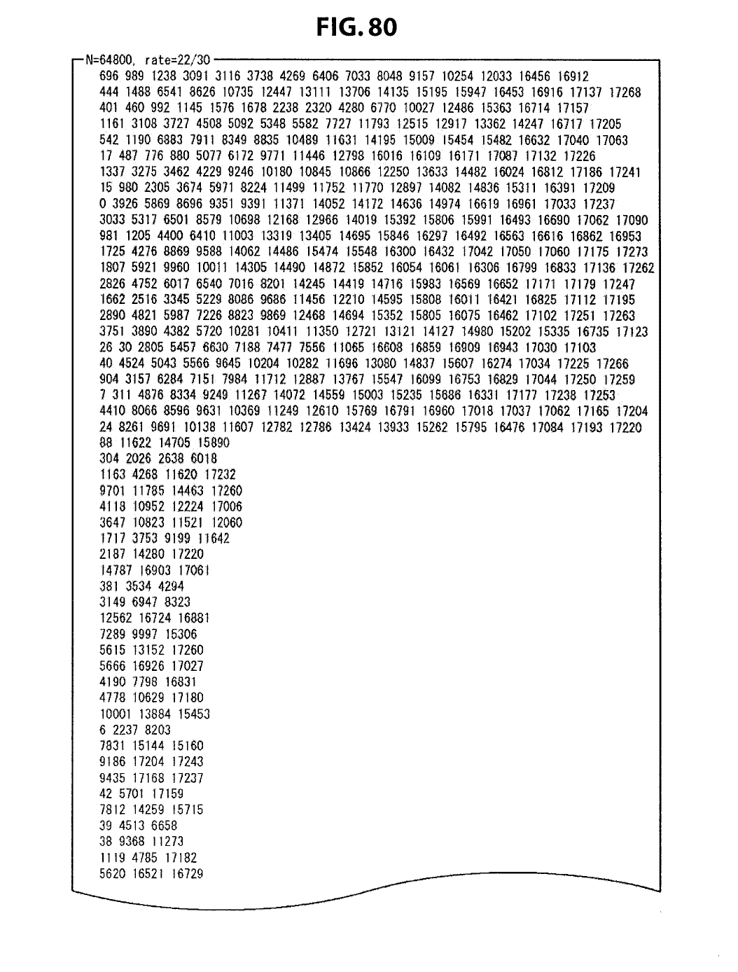

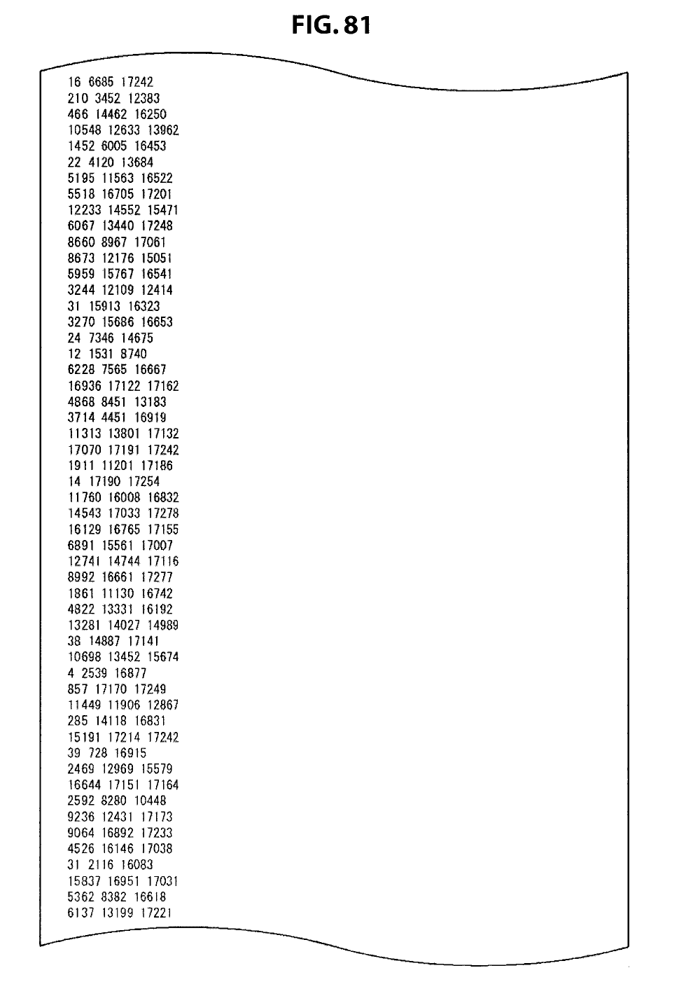

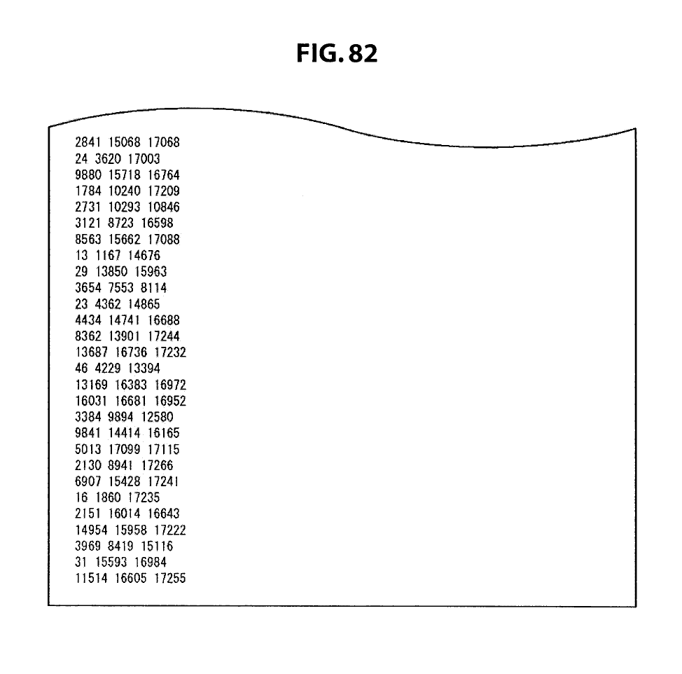

FIGS. 80, 81, and 82 illustrate a parity check matrix initial value table with respect to the parity check matrix H of the LDPC code with a code length N of 64 k bits and an encoding rate of 22/30.

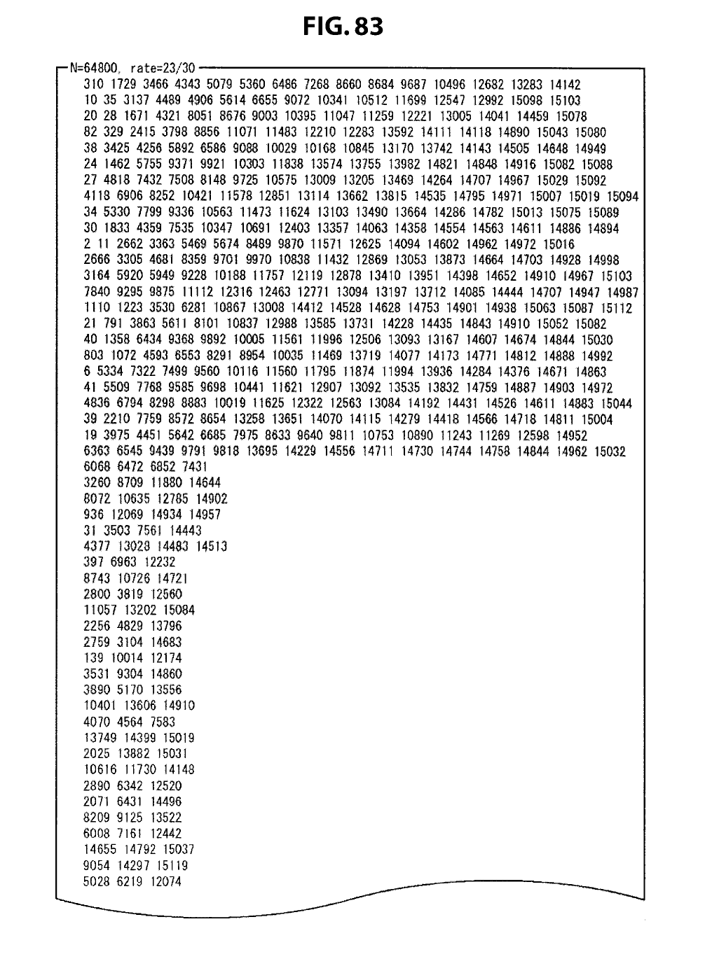

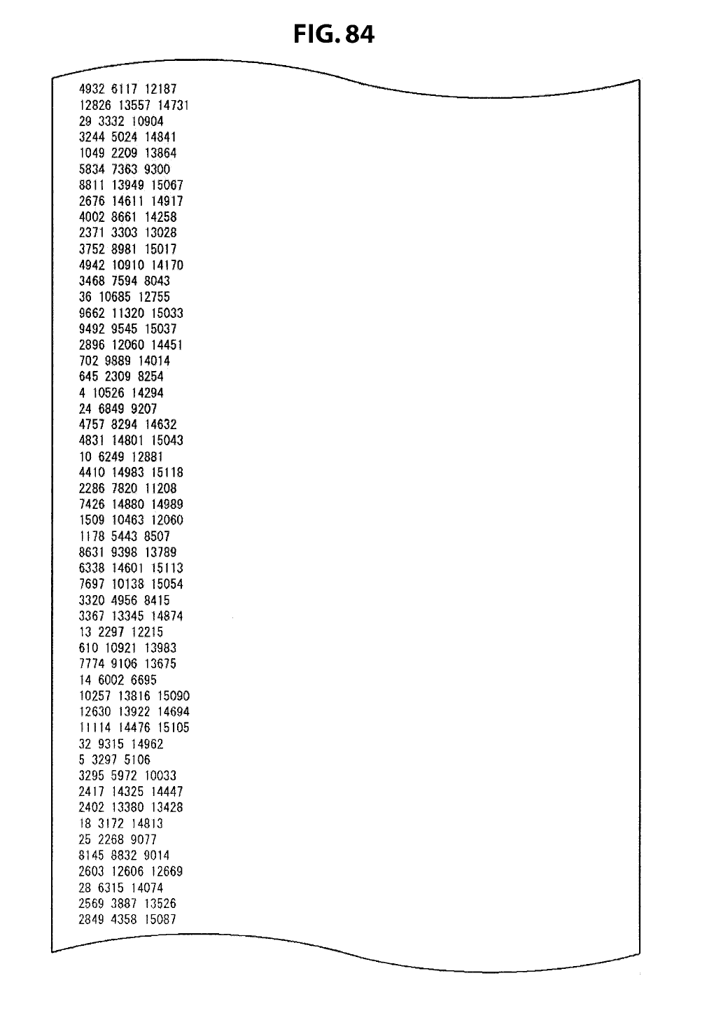

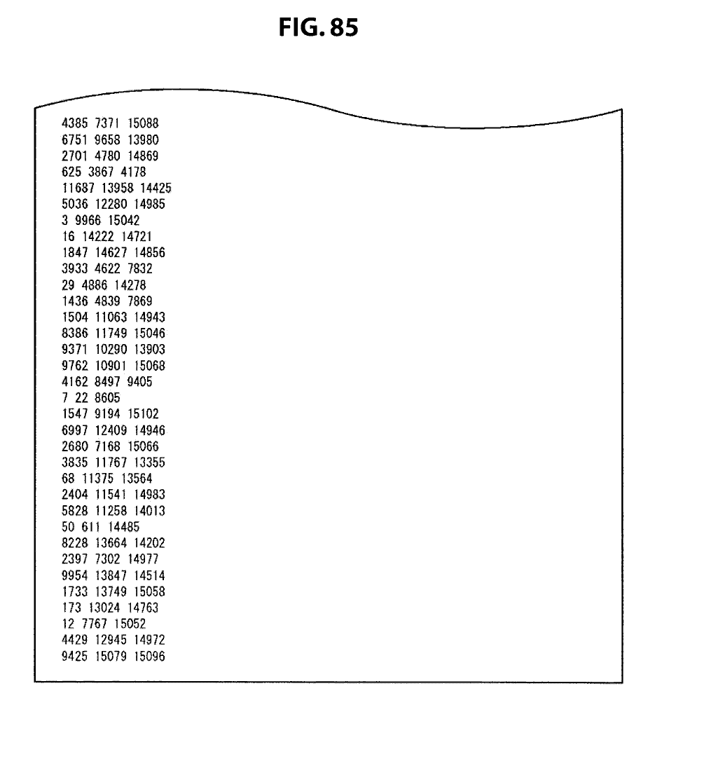

FIGS. 83, 84, and 85 illustrate a parity check matrix initial value table with respect to the parity check matrix H of the LDPC code with a code length N of 64 k bits and an encoding rate of 23/30.

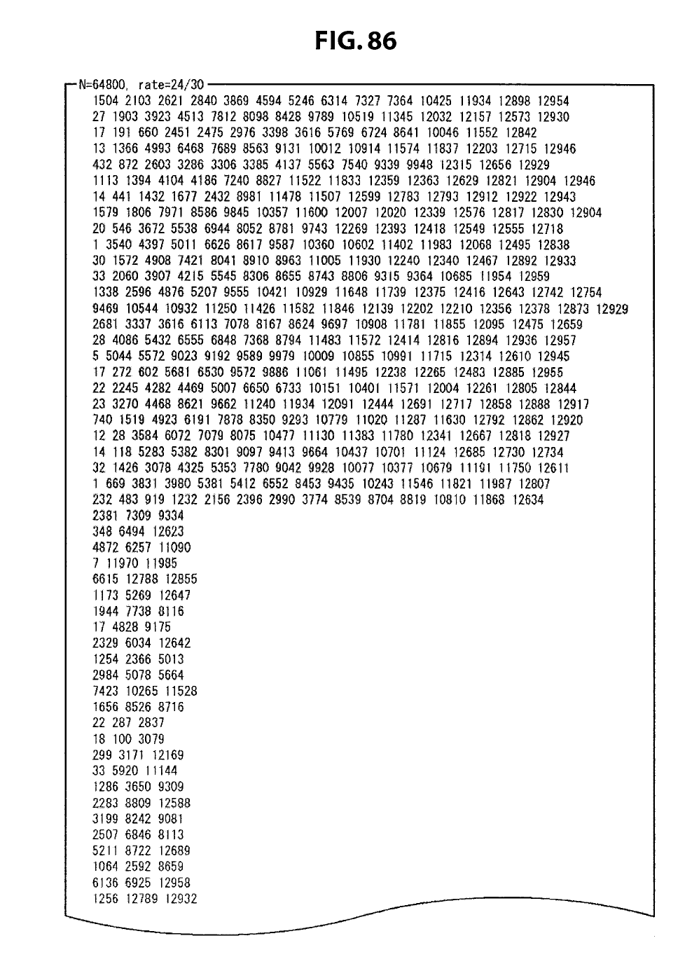

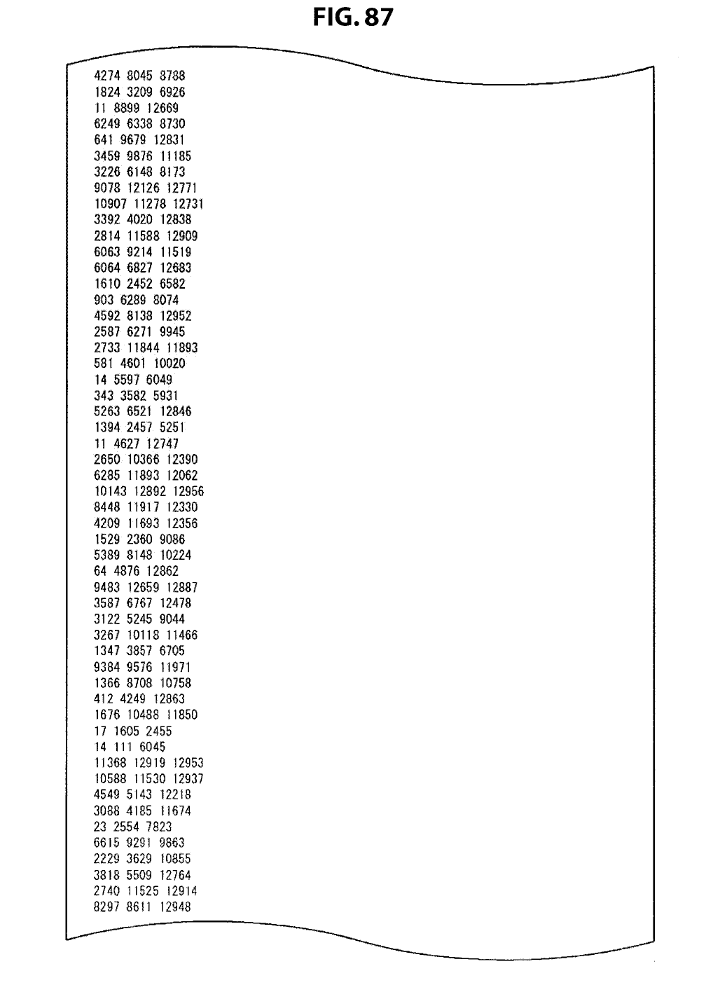

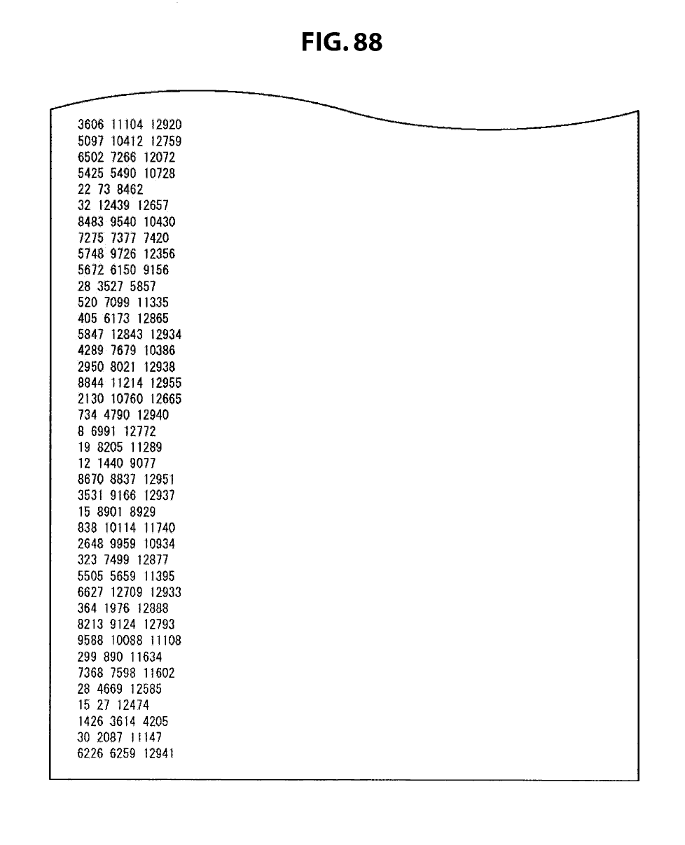

FIGS. 86, 87, and 88 illustrate a parity check matrix initial value table with respect to the parity check matrix H of the LDPC code with a code length N of 64 k bits and an encoding rate of 24/30.

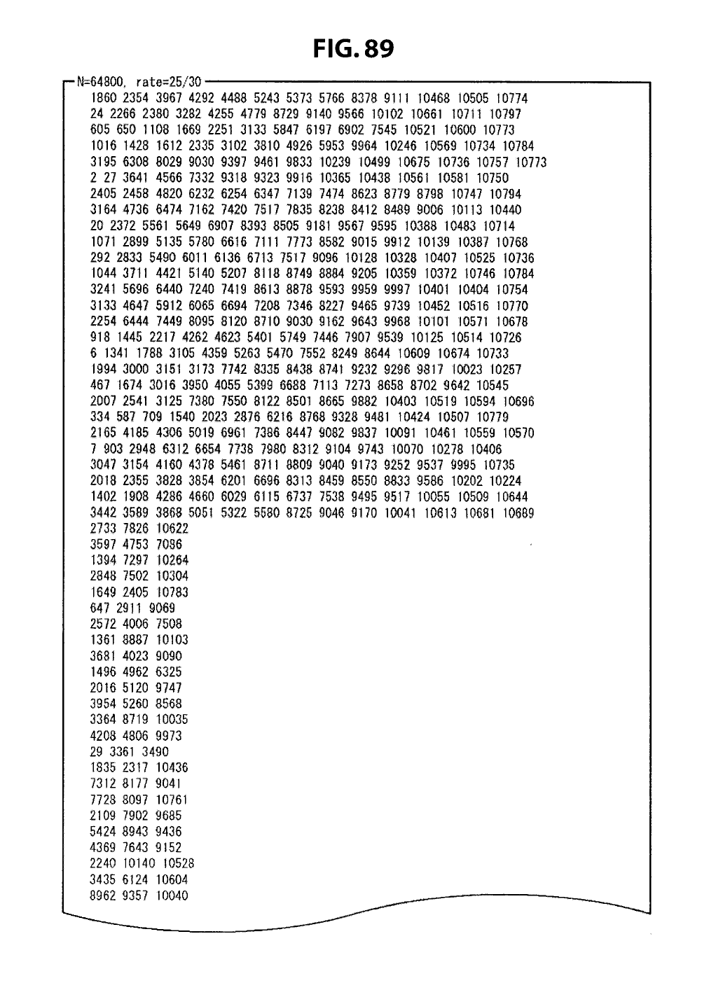

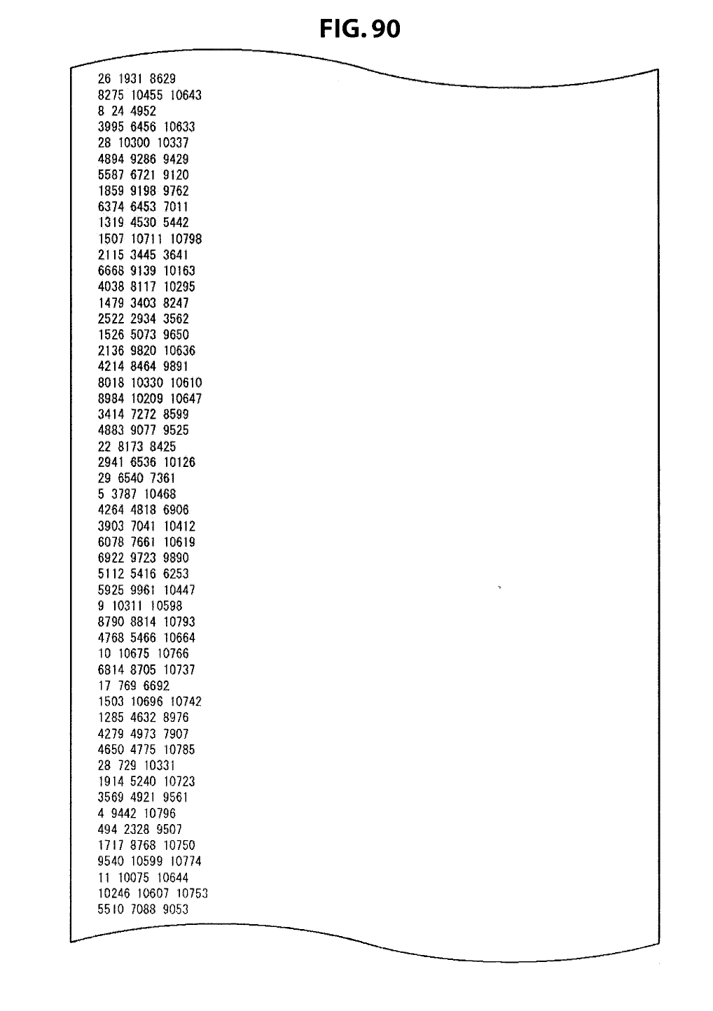

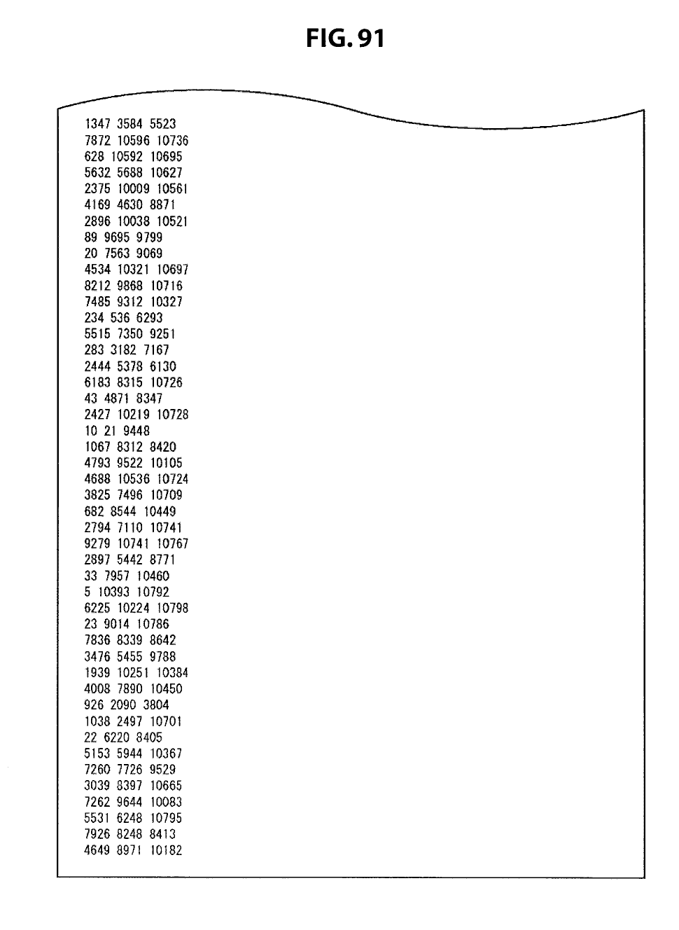

FIGS. 89, 90, and 91 illustrate a parity check matrix initial value table with respect to the parity check matrix H of the LDPC code with a code length N of 64 k bits and an encoding rate of 25/30.

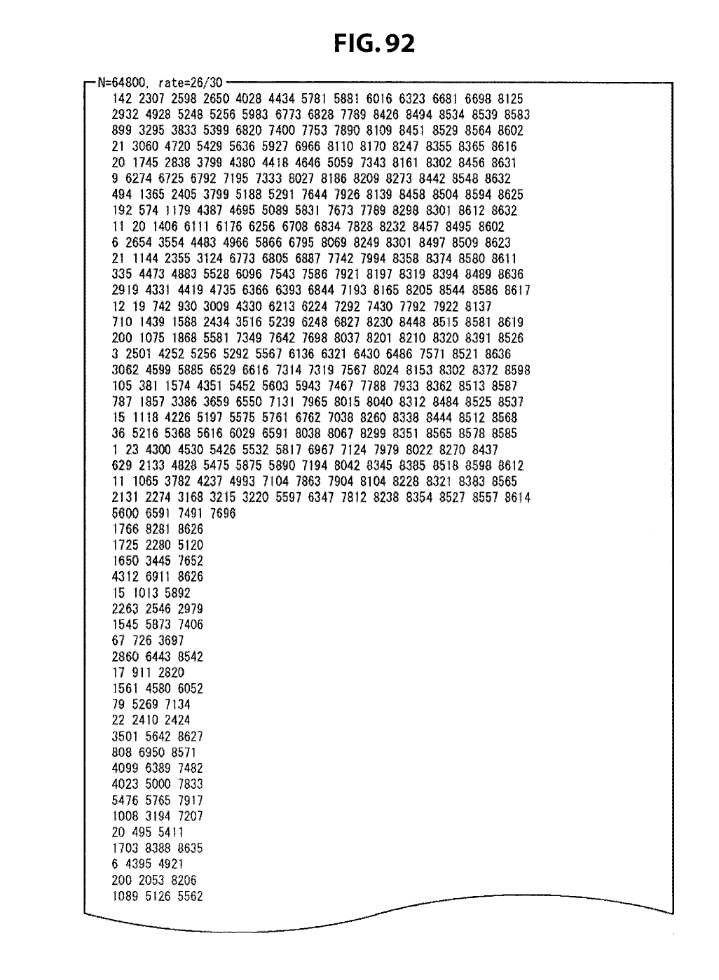

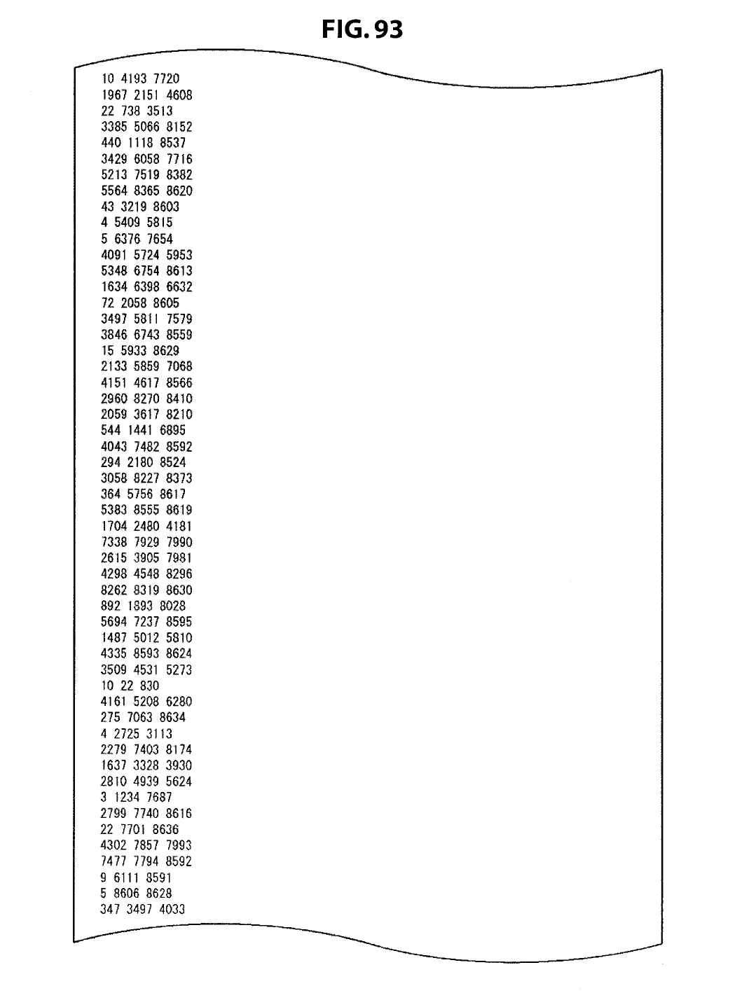

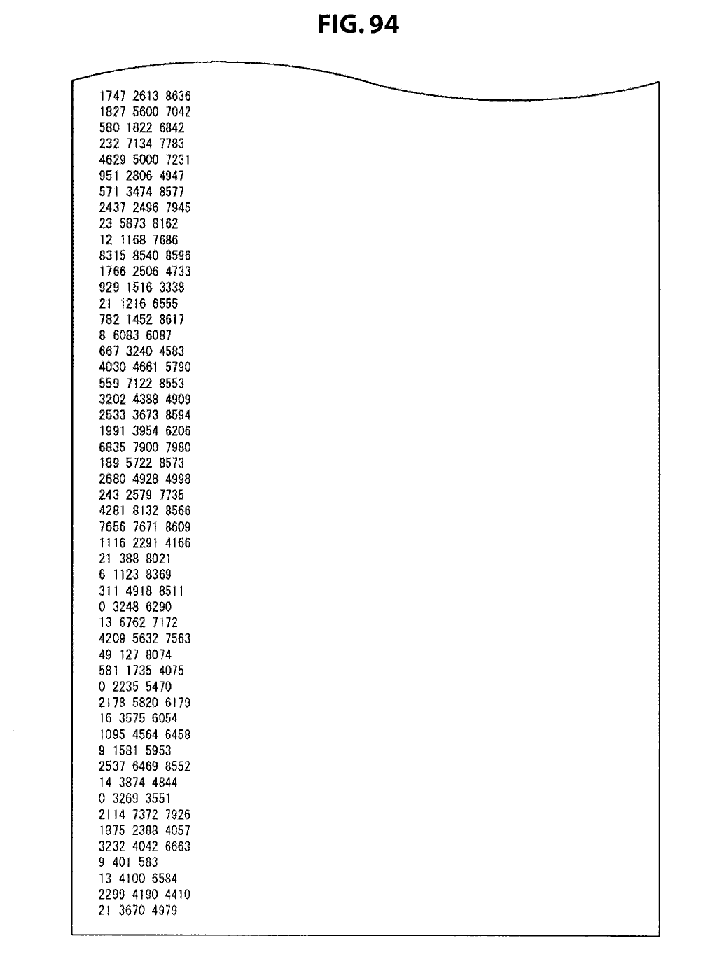

FIGS. 92, 93, and 94 illustrate a parity check matrix initial value table with respect to the parity check matrix H of the LDPC code with a code length N of 64 k bits and an encoding rate of 26/30.

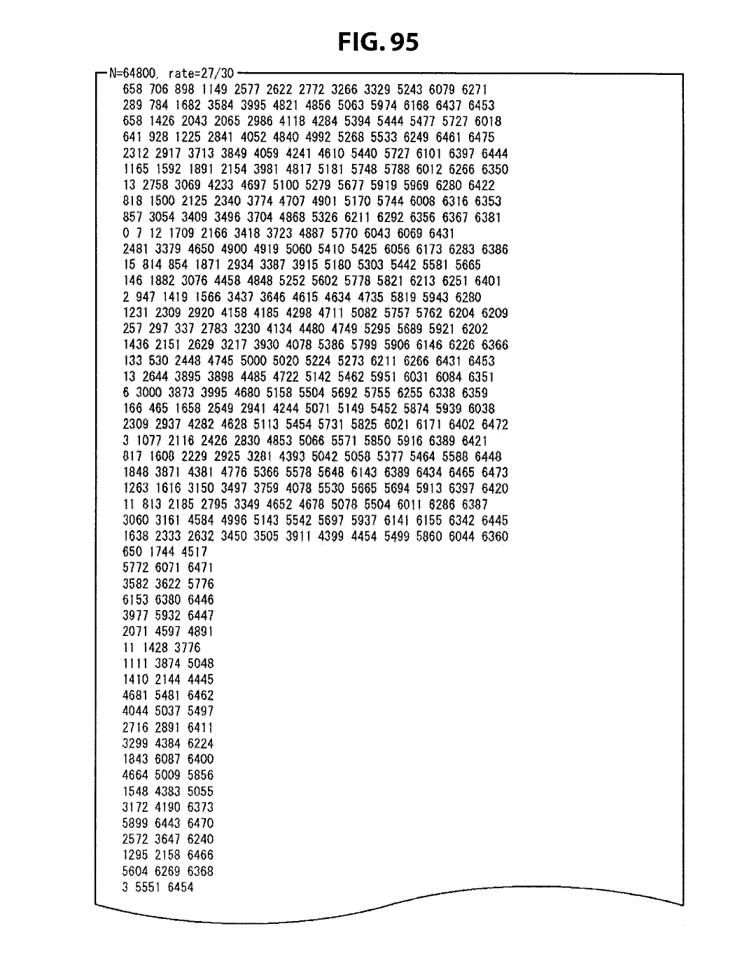

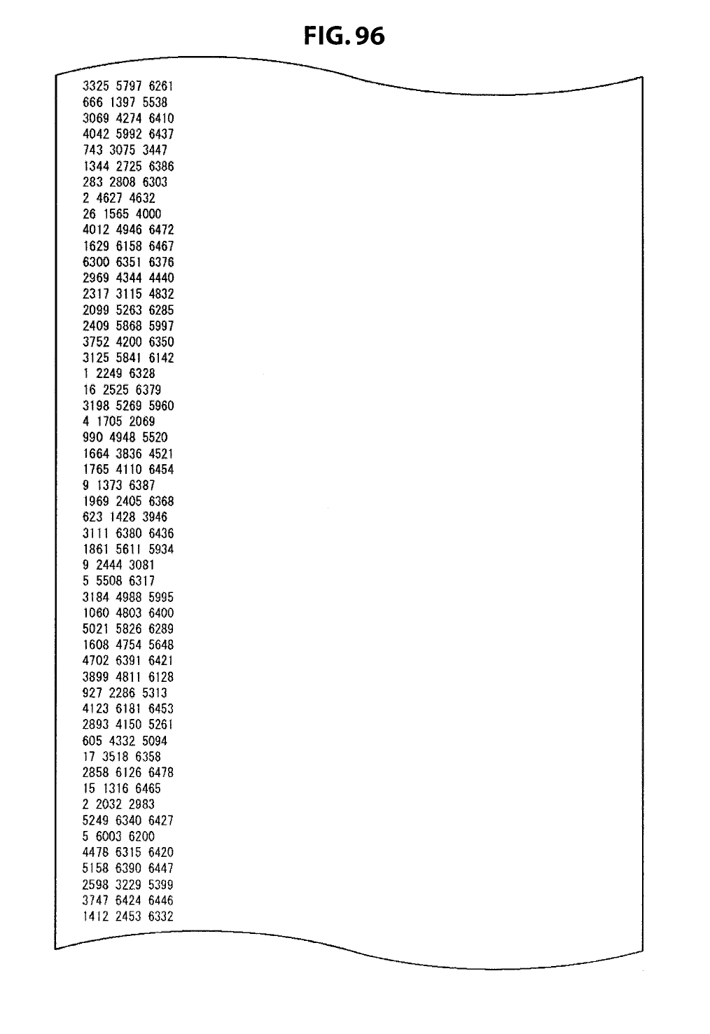

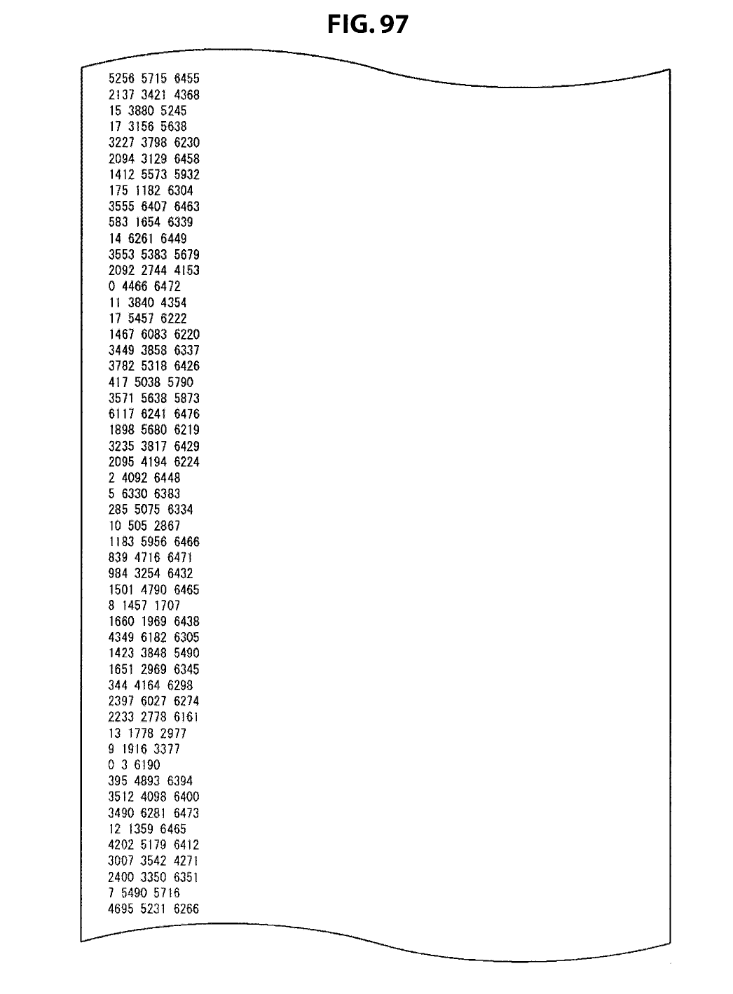

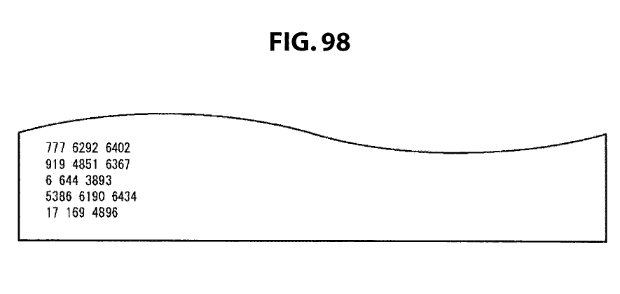

FIGS. 95, 96, and 97 illustrate a parity check matrix initial value table with respect to the parity check matrix H of the LDPC code with a code length N of 64 k bits and an encoding rate of 27/30.

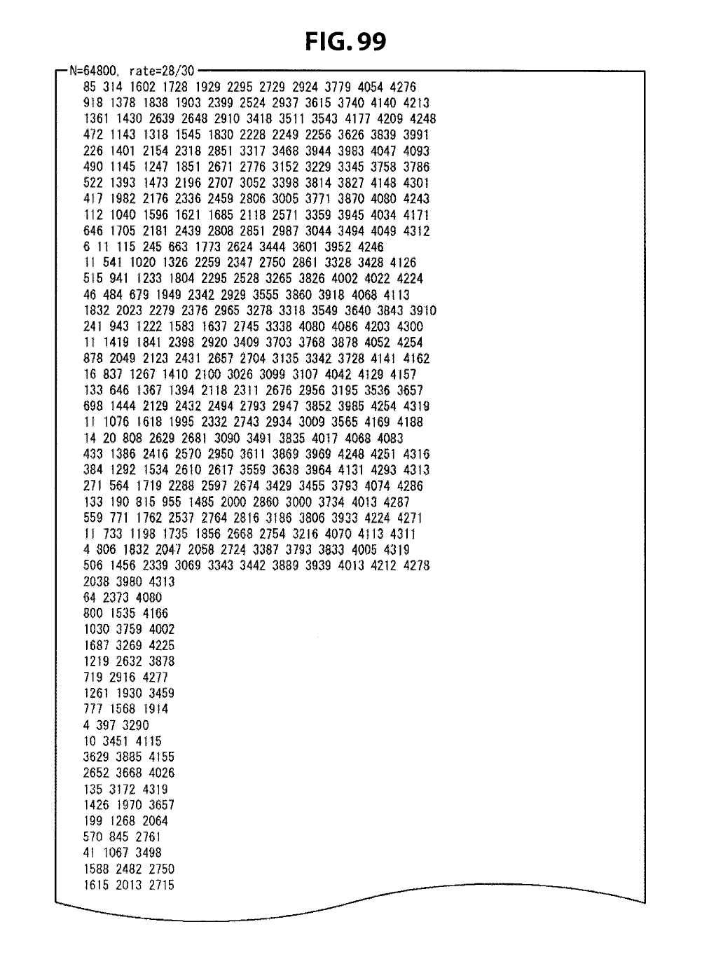

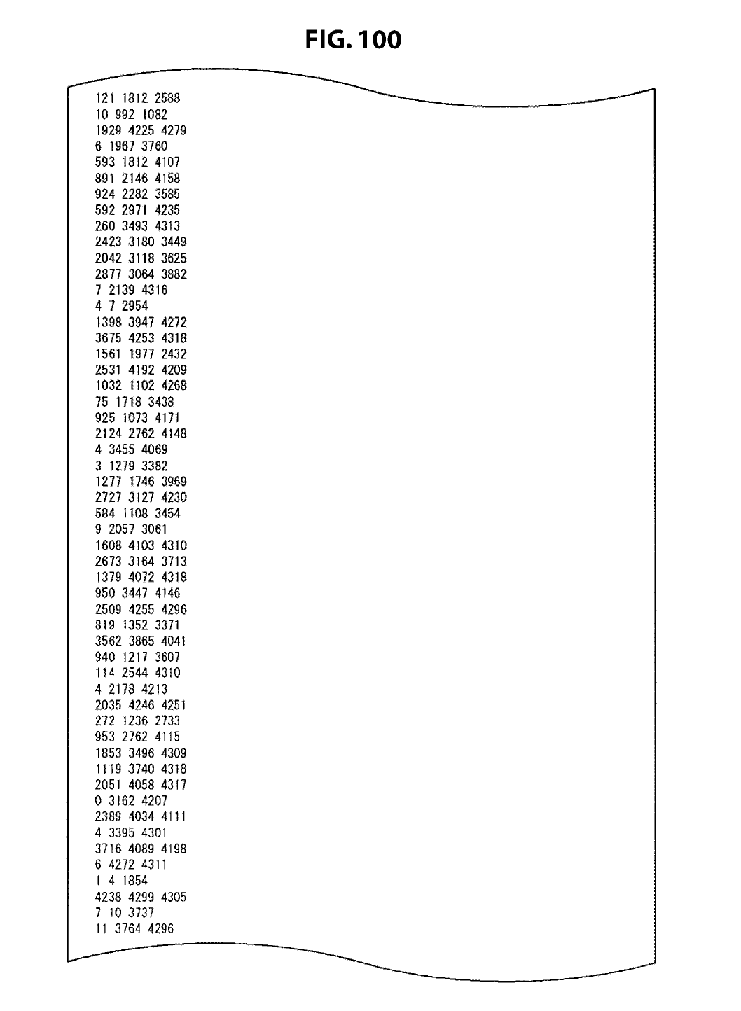

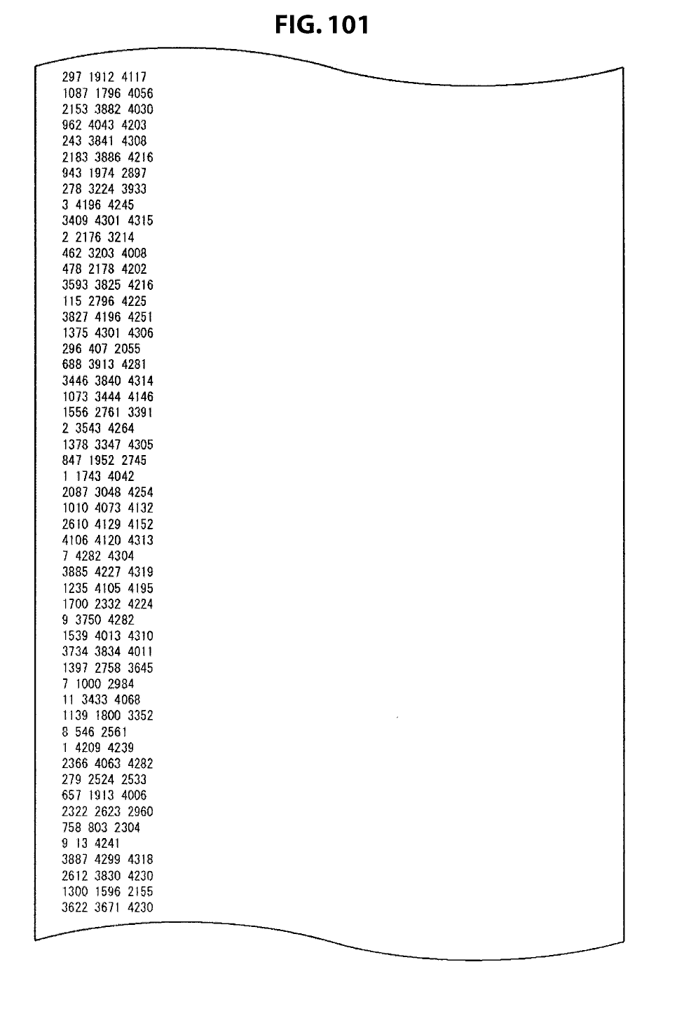

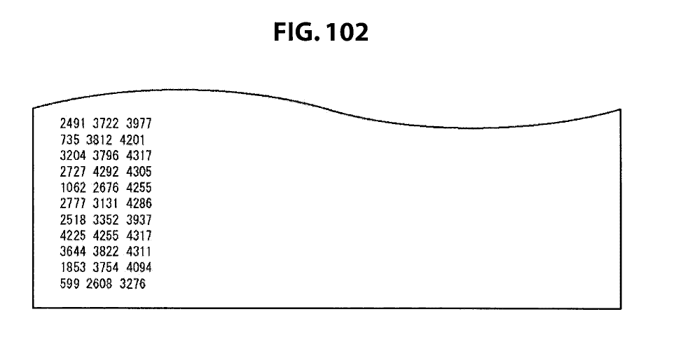

FIGS. 99, 100, 101, and 102 illustrate a parity check matrix initial value table with respect to the parity check matrix H of the LDPC code with a code length N of 64 k bits and an encoding rate of 28/30.

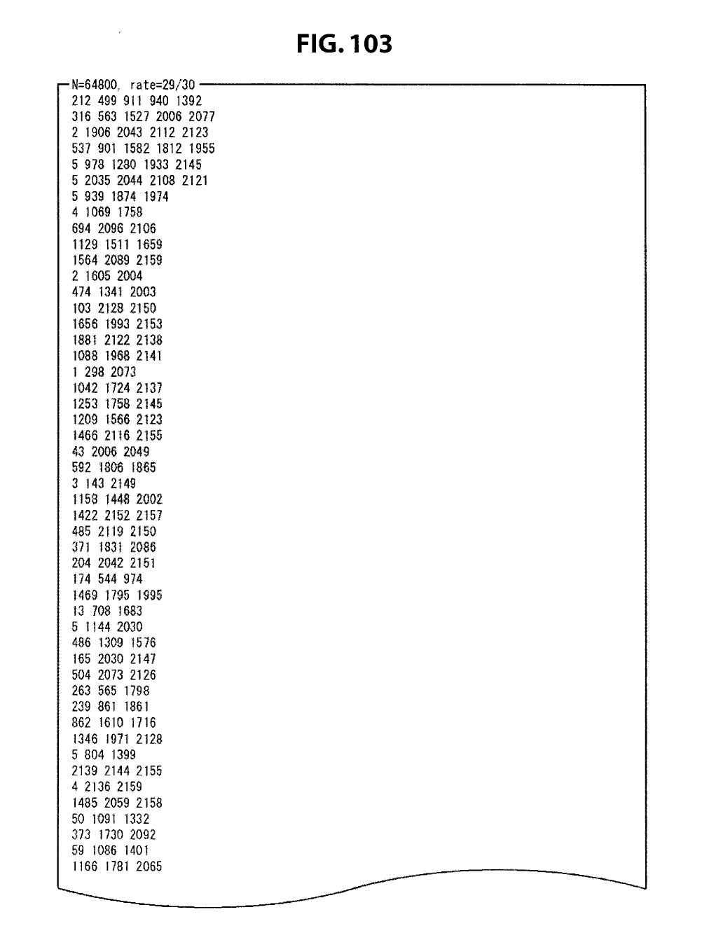

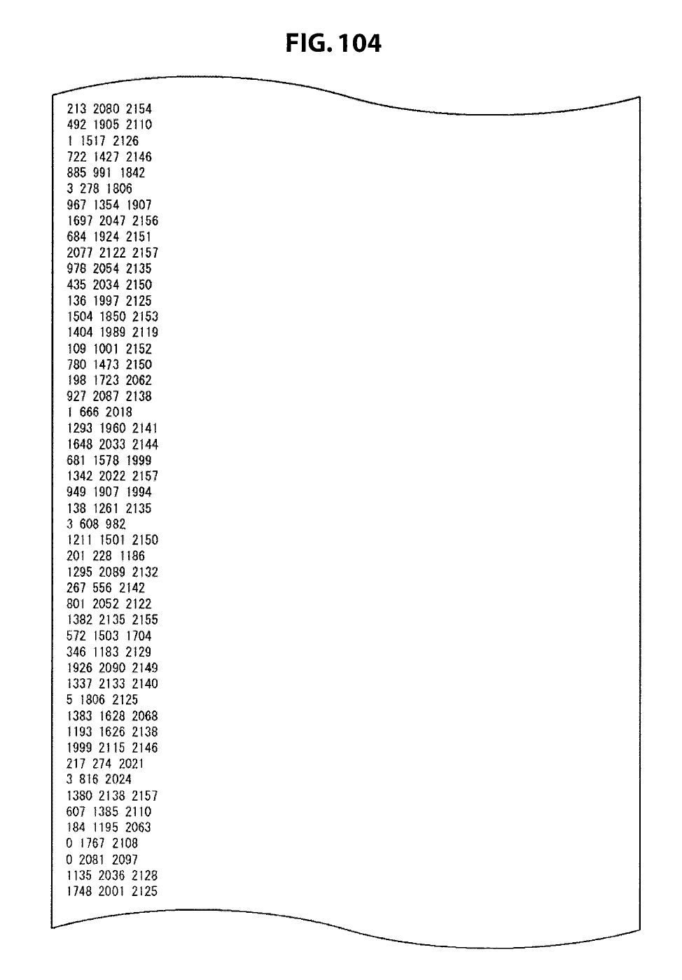

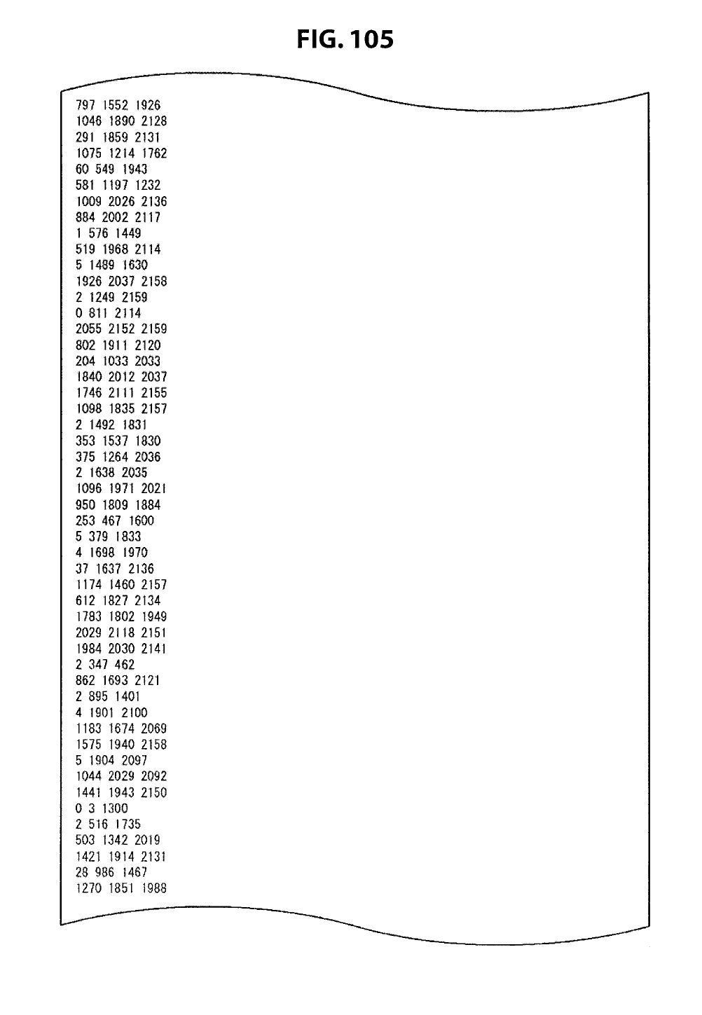

FIGS. 103, 104, 105, and 106 illustrate a parity check matrix initial value table with respect to the parity check matrix H of the LDPC code with a code length N of 64 k bits and an encoding rate of 29/30.

The LDPC encoder 115 (FIG. 8 and FIG. 35) can perform encoding into any (new) LDPC code with a code length N of 64 k among 28 kinds of encoding rates r of 2/30 to 29/30, by the use of the parity check matrix H found from the parity check matrix initial value tables illustrated in FIG. 40 to FIG. 106.

In this case, the parity check matrix initial value tables illustrated in FIG. 40 to FIG. 106 are stored in the storage unit 602 of the LDPC encoder 115 (FIG. 8).

Here, all of LDPC codes with 28 kinds of encoding rates r of 2/30 to 29/30 (found from the parity check matrix initial value tables) in FIG. 40 to FIG. 106 do not have to be necessarily adopted as a new LDPC. That is, as for the LDPC codes with 28 kinds of encoding rates r of 2/30 to 29/30 in FIG. 40 to FIG. 106, LDPC codes of one or more arbitrary encoding rates among them can be adopted as a new LDPC code.

An LDPC code obtained by the use of the parity check matrix H found from the parity check matrix initial value tables in FIG. 40 to FIG. 106 is an LDPC code of good performance.

Here, the LDPC code of good performance is an LDPC code obtained from an appropriate parity check matrix H.

Moreover, the appropriate parity check matrix H is a parity check matrix that satisfies a predetermined condition to make BER (and FER) smaller when an LDPC code obtained from the parity check matrix H is transmitted at low Eₛ/N₀ or E_{b}/Nₒ (signal-to-noise power ratio per bit).

For example, the appropriate parity check matrix H can be found by performing simulation to measure BER when LDPC codes obtained from various parity check matrices that satisfy a predetermined condition are transmitted at low Eₛ/Nₒ.

As a predetermined condition to be satisfied by the appropriate parity check matrix H, for example, an analysis result obtained by a code performance analysis method called density evolution (Density Evolution) is excellent, and a loop of elements of 1 does not exist, which is called cycle 4, and so on.

Here, in the information matrix H_{A}, it is known that the decoding performance of LDPC code is deteriorated when elements of 1 are dense like cycle 4, and therefore it is requested that cycle 4 does not exist, as a predetermined condition to be satisfied by the appropriate parity check matrix H.

Here, the predetermined condition to be satisfied by the appropriate parity check matrix H can be arbitrarily determined from the viewpoint of the improvement in the decoding performance of LDPC code and the facilitation (simplification) of decoding processing of LDPC code, and so on.

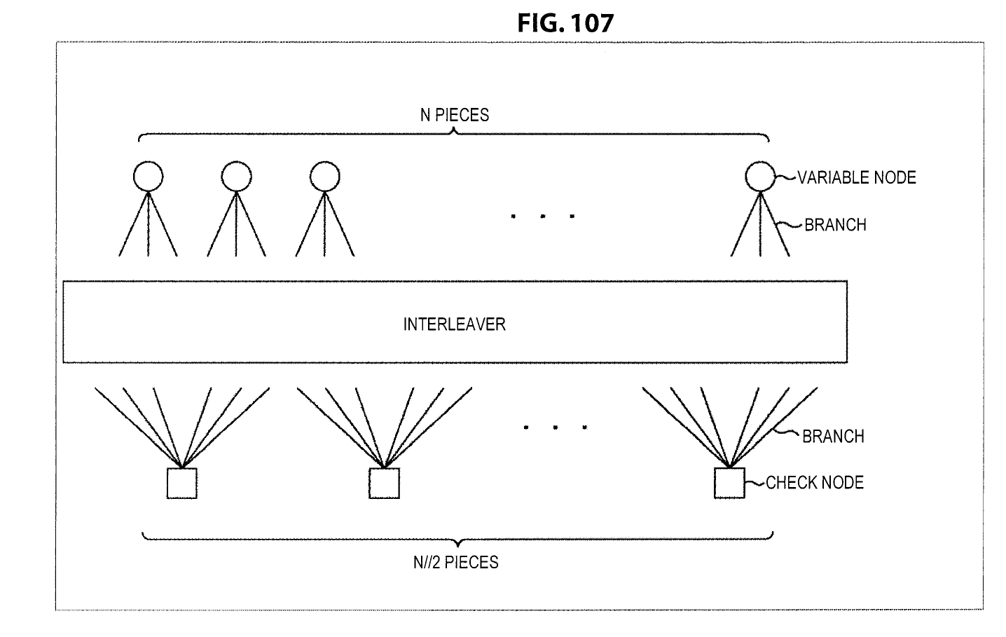

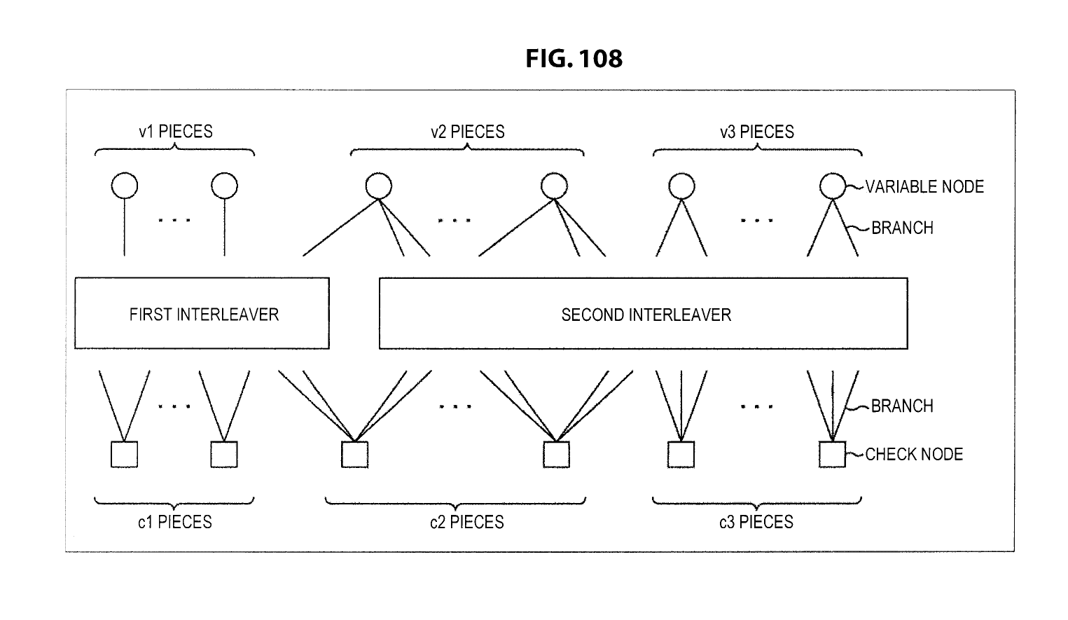

FIG. 107 and FIG. 108 are diagrams to describe the density evolution that can obtain an analytical result as a predetermined condition to be satisfied by the appropriate parity check matrix H.

The density evolution is a code analysis method that calculates the expectation value of the error probability of the entire LDPC code (ensemble) with a code length N of ω characterized by a degree sequence described later.

For example, when the dispersion value of noise is gradually increased from 0 on the AWGN channel, the expectation value of the error probability of a certain ensemble is 0 first, but, when the dispersion value of noise becomes equal to or greater than a certain threshold, it is not 0.

According to the density evolution, by comparison of the threshold of the dispersion value of noise (which may also be called a performance threshold) in which the expectation value of the error probability is not 0, it is possible to decide the quality of ensemble performance (appropriateness of the parity check matrix).

Here, as for a specific LDPC code, when an ensemble to which the LDPC code belongs is decided and density evolution is performed for the ensemble, rough performance of the LDPC code can be expected.

Therefore, if an ensemble of good performance is found, an LDPC code of good performance can be found from LDPC codes belonging to the ensemble.

Here, the above-mentioned degree sequence shows at what percentage a variable node or check node having the weight of each value exists with respect to the code length N of an LDPC code.

For example, a regular (3,6) LDPC code with an encoding rate of 1/2 belongs to an ensemble characterized by a degree sequence in which the weight (column weight) of all variable nodes is 3 and the weight (row weight) of all check nodes is 6.

FIG. 107 illustrates a Tanner graph of such an ensemble.

In the Tanner graph of FIG. 107, there are variable nodes shown by circles (sign O) in the diagram only by N pieces equal to the code length N, and there are check nodes shown by quadrangles (sign □) only by N/2 pieces equal to a multiplication value multiplying encoding rate 1/2 by the code length N.

Three branches (edge) equal to the column weight are connected with each variable node, and therefore there are totally 3N branches connected with N variable nodes.

Moreover, six branches (edge) equal to the row weight are connected with each check node, and therefore there are totally 3N branches connected with N/2 check nodes.

In addition, there is one interleaver in the Tanner graph in FIG. 107.

The interleaver randomly rearranges 3N branches connected with N variable nodes and connects each rearranged branch with any of 3N branches connected with N/2 check nodes.

There are (3N)! (=(3N)×(3N−1)× . . . ×1) rearrangement patterns to rearrange 3N branches connected with N variable nodes in the interleaver. Therefore, an ensemble characterized by the degree sequence in which the weight of all variable nodes is 3 and the weight of all check nodes is 6, becomes aggregation of (3N)! LDPC codes.

In simulation to find an LDPC code of good performance (appropriate parity check matrix), an ensemble of a multi-edge type is used in the density evolution.

In the multi edge type, an interleaver through which the branches connected with the variable nodes and the branches connected with the check nodes pass, is divided into plural (multi edge), and, by this means, the ensemble is characterized more strictly.

FIG. 108 illustrates an example of a Tanner graph of an ensemble of the multi-edge type.

In the Tanner graph of FIG. 108, there are two interleavers of the first interleaver and the second interleaver.

Moreover, in the Tanner graph chart of FIG. 108, v1 variable nodes with one branch connected with the first interleaver and no branch connected with the second interleaver exist, v2 variable nodes with one branch connected with the first interleaver and two branches connected with the second interleaver exist, and v3 variable nodes with no branch connected with the first interleaver and two branches connected with the second interleaver exist, respectively.

Furthermore, in the Tanner graph chart of FIG. 108, c1 check nodes with two branches connected with the first interleaver and no branch connected with the second interleaver exist, c2 check nodes with two branches connected with the first interleaver and two branches connected with the second interleaver exist, and c3 check nodes with no branch connected with the first interleaver and three branches connected with the second interleaver exist, respectively.

Here, for example, the density evolution and the mounting thereof are described in “On the Design of Low-Density Parity-Check Codes within 0.0045 dB of the Shannon Limit”, S. Y. Chung, G. D. Forney, T. J. Richardson, R. Urbanke, IEEE Communications Leggers, VOL. 5, NO. 2, February 2001.

In simulation to find (a parity check matrix initial value table of) a new LDPC code, by the density evaluation of the multi-edge type, an ensemble in which a performance threshold that is E_{b}/N₀ (signal-to-noise power ratio per bit) with deteriorating (decreasing) BER is equal to or less than a predetermined value is found, and an LDPC code that decreases BER in a plurality of modulation methods used in DVB-S.2 or the like such as QPSK is selected from LDPC codes belonging to the ensemble as an LDPC code of good performance.

The above-mentioned parity check matrix initial value table of the new LDPC code is a parity check matrix initial value table of an LDPC code with a code length N of 64 k bits found from the above-mentioned simulation.

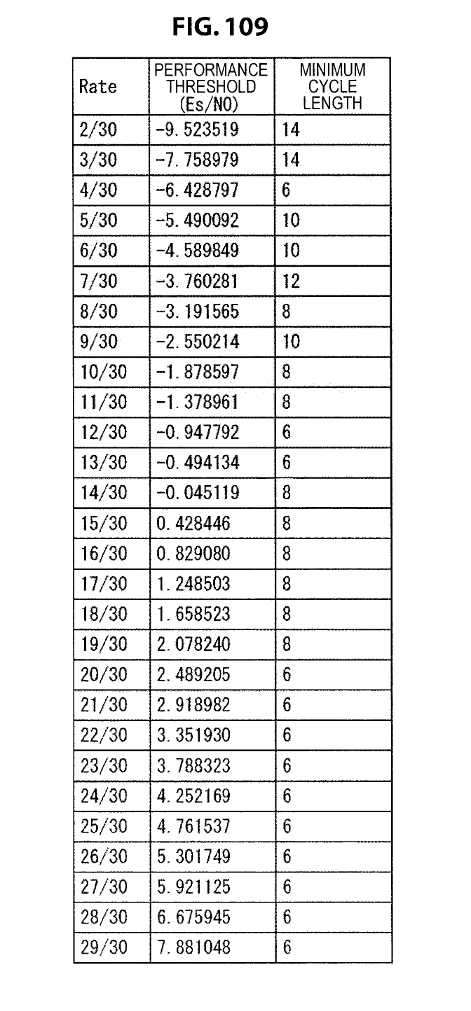

FIG. 109 is a diagram illustrating the minimum cycle length and performance threshold of the parity check matrix H found from the parity check matrix initial value tables of new LDPC codes with 28 kinds of encoding rates of 2/30 to 29/30 and a code length N of 64 k bits in FIG. 40 to FIG. 106.

Here, the minimum cycle length (girth) means the minimum value of the length of a loop (loop length) formed with elements of 1 in the parity check matrix H.

In the parity check matrix H found from the parity check matrix initial value table of the new LDPC code, cycle 4 (a loop of elements of 1 with a loop length of 4) does not exist.

Moreover, since the redundancy of an LDPC code becomes larger as the encoding rate r becomes smaller, the performance threshold tends to improve (decrease) as the encoding rate r decreases.

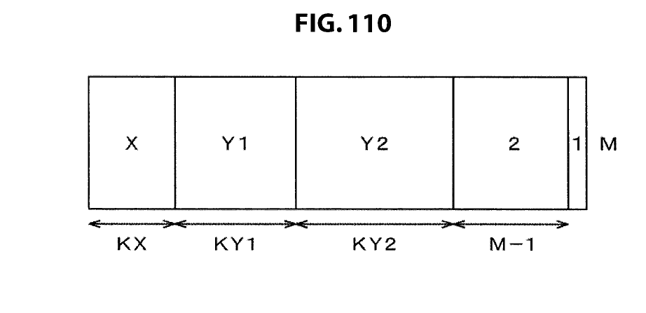

FIG. 110 is a diagram illustrating the parity check matrix H (which may be called a new LDPC code parity check matrix H) of FIG. 40 to FIG. 106 (which is found from a parity check matrix initial value table).

The column weight is X for the KX column from the first column of the new LDPC code parity check matrix H, the column weight is Y1 for the subsequent KY1 column, the column weight is Y2 for the subsequent KY2 column, the column weight is 2 for the subsequent M−1 column, and the column weight is 1 for the last column.

Here, KX+KY1+KY2+M−1+1 is equal to a code length of N=64800 bits.

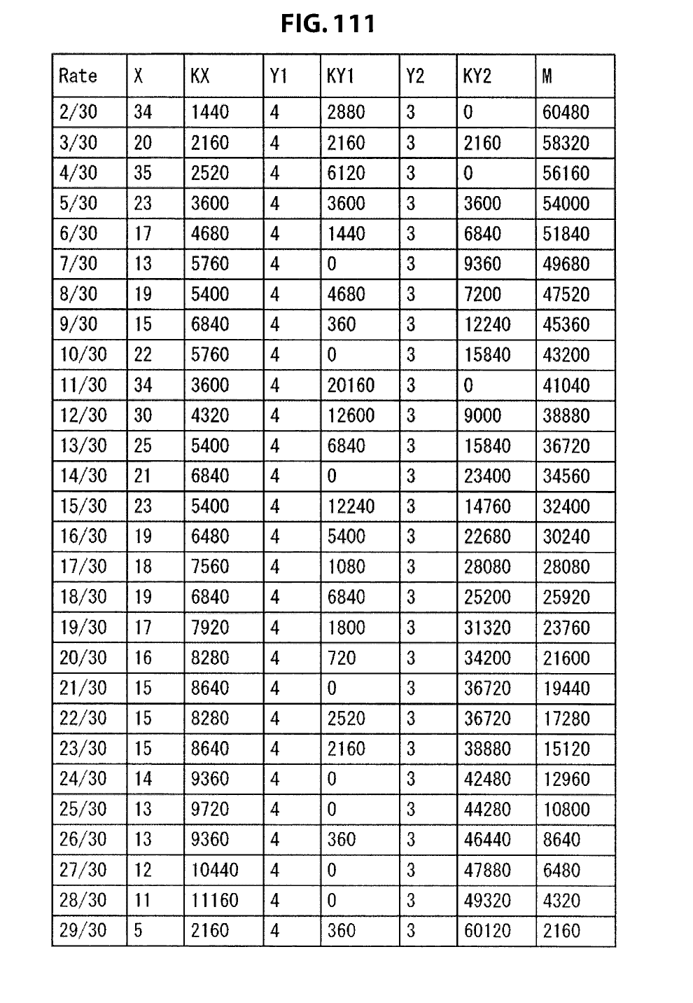

FIG. 111 is a diagram illustrating column numbers KX, KY1, KY2 and M and column weights X, Y1 and Y2 in FIG. 110, for each encoding rate r of a new LDPC code.

As for the new LDPC code parity check matrix H with a code length N of 64 k, similar to the parity check matrix described in FIG. 12 and FIG. 13, the column weight tends to be larger in a column closer to the head side (left side), and therefore a code bit closer to the head of the new LDPC code tends to be more tolerant to errors (have resistance to errors).

Here, shift amount q of cyclic shift, which is performed when a parity check matrix is found from the parity check matrix initial value table of a new LDPC code with a code length N of 64 k as described in FIG. 38, is expressed by an expression q=M/P=M/360.

Therefore, the shift amounts of new LDPC codes with encoding rates of 2/30, 3/30, 4/30, 5/30, 6/30, 7/30, 8/30, 9/30, 10/30, 11/30, 12/30, 13/30, 14/30, 15/30, 16/30, 17/30, 18/30, 19/30, 20/30, 21/30, 22/30, 23/30, 24/30, 25/30, 26/30, 27/30, 28/30 and 29/30 are 168, 162, 156, 150, 144, 138, 132, 126, 120, 114, 108, 102, 96, 90, 84, 78, 72, 66, 60, 54, 48, 42, 36, 30, 24, 18, 12 and 6, respectively.

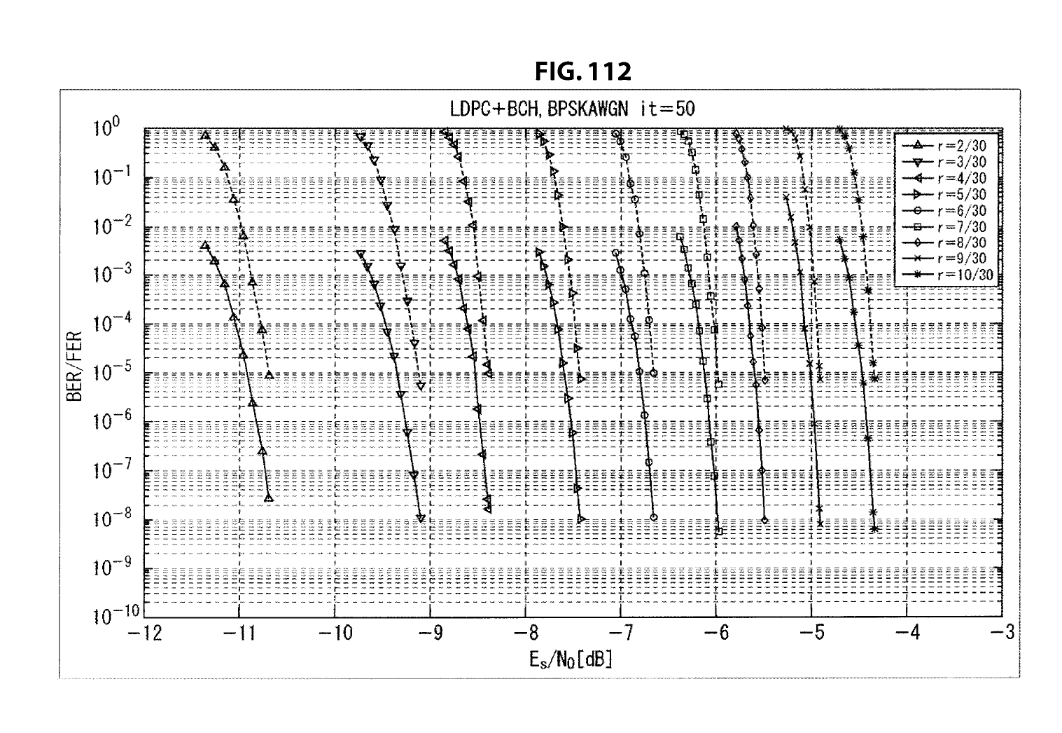

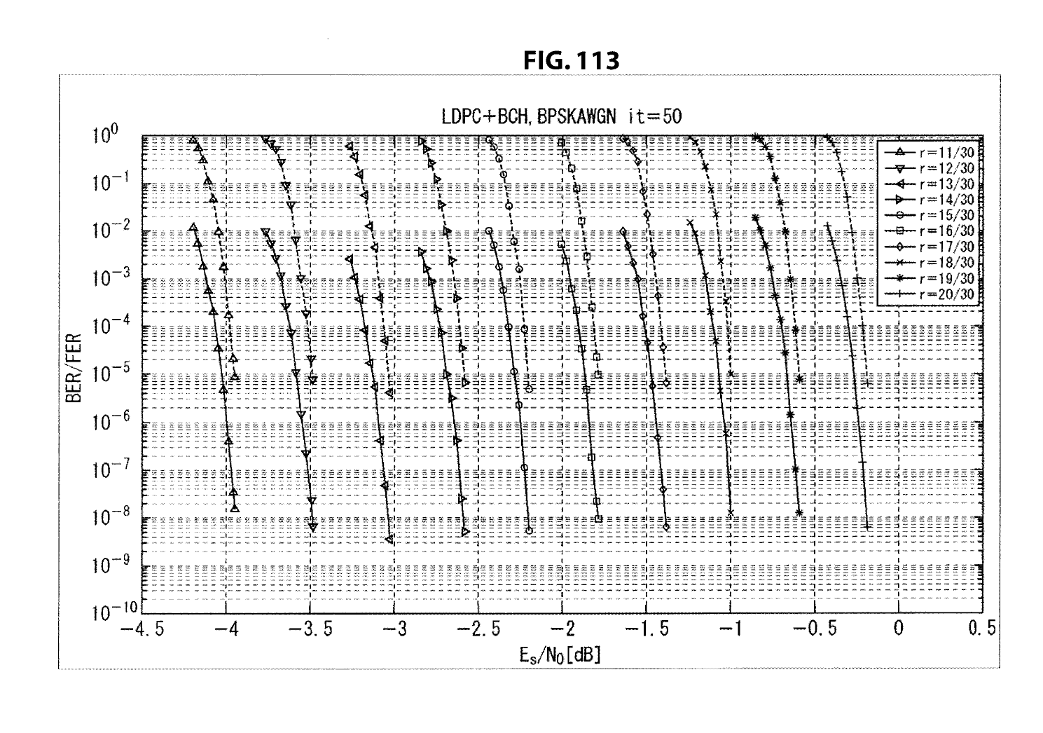

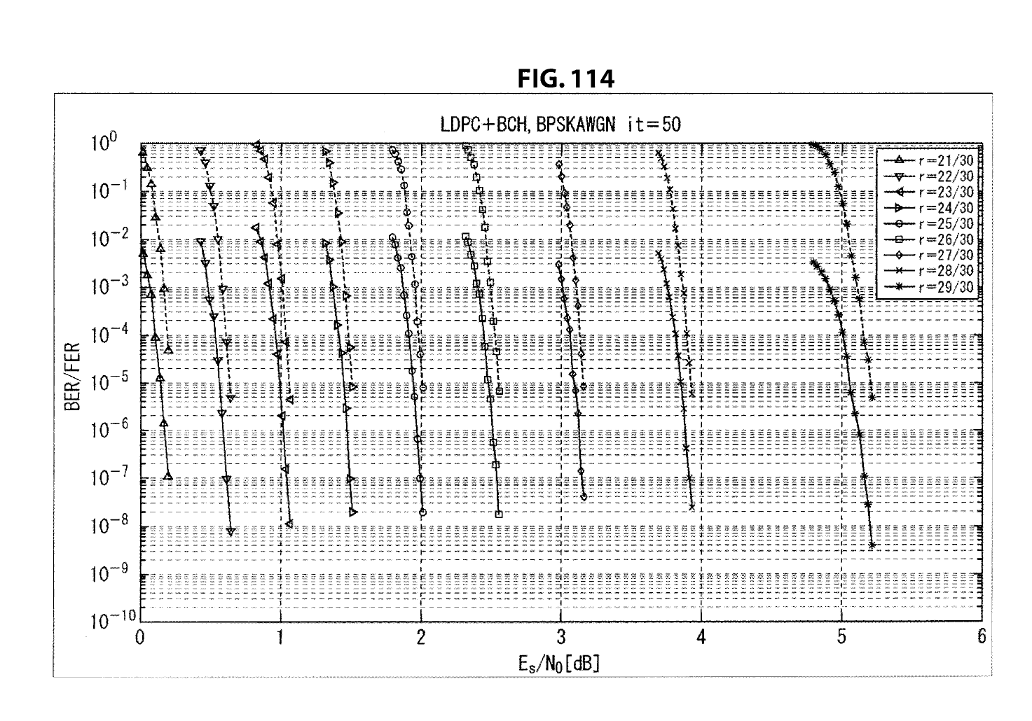

FIG. 112, FIG. 113 and FIG. 114 are diagrams illustrating a simulation result of BER/FER of new LDPC codes of FIG. 40 to FIG. 106.

In the simulation, a communication path (channel) of AWGN is assumed, BPSK is adopted as a modulation method and 50 times are adopted as an iterative decoding number C(it).

In FIG. 112, FIG. 113 and FIG. 114, the horizontal axis shows Eₛ/N₀ and the vertical axis shows BER/FER. Here, the solid line shows BER and the dotted line shows FER.

As for the FER (BER) curves of respective new LDPC codes with 28 kinds of encoding rates of 2/30 to 29/30 in FIG. 112 to FIG. 114, FER is equal to or less than 10⁻⁵ in a range of (about) 15 dB of Eₛ/N₀ from (almost) −10 dB to 5 dB.

According to the simulation, since it is possible to set 28 pieces of ModCod in which FER is equal to or less than 10⁻⁵ in a range of 15 dB in which Eₛ/N₀ is from −10 dB to 5 dB, by considering various modulation methods such as QPSK, 8PSK, 16APSK, 32APSK, 16QAM, 32QAM and 64QAM other than BPSK used in the simulation, it is sufficiently expected that it is possible to set 20 or more pieces of ModCod in which FER is equal to or less than 10⁻⁵ in a range of 7 dB from 5 dB to 12 dB.

Therefore, it is possible to provide an LDPC code of a good error rate, which satisfies the first request of CfT.

Moreover, according to FIG. 112 to FIG. 114, almost all of FER (BER) curves are arranged at relatively equal intervals for each of groups with encoding rates of Low, Medium and High at intervals less than 1 dB. Therefore, for broadcasters who broadcast a program by the transmitting device 11, there is an advantage that a new LDPC code easily selects an encoding rate used for broadcast according to the situation of a channel (communication path 13), and so on.

Here, in the simulation to find the BER/FER curves in FIG. 112 to FIG. 114, information is subjected to BCH encoding and a BCH code obtained as a result is subjected to LDPC encoding.

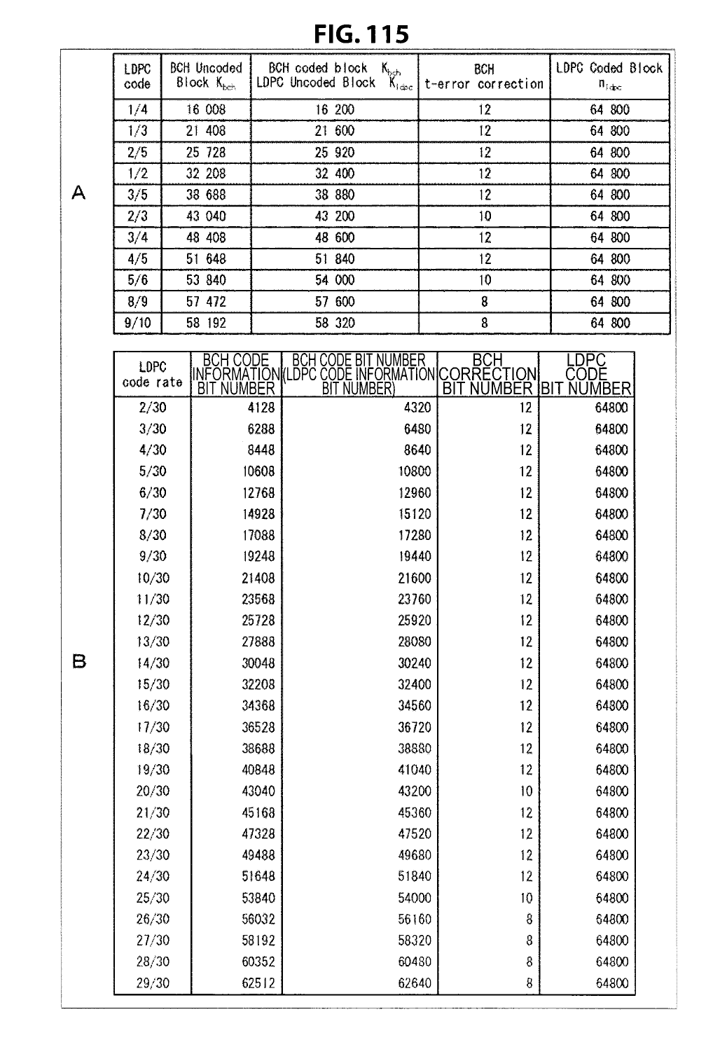

FIG. 115 is a diagram illustrating the BCH encoding used for the simulation.

That is, A of FIG. 115 is a diagram illustrating parameters of the BCH encoding performed before the LDPC encoding for an LDPC code of 64 k defined in DVB-S.2.

In DVB-S.2, by attaching redundancy bits of 192 bits, 160 bits or 128 bits according to the encoding rate of an LDPC code, BCH encoding that enables error correction of 12 bits, 10 bits or 8 bits is performed.

B of FIG. 115 is a diagram illustrating parameters of the BCH encoding used for the simulation.

In the simulation, similar to the case of DVB-S.2, by attaching redundancy bits of 192 bits, 160 bits or 128 bits according to the encoding rate of an LDPC code, the BCH encoding that enables error correction of 12 bits, 10 bits or 8 bits is performed.

### Configuration Example of Receiving Device 12

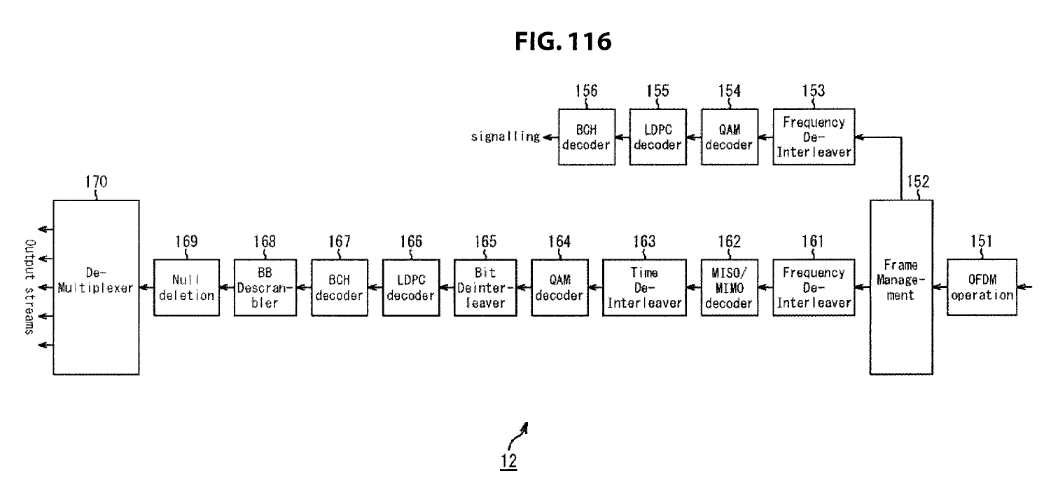

FIG. 116 is a block diagram illustrating a configuration example of the receiving device 12 of FIG. 7.

An OFDM operating unit 151 receives an OFDM signal from the transmitting device 11 (FIG. 7) and executes signal processing of the OFDM signal. Data (symbol) that is obtained by executing the signal processing by the OFDM operating unit 151 is supplied to a frame managing unit 152.

The frame managing unit 152 executes processing (frame interpretation) of a frame configured by the symbol supplied from the OFDM operating unit 151 and supplies a symbol of target data obtained as a result and a symbol of signaling to frequency deinterleavers 161 and 153.

The frequency deinterleaver 153 performs frequency deinterleave in a unit of symbol, with respect to the symbol supplied from the frame managing unit 152, and supplies the symbol to a QAM decoder 154.

The QAM decoder 154 demaps (signal point arrangement decoding) the symbol (symbol arranged on a signal point) supplied from the frequency deinterleaver 153, performs orthogonal demodulation, and supplies data (LDPC code) obtained as a result to a LDPC decoder 155.

The LDPC decoder 155 performs LDPC decoding of the LDPC code supplied from the QAM decoder 154 and supplies LDPC target data (in this case, a BCH code) obtained as a result to a BCH decoder 156.

The BCH decoder 156 performs BCH decoding of the LDPC target data supplied from the LDPC decoder 155 and outputs control data (signaling) obtained as a result.

Meanwhile, the frequency deinterleaver 161 performs frequency deinterleave in a unit of symbol, with respect to the symbol supplied from the frame managing unit 152, and supplies the symbol to a MISO/MIMO decoder 162.

The MISO/MIMO decoder 162 performs spatiotemporal decoding of the data (symbol) supplied from the frequency deinterleaver 161 and supplies the data to a time deinterleaver 163.

The time deinterleaver 163 performs time deinterleave in a unit of symbol, with respect to the data (symbol) supplied from the MISO/MIMO decoder 162, and supplies the data to a QAM decoder 164.

The QAM decoder 164 demaps (signal point arrangement decoding) the symbol (symbol arranged on a signal point) supplied from the time deinterleaver 163, performs orthogonal demodulation, and supplies data (symbol) obtained as a result to a bit deinterleaver 165.

The bit deinterleaver 165 performs bit deinterleave of the data (symbol) supplied from the QAM decoder 164 and supplies an LDPC code obtained as a result to an LDPC decoder 166.

The LDPC decoder 166 performs LDPC decoding of the LDPC code supplied from the bit deinterleaver 165 and supplies LDPC target data (in this case, a BCH code) obtained as a result to a BCH decoder 167.

The BCH decoder 167 performs BCH decoding of the LDPC target data supplied from the LDPC decoder 155 and supplies data obtained as a result to a BB descrambler 168.

The BB descrambler 168 executes BB descramble with respect to the data supplied from the BCH decoder 167 and supplies data obtained as a result to a null deletion unit 169.

The null deletion unit 169 deletes null inserted by the padder 112 of FIG. 8, from the data supplied from the BB descrambler 168, and supplies the data to a demultiplexer 170.

The demultiplexer 170 individually separates one or more streams (target data) multiplexed with the data supplied from the null deletion unit 169, performs necessary processing to output the streams as output streams.

Here, the receiving device 12 can be configured without including part of the blocks illustrated in FIG. 116. That is, for example, in a case where the transmitting device 11 (FIG. 8) is configured without including the time interleaver 118, the MISO/MIMO encoder 119, the frequency interleaver 120 and the frequency interleaver 124, the receiving device 12 can be configured without including the time deinterleaver 163, the MISO/MIMO decoder 162, the frequency deinterleaver 161 and the frequency deinterleaver 153 which are blocks respectively corresponding to the time interleaver 118, the MISO/MIMO encoder 119, the frequency interleaver 120 and the frequency interleaver 124 of the transmitting device 11.

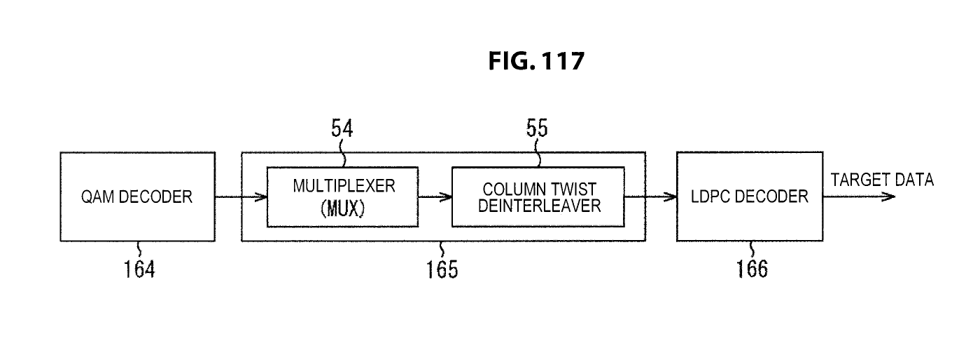

FIG. 117 is a block diagram illustrating a configuration example of the bit deinterleaver 165 of FIG. 116.

The bit deinterleaver 165 includes a multiplexer (MUX) 54 and a column twist deinterleaver 55 and performs (bit) deinterleave of symbol bits of the symbol supplied from the QAM decoder 164 (FIG. 116).

That is, the multiplexer 54 executes reverse interchange processing (reverse processing of the interchange processing) corresponding to the interchange processing executed by the demultiplexer 25 of FIG. 9, that is, reverse interchange processing for returning positions of the code bits (symbol bits) of the LDPC codes interchanged by the interchange processing to original positions, with respect to the symbol bits of the symbol supplied from the QAM decoder 164, and supplies an LDPC code obtained as a result to the column twist deinterleaver 55.

The column twist deinterleaver 55 performs the column twist deinterleave (reverse processing of the column twist interleave) corresponding to the column twist interleave as the rearrangement processing executed by the column twist interleaver 24 of FIG. 9, that is, the column twist deinterleave as the reverse rearrangement processing for returning the code bits of the LDPC codes of which an arrangement is changed by the column twist interleave as the rearrangement processing to the original arrangement, with respect to the LDPC code supplied from the multiplexer 54.

Specifically, the column twist deinterleaver 55 writes the code bits of the LDPC code to a memory for deinterleave having the same configuration as the memory 31 illustrated in FIG. 28, reads the code bits, and performs the column twist deinterleave.

However, in the column twist deinterleaver 55, writing of the code bits is performed in a row direction of the memory for the deinterleave, using read addresses when the code bits are read from the memory 31 as write addresses. In addition, reading of the code bits is performed in a column direction of the memory for the deinterleave, using write addresses when the code bits are written to the memory 31 as read addresses.

The LDPC code that is obtained as a result of the column twist deinterleave is supplied from the column twist deinterleaver 55 to the LDPC decoder 166.

Here, in a case where the parity interleave, the column twist interleave and the interchange processing are performed on an LDPC code supplied from the QAM decoder 164 to the bit deinterleaver 165, all of parity deinterleave (processing opposite to the parity interleave, that is, parity deinterleave that returns the code bits of an LDPC code in which the arrangement is changed by the parity interleave to the original arrangement) corresponding to the parity interleave, reverse interchange processing corresponding to the interchange processing and column twist deinterleave corresponding to the column twist interleave can be performed in the bit deinterleaver 165.

However, the bit deinterleaver 165 in FIG. 117 includes the multiplexer 54 that performs the reverse interchange processing corresponding to the interchange processing and the column twist deinterleaver 55 that performs the column twist deinterleave corresponding to the column twist interleave, but does not include a block that performs the parity deinterleave corresponding to the parity interleave, and the parity deinterleave is not performed.

Therefore, the LDPC code in which the reverse interchange processing and the column twist deinterleave are performed and the parity deinterleave is not performed is supplied from (the column twist deinterleaver 55 of) the bit deinterleaver 165 to the LDPC decoder 166.

The LDPC decoder 166 performs the LDPC decoding of the LDPC code supplied from the bit deinterleaver 165, using a transformed parity check matrix obtained by performing at least column replacement corresponding to the parity interleave with respect to the parity check matrix H used by the LDPC encoder 115 of FIG. 8 to perform the LDPC encoding, and outputs data obtained as a result to a decoding result of LDPC target data.

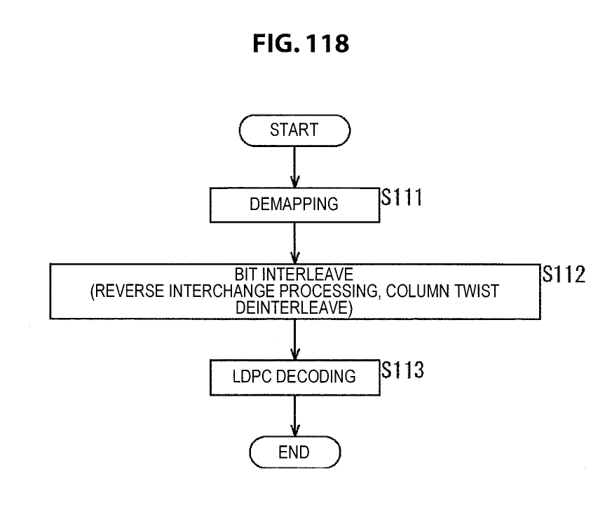

FIG. 118 is a flowchart illustrating processing that is executed by the QAM decoder 164, the bit deinterleaver 165, and the LDPC decoder 166 of FIG. 117.

In step S111, the QAM decoder 164 demaps the symbol (symbol mapped to a signal point) supplied from the time deinterleaver 163, performs orthogonal modulation, and supplies the symbol to the bit deinterleaver 165, and the processing proceeds to step S112.

In step S112, the bit deinterleaver 165 performs deinterleave (bit deinterleave) of the symbol bits of the symbol supplied from the QAM decoder 164 and the processing proceeds to step S113.

That is, in step S112, in the bit deinterleaver 165, the multiplexer 54 executes reverse interchange processing with respect to the symbol bits of the symbol supplied from the QAM decoder 164 and supplies code bits of an LDPC code obtained as a result to the column twist deinterleaver 55.

The column twist deinterleaver 55 performs the column twist deinterleave with respect to the LDPC code supplied from the multiplexer 54 and supplies an LDPC code obtained as a result to the LDPC decoder 166.

In step S113, the LDPC decoder 166 performs the LDPC decoding of the LDPC code supplied from the column twist deinterleaver 55, using a transformed parity check matrix obtained by performing at least column replacement corresponding to the parity interleave with respect to the parity check matrix H used by the LDPC encoder 115 of FIG. 8 to perform the LDPC encoding, and outputs data obtained as a result, as a decoding result of LDPC target data, to the BCH decoder 167.

In FIG. 117, for the convenience of explanation, the multiplexer 54 that executes the reverse interchange processing and the column twist deinterleaver 55 that performs the column twist deinterleave are individually configured, similar to the case of FIG. 9. However, the multiplexer 54 and the column twist deinterleaver 55 can be integrally configured.

In the bit interleaver 116 of FIG. 9, when the column twist interleave is not performed, it is not necessary to provide the column twist deinterleaver 55 in the bit deinterleaver 165 of FIG. 117.

Next, the LDPC decoding that is performed by the LDPC decoder 166 of FIG. 116 will be further described.

In the LDPC decoder 166 of FIG. 116, as described above, the LDPC decoding of the LDPC code from the column twist deinterleaver 55, in which the reverse interchange processing and the column twist deinterleave are performed and the parity deinterleave is not performed, is performed using a transformed parity check matrix obtained by performing at least column replacement corresponding to the parity interleave with respect to the parity check matrix H used by the LDPC encoder 115 of FIG. 8 to perform the LDPC encoding.

In this case, LDPC decoding that can suppress an operation frequency at a sufficiently realizable range while suppressing a circuit scale, by performing the LDPC decoding using the transformed parity check matrix, is previously suggested (for example, refer to JP 4224777B).

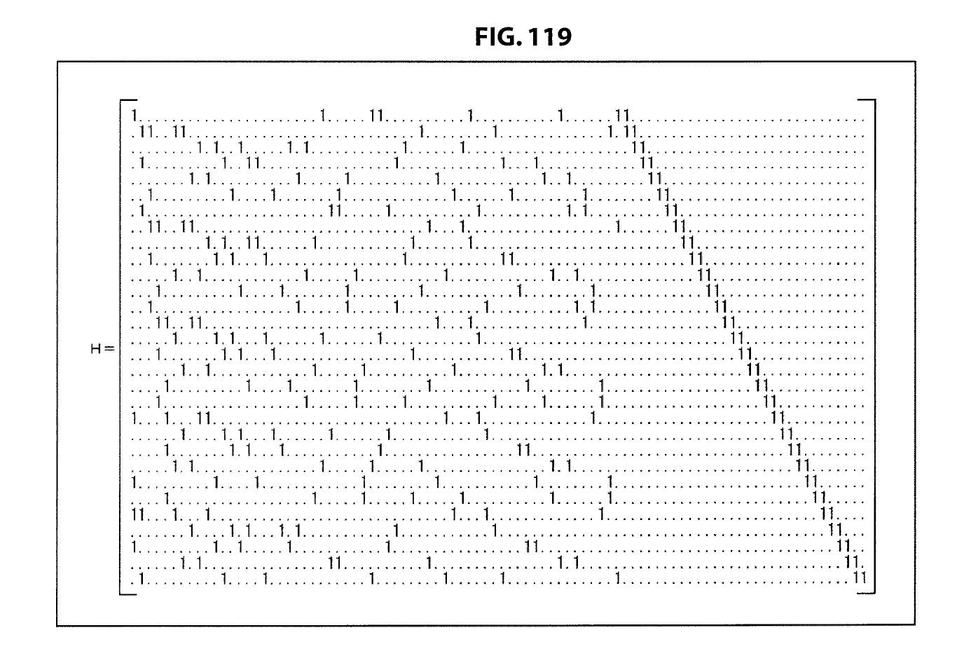

Therefore, first, the previously suggested LDPC decoding using the transformed parity check matrix will be described with reference to FIGS. 119 to 122.

FIG. 119 illustrates an example of a parity check matrix H of an LDPC code in which a code length N is 90 and an encoding rate is 2/3.

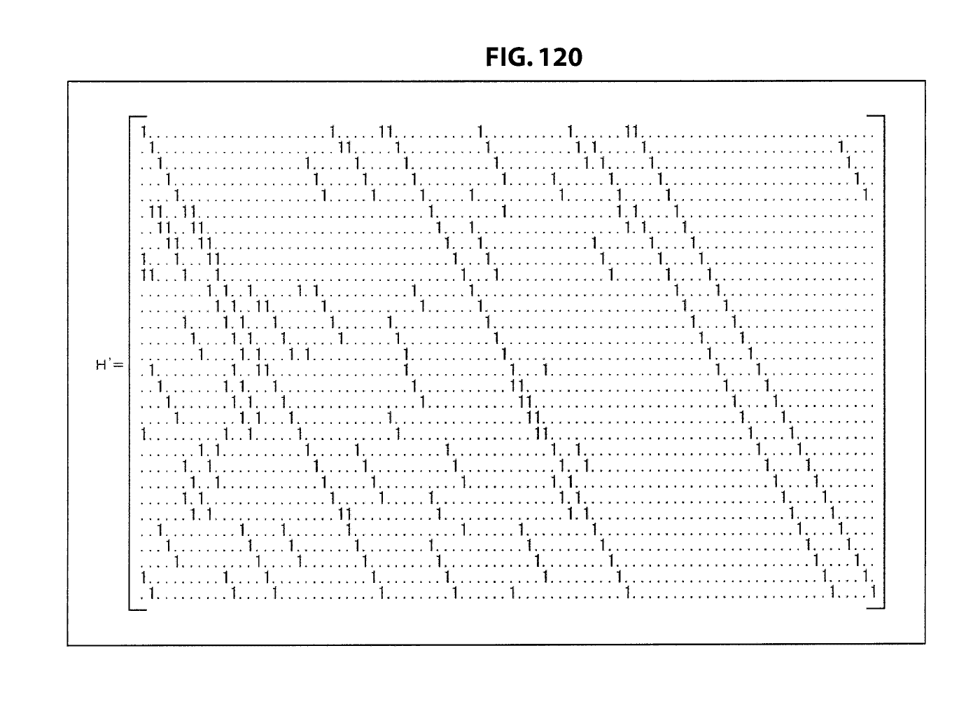

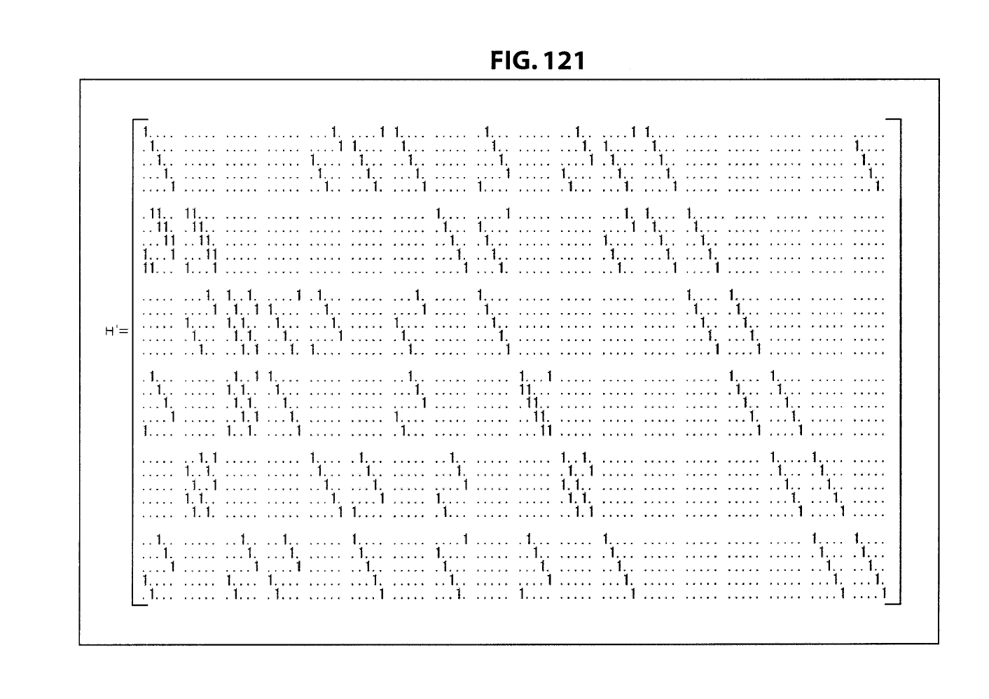

In FIG. 119 (and FIGS. 120 and 121 to be described later), 0 is represented by a period (.).

In the parity check matrix H of FIG. 119, the parity matrix becomes a staircase structure.

FIG. 120 illustrates a parity check matrix H′ that is obtained by executing row replacement of an expression (11) and column replacement of an expression (12) with respect to the parity check matrix H of FIG. 119.

Row Replacement:(6s+t+1)-th row→(5t+s+1)-th row (11)

Column Replacement:(6x+y+61)-th column→(5y+x+61)-th column (12)

In the expressions (11) and (12), s, t, x, and y are integers in ranges of 0≦s<5, 0≦t<6, 0≦x<5, and 0≦t<6, respectively.

According to the row replacement of the expression (11), replacement is performed such that the 1st, 7th, 13rd, 19th, and 25th rows having remainders of 1 when being divided by 6 are replaced with the 1st, 2nd, 3rd, 4th, and 5th rows, and the 2nd, 8th, 14th, 20th, and 26th rows having remainders of 2 when being divided by 6 are replaced with the 6th, 7th, 8th, 9th, and 10th rows, respectively.

According to the column replacement of the expression (12), replacement is performed such that the 61st, 67th, 73rd, 79th, and 85th columns having remainders of 1 when being divided by 6 are replaced with the 61st, 62nd, 63rd, 64th, and 65th columns, respectively, and the 62nd, 68th, 74th, 80th, and 86th columns having remainders of 2 when being divided by 6 are replaced with the 66th, 67th, 68th, 69th, and 70th columns, respectively, with respect to the 61st and following columns (parity matrix).

In this way, a matrix that is obtained by performing the replacements of the rows and the columns with respect to the parity check matrix H of FIG. 119 is a parity check matrix H′ of FIG. 120.

In this case, even when the row replacement of the parity check matrix H is performed, the arrangement of the code bits of the LDPC code is not influenced.

The column replacement of the expression (12) corresponds to parity interleave to interleave the (K+qx+y+1)-th code bit into the position of the (K+Py+x+1)-th code bit, when the information length K is 60, the column number P of the unit of the cyclic structure is 5, and the divisor q (=M/P) of the parity length M (in this case, 30) is 6.

Therefore, the parity check matrix H′ in FIG. 120 is a transformed parity check matrix obtained by performing at least column replacement that replaces the K+qx+y+1-th column of the parity check matrix H in FIG. 119 (which may be arbitrarily called an original parity check matrix below) with the K+Py+x+1-th column.

If the parity check matrix H′ of FIG. 120 is multiplied with a result obtained by performing the same replacement as the expression (12) with respect to the LDPC code of the parity check matrix H of FIG. 119, a zero vector is output. That is, if a row vector obtained by performing the column replacement of the expression (12) with respect to a row vector c as the LDPC code (one code word) of the original parity check matrix H is represented as c′, HcT becomes the zero vector from the property of the parity check matrix. Therefore, H′c′T naturally becomes the zero vector.

Thereby, the transformed parity check matrix H′ of FIG. 120 becomes a parity check matrix of an LDPC code c′ that is obtained by performing the column replacement of the expression (12) with respect to the LDPC code c of the original parity check matrix H.

Therefore, the column replacement of the expression (12) is performed with respect to the LDPC code of the original parity check matrix H, the LDPC code c′ after the column replacement is decoded (LDPC decoding) using the transformed parity check matrix H′ of FIG. 120, reverse replacement of the column replacement of the expression (12) is performed with respect to a decoding result, and the same decoding result as the case in which the LDPC code of the original parity check matrix H is decoded using the parity check matrix H can be obtained.

FIG. 121 illustrates the transformed parity check matrix H′ of FIG. 120 with being spaced in units of 5×5 matrixes.

In FIG. 121, the transformed parity check matrix H′ is represented by a combination of a 5×5 (=p×p) unit matrix, a matrix (hereinafter, appropriately referred to as a quasi unit matrix) obtained by setting one or more 1 of the unit matrix to zero, a matrix (hereinafter, appropriately referred to as a shifted matrix) obtained by cyclically shifting the unit matrix or the quasi unit matrix, a sum (hereinafter, appropriately referred to as a sum matrix) of two or more matrixes of the unit matrix, the quasi unit matrix, and the shifted matrix, and a 5×5 zero matrix.

The transformed parity check matrix H′ of FIG. 121 can be configured using the 5×5 unit matrix, the quasi unit matrix, the shifted matrix, the sum matrix, and the zero matrix. Therefore, the 5×5 matrixes (the unit matrix, the quasi unit matrix, the shifted matrix, the sum matrix, and the zero matrix) that constitute the transformed parity check matrix H′ are appropriately referred to as constitutive matrixes hereinafter.

When the LDPC code represented by the parity check matrix represented by the P×P constitutive matrixes is decoded, an architecture in which P check node operations and variable node operations are simultaneously performed can be used.

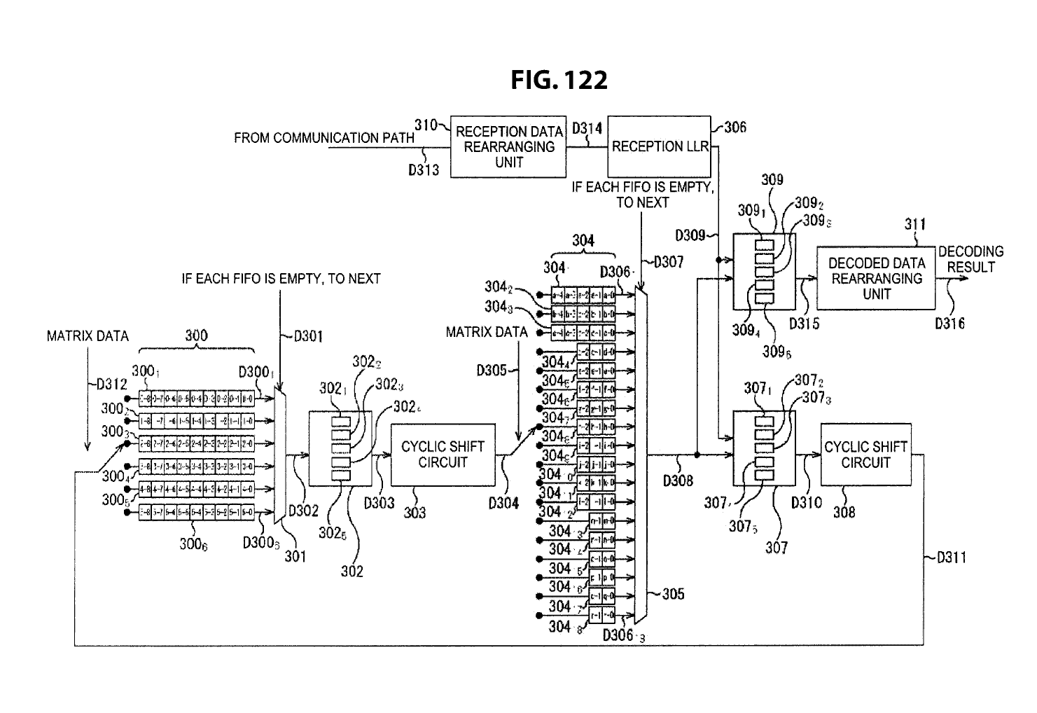

FIG. 122 is a block diagram illustrating a configuration example of a decoding device that performs the decoding.

That is, FIG. 122 illustrates the configuration example of the decoding device that performs decoding of the LDPC code, using the transformed parity check matrix H′ of FIG. 119 obtained by performing at least the column replacement of the expression (12) with respect to the original parity check matrix H of FIG. 121.

The decoding device of FIG. 122 includes a branch data storing memory 300 that includes 6 FIFOs 300₁ to 300₆, a selector 301 that selects the FIFOs 300₁ to 300₆, a check node calculating unit 302, two cyclic shift circuits 303 and 308, a branch data storing memory 304 that includes 18 FIFOs 304₁ to 304₁₈, a selector 305 that selects the FIFOs 304₁ to 304₁₈, a reception data memory 306 that stores reception data, a variable node calculating unit 307, a decoding word calculating unit 309, a reception data rearranging unit 310, and a decoded data rearranging unit 311.

First, a method of storing data in the branch data storing memories 300 and 304 will be described.

The branch data storing memory 300 includes the 6 FIFOs 300₁ to 300₆ that correspond to a number obtained by dividing a row number 30 of the transformed parity check matrix H′ of FIG. 121 by a row number 5 of the constitutive matrix (the column number P of the unit of the cyclic structure). The FIFO 300_{y} (y=1, 2, . . . , and 6) includes a plurality of steps of storage regions. In the storage region of each step, messages corresponding to five branches to be a row number and a column number of the constitutive matrix (the column number P of the unit of the cyclic structure) can be simultaneously read or written. The number of steps of the storage regions of the FIFO 300_{y} becomes 9 to be a maximum number of the number (Hamming weight) of 1 of a row direction of the transformed parity check matrix of FIG. 121.

In the FIFO 300₁, data (messages vᵢ from variable nodes) corresponding to positions of 1 in the first to fifth rows of the transformed parity check matrix H′ of FIG. 121 is stored in a form filling each row in a transverse direction (a form in which 0 is ignored). That is, if a j-th row and an i-th column are represented as (j, i), data corresponding to positions of 1 of a 5×5 unit matrix of (1, 1) to (5, 5) of the transformed parity check matrix H′ is stored in the storage region of the first step of the FIFO 300₁. In the storage region of the second step, data corresponding to positions of 1 of a shifted matrix (shifted matrix obtained by cyclically shifting the 5×5 unit matrix to the right side by 3) of (1, 21) to (5, 25) of the transformed parity check matrix H′ is stored. Similar to the above case, in the storage regions of the third to eighth steps, data is stored in association with the transformed parity check matrix H′. In the storage region of the ninth step, data corresponding to positions of 1 of a shifted matrix (shifted matrix obtained by replacing 1 of the first row of the 5×5 unit matrix with 0 and cyclically shifting the unit matrix to the left side by 1) of (1, 86) to (5, 90) of the transformed parity check matrix H′ is stored.

In the FIFO 300₂, data corresponding to positions of 1 in the sixth to tenth rows of the transformed parity check matrix H′ of FIG. 121 is stored. That is, in the storage region of the first step of the FIFO 300₂, data corresponding to positions of 1 of the first shifted matrix constituting a sum matrix (sum matrix to be a sum of the first shifted matrix obtained by cyclically shifting the 5×5 unit matrix to the right side by 1 and the second shifted matrix obtained by cyclically shifting the 5×5 unit matrix to the right side by 2) of (6, 1) to (10, 5) of the transformed parity check matrix H′ is stored. In addition, in the storage region of the second step, data corresponding to positions of 1 of the second shifted matrix constituting the sum matrix of (6, 1) to (10, 5) of the transformed parity check matrix H′ is stored.

That is, with respect to a constitutive matrix of which the weight is two or more, when the constitutive matrix is represented by a sum of multiple parts of a P×P unit matrix of which the weight is 1, a quasi unit matrix in which one or more elements of 1 in the unit matrix become 0, or a shifted matrix obtained by cyclically shifting the unit matrix or the quasi unit matrix, data (messages corresponding to branches belonging to the unit matrix, the quasi unit matrix, or the shifted matrix) corresponding to the positions of 1 in the unit matrix of the weight of 1, the quasi unit matrix, or the shifted matrix is stored at the same address (the same FIFO among the FIFOs 300₁ to 300₆).

Subsequently, in the storage regions of the third to ninth steps, data is stored in association with the transformed parity check matrix H′, similar to the above case.

In the FIFOs 300₃ to 300₆, data is stored in association with the transformed parity check matrix H′, similar to the above case.

The branch data storing memory 304 includes 18 FIFOs 304₁ to 304₁₈ that correspond to a number obtained by dividing a column number 90 of the transformed parity check matrix H′ by 5 to be a column number of a constitutive matrix (the column number P of the unit of the cyclic structure). The FIFO 304ₓ (x=1, 2, . . . , and 18) includes a plurality of steps of storage regions. In the storage region of each step, messages corresponding to five branches corresponding to a row number and a column number of the constitutive matrix (the column number P of the unit of the cyclic structure) can be simultaneously read or written.

In the FIFO 304₁, data (messages uⱼ from check nodes) corresponding to positions of 1 in the first to fifth columns of the transformed parity check matrix H′ of FIG. 121 is stored in a form filling each column in a longitudinal direction (a form in which 0 is ignored). That is, if a j-th row and an i-th column are represented as (j, i), data corresponding to positions of 1 of a 5×5 unit matrix of (1, 1) to (5, 5) of the transformed parity check matrix H′ is stored in the storage region of the first step of the FIFO 304₁. In the storage region of the second step, data corresponding to positions of 1 of the first shifted matrix constituting a sum matrix (sum matrix to be a sum of the first shifted matrix obtained by cyclically shifting the 5×5 unit matrix to the right side by 1 and the second shifted matrix obtained by cyclically shifting the 5×5 unit matrix to the right side by 2) of (6, 1) to (10, 5) of the transformed parity check matrix H′ is stored. In addition, in the storage region of the third step, data corresponding to positions of 1 of the second shifted matrix constituting the sum matrix of (6, 1) to (10, 5) of the transformed parity check matrix H′ is stored.

That is, with respect to a constitutive matrix of which the weight is two or more, when the constitutive matrix is represented by a sum of multiple parts of a P×P unit matrix of which the weight is 1, a quasi unit matrix in which one or more elements of 1 in the unit matrix become 0, or a shifted matrix obtained by cyclically shifting the unit matrix or the quasi unit matrix, data (messages corresponding to branches belonging to the unit matrix, the quasi unit matrix, or the shifted matrix) corresponding to the positions of 1 in the unit matrix of the weight of 1, the quasi unit matrix, or the shifted matrix is stored at the same address (the same FIFO among the FIFOs 304₁ to 304₁₈).

Subsequently, in the storage regions of the fourth and fifth steps, data is stored in association with the transformed parity check matrix H′, similar to the above case. The number of steps of the storage regions of the FIFO 304₁ becomes 5 to be a maximum number of the number (Hamming weight) of 1 of a row direction in the first to fifth columns of the transformed parity check matrix H′.

In the FIFOs 304₂ and 304₃, data is stored in association with the transformed parity check matrix H′, similar to the above case, and each length (the number of steps) is 5. In the FIFOs 304₄ to 304₁₂, data is stored in association with the transformed parity check matrix H′, similar to the above case, and each length is 3. In the FIFOs 304₁₃ to 304₁₈, data is stored in association with the transformed parity check matrix H′, similar to the above case, and each length is 2.

Next, an operation of the decoding device of FIG. 122 will be described.

The branch data storing memory 300 includes the 6 FIFOs 300₁ to 300₆. According to information (matrix data) D312 on which row of the transformed parity check matrix H′ in FIG. 121 five messages D311 supplied from a cyclic shift circuit 308 of a previous step belongs to, the FIFO storing data is selected from the FIFOs 300₁ to 300₆ and the five messages D311 are collectively stored sequentially in the selected FIFO. When the data is read, the branch data storing memory 300 sequentially reads the five messages D300₁ from the FIFO 300₁ and supplies the messages to the selector 301 of a next step. After reading of the messages from the FIFO 300₁ ends, the branch data storing memory 300 reads the messages sequentially from the FIFOs 300₂ to 300₆ and supplies the messages to the selector 301.

The selector 301 selects the five messages from the FIFO from which data is currently read, among the FIFOs 300₁ to 300₆, according to a select signal D301, and supplies the selected messages as messages D302 to the check node calculating unit 302.

The check node calculating unit 302 includes five check node calculators 302₁ to 302₅. The check node calculating unit 302 performs a check node operation according to the expression (7), using the messages D302 (D302₁ to D302₅) (messages vᵢ of the expression 7) supplied through the selector 301, and supplies five messages D303 (D303₁ to D303₅) (messages uⱼ of the expression (7)) obtained as a result of the check node operation to a cyclic shift circuit 303.

The cyclic shift circuit 303 cyclically shifts the five messages D303₁ to D303₅ calculated by the check node calculating unit 302, on the basis of information (matrix data) D305 on how many the unit matrixes (or the quasi unit matrix) becoming the origin in the transformed parity check matrix H′ are cyclically shifted to obtain the corresponding branches, and supplies a result as messages D304 to the branch data storing memory 304.

The branch data storing memory 304 includes the eighteen FIFOs 304₁ to 304₁₈. According to information D305 on which row of the transformed parity check matrix H′ five messages D304 supplied from a cyclic shift circuit 303 of a previous step belongs to, the FIFO storing data is selected from the FIFOs 304₁ to 304₁₈ and the five messages D304 are collectively stored sequentially in the selected FIFO. When the data is read, the branch data storing memory 304 sequentially reads the five messages D304₁ from the FIFO 304₁ and supplies the messages to the selector 305 of a next step. After reading of the messages from the FIFO 304₁ ends, the branch data storing memory 304 reads the messages sequentially from the FIFOs 304₂ to 304₁₈ and supplies the messages to the selector 305.

The selector 305 selects the five messages from the FIFO from which data is currently read, among the FIFOs 304₁ to 304₁₈, according to a select signal D307, and supplies the selected messages as messages D308 to the variable node calculating unit 307 and the decoding word calculating unit 309.

Meanwhile, the reception data rearranging unit 310 rearranges the LDPC code D313, that is corresponding to the parity check matrix H in FIG. 119, received through the communication path 13 by performing the column replacement of the expression (12) and supplies the LDPC code as reception data D314 to the reception data memory 306. The reception data memory 306 calculates a reception LLR (Log Likelihood Ratio) from the reception data D314 supplied from the reception data rearranging unit 310, stores the reception LLR, collects five reception LLRs, and supplies the reception LLRs as reception values D309 to the variable node calculating unit 307 and the decoding word calculating unit 309.

The variable node calculating unit 307 includes five variable node calculators 307₁ to 307₅. The variable node calculating unit 307 performs the variable node operation according to the expression (1), using the messages D308 (D308₁ to D308₅) (messages uⱼ of the expression (1)) supplied through the selector 305 and the five reception values D309 (reception values u₀ᵢ of the expression (1)) supplied from the reception data memory 306, and supplies messages D310 (D310₁ to D310₅) (message vᵢ of the expression (1)) obtained as an operation result to the cyclic shift circuit 308.

The cyclic shift circuit 308 cyclically shifts the messages D310₁ to D310₅ calculated by the variable node calculating unit 307, on the basis of information on how many the unit matrixes (or the quasi unit matrix) becoming the origin in the transformed parity check matrix H′ are cyclically shifted to obtain the corresponding branches, and supplies a result as messages D311 to the branch data storing memory 300.

By circulating the above operation in one cycle, decoding (variable node operation and check node operation) of the LDPC code can be performed once. After decoding the LDPC code by the predetermined number of times, the decoding device of FIG. 122 calculates a final decoding result and outputs the final decoding result, in the decoding word calculating unit 309 and the decoded data rearranging unit 311.

That is, the decoding word calculating unit 309 includes five decoding word calculators 309₁ to 309₅. The decoding word calculating unit 309 calculates a decoding result (decoding word) on the basis of the expression (5), as a final step of multiple decoding, using the five messages D308 (D308₁ to D308₅) (messages uⱼ of the expression) output by the selector 305 and the five reception values D309 (reception values u₀ᵢ of the expression (5)) supplied from the reception data memory 306, and supplies decoded data D315 obtained as a result to the decoded data rearranging unit 311.

The decoded data rearranging unit 311 performs the reverse replacement of the column replacement of the expression (12) with respect to the decoded data D315 supplied from the decoding word calculating unit 309, rearranges the order thereof, and outputs the decoded data as a final decoding result D316.

As mentioned above, by performing one or both of row replacement and column replacement on the parity check matrix (original parity check matrix) and converting it into a parity check matrix (transformed parity check matrix) that can be shown by the combination of a p×p unit matrix, a quasi unit matrix in which one or more elements of 1 thereof become 0, a shifted matrix that cyclically shifts the unit matrix or the quasi unit matrix, a sum matrix that is the sum of two or more of the unit matrix, the quasi unit matrix and the shifted matrix, and a p×p 0 matrix, that is, the combination of constitutive matrixes, as for LDPC code decoding, it becomes possible to adopt architecture that simultaneously performs check node calculation and variable node calculation by P which is the number less than the row number and column number of the parity check matrix. In the case of adopting the architecture that simultaneously performs node calculation (check node calculation and variable node calculation) by P which is the number less than the row number and column number of the parity check matrix, as compared with a case where the node calculation is simultaneously performed by the number equal to the row number and column number of the parity check matrix, it is possible to suppress the operation frequency within a feasible range and perform many items of iterative decoding.

The LDPC decoder 166 that constitutes the receiving device 12 of FIG. 116 performs the LDPC decoding by simultaneously performing P check node operations and variable node operations, similar to the decoding device of FIG. 122.

That is, for the simplification of explanation, if the parity check matrix of the LDPC code output by the LDPC encoder 115 constituting the transmitting device 11 of FIG. 8 is regarded as the parity check matrix H illustrated in FIG. 119 in which the parity matrix becomes a staircase structure, in the parity interleaver 23 of the transmitting device 11, the parity interleave to interleave the (K+qx+y+1)-th code bit into the position of the (K+Py+x+1)-th code bit is performed in a state in which the information K is set to 60, the column number P of the unit of the cyclic structure is set to 5, and the divisor q (=M/P) of the parity length M is set to 6.

Because the parity interleave corresponds to the column replacement of the expression (12) as described above, it is not necessary to perform the column replacement of the expression (12) in the LDPC decoder 166.

For this reason, in the receiving device 12 of FIG. 116, as described above, the LDPC code in which the parity deinterleave is not performed, that is, the LDPC code in a state in which the column replacement of the expression (12) is performed is supplied from the column twist deinterleaver 55 to the LDPC decoder 166. In the LDPC decoder 166, the same processing as the decoding device of FIG. 122, except that the column replacement of the expression (12) is not performed, is executed.

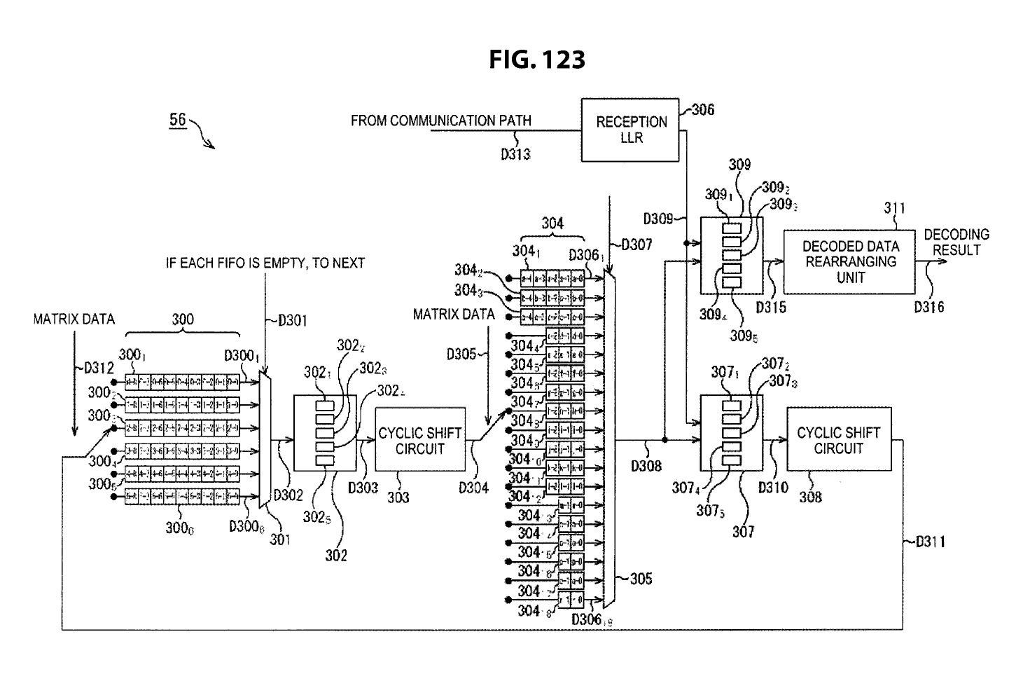

That is, FIG. 123 illustrates a configuration example of the LDPC decoder 166 of FIG. 116.

In FIG. 123, the LDPC decoder 166 has the same configuration as the decoding device of FIG. 122, except that the reception data rearranging unit 310 of FIG. 122 is not provided, and executes the same processing as the decoding device of FIG. 122, except that the column replacement of the expression (12) is not performed. Therefore, explanation of the LDPC decoder is omitted.

As described above, because the LDPC decoder 166 can be configured without providing the reception data rearranging unit 310, a scale can be decreased as compared with the decoding device of FIG. 122.

In FIGS. 119 to 123, for the simplification of explanation, the code length N of the LDPC code is set to 90, the information length K is set to 60, the column number (the row number and the column number of the constitutive matrix) P of the unit of the cyclic structure is set to 5, and the divisor q (=M/P) of the parity length M is set to 6. However, the code length N, the information length K, the column number P of the unit of the cyclic structure, and the divisor q (=M/P) are not limited to the above values.

That is, in the transmitting device 11 of FIG. 8, the LDPC encoder 115 outputs the LDPC code in which the code length N is set to 64800 or 16200, the information length K is set to N−Pq (=N−M), the column number P of the unit of the cyclic structure is set to 360, and the divisor q is set to M/P. However, the LDPC decoder 166 of FIG. 123 can be applied to the case in which P check node operation and variable node operations are simultaneously performed with respect to the LDPC code and the LDPC decoding is performed.

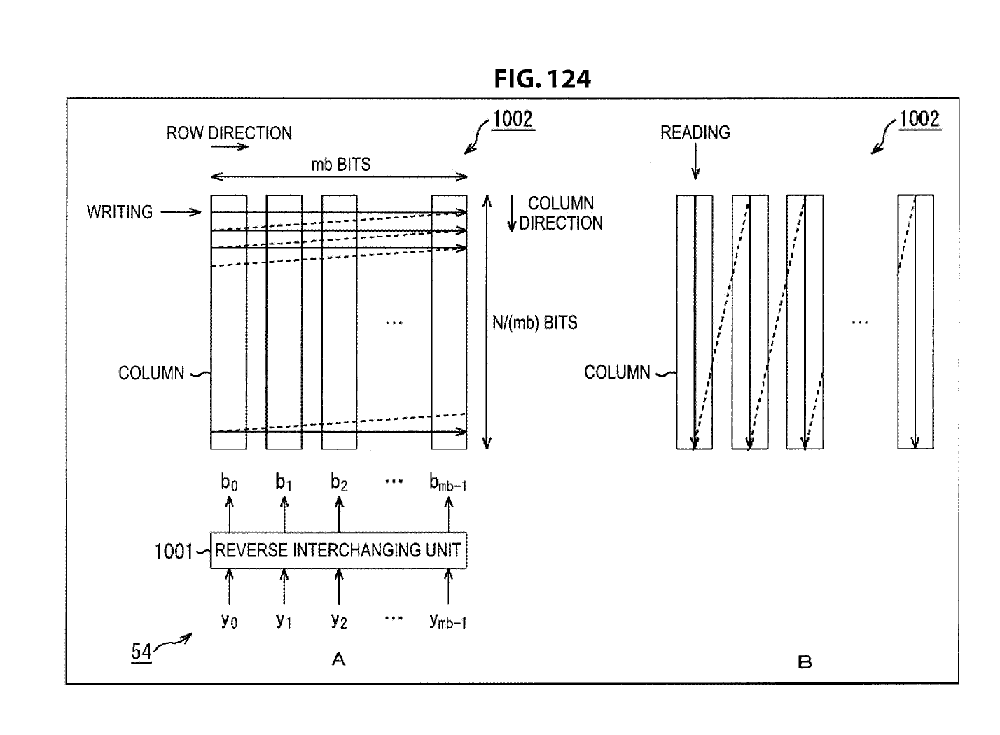

FIG. 124 is an illustration of processing of the multiplexer 54 constituting the bit deinterleaver 165 of FIG. 117.

That is, A of FIG. 124 illustrates a functional configuration example of the multiplexer 54.

The multiplexer 54 includes a reverse interchanging unit 1001 and a memory 1002.

The multiplexer 54 executes reverse interchange processing (reverse processing of the interchange processing) corresponding to the interchange processing executed by the demultiplexer 25 of the transmitting device 11, that is, reverse interchange processing for returning positions of the code bits (symbol bits) of the LDPC codes interchanged by the interchange processing to original positions, with respect to the symbol bits of the symbol supplied from the QAM decoder 164 of the previous step, and supplies an LDPC code obtained as a result to the column twist deinterleaver 55 of the following step.

That is, in the multiplexer 54, symbol bits y₀, y₁, . . . , and t_{mb-1} of mb bits of b symbols are supplied to the reverse interchanging unit 1001 in a unit of the b (consecutive) symbols.

The reverse interchanging unit 1001 performs reverse interchanging for returning the symbol bits y₀, y₁, . . . , and y_{mb-1} of the mb bits to an arrangement of code bits b₀, b₁, . . . , and b_{mb-1} of original mb bits (arrangement of the code bits b₀ to b_{mb-1} before interchanging is performed in the interchanging unit 32 constituting the demultiplexer 25 of the side of the transmitting device 11) and outputs the code bits b₀ to b_{mb-1} of the mb bits obtained as a result.

The memory 1002 has a storage capacity to store the mb bits in a row (transverse) direction and store N/(mb) bits in a column (longitudinal) direction, similar to the memory 31 constituting the demultiplexer 25 of the side of the transmitting device 11. That is, the memory 1002 includes mb columns that store N/(mb) bits.

However, in the memory 1002, writing of the code bits of the LDPC code output by the reverse interchanging unit 1001 is performed in a direction in which reading of the code bits from the memory 31 of the demultiplexer 25 of the transmitting device 11 is performed and reading of the code bits written to the memory 1002 is performed in a direction in which writing of the code bits to the memory 31 is performed.

That is, in the multiplexer 54 of the receiving device 12, as illustrated by A of FIG. 124, writing of the code bits of the LDPC code output by the reverse interchanging unit 1001 in the row direction in a unit of the mb bits is sequentially performed toward the lower rows from the first row of the memory 1002.

If writing of the code bits corresponding to one code length ends, the multiplexer 54 reads the code bits from the memory 1002 in the column direction and supplies the code bits to the column twist deinterleaver 55 of a following step.

In this case, B of FIG. 124 is an illustration of reading of the code bits from the memory 1002.

In the multiplexer 54, reading of the code bits of the LDPC code in the downward direction (column direction) from the upper side of the columns constituting the memory 1002 is performed toward the columns of the rightward direction from the left side.

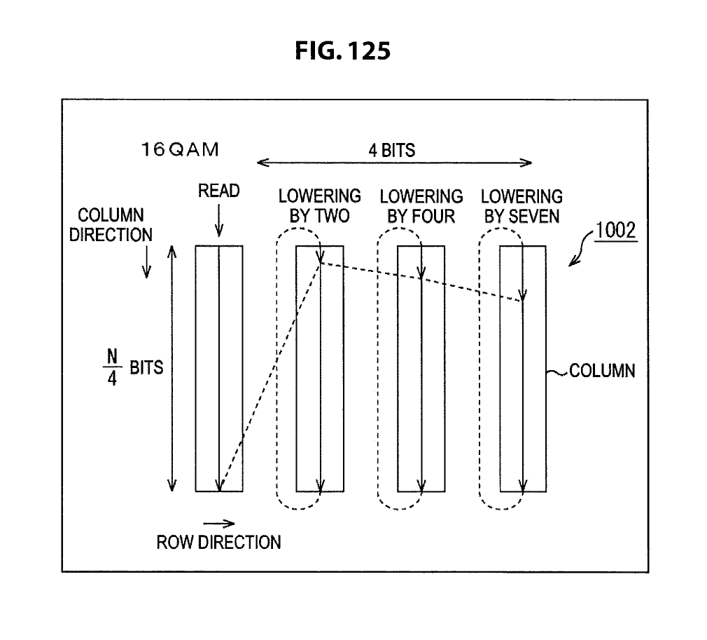

FIG. 125 is an illustration of processing of the column twist deinterleaver 55 constituting the bit deinterleaver 165 of FIG. 117.

That is, FIG. 125 illustrates a configuration example of the memory 1002 of the multiplexer 54.

The memory 1002 has a storage capacity to store the mb bits in the column (longitudinal) direction and store the N/(mb) bits in the row (transverse) direction and includes mb columns.

The column twist deinterleaver 55 writes the code bits of the LDPC code to the memory 1002 in the row direction, controls a read start position when the code bits are read in the column direction, and performs the column twist deinterleave.

That is, in the column twist deinterleaver 55, a read start position to start reading of the code bits is appropriately changed with respect to each of the plurality of columns and the reverse rearrangement processing for returning the arrangement of the code bits rearranged by the column twist interleave to the original arrangement is executed.

In this case, FIG. 125 illustrates a configuration example of the memory 1002 when the modulation method is the 16APSK, the 16QAM or the like and the multiple b is 1, described in FIG. 28. In this case, a bit number m of one symbol is 4 bits and the memory 1002 includes four (=mb) columns.

The column twist deinterleaver 55, (instead of the multiplexer 54), sequentially performs writing of the code bits of the LDPC code output by the reverse interchanging unit 1001 in the row direction, toward the lower rows from the first row of the memory 1002.

If writing of the code bits corresponding to one code length ends, the column twist deinterleaver 55 performs reading of the code bits in the downward direction (column direction) from the upper side of the memory 1002, toward the columns of the rightward direction from the left side.

However, the column twist deinterleaver 55 performs reading of the code bits from the memory 1002, using the write start position to write the code bits by the column twist interleaver 24 of the side of the transmitting device 11 as the read start position of the code bits.

That is, if an address of a position of a head (top) of each column is set to 0 and an address of each position of the column direction is represented by an integer of ascending order, when the modulation method is the 16APSK or the 16QAM and the multiple b is 1, in the column twist deinterleaver 55, a read start position is set as a position of which an address is 0, with respect the leftmost column. With respect the second column (from the left side), a read start position is set as a position of which an address is 2. With respect the third column, a read start position is set as a position of which an address is 4. With respect the fourth column, a read start position is set as a position of which an address is 7.

With respect to the columns in which the read start positions are the positions other than the position of which the address is 0, after reading of the code bits is performed to the lowermost position, the position returns to the head (position of which the address is 0), and reading to the position immediately before the read start position is performed. Then, reading from a next (right) column is performed.

By performing the column twist deinterleave described above, the arrangement of the code bits that are rearranged by the column twist interleave returns to the original arrangement.

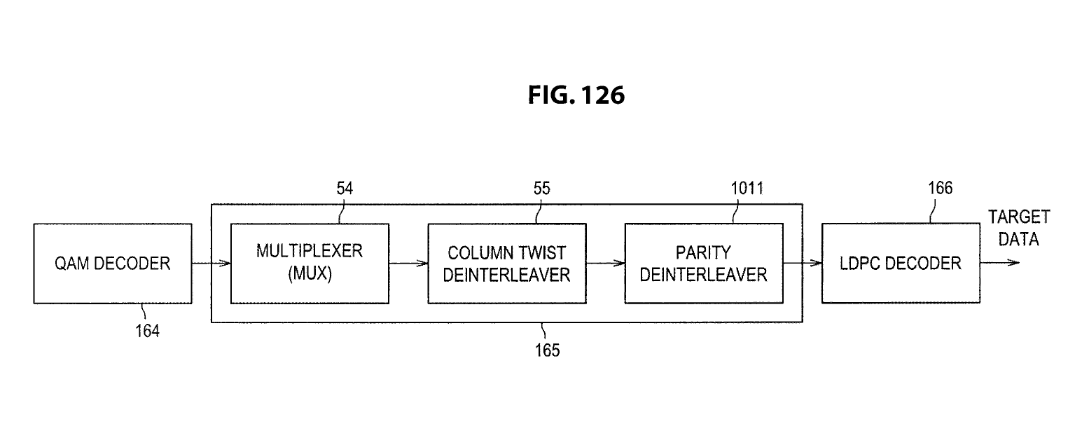

FIG. 126 is a block diagram illustrating another configuration example of the bit deinterleaver 165 of FIG. 116.

In the drawings, portions that correspond to the case of FIG. 117 are denoted with the same reference numerals and explanation thereof is appropriately omitted hereinafter.

That is, the bit deinterleaver 165 of FIG. 126 has the same configuration as the case of FIG. 117, except that a parity deinterleaver 1011 is newly provided.

In FIG. 126, the bit deinterleaver 165 includes a multiplexer (MUX) 54, a column twist deinterleaver 55, and a parity deinterleaver 1011 and performs bit deinterleave of code bits of the LDPC code supplied from the QAM decoder 164.

That is, the multiplexer 54 executes the reverse interchange processing (reverse processing of the interchange processing) corresponding to the interchange processing executed by the demultiplexer 25 of the transmitting device 11, that is, the reverse interchange processing for returning the positions of the code bits interchanged by the interchange processing to the original positions, with respect to the LDPC code supplied from the QAM decoder 164, and supplies an LDPC code obtained as a result to the column twist deinterleaver 55.

The column twist deinterleaver 55 performs the column twist deinterleave corresponding to the column twist interleave as the rearranging processing executed by the column twist interleaver 24 of the transmitting device 11, with respect to the LDPC code supplied from the multiplexer 54.

The LDPC code that is obtained as a result of the column twist deinterleave is supplied from the column twist deinterleaver 55 to the parity deinterleaver 1011.

The parity deinterleaver 1011 performs the parity deinterleave (reverse processing of the parity interleave) corresponding to the parity interleave performed by the parity interleaver 23 of the transmitting device 11, that is, the parity deinterleave to return the arrangement of the code bits of the LDPC code of which an arrangement is changed by the parity interleave to the original arrangement, with respect to the code bits after the column twist deinterleave in the column twist deinterleaver 55.

The LDPC code that is obtained as a result of the parity deinterleave is supplied from the parity deinterleaver 1011 to the LDPC decoder 166.

Therefore, in the bit deinterleaver 165 of FIG. 126, the LDPC code in which the reverse interchange processing, the column twist deinterleave, and the parity deinterleave are performed, that is, the LDPC code that is obtained by the LDPC encoding according to the parity check matrix H is supplied to the LDPC decoder 166.

The LDPC decoder 166 performs LDPC decoding of an LDPC code from the bit deinterleaver 165 by the use of the parity check matrix H used for LDPC encoding by the LDPC encoder 115 of the transmitting device 11. That is, the LDPC decoder 166 performs LDPC decoding of the LDPC code from the bit deinterleaver 165 by the use of the parity check matrix H itself used for LDPC encoding by the LDPC encoder 115 of the transmitting device 11 or by the use of a transformed parity check matrix obtained by performing at least column replacement corresponding to parity interleave with respect to the parity check matrix H.

In FIG. 126, the LDPC code that is obtained by the LDPC encoding according to the parity check matrix H is supplied from (the parity deinterleaver 1011 of) the bit deinterleaver 165 to the LDPC decoder 166. For this reason, when the LDPC decoding of the LDPC code is performed using the parity check matrix H used by the LDPC encoder 115 of the transmitting device 11 to perform the LDPC encoding, the LDPC decoder 166 can be configured by a decoding device performing the LDPC decoding according to a full serial decoding method to sequentially perform operations of messages (a check node message and a variable node message) for each node or a decoding device performing the LDPC decoding according to a full parallel decoding method to simultaneously (in parallel) perform operations of messages for all nodes.

In the LDPC decoder 166, when the LDPC decoding of the LDPC code is performed using the transformed parity check matrix obtained by performing at least the column replacement corresponding to the parity interleave with respect to the parity check matrix H used by the LDPC encoder 115 of the transmitting device 11 to perform the LDPC encoding, the LDPC decoder 166 can be configured by a decoding device (FIG. 122) that is a decoding device of an architecture simultaneously performing P (or divisor of P other than 1) check node operations and variable node operations and has the reception data rearranging unit 310 to perform the same column replacement as the column replacement to obtain the transformed parity check matrix with respect to the LDPC code and rearrange the code bits of the LDPC code.

In FIG. 126, for the convenience of explanation, the multiplexer 54 executing the reverse interchange processing, the column twist deinterleaver 55 performing the column twist deinterleave, and the parity deinterleaver 1011 performing the parity deinterleave are individually configured. However, two or more elements of the multiplexer 54, the column twist deinterleaver 55, and the parity deinterleaver 1011 can be integrally configured, similar to the parity interleaver 23, the column twist interleaver 24, and the demultiplexer 25 of the transmitting device 11.

Moreover, in a case where the bit interleaver 116 (FIG. 8) of the transmitting device 11 is configured without including the parity interleaver 23 and the column twist interleaver 24, in FIG. 126, the bit deinterleaver 165 can be configured without including the column twist deinterleaver 55 and the parity deinterleaver 1011.

Even in this case, the LDPC decoder 166 can be configured with a decoding device of a full serial decoding method to perform LDPC decoding by the use of the parity check matrix H itself, a decoding device of a full parallel decoding method to perform LDPC decoding by the use of the parity check matrix H itself, and a decoding device (FIG. 122) having the reception data rearranging unit 310 that performs LDPC decoding by P simultaneous check node calculations and variable node calculations by the use of the transformed parity check matrix H′.

### Configuration Example of Reception System

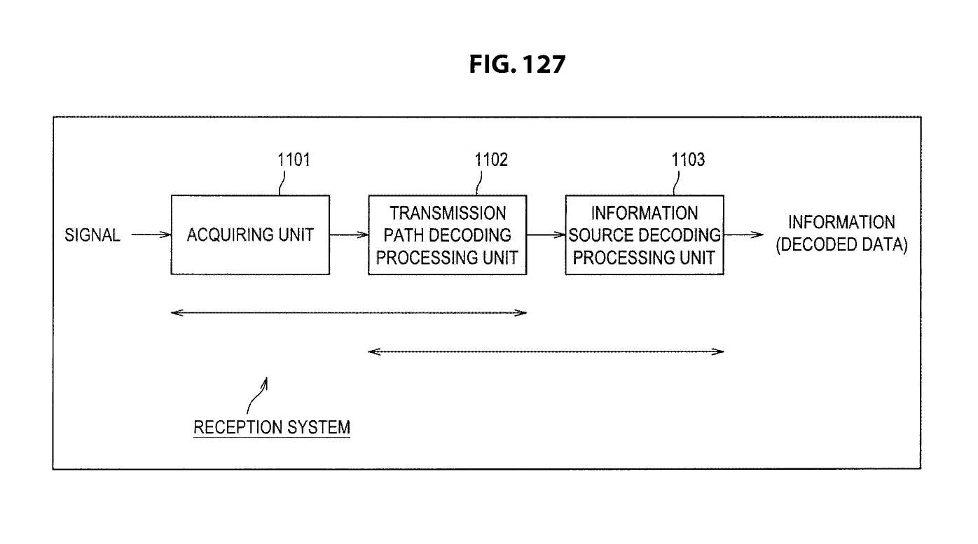

FIG. 127 is a block diagram illustrating a first configuration example of a reception system that can be applied to the receiving device 12.

In FIG. 127, the reception system includes an acquiring unit 1101, a transmission path decoding processing unit 1102, and an information source decoding processing unit 1103.

The acquiring unit 1101 acquires a signal including an LDPC code obtained by performing at least LDPC encoding with respect to LDPC target data such as image data or sound data of a program, through a transmission path (communication path) not illustrated in the drawings, such as terrestrial digital broadcasting, satellite digital broadcasting, a CATV network, the Internet, or other networks, and supplies the signal to the transmission path decoding processing unit 1102.

In this case, when the signal acquired by the acquiring unit 1101 is broadcast from a broadcasting station through a ground wave, a satellite wave, or a CATV (Cable Television) network, the acquiring unit 1101 is configured using a tuner and an STB (Set Top Box). When the signal acquired by the acquiring unit 1101 is transmitted from a web server by multicasting like an IPTV (Internet Protocol Television), the acquiring unit 1101 is configured using a network I/F (Interface) such as an NIC (Network Interface Card).

The transmission path decoding processing unit 1102 corresponds to the receiving device 12. The transmission path decoding processing unit 1102 executes transmission path decoding processing including at least processing for correcting error generated in a transmission path, with respect to the signal acquired by the acquiring unit 1101 through the transmission path, and supplies a signal obtained as a result to the information source decoding processing unit 1103.

That is, the signal that is acquired by the acquiring unit 1101 through the transmission path is a signal that is obtained by performing at least error correction encoding to correct the error generated in the transmission path. The transmission path decoding processing unit 1102 executes transmission path decoding processing such as error correction processing, with respect to the signal.

As the error correction encoding, for example, LDPC encoding or BCH encoding exists. In this case, as the error correction encoding, at least the LDPC encoding is performed.

The transmission path decoding processing includes demodulation of a modulation signal.

The information source decoding processing unit 1103 executes information source decoding processing including at least processing for extending compressed information to original information, with respect to the signal on which the transmission path decoding processing is executed.

That is, compression encoding that compresses information may be performed with respect to the signal acquired by the acquiring unit 1101 through the transmission path to decrease a data amount of an image or a sound corresponding to information. In this case, the information source decoding processing unit 1103 executes the information source decoding processing such as the processing (extension processing) for extending the compressed information to the original information, with respect to the signal on which the transmission path decoding processing is executed.

When the compression encoding is not performed with respect to the signal acquired by the acquiring unit 1101 through the transmission path, the processing for extending the compressed information to the original information is not executed in the information source decoding processing unit 1103.

In this case, as the extension processing, for example, MPEG decoding exists. In the transmission path decoding processing, in addition to the extension processing, descramble may be included.

In the reception system that is configured as described above, in the acquiring unit 1101, a signal in which the compression encoding such as the MPEG encoding and the error correction encoding such as the LDPC encoding are performed with respect to data such as an image or a sound is acquired through the transmission path and is supplied to the transmission path decoding processing unit 1102.

In the transmission path decoding processing unit 1102, the same processing as the receiving device 12 executes as the transmission path decoding processing with respect to the signal supplied from the acquiring unit 1101 and a signal obtained as a result is supplied to the information source decoding processing unit 1103.

In the information source decoding processing unit 1103, the information source decoding processing such as the MPEG decoding is executed with respect to the signal supplied from the transmission path decoding processing unit 1102 and an image or a sound obtained as a result is output.

The reception system of FIG. 127 described above can be applied to a television tuner to receive television broadcasting corresponding to digital broadcasting.

Each of the acquiring unit 1101, the transmission path decoding processing unit 1102, and the information source decoding processing unit 1103 can be configured as one independent device (hardware (IC (Integrated Circuit) and the like) or software module).

With respect to the acquiring unit 1101, the transmission path decoding processing unit 1102, and the information source decoding processing unit 1103, each of a set of the acquiring unit 1101 and the transmission path decoding processing unit 1102, a set of the transmission path decoding processing unit 1102 and the information source decoding processing unit 1103, and a set of the acquiring unit 1101, the transmission path decoding processing unit 1102, and the information source decoding processing unit 1103 can be configured as one independent device.

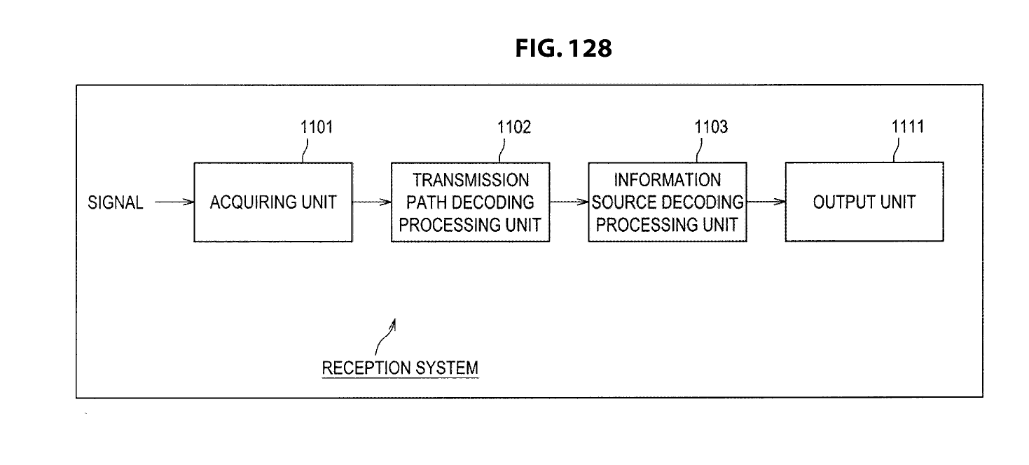

FIG. 128 is a block diagram illustrating a second configuration example of the reception system that can be applied to the receiving device 12.

In the drawings, portions that correspond to the case of FIG. 127 are denoted with the same reference numerals and explanation thereof is appropriately omitted hereinafter.

The reception system of FIG. 128 is common to the case of FIG. 127 in that the acquiring unit 1101, the transmission path decoding processing unit 1102, and the information source decoding processing unit 1103 are provided and is different from the case of FIG. 127 in that an output unit 1111 is newly provided.

The output unit 1111 is a display device to display an image or a speaker to output a sound and outputs an image or a sound corresponding to a signal output from the information source decoding processing unit 1103. That is, the output unit 1111 displays the image or outputs the sound.

The reception system of FIG. 128 described above can be applied to a TV (television receiver) receiving television broadcasting corresponding to digital broadcasting or a radio receiver receiving radio broadcasting.

When the compression encoding is not performed with respect to the signal acquired in the acquiring unit 1101, the signal that is output by the transmission path decoding processing unit 1102 is supplied to the output unit 1111.

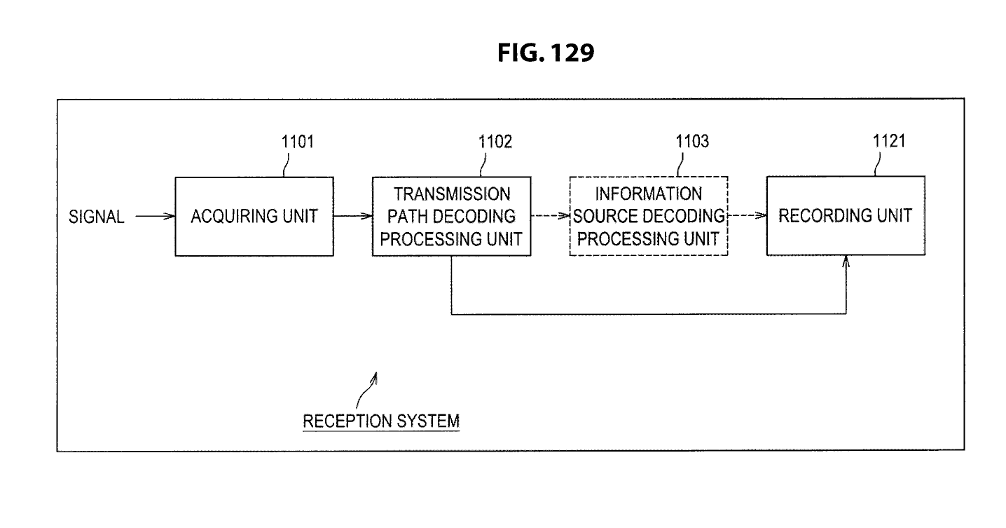

FIG. 129 is a block diagram illustrating a third configuration example of the reception system that can be applied to the receiving device 12.

In the drawings, portions that correspond to the case of FIG. 127 are denoted with the same reference numerals and explanation thereof is appropriately omitted hereinafter.

The reception system of FIG. 129 is common to the case of FIG. 127 in that the acquiring unit 1101 and the transmission path decoding processing unit 1102 are provided.

However, the reception system of FIG. 129 is different from the case of FIG. 127 in that the information source decoding processing unit 1103 is not provided and a recording unit 1121 is newly provided.

The recording unit 1121 records (stores) a signal (for example, TS packets of TS of MPEG) output by the transmission path decoding processing unit 1102 on recording (storage) media such as an optical disk, a hard disk (magnetic disk), and a flash memory.

The reception system of FIG. 129 described above can be applied to a recorder that records television broadcasting.

In FIG. 129, the reception system is configured by providing the information source decoding processing unit 1103 and can record the signal obtained by executing the information source decoding processing by the information source decoding processing unit 1103, that is, the image or the sound obtained by decoding, by the recording unit 1121.

### Embodiment of Computer

Next, the series of processing described above can be executed by hardware or can be executed by software. In the case in which the series of processing is executed by the software, a program configuring the software is installed in a general-purpose computer.

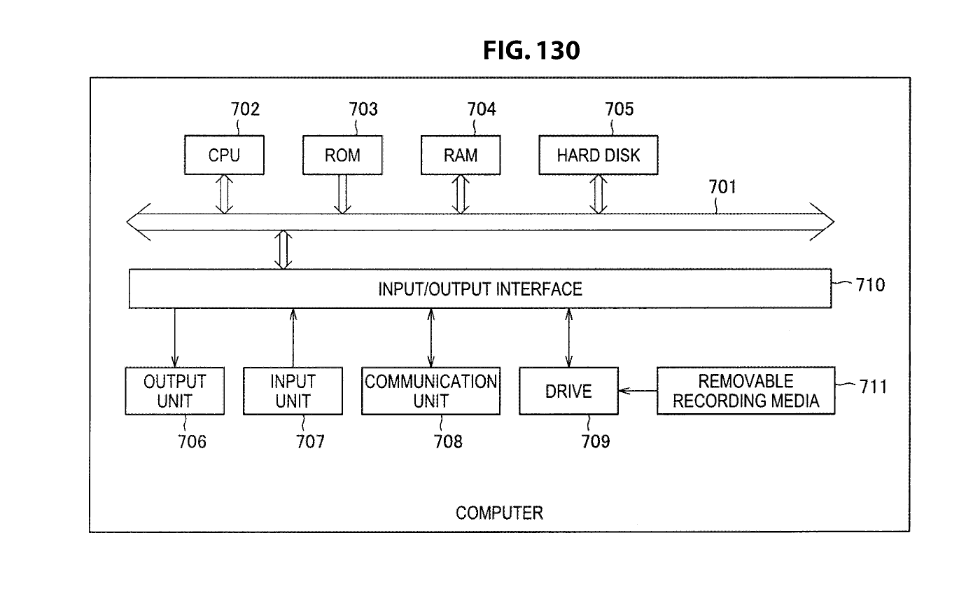

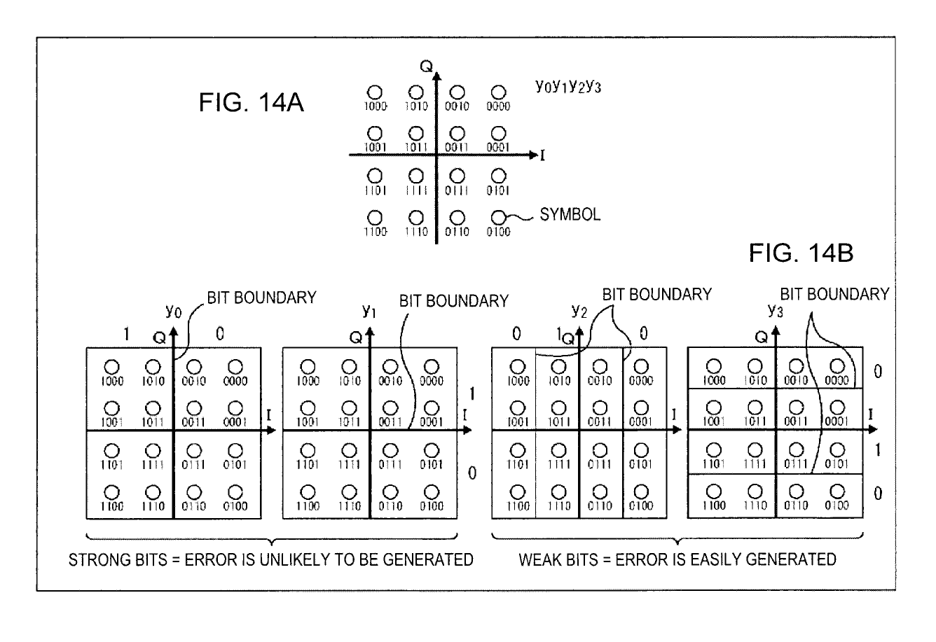

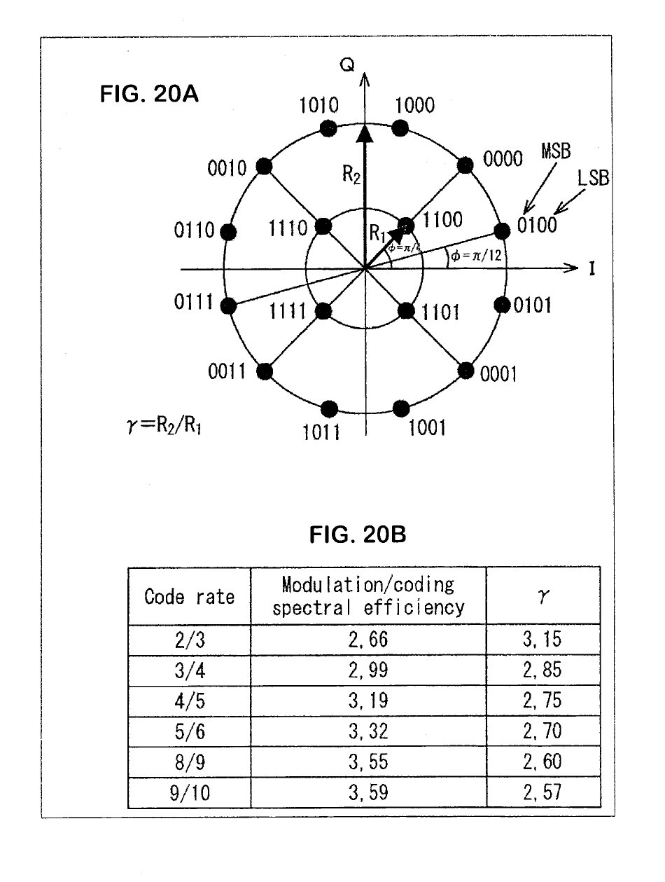

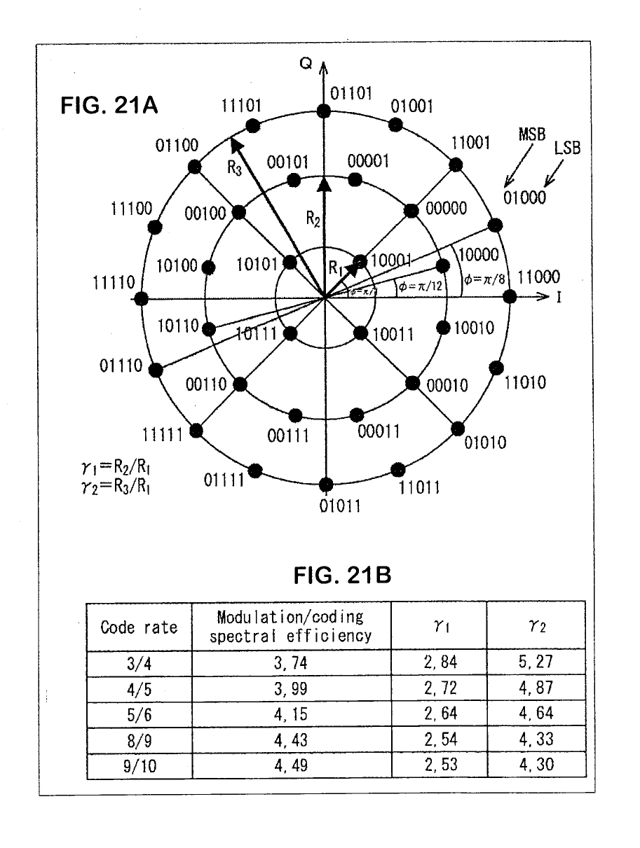

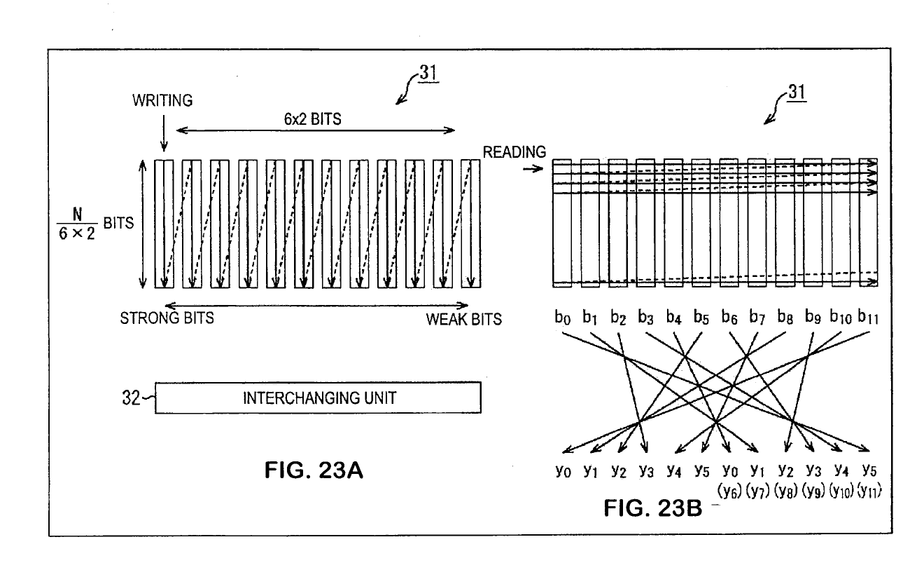

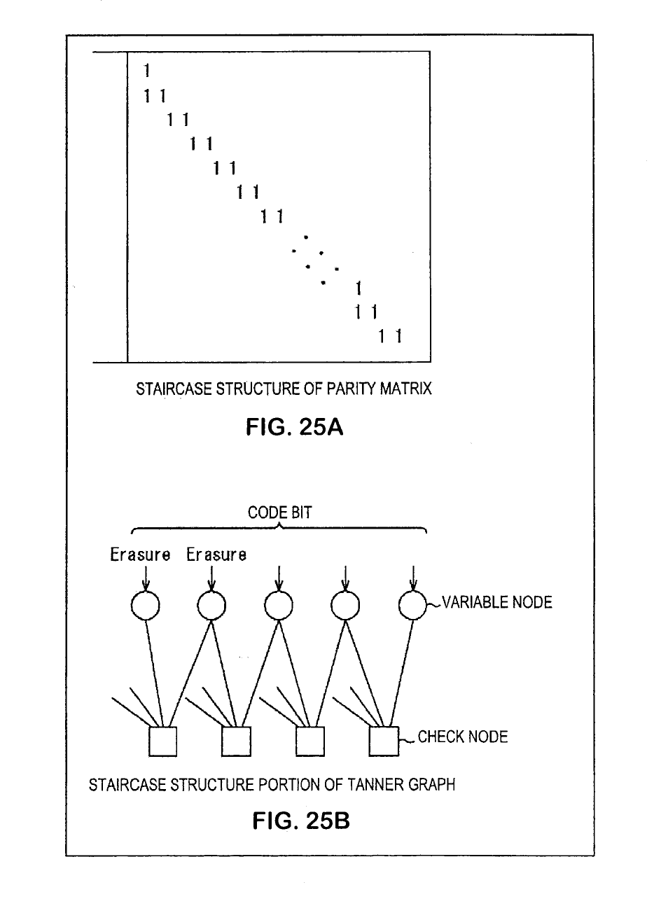

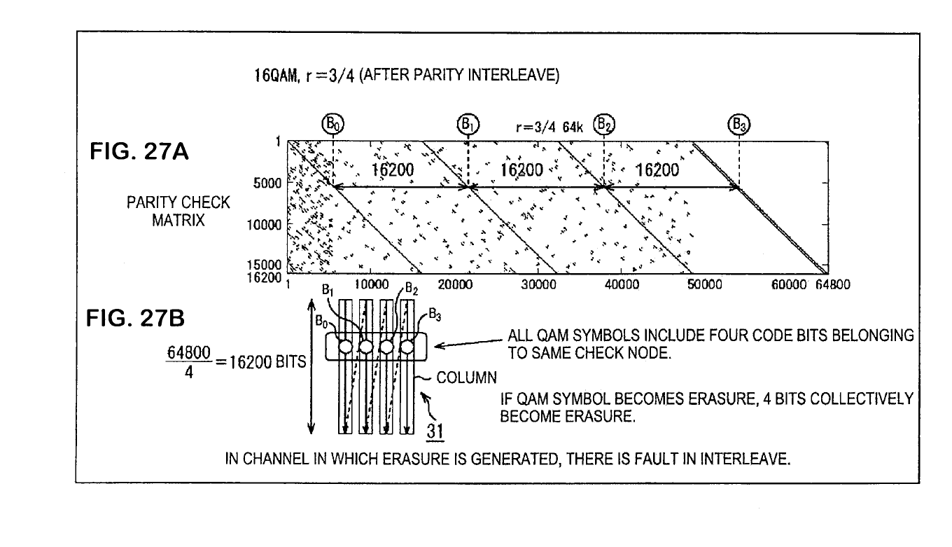

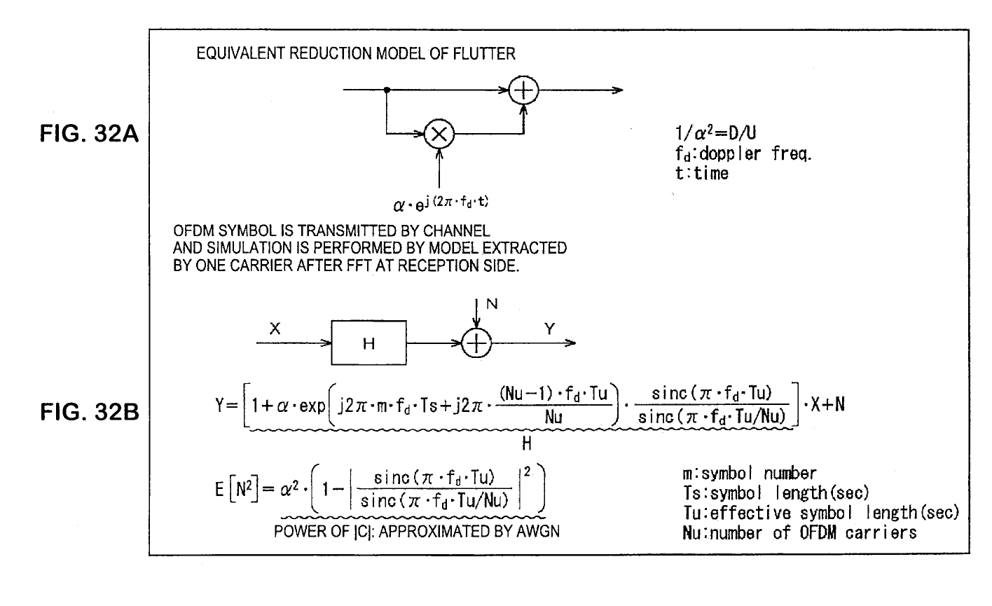

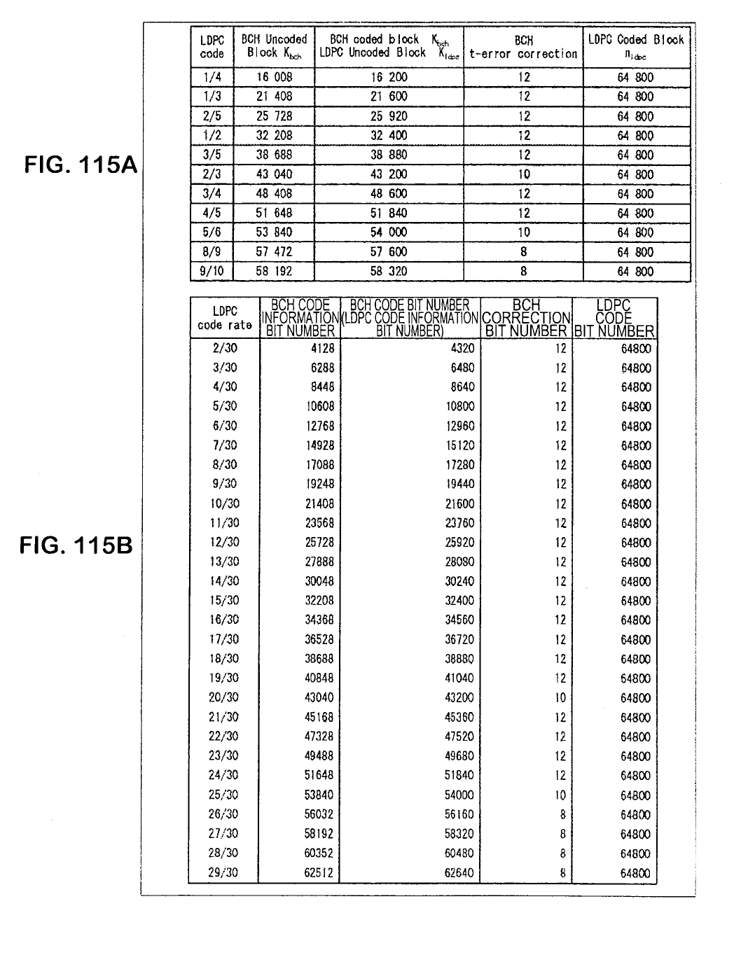

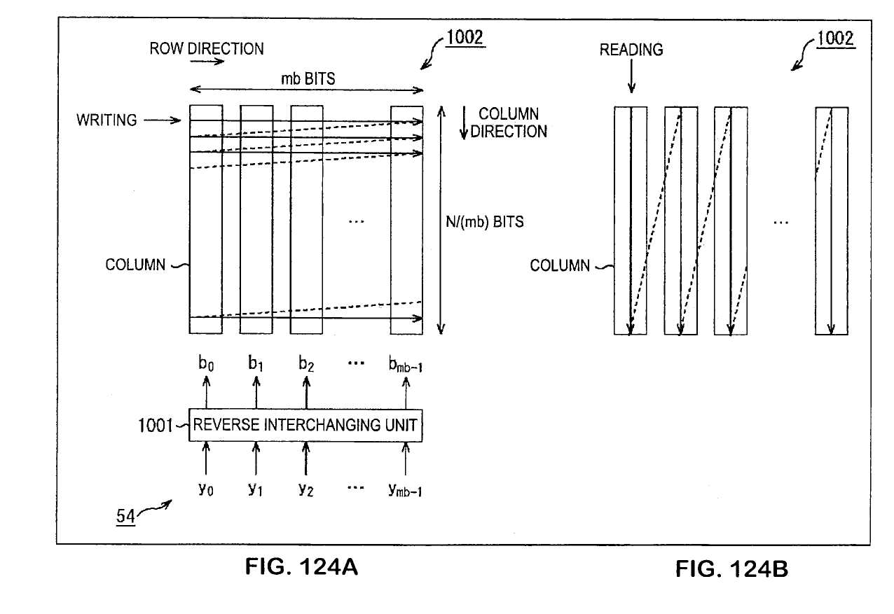

Therefore, FIG. 130 illustrates a configuration example of an embodiment of the computer in which a program executing the series of processing is installed.

The program can be previously recorded on a hard disk 705 and a ROM 703 corresponding to recording media embedded in the computer.

Alternatively, the program can be temporarily or permanently stored (recorded) on removable recording media 711 such as a flexible disk, a CD-ROM (Compact Disc Read Only Memory), an MO (Magneto Optical) disk, a DVD (Digital Versatile Disc), a magnetic disk, and a semiconductor memory. The removable recording media 711 can be provided as so-called package software.

The program is installed from the removable recording media 711 to the computer. In addition, the program can be transmitted from a download site to the computer by wireless through an artificial satellite for digital satellite broadcasting or can be transmitted to the computer by wire through a network such as a LAN (Local Area Network) or the Internet. The computer can receive the program transmitted as described above by a communication unit 708 and install the program in the embedded hard disk 705.

The computer includes a CPU (Central Processing Unit) 702 embedded therein. An input/output interface 710 is connected to the CPU 702 through a bus 701. If a user operates an input unit 707 configured using a keyboard, a mouse, and a microphone and a command is input through the input/output interface 710, the CPU 702 executes the program stored in the ROM (Read Only Memory) 703, according to the command. Alternatively, the CPU 702 loads the program stored in the hard disk 705, the program transmitted from a satellite or a network, received by the communication unit 708, and installed in the hard disk 705, or the program read from the removable recording media 711 mounted to a drive 709 and installed in the hard disk 705 to the RAM (Random Access Memory) 704 and executes the program. Thereby, the CPU 702 executes the processing according to the flowcharts described above or the processing executed by the configurations of the block diagrams described above. In addition, the CPU 702 outputs the processing result from the output unit 706 configured using an LCD (Liquid Crystal Display) or a speaker, transmits the processing result from the communication unit 708, and records the processing result on the hard disk 705, through the input/output interface 710, according to necessity.

In the present specification, it is not necessary to process the processing steps describing the program for causing the computer to execute the various processing in time series according to the order described as the flowcharts and processing executed in parallel or individually (for example, parallel processing or processing using an object) is also included.

The program may be processed by one computer or may be processed by a plurality of computers in a distributed manner. The program may be transmitted to a remote computer and may be executed.

An embodiment of the disclosure is not limited to the embodiments described above, and various changes and modifications may be made without departing from the scope of the disclosure.

That is, for example, (the parity check matrix initial value table of) the above-described new LDPC code can be used even if the communication path 13 (FIG. 7) is any of a satellite circuit, a ground wave, a cable (wire circuit) and others. In addition, the new LDPC code can also be used for data transmission other than digital broadcasting.

### REFERENCE SIGNS LIST

11 transmitting device
12 receiving device
23 parity interleaver
24 column twist interleaver
25 demultiplexer
31 memory
32 interchanging unit
54 multiplexer
55 column twist interleaver
111 mode adaptation/multiplexer
112 padder
113 BB scrambler
114 BCH encoder
115 LDPC encoder
116 bit interleaver
117 QAM encoder
118 time interleaver
119 MISO/MIMO encoder
120 frequency interleaver
121 BCH encoder
122 LDPC encoder
123 QAM encoder
124 frequency interleaver
131 frame builder/resource allocation unit
132 OFDM generating unit
151 OFDM operating unit
152 frame managing unit
153 frequency deinterleaver
154 QAM decoder
155 LDPC decoder
156 BCH decoder
161 frequency deinterleaver
162 MISO/MIMO decoder
163 time deinterleaver
164 QAM decoder
165 bit deinterleaver
166 LDPC decoder
167 BCH decoder
168 BB descrambler
169 null deletion unit
170 demultiplexer
300 branch data storing memory
301 selector
302 check node calculating unit
303 cyclic shift circuit
304 branch data storing memory
305 selector
306 reception data memory
307 variable node calculating unit
308 cyclic shift circuit
309 decoding word calculating unit
310 reception data rearranging unit
311 decoded data rearranging unit
601 encoding processing unit
602 storage unit
611 encoding rate setting unit
612 initial value table reading unit
613 parity check matrix generating unit
614 information bit reading unit
615 encoding parity operation unit
616 control unit
701 bus
702 CPU
703 ROM
704 RAM
705 hard disk
706 output unit
707 input unit
708 communication unit
709 drive
710 input/output interface
711 removable recording media
1001 reverse interchanging unit
1002 memory
1011 parity deinterleaver
1101 acquiring unit
1101 transmission path decoding processing unit
1103 information source decoding processing unit
1111 output unit
1121 recording unit

1. A data processing device comprising:
an encoding unit configured to encode an information bit into an LDPC code with a code length of 64800 bits and an encoding rate of 12/30, based on a parity check matrix of an LDPC (Low Density Parity Check) code, wherein
the LDPC code includes an information bit and a parity bit,
the parity check matrix includes an information matrix part corresponding to the information bit and a parity matrix part corresponding to the parity bit,
the information matrix part is shown by a parity check matrix initial value table, and
the parity check matrix initial value table is a table showing positions of elements of 1 of the information matrix part every 360 columns and is expressed as follows
2455 2650 6184 7016 7280 7409 7507 8261 8591 8829 11277 13729 14302 15883 17754 18506 19816 19940 22442 23981 26881 26981 28760 29688 31138 31497 32673 35889 37690 38665
50 327 3574 4465 5954 9702 10606 11684 11715 12627 14132 14951 20099 24111 24283 27026 27473 28162 30076 31032 31476 35031 36675 36914 37008 37425 37530 37689 38830 38856
59 102 5278 5548 5850 11840 13813 16641 19597 20543 24088 24298 25171 25224 26925 28312 28867 31551 31898 32849 33616 34486 34562 35252 35931 36107 37950 38494 38537 38547
79 2084 2361 2922 3048 3525 5712 9376 10012 10463 11842 15200 18443 19223 20476 21361 22584 24343 24594 28001 28304 28475 28969 31149 31528 32574 33007 35120 38245 38253
821 2803 8187 8501 10063 10497 14472 14570 15613 18469 19620 23034 24029 24578 26538 31025 32621 34134 34508 34988 35201 35907 36693 36793 37608 37998 38090 38506 38611 38682
9 50 88 1222 2430 2824 7233 9972 10225 15762 18283 18961 20711 28455 29946 32016 35611 35763 37263 37325 38287 38360 38416 38471 38518 38551 38643 38759 38763 38818
33 38 151 2523 3787 5069 6710 7667 8501 11083 17631 19589 24263 24684 24940 28493 30646 31916 33741 35060 35810 36284 36394 36400 38209 38312 38340 38782 38825 38858
8 49 84 381 4009 6978 9983 14028 14051 16325 17393 24325 25130 25838 30998 35159 36135 37516 37636 37837 37927 38433 38620 38647 38650 38699 38733 38784 38804 38862
44 76 4362 4480 8679 8833 13730 16493 16507 22419 24544 25614 25671 33032 33120 35219 35986 36415 36505 38169 38173 38327 38371 38468 38508 38546 38551 38747 38761 38853
16 683 1013 8364 8665 12213 12279 12643 13134 15450 16703 17846 20656 21664 22896 23487 25022 32049 32482 33647 35029 35197 36636 37162 38376 38408 38430 38520 38721 38734
3 760 1052 6377 8526 9014 11769 12589 16661 18156 20521 21303 23361 27434 32315 34602 34892 35078 35262 35639 36655 37893 38063 38578 38602 38719 38737 38748 38837 38861
15 30 79 99 16844 19586 24117 24702 25088 26129 27790 28383 30976 33472 34613 35266 35337 36278 36841 36980 37214 37651 37817 38085 38218 38338 38396 38432 38760 38812
12483 24049 35782 38706
12146 19270 23193 38389
26418 34831 37883 38501
25045 36512 37567 38487
15238 33547 38210 38696
14 6773 17384 38679
14367 16694 16867 38453
15371 37498 37910 38610
2509 18705 27907 28422
21246 37360 38125 38868
11357 23312 24884 36318
14467 19559 22338 37893
26899 35264 36300 37973
17311 28273 32934 38607
0 14452 16264 38585
6736 19801 31034 38279
35256 36593 38204 38655
10037 29019 32956 38670
98 17138 28233 37750
576 4888 14014 23030
2003 2470 18968 38841
1042 4623 8098 9963
61 3037 9719 27052
15129 26628 31307 37604
9791 11904 12369 34528
7996 15467 21456 38165
7644 12741 34083 38851
4766 26027 31133 38830
17783 36021 37697 38571
4925 9033 28100 32671
9452 23191 32529 36265
6124 19224 27145 30628
24 26468 35718 38718
14403 14741 20334 38444
322 15324 22539 33347
22663 29889 38488
7 13998 38748
8835 20728 20777
9742 24551 26087
23173 24287 38644
16606 30002 32432
30691 37266 38776
20366 21134 35082
21617 28615 29424
15974 26095 34262
92 35091 36358
9348 28177 38737
16104 37933 38151
14133 30118 38803
1314 37661 38852
19118 28886 37980
20212 22241 32326
3885 17856 38675
12577 21905 30465
28672 35317 35384
12880 16994 34495
16353 34789 38134
465 37194 38658
23 6202 38823
24020 25383 37955.

2. The data processing device according to claim 1, wherein
when a row of the parity check matrix initial value table is expressed as i and a parity length of the LDPC code is expressed as M, a 2+360×(i−1)-th column of the parity check matrix is a column subjected to cyclic shift of a 1+360×(i−1)-th column of the parity check matrix showing the positions of the elements of 1 in the parity check matrix initial value table by q=M/360 in a downward direction.

3. The data processing device according to claim 2, wherein
as for the 1+360×(i−1)-th column of the parity check matrix, an i-th row of the parity check matrix initial value table shows a row number of an element of 1 of the 1+360×(i−1)-th column of the parity check matrix, and
as for each of columns from the 2+360×(i−1)-th column to a 360×i-th column which are columns other than the 1+360×(i−1)-th column of the parity check matrix, when a numerical value of an i-th row and j-th column of the parity check matrix initial value table is expressed as h_{i,j} and a row number of a j-th element of 1 of a w-th column of the parity check matrix H is expressed as H_{w-j}, the row number H_{w-j} of the element of 1 in the w-th column which is a column other than the 1+360×(i−1)-th column of the parity check matrix is expressed by an expression H_{w-j}=mod {h_{i,j}+mod((w−1),360)×M/360,M).

4. The data processing device according to claim 2, wherein
the q is 108.

5. The data processing device according to claim 1, further comprising:
a parity interleave unit configured to interleave only a parity bit of a code bit of the LDPC code.

6. The data processing device according to claim 1, further comprising:
a column twist interleave unit configured to perform column twist interleave by shifting a code bit of the LDPC code in a column direction and storing the code bit.

7. The data processing device according to claim 1, further comprising:
an interchange unit configured to interchange a code bit of the LDPC code with a symbol bit of a symbol corresponding to any of a predetermined number of signal points defined by a predetermined digital modulation method.

8. The data processing device according to claim 7, wherein
the interchange unit interchanges the code bit stored in a column direction and read in a row direction.

9. The data processing device according to claim 1, wherein
the parity check matrix is a parity check matrix without cycle 4.

10. The data processing device according to claim 1, wherein
the parity check matrix is a parity check matrix of an LDPC code belonging to an ensemble of an LDPC code in which a performance threshold that is E_{b}/N₀ with decreasing BER is equal to or less than a predetermined value, which is detected by density evolution of a multi-edge type.

11. A data processing method comprising:
an encoding step of encoding an information bit into an LDPC code with a code length of 64800 bits and an encoding rate of 12/30, based on a parity check matrix of an LDPC (Low Density Parity Check) code, wherein
the LDPC code includes an information bit and a parity bit,
the parity check matrix includes an information matrix part corresponding to the information bit and a parity matrix part corresponding to the parity bit,
the information matrix part is shown by a parity check matrix initial value table, and
the parity check matrix initial value table is a table showing positions of elements of 1 of the information matrix part every 360 columns and is expressed as follows
2455 2650 6184 7016 7280 7409 7507 8261 8591 8829 11277 13729 14302 15883 17754 18506 19816 19940 22442 23981 26881 26981 28760 29688 31138 31497 32673 35889 37690 38665
50 327 3574 4465 5954 9702 10606 11684 11715 12627 14132 14951 20099 24111 24283 27026 27473 28162 30076 31032 31476 35031 36675 36914 37008 37425 37530 37689 38830 38856
59 102 5278 5548 5850 11840 13813 16641 19597 20543 24088 24298 25171 25224 26925 28312 28867 31551 31898 32849 33616 34486 34562 35252 35931 36107 37950 38494 38537 38547
79 2084 2361 2922 3048 3525 5712 9376 10012 10463 11842 15200 18443 19223 20476 21361 22584 24343 24594 28001 28304 28475 28969 31149 31528 32574 33007 35120 38245 38253
821 2803 8187 8501 10063 10497 14472 14570 15613 18469 19620 23034 24029 24578 26538 31025 32621 34134 34508 34988 35201 35907 36693 36793 37608 37998 38090 38506 38611 38682
9 50 88 1222 2430 2824 7233 9972 10225 15762 18283 18961 20711 28455 29946 32016 35611 35763 37263 37325 38287 38360 38416 38471 38518 38551 38643 38759 38763 38818
33 38 151 2523 3787 5069 6710 7667 8501 11083 17631 19589 24263 24684 24940 28493 30646 31916 33741 35060 35810 36284 36394 36400 38209 38312 38340 38782 38825 38858
8 49 84 381 4009 6978 9983 14028 14051 16325 17393 24325 25130 25838 30998 35159 36135 37516 37636 37837 37927 38433 38620 38647 38650 38699 38733 38784 38804 38862
44 76 4362 4480 8679 8833 13730 16493 16507 22419 24544 25614 25671 33032 33120 35219 35986 36415 36505 38169 38173 38327 38371 38468 38508 38546 38551 38747 38761 38853
16 683 1013 8364 8665 12213 12279 12643 13134 15450 16703 17846 20656 21664 22896 23487 25022 32049 32482 33647 35029 35197 36636 37162 38376 38408 38430 38520 38721 38734
3 760 1052 6377 8526 9014 11769 12589 16661 18156 20521 21303 23361 27434 32315 34602 34892 35078 35262 35639 36655 37893 38063 38578 38602 38719 38737 38748 38837 38861
15 30 79 99 16844 19586 24117 24702 25088 26129 27790 28383 30976 33472 34613 35266 35337 36278 36841 36980 37214 37651 37817 38085 38218 38338 38396 38432 38760 38812
12483 24049 35782 38706
12146 19270 23193 38389
26418 34831 37883 38501
25045 36512 37567 38487
15238 33547 38210 38696
14 6773 17384 38679
14367 16694 16867 38453
15371 37498 37910 38610
2509 18705 27907 28422
21246 37360 38125 38868
11357 23312 24884 36318
14467 19559 22338 37893
26899 35264 36300 37973
17311 28273 32934 38607
0 14452 16264 38585
6736 19801 31034 38279
35256 36593 38204 38655
10037 29019 32956 38670
98 17138 28233 37750
576 4888 14014 23030
2003 2470 18968 38841
1042 4623 8098 9963
61 3037 9719 27052
15129 26628 31307 37604
9791 11904 12369 34528
7996 15467 21456 38165
7644 12741 34083 38851
4766 26027 31133 38830
17783 36021 37697 38571
4925 9033 28100 32671
9452 23191 32529 36265
6124 19224 27145 30628
24 26468 35718 38718
14403 14741 20334 38444
322 15324 22539 33347
22663 29889 38488
7 13998 38748
8835 20728 20777
9742 24551 26087
23173 24287 38644
16606 30002 32432
30691 37266 38776
20366 21134 35082
21617 28615 29424
15974 26095 34262
92 35091 36358
9348 28177 38737
16104 37933 38151
14133 30118 38803
1314 37661 38852
19118 28886 37980
20212 22241 32326
3885 17856 38675
12577 21905 30465
28672 35317 35384
12880 16994 34495
16353 34789 38134
465 37194 38658
23 6202 38823
24020 25383 37955.

12. The data processing method according to claim 11, wherein
when a row of the parity check matrix initial value table is expressed as i and a parity length of the LDPC code is expressed as M, a 2+360×(i−1)-th column of the parity check matrix is a column subjected to cyclic shift of a 1+360×(i−1)-th column of the parity check matrix showing the positions of the elements of 1 in the parity check matrix initial value table by q=M/360 in a downward direction.

13. The data processing method according to claim 12, wherein
as for the 1+360×(i−1)-th column of the parity check matrix, an i-th row of the parity check matrix initial value table shows a row number of an element of 1 of the 1+360×(i−1)-th column of the parity check matrix, and
as for each of columns from the 2+360×(i−1)-th column to a 360×i-th column which are columns other than the 1+360×(i−1)-th column of the parity check matrix, when a numerical value of an i-th row and j-th column of the parity check matrix initial value table is expressed as h_{i,j} and a row number of a j-th element of 1 of a w-th column of the parity check matrix H is expressed as H_{w-j}, the row number H_{w-j} of the element of 1 in the w-th column which is a column other than the 1+360×(i−1)-th column of the parity check matrix is expressed by an expression H_{w-j}=mod {h_{i,j}+mod((w−1),360)×M/360,M).

14. The data processing method according to claim 12, wherein
the q is 108.

15. The data processing method according to claim 11, comprising:
interleaving only a parity bit of a code bit of the LDPC code.

16. The data processing method according to claim 11, comprising:
performing column twist interleave by shifting a code bit of the LDPC code in a column direction and storing the code bit.

17. The data processing method according to claim 11, comprising:
interchanging a code bit of the LDPC code with a symbol bit of a symbol corresponding to any of a predetermined number of signal points defined by a predetermined digital modulation method.

18. The data processing method according to claim 17, wherein
in the interchange of the code bit, the code bit that is stored in a column direction and read in a row direction is interchanged.

19. The data processing method according to claim 11, wherein
the parity check matrix is a parity check matrix without cycle 4.

20. The data processing method according to claim 11, wherein
the parity check matrix is a parity check matrix of an LDPC code belonging to an ensemble of an LDPC code in which a performance threshold that is E_{b}/N₀ with decreasing BER is equal to or less than a predetermined value, which is detected by density evolution of a multi-edge type.

21. A data processing device comprising:
a decoding unit configured to decode an LDPC code with a code length of 64800 bits and an encoding rate of 12/30, based on a parity check matrix of an LDPC (Low Density Parity Check) code, wherein
the LDPC code includes an information bit and a parity bit,
the parity check matrix includes an information matrix part corresponding to the information bit and a parity matrix part corresponding to the parity bit,
the information matrix part is shown by a parity check matrix initial value table, and
the parity check matrix initial value table is a table showing positions of elements of 1 of the information matrix part every 360 columns and is expressed as follows
2455 2650 6184 7016 7280 7409 7507 8261 8591 8829 11277 13729 14302 15883 17754 18506 19816 19940 22442 23981 26881 26981 28760 29688 31138 31497 32673 35889 37690 38665
50 327 3574 4465 5954 9702 10606 11684 11715 12627 14132 14951 20099 24111 24283 27026 27473 28162 30076 31032 31476 35031 36675 36914 37008 37425 37530 37689 38830 38856
59 102 5278 5548 5850 11840 13813 16641 19597 20543 24088 24298 25171 25224 26925 28312 28867 31551 31898 32849 33616 34486 34562 35252 35931 36107 37950 38494 38537 38547
79 2084 2361 2922 3048 3525 5712 9376 10012 10463 11842 15200 18443 19223 20476 21361 22584 24343 24594 28001 28304 28475 28969 31149 31528 32574 33007 35120 38245 38253
821 2803 8187 8501 10063 10497 14472 14570 15613 18469 19620 23034 24029 24578 26538 31025 32621 34134 34508 34988 35201 35907 36693 36793 37608 37998 38090 38506 38611 38682
9 50 88 1222 2430 2824 7233 9972 10225 15762 18283 18961 20711 28455 29946 32016 35611 35763 37263 37325 38287 38360 38416 38471 38518 38551 38643 38759 38763 38818
33 38 151 2523 3787 5069 6710 7667 8501 11083 17631 19589 24263 24684 24940 28493 30646 31916 33741 35060 35810 36284 36394 36400 38209 38312 38340 38782 38825 38858
8 49 84 381 4009 6978 9983 14028 14051 16325 17393 24325 25130 25838 30998 35159 36135 37516 37636 37837 37927 38433 38620 38647 38650 38699 38733 38784 38804 38862
44 76 4362 4480 8679 8833 13730 16493 16507 22419 24544 25614 25671 33032 33120 35219 35986 36415 36505 38169 38173 38327 38371 38468 38508 38546 38551 38747 38761 38853
16 683 1013 8364 8665 12213 12279 12643 13134 15450 16703 17846 20656 21664 22896 23487 25022 32049 32482 33647 35029 35197 36636 37162 38376 38408 38430 38520 38721 38734
3 760 1052 6377 8526 9014 11769 12589 16661 18156 20521 21303 23361 27434 32315 34602 34892 35078 35262 35639 36655 37893 38063 38578 38602 38719 38737 38748 38837 38861
15 30 79 99 16844 19586 24117 24702 25088 26129 27790 28383 30976 33472 34613 35266 35337 36278 36841 36980 37214 37651 37817 38085 38218 38338 38396 38432 38760 38812
12483 24049 35782 38706
12146 19270 23193 38389
26418 34831 37883 38501
25045 36512 37567 38487
15238 33547 38210 38696
14 6773 17384 38679
14367 16694 16867 38453
15371 37498 37910 38610
2509 18705 27907 28422
21246 37360 38125 38868
11357 23312 24884 36318
14467 19559 22338 37893
26899 35264 36300 37973
17311 28273 32934 38607
0 14452 16264 38585
6736 19801 31034 38279
35256 36593 38204 38655
10037 29019 32956 38670
98 17138 28233 37750
576 4888 14014 23030
2003 2470 18968 38841
1042 4623 8098 9963
61 3037 9719 27052
15129 26628 31307 37604
9791 11904 12369 34528
7996 15467 21456 38165
7644 12741 34083 38851
4766 26027 31133 38830
17783 36021 37697 38571
4925 9033 28100 32671
9452 23191 32529 36265
6124 19224 27145 30628
24 26468 35718 38718
14403 14741 20334 38444
322 15324 22539 33347
22663 29889 38488
7 13998 38748
8835 20728 20777
9742 24551 26087
23173 24287 38644
16606 30002 32432
30691 37266 38776
20366 21134 35082
21617 28615 29424
15974 26095 34262
92 35091 36358
9348 28177 38737
16104 37933 38151
14133 30118 38803
1314 37661 38852
19118 28886 37980
20212 22241 32326
3885 17856 38675
12577 21905 30465
28672 35317 35384
12880 16994 34495
16353 34789 38134
465 37194 38658
23 6202 38823
24020 25383 37955.

22-58. (canceled)
